(19) United States
(12) Patent Application Publication
(10) Pub. No.: US 2025/0366301 A1
(43) Pub. Date: Nov. 27, 2025

(54) LIGHT EMITTING ELEMENT, FUSED POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: MUN-KI SIM, Yongin-si (KR); TAEIL KIM, Yongin-si (KR); Hyungjong KIM, Yongin-si (KR); SUN YOUNG PAK, Yongin-si (KR); JUNHA PARK, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 19/076,179

(22) Filed: Mar. 11, 2025

(30) Foreign Application Priority Data
May 23, 2024 (KR) 10-2024-0066957

(51) Int. Cl. H10K 50/12; H10K 50/155; H10K 50/16; H10K 59/38; H10K 59/80; H10K 85/30; H10K 85/40; H10K 85/60; H10K 101/00; H10K 101/25

(52) U.S. Cl. CPC H10K 50/12; H10K 50/155; H10K 50/16; H10K 59/38; H10K 59/879; H10K 85/342; H10K 85/346; H10K 85/40; H10K 85/622; H10K 85/623; H10K 85/626; H10K 85/633; H10K 85/636; H10K 85/654; H10K 85/6572; H10K 85/6574; H10K 85/6576; H10K 85/658; H10K 2101/25; H10K 2101/90

(57) ABSTRACT

Embodiments provide a fused polycyclic compound, a light emitting element that includes the fused polycyclic compound, and an electronic apparatus that includes the light emitting element. The light emitting element includes a first electrode, a second electrode disposed on the first electrode, and a light emitting layer disposed between the first electrode and the second electrode, wherein the light emitting layer includes the fused polycyclic compound. The fused polycyclic compound is represented by Formula 1, which is explained in the specification.

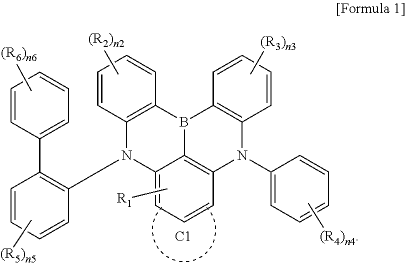

### CROSS-REFERENCE TO RELATED APPLICATION(S)

This application claims priority to and benefits of Korean Patent Application No. 10-2024-0066957 under 35 U.S.C. § 119, filed on May 23, 2024, in the Korean Intellectual Property Office, the entire contents of which are incorporated herein by reference.

### BACKGROUND

### 1. Technical Field

The disclosure relates to a light emitting element, a fused polycyclic compound for the light emitting element, and an electronic apparatus including the light emitting element.

### 2. Description of the Related Art

An electronic apparatus includes a display device that displays an image. Ongoing development continues for an organic electroluminescence display device as an image display device. An organic electroluminescence display device is different from a liquid crystal display device and the like in that it is a so-called self-luminescent display device in which holes and electrons respectively injected from a first electrode and a second electrode recombine in a light emitting layer, so that a light emitting material including an organic compound in the light emitting layer emits light, thereby achieving display.

In the application of an organic electroluminescence element in a display device, there is a persistent demand for organic electroluminescence element having a low driving voltage, high luminous efficiency, and long lifespan. Thus, continuous development is required on a material for an organic electroluminescence element that is capable of stably achieving such characteristics.

In order to implement a high-efficiency organic electroluminescence element, technologies pertaining to phosphorescence light emission, which uses triplet state energy, or pertaining to fluorescence light emission, which uses triplet-triplet annihilation (TTA) in which a singlet exciton is generated by the collision of a triplet excitons, are being developed. Research and development are presently directed to thermally activated delayed fluorescence (TADF) materials that use delayed fluorescence phenomena.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element with improved luminous efficiency and element lifespan.

The disclosure also provides a fused polycyclic compound capable of improving luminous efficiency and element lifespan of a light emitting element.

The disclosure also provides an electronic apparatus with excellent display quality by including a light emitting element with improved luminous efficiency and lifespan.

According to an embodiment, a light emitting element may include a first electrode, a second electrode disposed on the first electrode, and a light emitting layer disposed between the first electrode and the second electrode, and including a first compound represented by Formula 1:

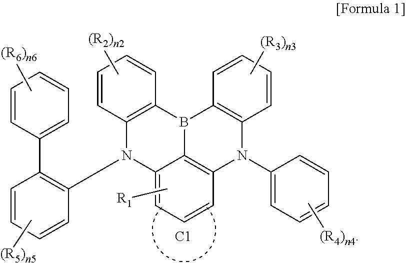

In Formula 1, C1 may be a substituted or unsubstituted aromatic hydrocarbon ring having 6 to 30 ring-forming carbon atoms; R₁ to R₆ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; n2, n3, and n5 may each independently be an integer from 0 to 4; and n4 and n6 may each independently be an integer from 0 to 5.

In an embodiment, the first compound represented by Formula 1 may be represented by Formula 2-1 or Formula 2-2:

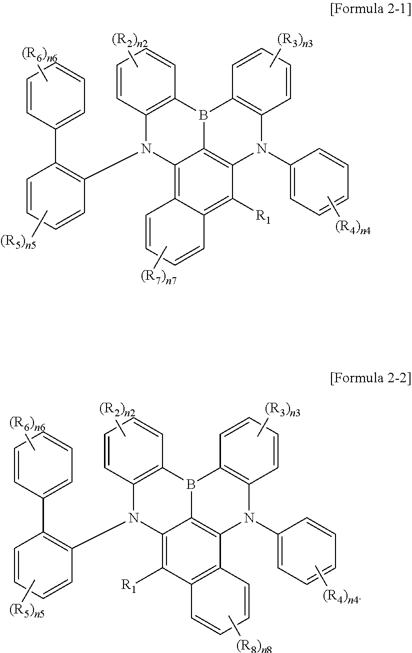

In Formula 2-1 and Formula 2-2, R₇ and R₈ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; n7 and n8 may each independently be an integer from 0 to 4; and R₁ to R₆ and n2 to n6 may be the same as defined in Formula 1.

In an embodiment, the first compound represented by Formula 1 may be represented by one of Formula 3-1 to Formula 3-6:

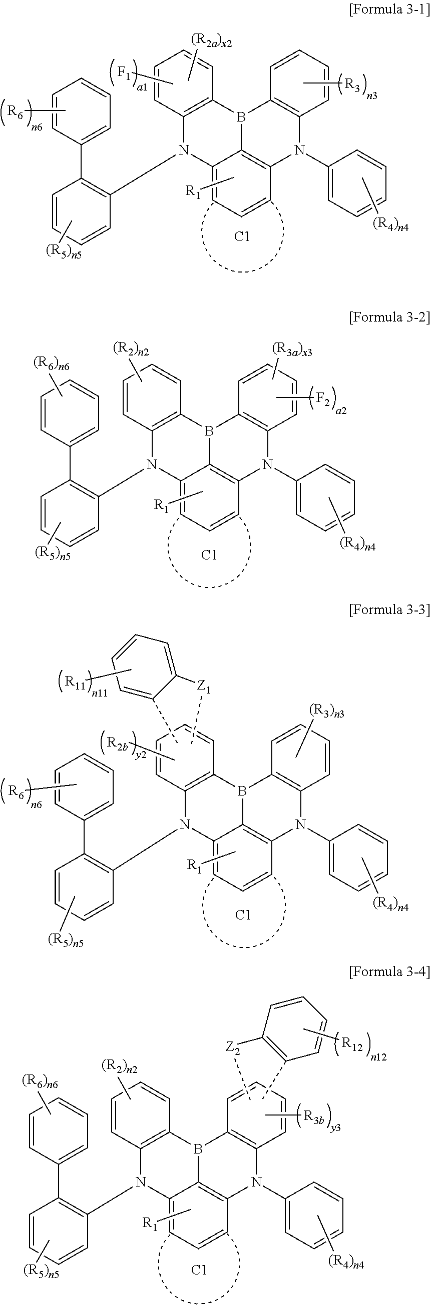

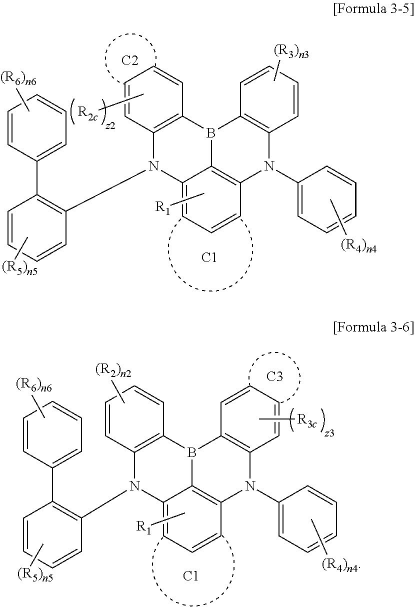

In Formula 3-1 to Formula 3-6, F₁ and F₂ may each independently be a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; Z₁ and Z₂ may each independently be O, S, N(R₁₃), or C(R₁₄)(R₁₅); R₂ₐ, R₃ₐ, R_{2b}, R_{3b}, R_{2c}, R_{3c}, and R₁₁ to R₁₅ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; C2 and C3 may each independently be a substituted or unsubstituted aromatic hydrocarbon ring having 6 to 30 ring-forming carbon atoms; a1 and a2 may each independently be 1 or 2; x2 may be an integer from 0 to (4-a1); x3 may be an integer from 0 to (4-a2); y2, y3, z2, and z3 may each independently be an integer from 0 to 2; and n11 and n12 may each independently be an integer from 0 to 4.

In Formula 3-1 to Formula 3-6, C1, R₁ to R₆, and n2 to n6 may be the same as defined in Formula 1.

In an embodiment, in Formula 3-1 and Formula 3-2, F₁ and F₂ may each independently be a substituted or unsubstituted diphenylamine group, a substituted or unsubstituted phenyl group, a substituted or unsubstituted biphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or bonded to an adjacent group to form a ring.

In an embodiment, the first compound represented by Formula 1 may be represented by one of Formula 4-1 to Formula 4-6:

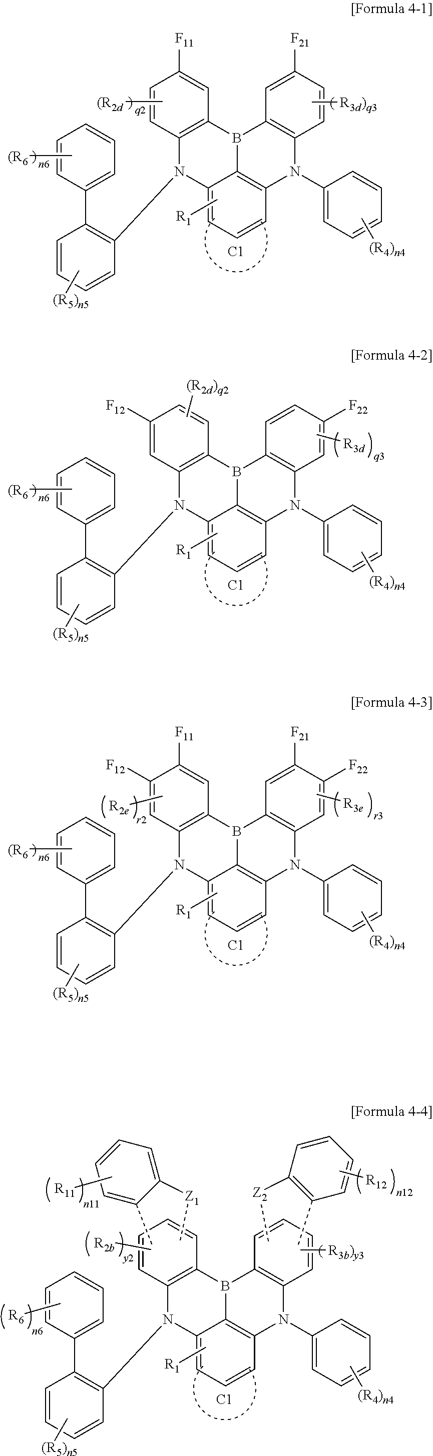

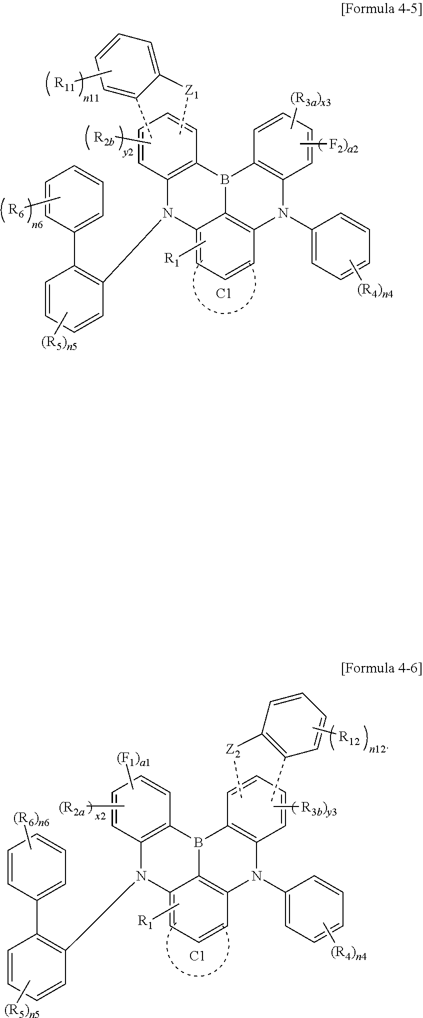

In Formula 4-1 to Formula 4-6, F₁, F₂, F₁₁, F₁₂, F₂₁, and F₂₂ may each independently be a substituted or unsubstituted amine group, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; Z₁ and Z₂ may each independently be O, S, N(R₁₃), or C(R₁₄)(R₁₅); R₂ₐ, R₃ₐ, R_{2b}, R_{3b}, R_{2d}, R_{3d}, R₂ₑ, R₃ₑ, and R₁₁ to R₁₅ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; a1 and a2 may each independently be 1 or 2; x2 may be an integer from 0 to (4-a1); x3 may be an integer from 0 to (4-a2); q2 and q3 may each independently be an integer from 0 to 3; y2, y3, r2, and r3 may each independently be an integer from 0 to 2; and n11 and n12 may each independently be an integer from 0 to 4.

In Formula 4-1 to Formula 4-6, C1, R₁, R₄ to R₆, and n4 to n6 may be the same as defined in Formula 1.

In an embodiment, the first compound represented by Formula 1 may be represented by one of Formula 5-1 to Formula 5-3:

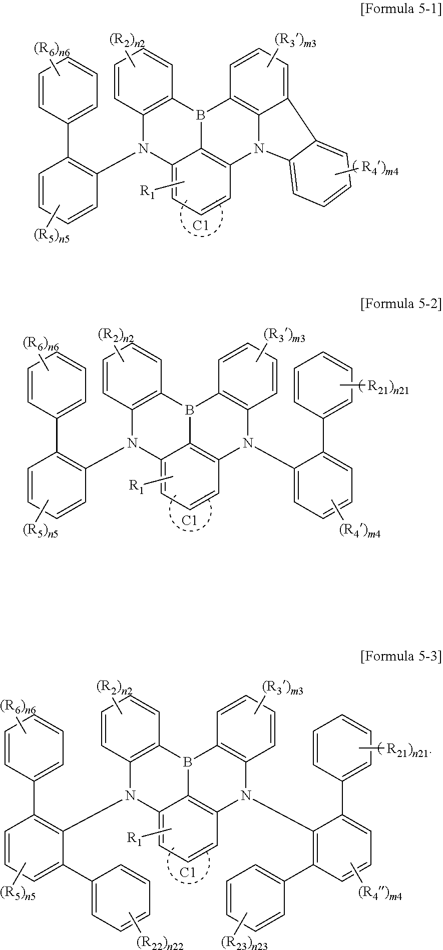

In Formula 5-1 to Formula 5-3, R₃′, R₄′, R₄″, R₅′, and R₂₁ to R₂₃ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; m4 may be an integer from 0 to 4; m3, w4, and m5 may each independently be an integer from 0 to 3; and n21 to n23 may each independently be an integer from 0 to 5.

In Formula 5-1 to Formula 5-3, C1, R₁ to R₃, R₅, R₆, n2, n3, n5, and n6 may be the same as defined in Formula 1.

In an embodiment, the first compound represented by Formula 1 may be represented by Formula 6-1 or Formula 6-2:

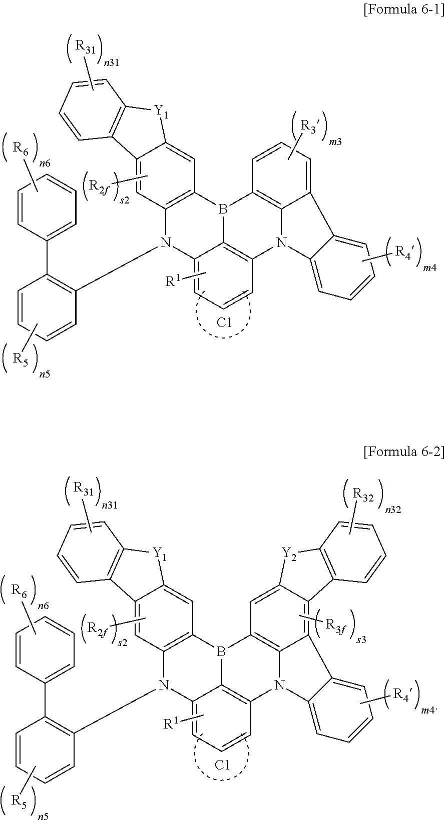

In Formula 6-1 and Formula 6-2, Y1 and Y2 may each independently be O, S, N(R₃₃), or C(R₃₄)(R₃₅); R₃′, R₄′, R_{2f}, R_{3f}, and R₃₁ to R₃₅ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; m4 may be an integer from 0 to 4; m3 may be an integer from 0 to 3; s2 and s3 may each independently be an integer from 0 to 2; and n31 and n32 may each independently be an integer from 0 to 4.

In Formula 6-1 and Formula 6-2, C1, R₁, R₃, R₄, R₅, R₆, n3, n4, n5, and n6 may be the same as defined in Formula 1.

In an embodiment, the first compound may include at least one compound selected from Compound Group 1, which is explained below.

In an embodiment, the light emitting layer may emit green light.

In an embodiment, the light emitting layer may further include at least one of a second compound represented by Formula HT-1, a third compound represented by Formula ET-1, and a fourth compound represented by Formula D-1.

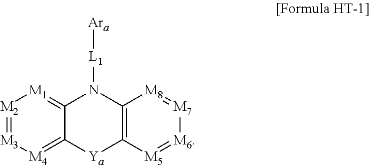

In Formula HT-1, M₁ to M₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Ya may be a direct linkage, C(R₅₂)(R₅₃), or Si(R₅₄)(R₅₅); Arₐ may be a substituted or unsubstituted aryl group having 6 to 30 ring-forming carbon atoms or a substituted or unsubstituted heteroaryl group having 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

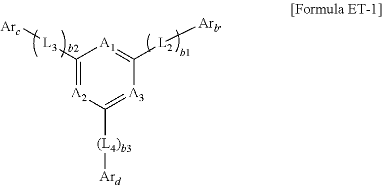

In Formula ET-1, at least one of A1 to A3 may each be N; the remainder of A1 to A3 may each independently be C(R₅₆); R₅₆ may be a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Arb to Ara may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

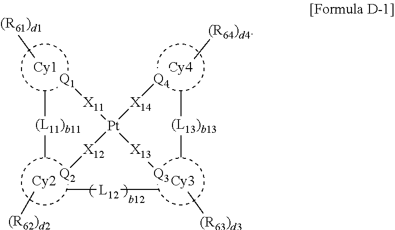

In Formula D-1, Q1 to Q4 may each independently be C or N; Cy1 to Cy4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms; X₁₁ to X₁₄ may each independently be a direct linkage or

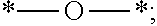

L₁ to L₁₃ may each independently be a direct linkage,

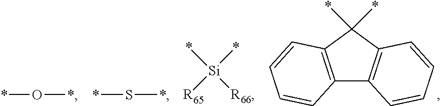

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms; and d1 to d4 may each independently be an integer from 0 to 4.

According to an embodiment, an electronic apparatus may include a circuit layer disposed on a base layer, and a display element layer disposed on the circuit layer, and including a light emitting element; the light emitting element may include a first electrode, a second electrode disposed on the first electrode, and a light emitting layer disposed between the first electrode and the second electrode; and the light emitting layer may include a first compound represented by Formula 1, which is explained herein.

In an embodiment, the light emitting element may further include a capping layer disposed on the second electrode; and the capping layer may have a refractive index equal to or greater than about 1.6, with respect to light in a wavelength range of about 550 nm to about 660 nm.

In an embodiment, the electronic apparatus may further include a light control layer disposed on the display element layer and including a quantum dot; the light emitting element may emit a first color light; and the light control layer may include a first light control unit including a first quantum dot that converts the first color light into a second color light having a longer wavelength range than the first color light, a second light control unit including a second quantum dot that converts the first color light into a third color light having a longer wavelength range than the first color light and the second color light, and a third light control unit that transmits the first color light.

In an embodiment, the electronic apparatus may further include a color filter layer disposed on the light control layer, wherein the color filter layer may include a first filter that transmits the second color light, a second filter that transmits the third color light, and a third filter that transmits the first color light.

According to an embodiment, a fused polycyclic compound may be represented by Formula 1, which is explained herein.

In an embodiment, the fused polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic diagram of an interior of a vehicle in which a display device according to an embodiment is disposed;

FIG. 12 is a schematic perspective view of an electronic apparatus according to an embodiment;

FIG. 13 is an exploded perspective view of an electronic apparatus according to an embodiment;

FIG. 14 is a block diagram of an electronic apparatus according to an embodiment;

FIG. 15 shows schematic diagrams of electronic apparatuses according to embodiments; and

FIG. 16 shows schematic diagrams of electronic apparatuses according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

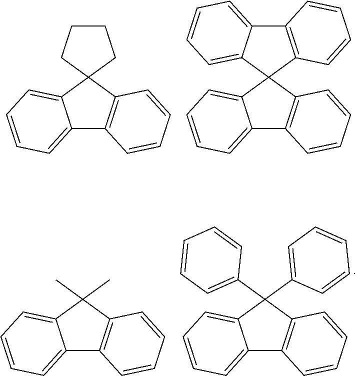

In the specification, a heterocyclic group may be any functional group or substituent derived from a ring that includes at least one of B, O, N, P, Si, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

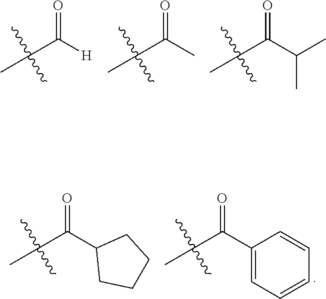

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

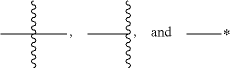

each represent a bond to a neighboring atom in a corresponding formula or moiety.

Hereinafter, embodiments will be described with reference to the accompanying drawings.

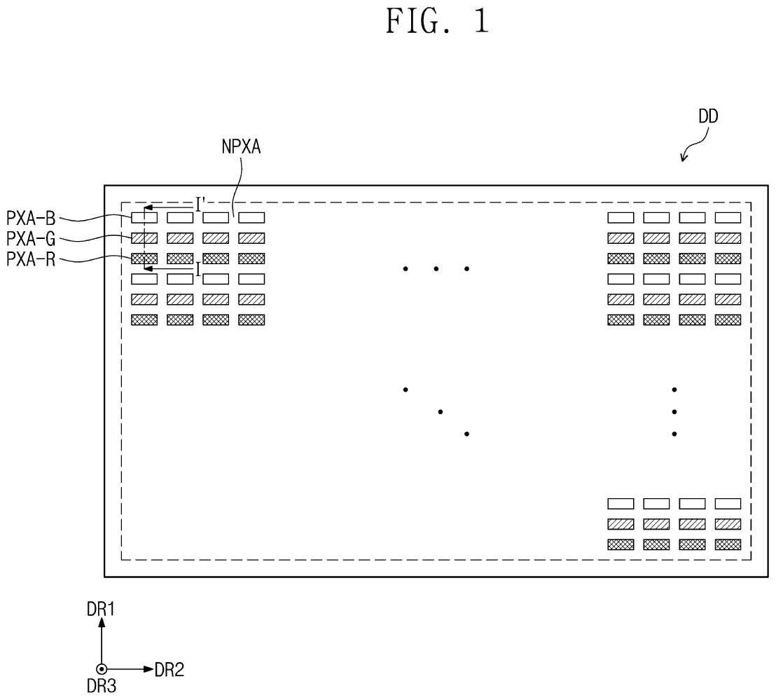

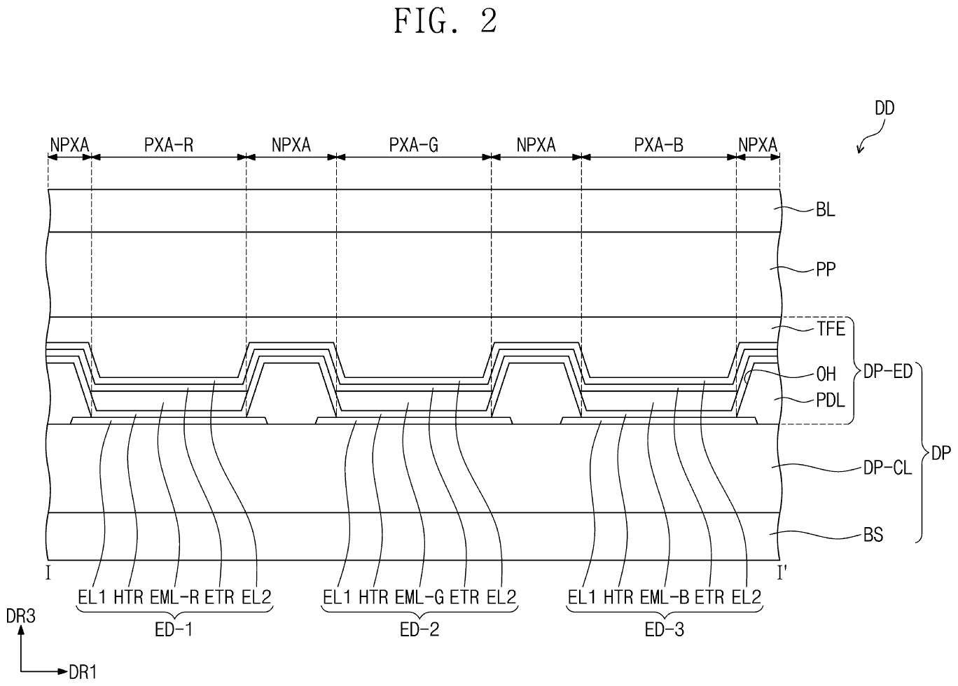

FIG. 1 is a schematic plan view of a display device DD according to an embodiment. FIG. 2 is a schematic cross-sectional view of a display device DD according to an embodiment. FIG. 2 is a schematic cross-sectional view of a portion of the display device DD taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

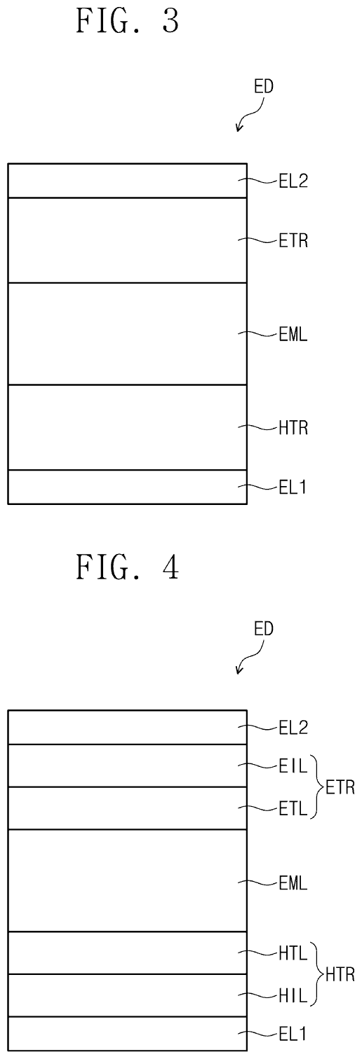

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, light emitting layers EML-R, EML-G, and EML-B, an electron transport region ETR, and a second electrode EL2.

FIG. 2 illustrates an embodiment in which the light emitting layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not shown in FIG. 2, the hole transport region HTR and the electron transport region ETR may each be provided by being patterned in the openings OH defined in the pixel defining film PDL. For example, in an embodiment, the hole transport region HTR, the light emitting layers EML-R, EML-G, and EML-B, and the electron transport region ETR of the light emitting elements ED-1, ED-2, and ED-3 may be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The light emitting layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel™).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. The light emitting element ED according to an embodiment may include a first electrode EL1, a second electrode EL2 facing the first electrode EL1, and at least one functional layer disposed between the first electrode EL1 and the second electrode EL2. The light emitting element ED according to an embodiment may include a fused polycyclic compound according to an embodiment, which will be explained later, in the at least one functional layer.

The light emitting element ED may include a hole transport region HTR, a light emitting layer EML, an electron transport region ETR, or the like, stacked in order, as the at least one functional layer. Referring to FIG. 3, the light emitting element ED according to an embodiment may include a first electrode EL1, a hole transport region HTR, a light emitting layer EML, an electron transport region ETR, and a second electrode EL2, stacked in that order.

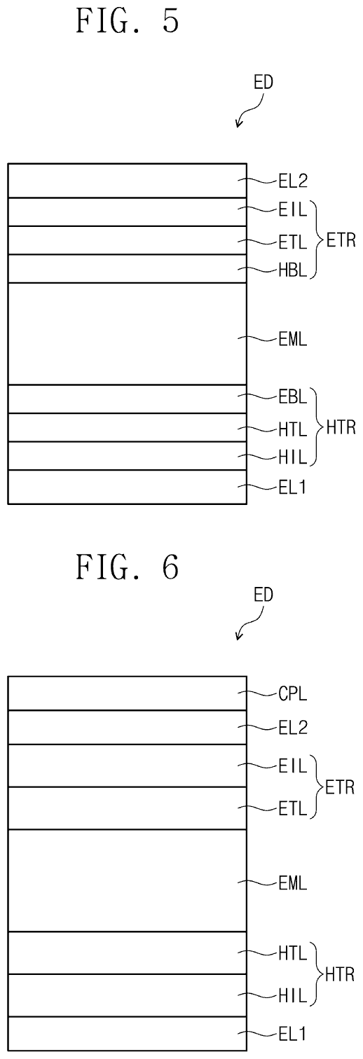

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The light emitting element ED may include a fused polycyclic compound according to an embodiment, which will be explained later, in the at least one functional layer. In the light emitting element ED, at least one of the hole transport region HTR, the light emitting layer EML, and the electron transport region ETR may include the fused polycyclic compound according to an embodiment. For example, in the light emitting element ED, the light emitting layer EML may include the fused polycyclic compound.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure formed of a hole injection material and a hole transport material. In embodiments, the hole transport region HTR may have a single-layered structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respectively stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

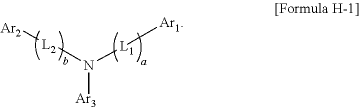

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

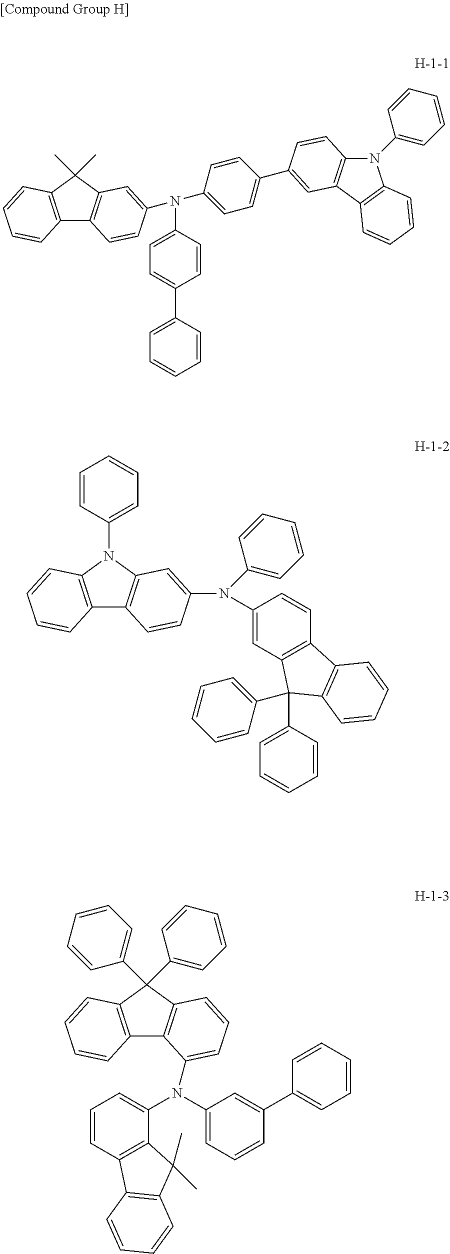 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

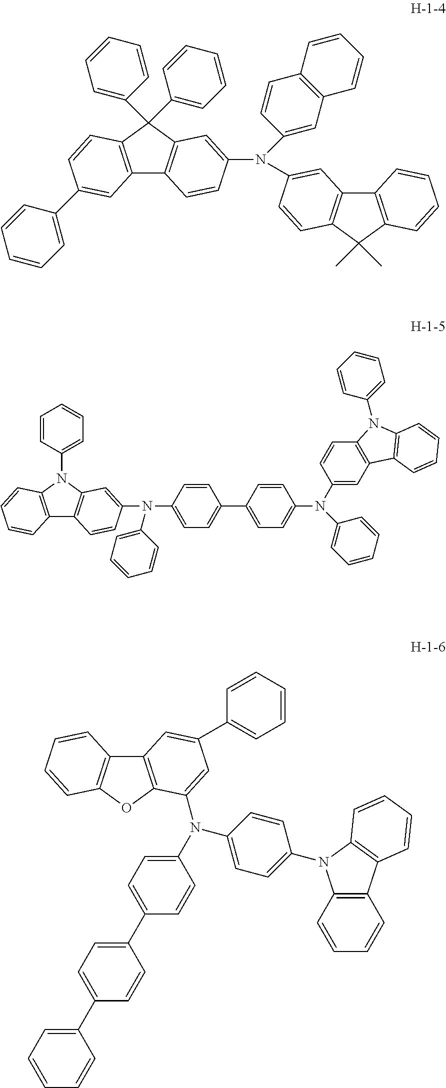 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

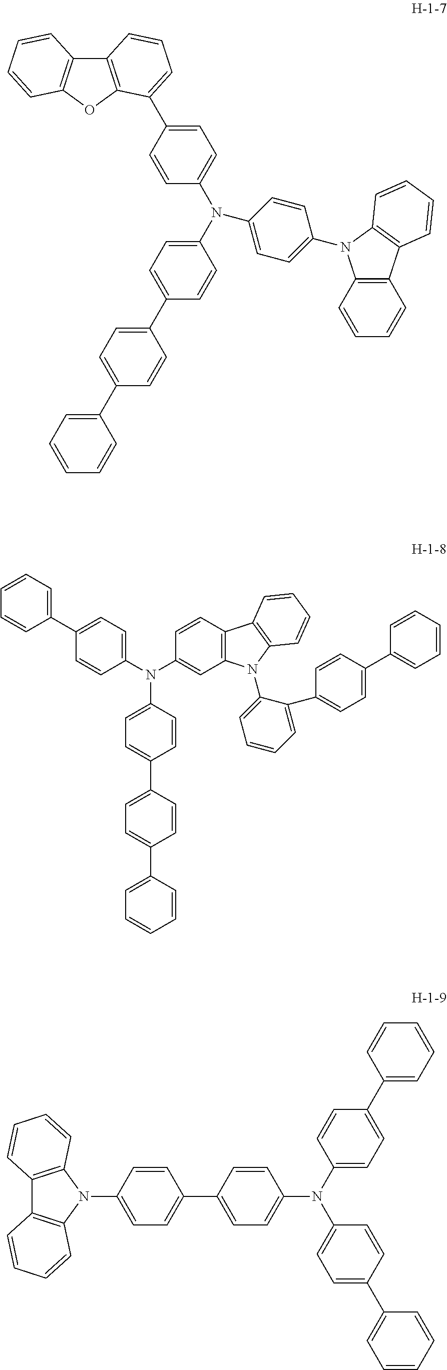 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

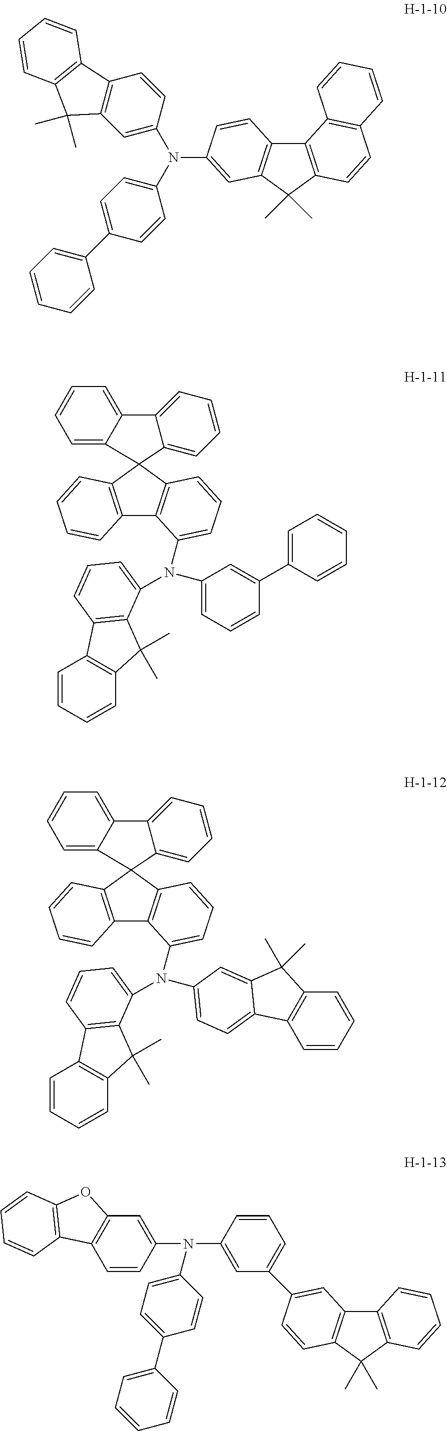 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

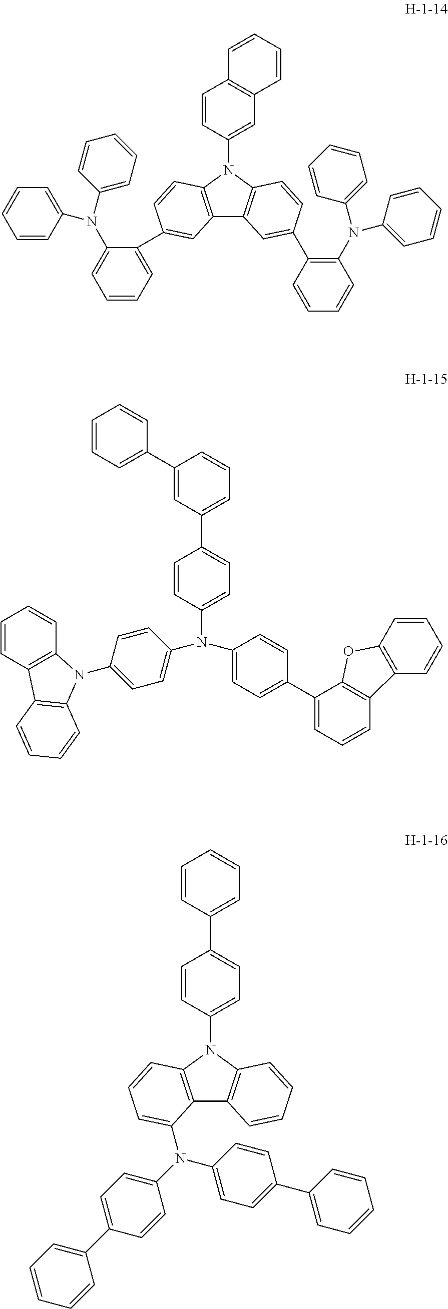 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

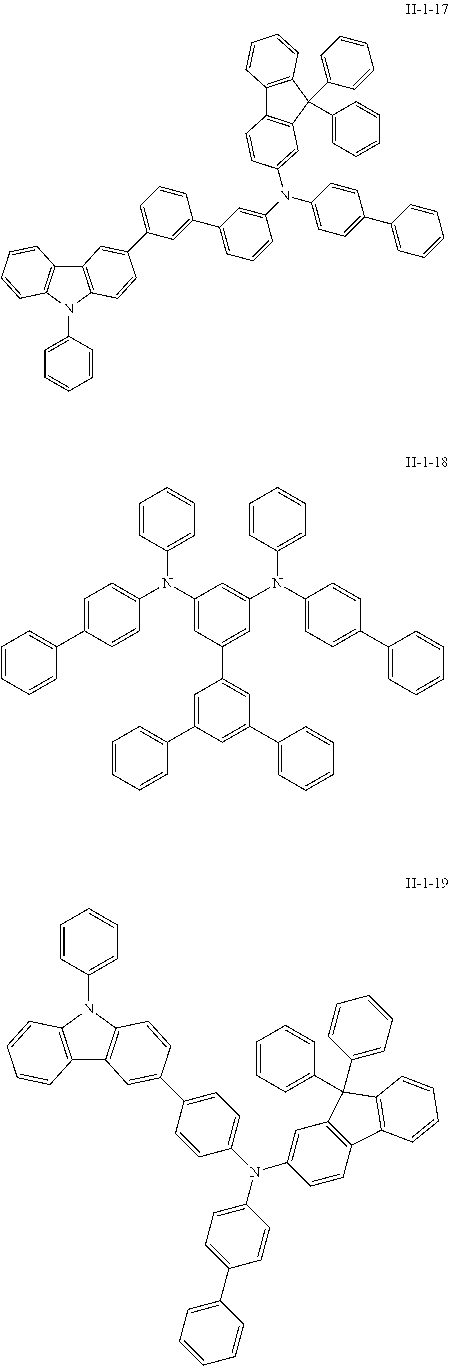 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

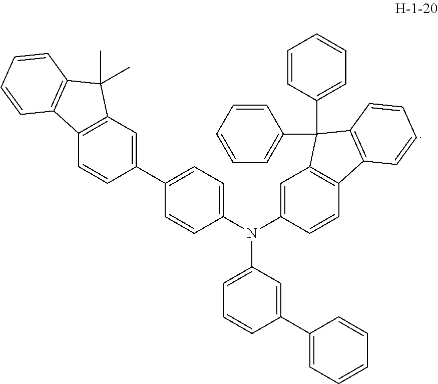 [SMILES: CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium[tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′8,8-tetracyanoquinodimethane (F₄-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to the hole injection layer HIL and the hole transport layer HTL. The buffer layer (not shown) may compensate for a resonance distance according to a wavelength of light emitted from the light emitting layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The light emitting layer EML may be provided on the hole transport region HTR. The light emitting layer EML may have a thickness in a range of about 100 Å to about 1,000 Å. For example, the light emitting layer EML may have a thickness in a range of about 100 Å to about 300 Å. The light emitting layer EML may have a structure consisting of a layer consisting of a single material, a structure consisting of a layer including different materials, or a structure including multiple layers including different materials.

The light emitting element ED according to an embodiment may include a fused polycyclic compound represented by Formula 1 in at least one functional layer disposed between the first electrode EL1 and the second electrode EL2. In the light emitting element ED, the light emitting layer EML may include the fused polycyclic compound according to an embodiment. In an embodiment, the light emitting layer EML may include the fused polycyclic compound as a dopant. The fused polycyclic compound may be a dopant material of the light emitting layer EML. In the specification, the fused polycyclic compound according to an embodiment may be referred to as a first compound.

The fused polycyclic compound may have a fused heteropolycyclic structure in which five rings are fused, and which includes a boron atom and first and second nitrogen atoms. The fused polycyclic compound may have a structure in which a first aromatic hydrocarbon ring is connected to the fused heteropolycyclic structure. In the fused polycyclic compound according to an embodiment, the first aromatic hydrocarbon ring may be connected to the fused heteropolycyclic structure to form an additional fused ring. In the specification, the fused heteropolycyclic structure may be referred to as a “fused ring core.”

In an embodiment, the fused ring core in the fused polycyclic compound may form five rings as three substituted or unsubstituted benzene rings are connected through the boron atom, the first nitrogen atom, and the second nitrogen atom. Among the three benzene rings included in the fused ring core, the three benzene rings may each be connected to the boron atom, wherein a first benzene ring and a second benzene ring may be connected through the first nitrogen atom, and the third benzene ring may be connected through the second nitrogen atom to the first benzene ring. The boron atom and the first and second nitrogen atoms may all be connected to the first benzene ring.

In an embodiment, the first aromatic hydrocarbon ring included in the fused polycyclic compound may be connected to the fused ring core to form an additional fused ring. In the fused polycyclic compound according to an embodiment, the first aromatic hydrocarbon ring may be connected to the first benzene ring of the fused ring core as described above to form the additional fused ring.

In an embodiment, the first aromatic hydrocarbon ring may be a substituted or unsubstituted aromatic hydrocarbon ring having 6 to 30 ring carbon atoms. For example, the first aromatic hydrocarbon ring may be a substituted or unsubstituted benzene ring. If the first aromatic hydrocarbon ring is a substituted or unsubstituted benzene ring, the first aromatic hydrocarbon ring may be referred to as a fourth benzene ring. In the fused polycyclic compound of an embodiment, the fourth benzene ring may be connected to the first benzene ring of the fused ring core to form a naphthalene ring. The fourth benzene ring may be fused to the fused ring core to form a naphthalene ring that includes the first benzene ring and the fourth benzene ring.

The fused polycyclic compound according to an embodiment may include first and second substituents that are connected to the fused ring core.

The first substituent may be connected to the first nitrogen atom of the fused ring core of the fused polycyclic compound. The first substituent may include a first benzene moiety, and a first sub-substituent that is bonded at a specific position of the first benzene moiety. The first substituent may include the first benzene moiety connected to the first nitrogen atom of the fused ring core, and the first sub-substituent connected to the first benzene moiety at an ortho position with respect to the first nitrogen atom. The first sub-substituent may be a substituted or unsubstituted aryl group having 6 to 30 ring-forming carbon atoms. For example, the first sub-substituent may be a substituted or unsubstituted phenyl group.

The second substituent may be connected to the second nitrogen atom of the fused ring core of the fused polycyclic compound. The second substituent may include a second benzene moiety. In the fused polycyclic compound according to an embodiment, the second substituent may further include a second sub-substituent connected to the second benzene moiety. The second sub-substituent may be connected to the second benzene moiety at a specific position. For example, the second substituent may include the second benzene moiety connected to the second nitrogen atom of the fused ring core, and the second sub-substituent connected to the second benzene moiety at an ortho position with respect to the second nitrogen atom. The second sub-substituent may be a substituted or unsubstituted aryl group having 6 to 30 ring-forming carbon atoms. For example, the second sub-substituent may be a substituted or unsubstituted phenyl group.

The light emitting element ED according to an embodiment may include a fused polycyclic compound according to an embodiment. The fused polycyclic compound according to an embodiment may be represented by Formula 1:

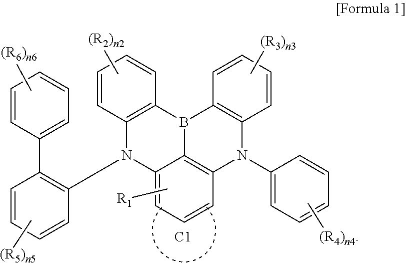

The fused polycyclic compound represented by Formula 1 may include a fused ring core that is formed by fusing five rings centered on a boron atom and first and second nitrogen atoms, in which a first aromatic hydrocarbon ring is connected to the fused ring core. In the specification, in Formula 1, a benzene ring substituted with R₁ corresponds to the first benzene ring as described above, a benzene ring substituted with R₂ corresponds to the second benzene ring as described above, and a benzene ring substituted with R₃ corresponds to the third benzene ring as described above. In Formula 1, C1 may correspond to the first aromatic hydrocarbon ring as described above.

In Formula 1, C1 may be a substituted or unsubstituted aromatic hydrocarbon ring having 6 to 30 ring-forming carbon atoms. For example, C1 may be a substituted or unsubstituted benzene ring.

In Formula 1, R₁ to R₆ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In an embodiment, R₁ to R₆ may each independently be a hydrogen atom, a hydroxy group, a substituted or unsubstituted t-butyl group, a substituted or unsubstituted arylamine group, a substituted or unsubstituted aryloxy group, a substituted or unsubstituted arylthio group, a substituted or unsubstituted phenyl group, a substituted or an unsubstituted biphenyl group, a substituted or unsubstituted terphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or bonded to an adjacent group to form a ring.

In Formula 1, n2, n3, and n5 may each independently be an integer from 0 to 4. If n2, n3, and n5 are each 0, the fused polycyclic compound may not be substituted with R₂, R₃, and R₅, respectively. If n2, n3, and n5 are each 4, and four groups of each of R₂, R₃, and R₅ are all hydrogen atoms, it may be the same as a case in which n2, n3, and n5 are each 0. If n2, n3, and n5 are each 2 or greater, multiple groups of each of R₂, R₃, and R₅ may all be the same, or at least one thereof may be different from the remainder.

In Formula 1, n4 and n6 may each independently be an integer from 0 to 5. If n4 and n6 are each 0, the fused polycyclic compound may not be substituted with R₄ and R₆, respectively. If n4 and n6 are each 5, and five groups of each of R₄ and R₆ are all hydrogen atoms, it may be the same as a case in which n4 and n6 are each 0. If n4 and n6 are each 2 or greater, multiple groups of each of R₄ and R₆ may all be the same, or at least one thereof may be different from the remainder.

In an embodiment, the first compound represented by Formula 1 may be represented by Formula 2-1 or Formula 2-2:

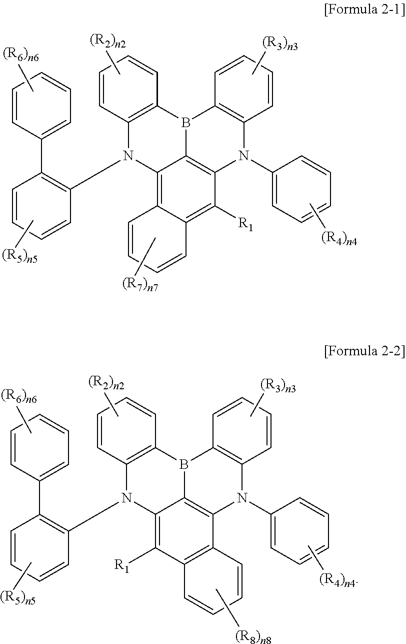

Formula 2-1 and Formula 2-2 each represent a case in which the type and connection position of C1 in Formula 1 are further defined.

In Formula 2-1 and Formula 2-2, R₇ and R₈ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₇ and R₈ may each be a hydrogen atom.

In Formula 2-1, n7 may be an integer from 0 to 4. If n7 is 0, the fused polycyclic compound may not be substituted with R₇. If n7 is 4 and four groups of R₇ are all hydrogen atoms, it may be the same as a case in which n7 is 0. If n7 is 2 or greater, multiple R₇ groups may all be the same, or at least one thereof may be different from the remainder.

In Formula 2-2, n8 may be an integer from 0 to 4. If n8 is 0, the fused polycyclic compound may not be substituted with R₈. If n8 is 4 and four groups of R₈ are all hydrogen atoms, it may be the same as a case in which n8 is 0. If n8 is 2 or greater, multiple R₈ groups may all be the same, or at least one thereof may be different from the remainder.

In Formula 2-1 and Formula 2-2, R₁ to R₆ and n2 to n6 may be the same as defined in Formula 1.

In an embodiment, the first compound represented by Formula 1 may be represented by one of Formula 3-1 to Formula 3-6:

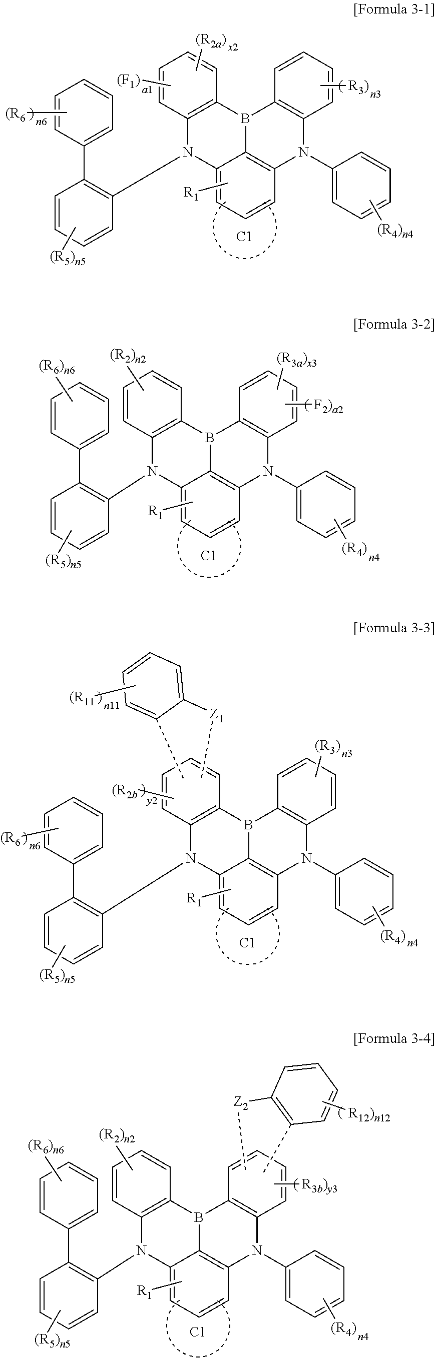

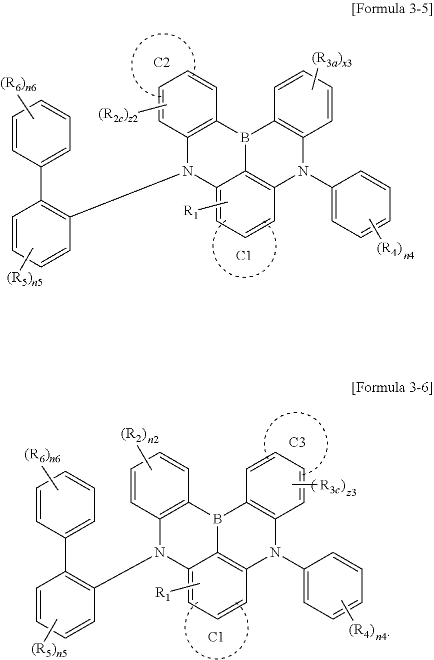

In Formula 3-1 and Formula 3-2, F₁ and F₂ may each independently be a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In an embodiment, in Formula 3-1 and Formula 3-2, F₁ and F₂ may each independently be a substituted or unsubstituted diphenylamine group, a substituted or unsubstituted phenyl group, a substituted or unsubstituted biphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or bonded to an adjacent group to form a ring.

In Formula 3-3 and Formula 3-4, Z₁ and Z₂ may each independently be O, S, N(R₁₃), or C(R₁₄)(R₁₅).

In Formula 3-1 to Formula 3-6, R₂ₐ, R₃ₐ, R_{2b}, R_{3b}, R_{2c}, R_{3c}, and R₁₁ to R₁₅ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In an embodiment, R₂ₐ, R₃ₐ, R_{2b}, R_{3b}, R_{2c}, R_{3c}, and R₁₁ to R₁₅ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₂ₐ, R₃ₐ, R_{2b}, R_{3b}, R_{2c}, and R_{3c} may each be a hydrogen atom; R₁₁ and R₁₂ may each independently be a hydrogen atom, a substituted or unsubstituted t-butyl group, a substituted or unsubstituted phenyl group, or a substituted or unsubstituted carbazole group; and R₁₃ to R₁₅ may each independently be a substituted or unsubstituted phenyl group.

In Formula 3-5 and Formula 3-6, C2 and C3 may each independently be a substituted or unsubstituted aromatic hydrocarbon ring having 6 to 30 ring-forming carbon atoms. For example, C2 and C3 may each independently be a substituted or unsubstituted benzene ring. In Formula 3-1 and Formula 3-2, a1 and a2 may each independently be 1 or 2.

In Formula 3-1, x2 may be an integer from 0 to (4-a1). For example, x2 may be 0, or 2 or 3. If x2 is 0, the fused polycyclic compound may not be substituted with R₂ₐ. If x2 is 3, and three R₂ₐ groups are all hydrogen atoms, it may be the same as a case in which x2 is 0. If x2 is 2 or 3, two or three R₂ₐ groups may all be the same, or at least one thereof may be different from the remainder.

In Formula 3-2, x3 may be an integer from 0 to (4-a2). For example, x3 may be 0, or 2 or 3. If x3 is 0, the fused polycyclic compound may not be substituted with R₃ₐ. If x3 is 3, and three R₃ₐ groups are all hydrogen atoms, it may be the same as a case in which x3 is 0. If x3 is 2 or 3, two or three R₃ₐ groups may all be the same, or at least one thereof may be different from the remainder.

In Formula 3-3 and Formula 3-4, y2 and y3 may each independently be an integer from 0 to 2. If y2 and y3 are each 0, the fused polycyclic compound may not be substituted with R_{2b} and R_{3b}, respectively. If y2 and y3 are each 2, and two groups of each of R_{2b} and R_{3b} are all hydrogen atoms, it may be the same as a case in which y2 and y3 are each 0. If y2 and y3 are each 2, two R_{2b} groups and two R_{3b} groups may all be the same, or at least one thereof may be different from the remainder.

In Formula 3-4 and Formula 3-5, z2 and z3 may each independently be an integer from 0 to 2. If z2 and z3 are each 0, the fused polycyclic compound may not be substituted with R_{2c} and R_{3c}, respectively. If z2 and z3 are each 2, and two groups of each of R_{2c} and R_{3c} are all hydrogen atoms, it may be the same as a case in which z2 and z3 are each 0. If z2 and z3 are each 2, two R_{2c} groups and two R_{3c} groups may all be the same, or at least one thereof may be different from the remainder.

In Formula 3-3 and Formula 3-4, n11 and n12 may each independently be an integer from 0 to 4. If n11 and n12 are each 0, the fused polycyclic compound may not be substituted with R₁₁ and R₁₂, respectively. If n11 and n12 are each 4, and four groups of each of R₁₁ and R₁₂ are all hydrogen atoms, it may be the same as a case in which n11 and n12 are each 0. If n11 and n12 are each 2 or greater, multiple groups of each of R₁₁ and R₁₂ may all be the same, or at least one thereof may be different from the remainder.

In Formula 3-1 to Formula 3-6, C1, R₁ to R₆, and n2 to n6 may be the same as defined in Formula 1.

In an embodiment, the first compound represented by Formula 3-3 may be represented by one of Formula 3-3-1 to Formula 3-3-6:

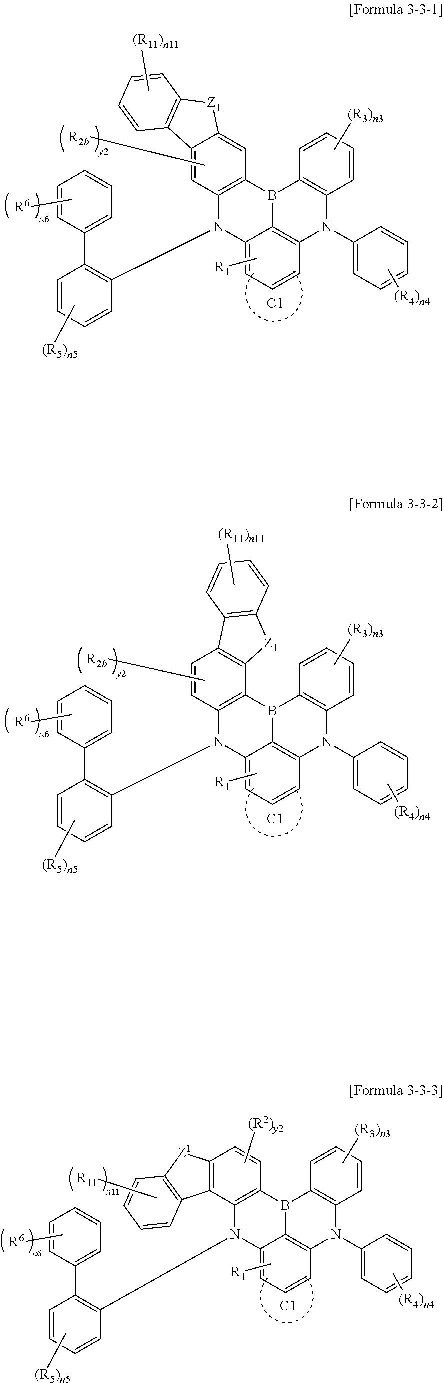

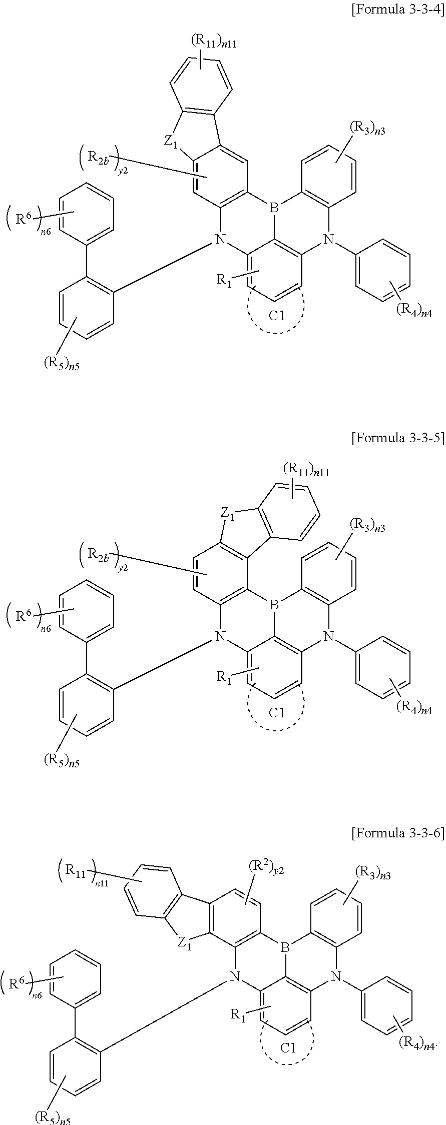

In Formula 3-3-1 to Formula 3-3-6, C1, R₁, R₃ to R₆, and n3 to n6 may be the same as defined in Formula 1.

In Formula 3-3-1 to Formula 3-3-6, R₁₁, n11, R_{2b}, y2, and Z₁ may be the same as defined in Formula 3-3.

In an embodiment, the first compound represented by Formula 3-4 may be represented by one of Formula 3-4-1 to Formula 3-4-6:

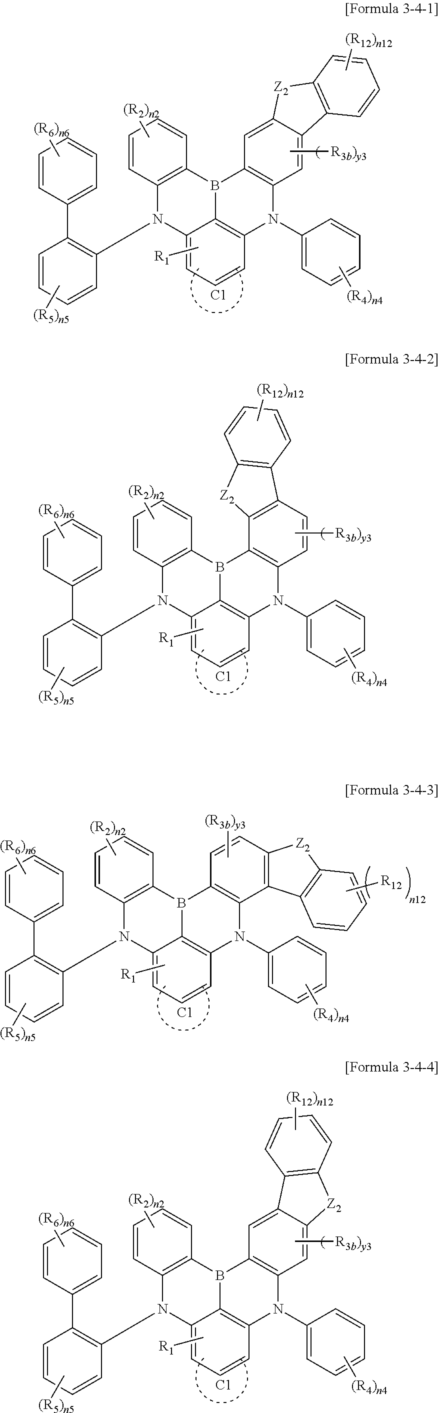

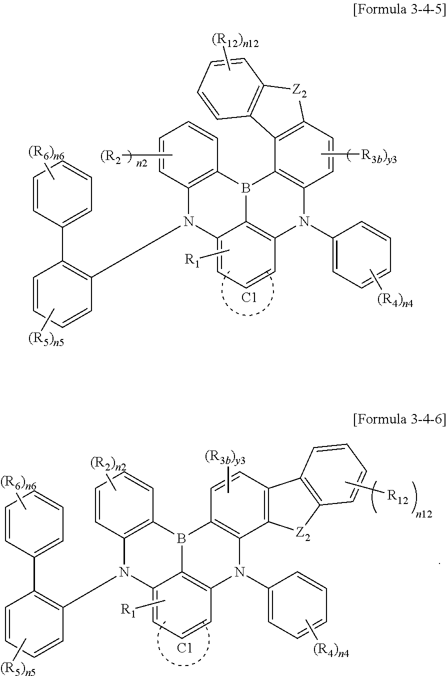

In Formula 3-4-1 to Formula 3-4-6, C1, R₁, R₂, R₄ to R₆, n2, and n4 to n6 may be the same as defined in Formula 1.

In Formula 3-4-1 to Formula 3-4-6, Z₂, R_{3b}, y3, R₁₂, and n12 may be the same as defined in Formula 3-4.

In an embodiment, the first compound represented by Formula 1 may be represented by one of Formula 4-1 to Formula 4-6:

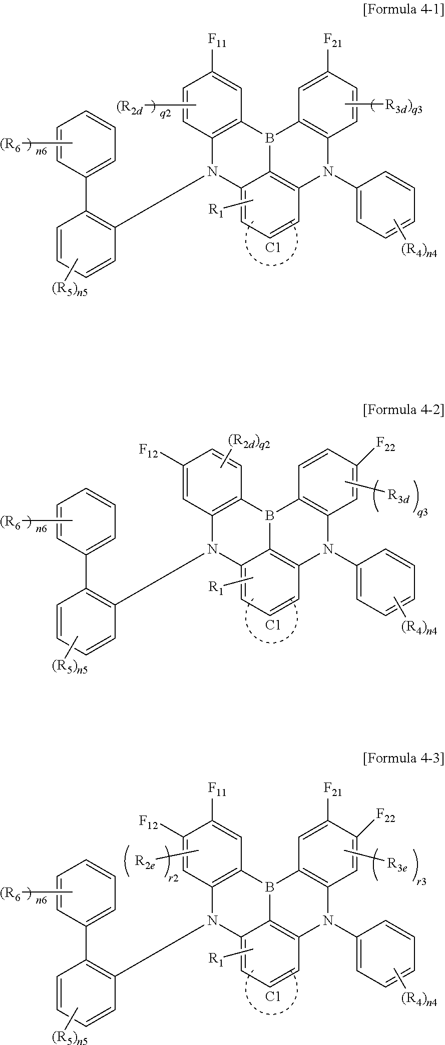

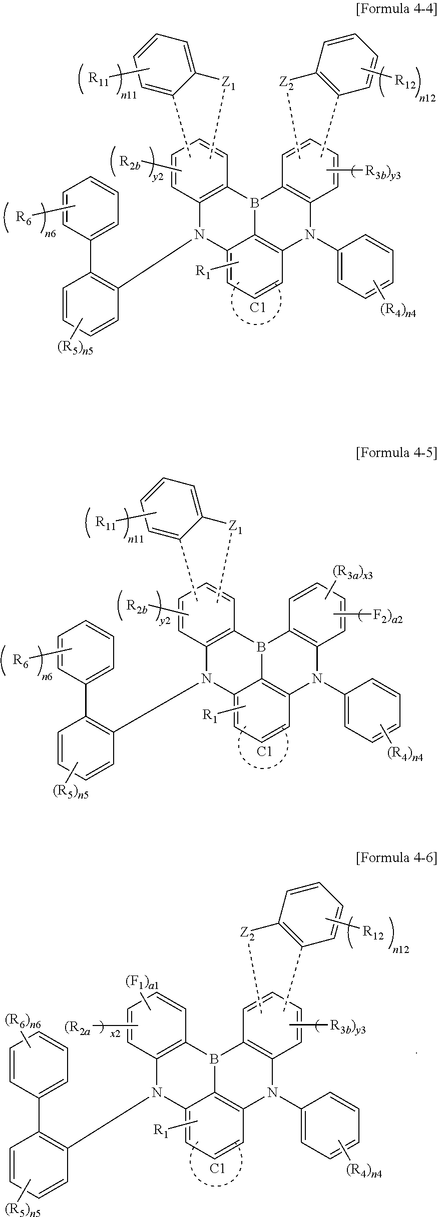

In Formula 4-1 to Formula 4-6, F₁, F₂, F₁₁, F₁₂, F₂₁, and F₂₂ may each independently be a substituted or unsubstituted amine group, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In an embodiment, F₁₁, F₁₂, F₂₁, and F₂₂ may each independently be a substituted or unsubstituted diphenylamine group, a substituted or unsubstituted phenyl group, a substituted or unsubstituted biphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or may be bonded to an adjacent group to form a ring.

In Formula 4-1 to Formula 4-3, R_{2d}, R_{3d}, R₂ₑ, and R₃ₑ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R_{2d}, R_{3d}, R₂ₑ, and R₃ₑ may each be a hydrogen atom.

In Formula 4-1 and Formula 4-2, q2 and q3 are each independently an integer of 0 to 3. If q2 and q3 are each 0, the fused polycyclic compound of an embodiment may have not been substituted with each of R_{2d} and R_{3d}. In Formula 4-1 and Formula 4-2, if q2 and q3 are each 3, and each of R_{2d} and R_{3d} is all hydrogen atoms, it may be the same as the case in which q2 and q3 are each 0 in Formula 4-1 and Formula 4-2. If q2 and q3 are each an integer of 2 or greater, each of R_{2d} and R_{3d} provided in a may all be the same, or at least one of the of R_{2d} and R_{3d} may be different.

In Formula 4-3, r2 and r3 may each independently be an integer from 0 to 2. If r2 and r3 are each 0, the fused polycyclic compound may not be substituted with R₂ₑ and R₃ₑ, respectively. If r2 and r3 are each 2, and two groups each of R₂ₑ and R₃ₑ are all hydrogen atoms, it may be the same as a case in which r2 and r3 are each 0. If r2 and r3 are each 2, two R₂ₑ groups and two R₃ₑ groups may all be the same, or at least one thereof may be different from the remainder.

In Formula 4-5 and Formula 4-6, R₂ₐ, R₃ₐ, a1, a2, x2, and x3 may be the same as defined in Formulas 3-1 and 3-2.

In Formula 4-3 to Formula 4-6, R_{2b}, R_{3b}, R₁₁, R₁₂, Z₁, Z₂, y2, y3, n11, and n12 may be the same as defined in Formulas 3-3 and 3-4.

In Formula 4-1 to Formula 4-6, C1, R₁, R₄ to R₆, and n4 to n6 may be the same as defined in Formula 1.

In an embodiment, the first compound represented by Formula 1 may be represented by one of Formula 5-1 to Formula 5-3:

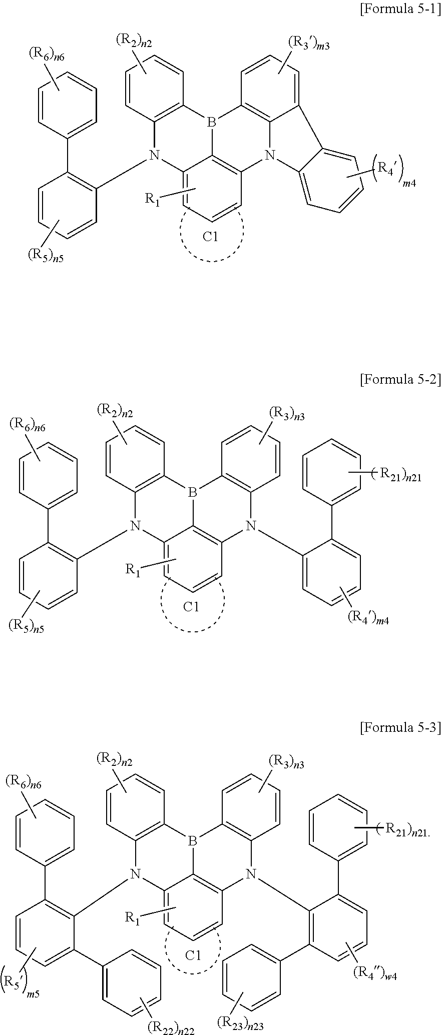

In Formula 5-1 to Formula 5-3, R₃′, R₄′, R₄″, R₅′, and R₂₁ to R₂₃ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃′, R₄′, R₄″, R₅′, and R₂₁ to R₂₃ may each independently be a hydrogen atom, a hydroxy group, a substituted or unsubstituted arylamine group, a substituted or unsubstituted aryloxy group, a substituted or unsubstituted arylthio group, a substituted or unsubstituted t-butyl group, a substituted or unsubstituted phenyl group, a substituted or unsubstituted biphenyl group, or a substituted or unsubstituted carbazole group.

In Formula 5-1 and Formula 5-2, m4 may be an integer of 0 to 4. If m4 is 0, the fused polycyclic compound may not be substituted with R₄′. If m4 is 4, and four R₄′ groups are all hydrogen atoms, it may be the same as a case in which m4 is 0. If m4 is 2 or greater, multiple R₄′ groups may all be the same, or at least one thereof may be different from the remainder.

In Formula 5-1 and Formula 5-3, m3, w4, and m5 may each independently be an integer from 0 to 3. If m3, w4, and m5 are each 0, the fused polycyclic compound may not be substituted with R₃′, R₄″, and R₅′, respectively. If m3, w4, and m5 are each 3, and three groups of each of R₃′, R₄″, and R₅′ are all hydrogen atoms, it may be the same as a case in which m3, w4, and m5 are each 0. If m3, w4, and m5 are each 2 or greater, multiple groups of each of R₃′, R₄″, and R₅′ may all be the same, or at least one thereof may be different from the remainder.

In Formula 5-2 and Formula 5-3, n21 to n23 may each independently be an integer from 0 to 5. If n21 to n23 are each 0, the fused polycyclic compound may not be substituted with R₂₁ to R₂₃, respectively. If n21 to n23 are each 5, and five groups of each of R₂₁ to R₂₃ are all hydrogen atoms, it may be the same as a case in which n21 to n23 are each 0. If n21 to n23 are each 2 or greater, multiple groups of each of R₂₁ to R₂₃ may all be the same, or at least one thereof may be different from the remainder.

In Formula 5-1 to Formula 5-3, C1, R₁ to R₃, R₅, R₆, n2, n3, n5, and n6 may be the same as defined in Formula 1.

In an embodiment, the first compound represented by Formula 1 may be represented by Formula 6-1 or Formula 6-2:

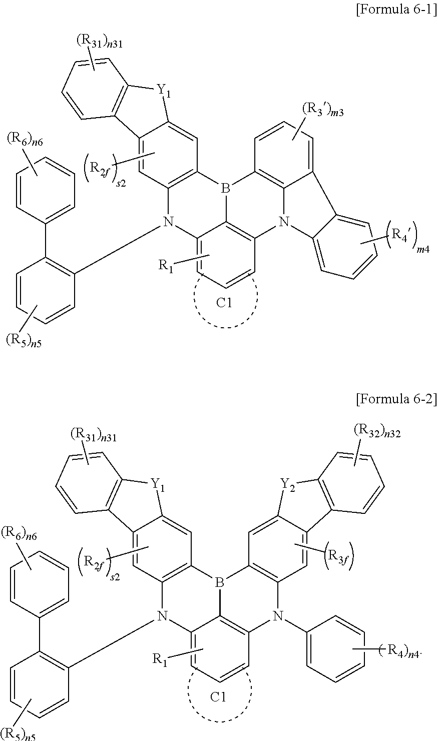

In Formula 6-1 and Formula 6-2, Y1 and Y2 may each independently be O, S, N(R₃₃), or C(R₃₄)(R₃₅).

In Formula 6-1 and Formula 6-2, R_{2f}, R_{3f}, and R₃₁ to R₃₅ may each independently be a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R_{2f} and R_{3f} may each be a hydrogen atom; R₃₁ and R₃₂ may each independently be a hydrogen atom, a substituted or unsubstituted t-butyl group, a substituted or unsubstituted phenyl group, or a substituted or unsubstituted carbazole group; and R₃₃ to R₃₅ may each independently be a substituted or unsubstituted phenyl group.

In Formula 6-1 and Formula 6-2, s2 and s3 may each independently be an integer from 0 to 2. If s2 and s3 are each 0, the fused polycyclic compound may not be substituted with R_{2f} and R_{3f}, respectively. If s2 and s3 are each 2, and two groups of each of R_{2f} and R_{3f} are all hydrogen atoms, it may be the same as a case in which s2 and s3 are each 0. If s2 and s3 are each 2, two R_{2f} groups and two R_{3f} groups may all be the same, or at least one thereof may be different from the remainder.

In Formula 6-1 and Formula 6-2, n31 and n32 may each independently be an integer from 0 to 4. If n31 and n32 are each 0, the fused polycyclic compound may not be substituted with R₃₁ to R₃₃, respectively. If n31 and n32 are each 4, and four groups of each of R₃₁ to R₃₃ are all hydrogen atoms, it may be the same as a case in which n31 and n32 are each 0. If n31 and n32 are each 2 or greater, multiple groups of each of R₃₁ to R₃₃ may all be the same, or at least one thereof may be different from the remainder.

In Formula 6-1 and Formula 6-2, R³′, R₄′, m3, and m4 may be the same as defined in Formula 5-1.

In Formula 6-1 and Formula 6-2, C1, R₁, R₃, R₄, R₅, R₆, n3, n4, n5, and n6 may be the same as defined in Formula 1.

In an embodiment, the fused polycyclic compound represented by Formula 1 may be any compound selected from Compound Group 1. In an embodiment, in the light emitting element ED, at least one functional layer may include at least one compound selected from Compound Group 1. In an embodiment, the light emitting element ED the first compound may include at least one compound selected from Compound Group 1:

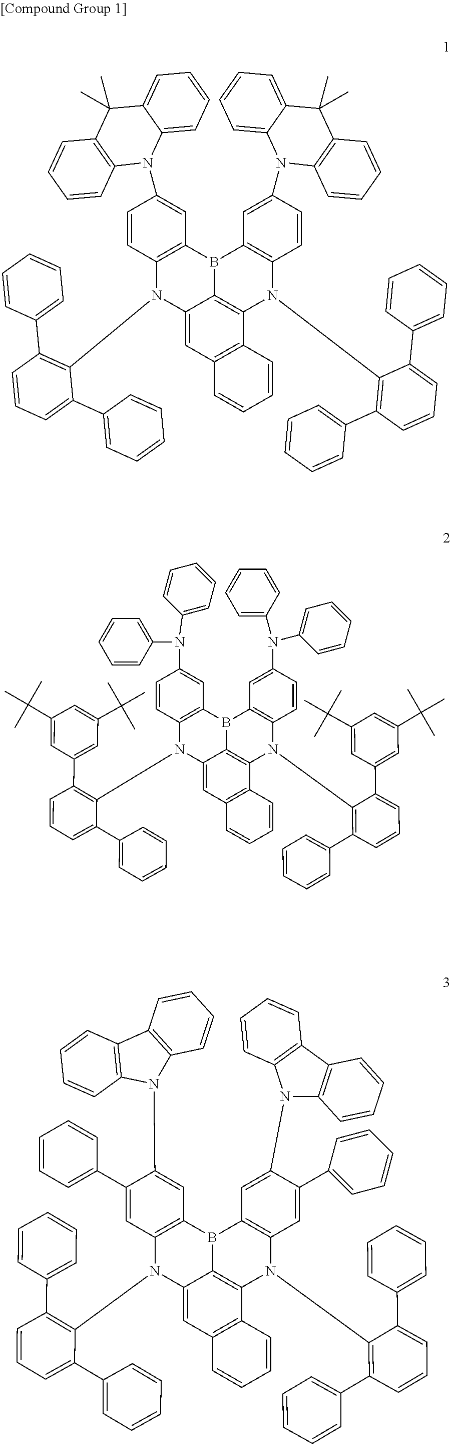 [SMILES: CC1(C)c2ccccc2N(c2ccc3c(c2)B2c4cc(N5c6ccccc6C(C)(C)c6ccccc65)ccc4N(c4c(-c5ccccc5)cccc4-c4ccccc4)c4c2c(cc2ccccc42)N3c2c(-c3ccccc3)cccc2-c2ccccc2)c2ccccc21 ; CC(C)(C)c1cc(-c2cccc(-c3ccccc3)c2N2c3ccc(N(c4ccccc4)c4ccccc4)cc3B3c4cc(N(c5ccccc5)c5ccccc5)ccc4N(c4c(-c5ccccc5)cccc4-c4cc(C(C)(C)C)cc(C(C)(C)C)c4)c4c3c2cc2ccccc42)cc(C(C)(C)C)c1 ; c1ccc(-c2cc3c(cc2-n2c4ccccc4c4ccccc42)B2c4cc(-n5c6ccccc6c6ccccc65)c(-c5ccccc5)cc4N(c4c(-c5ccccc5)cccc4-c4ccccc4)c4c2c(cc2ccccc42)N3c2c(-c3ccccc3)cccc2-c2ccccc2)cc1]

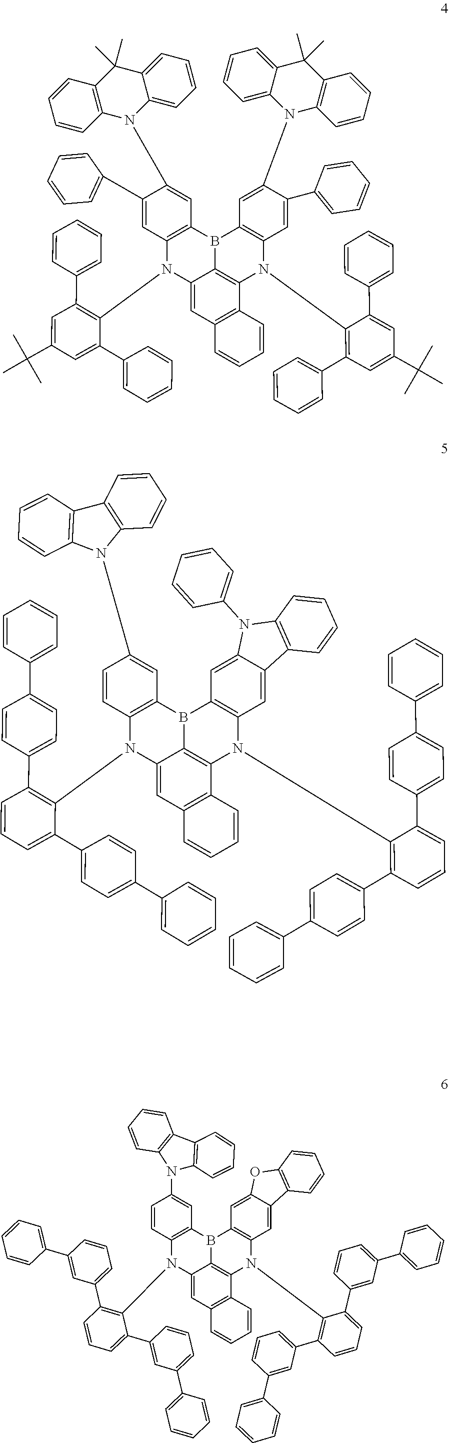

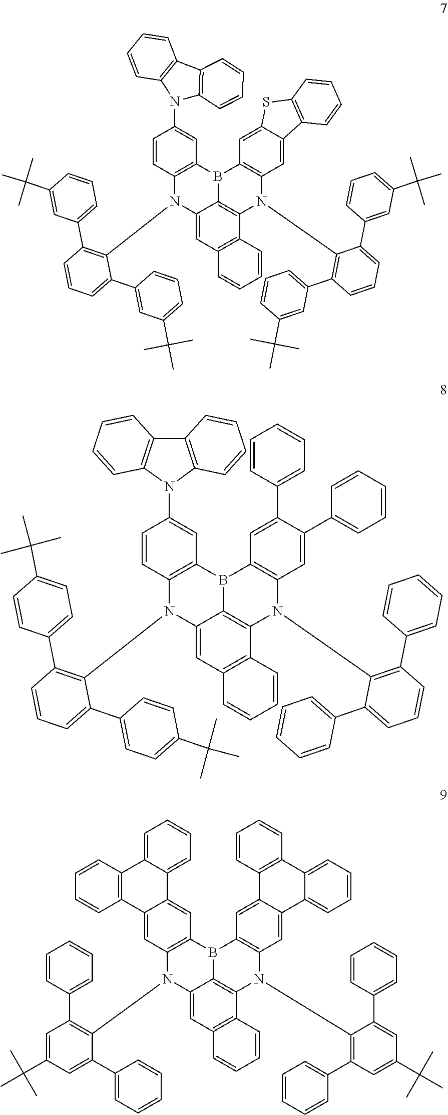

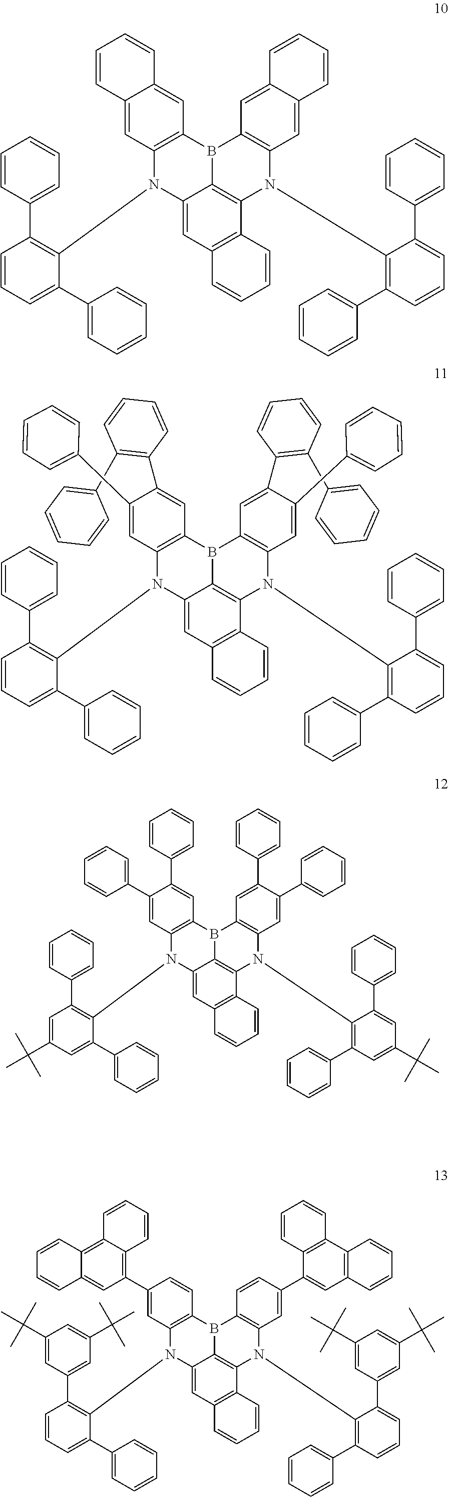

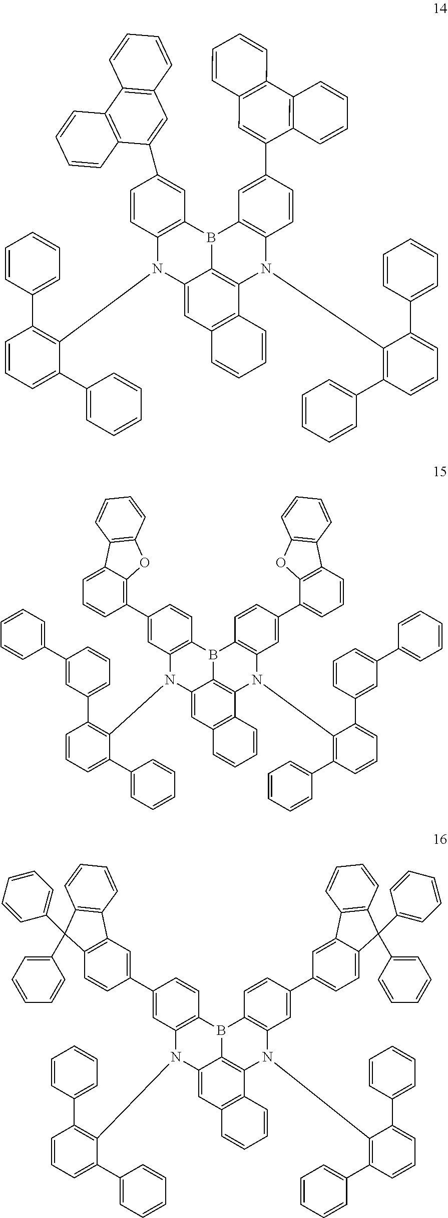 [SMILES: c1ccc(-c2cccc(-c3ccccc3)c2N2c3ccc(-c4cc5ccccc5c5ccccc45)cc3B3c4cc(-c5cc6ccccc6c6ccccc56)ccc4N(c4c(-c5ccccc5)cccc4-c4ccccc4)c4c3c2cc2ccccc42)cc1 ; c1ccc(-c2cccc(-c3cccc(-c4ccccc4)c3N3c4cc(-c5cccc6c5oc5ccccc56)ccc4B4c5ccc(-c6cccc7c6oc6ccccc67)cc5N(c5c(-c6ccccc6)cccc5-c5cccc(-c6ccccc6)c5)c5c4c3cc3ccccc53)c2)cc1 ; c1ccc(-c2cccc(-c3ccccc3)c2N2c3cc(-c4ccc5c(c4)-c4ccccc4C5(c4ccccc4)c4ccccc4)ccc3B3c4ccc(-c5ccc6c(c5)-c5ccccc5C6(c5ccccc5)c5ccccc5)cc4N(c4c(-c5ccccc5)cccc4-c4ccccc4)c4c3c2cc2ccccc42)cc1]

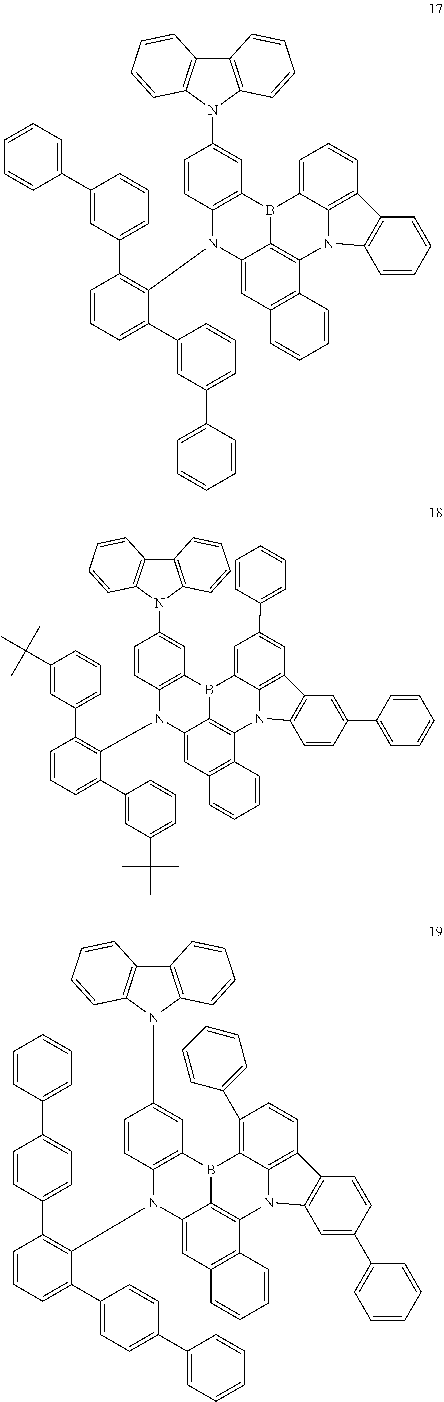 [SMILES: c1ccc(-c2cccc(-c3cccc(-c4cccc(-c5ccccc5)c4)c3N3c4ccc(-n5c6ccccc6c6ccccc65)cc4B4c5c3cc3ccccc3c5-n3c5ccccc5c5cccc4c53)c2)cc1 ; CC(C)(C)c1cccc(-c2cccc(-c3cccc(C(C)(C)C)c3)c2N2c3ccc(-n4c5ccccc5c5ccccc54)cc3B3c4c2cc2ccccc2c4-n2c4ccc(-c5ccccc5)cc4c4cc(-c5ccccc5)cc3c42)c1 ; c1ccc(-c2ccc(-c3cccc(-c4ccc(-c5ccccc5)cc4)c3N3c4ccc(-n5c6ccccc6c6ccccc65)cc4B4c5c3cc3ccccc3c5-n3c5cc(-c6ccccc6)ccc5c5ccc(-c6ccccc6)c4c53)cc2)cc1]

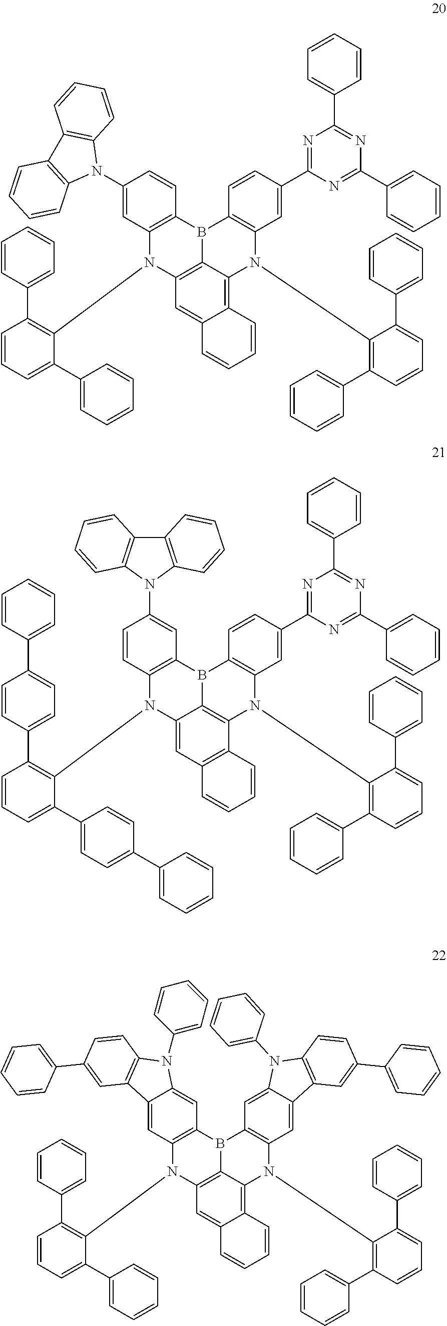

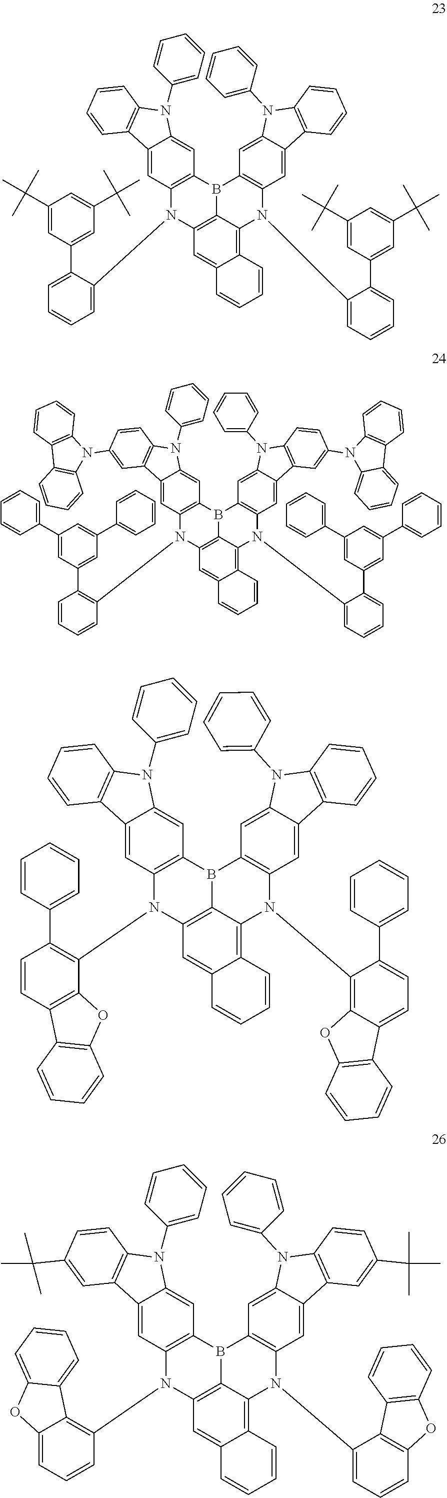

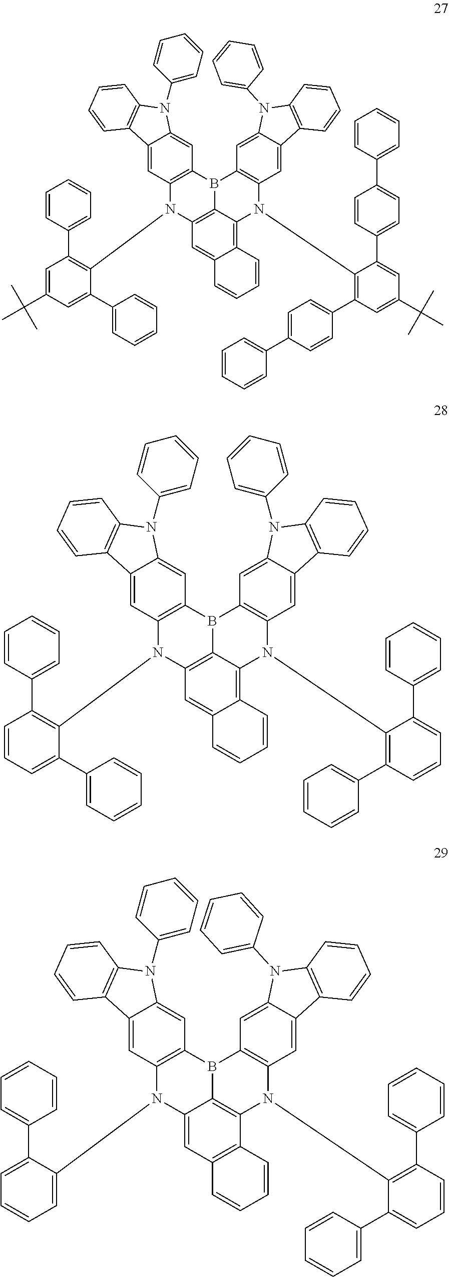 [SMILES: CC(C)(C)c1cc(-c2ccccc2)c(N2c3cc4c5ccccc5n(-c5ccccc5)c4cc3B3c4cc5c(cc4N(c4c(-c6ccc(-c7ccccc7)cc6)cc(C(C)(C)C)cc4-c4ccc(-c6ccccc6)cc4)c4c3c2cc2ccccc42)c2ccccc2n5-c2ccccc2)c(-c2ccccc2)c1 ; c1ccc(-c2cccc(-c3ccccc3)c2N2c3cc4c5ccccc5n(-c5ccccc5)c4cc3B3c4cc5c(cc4N(c4c(-c6ccccc6)cccc4-c4ccccc4)c4c3c2cc2ccccc42)c2ccccc2n5-c2ccccc2)cc1 ; c1ccc(-c2ccccc2N2c3cc4c5ccccc5n(-c5ccccc5)c4cc3B3c4cc5c(cc4N(c4c(-c6ccccc6)cccc4-c4ccccc4)c4c3c2cc2ccccc42)c2ccccc2n5-c2ccccc2)cc1]

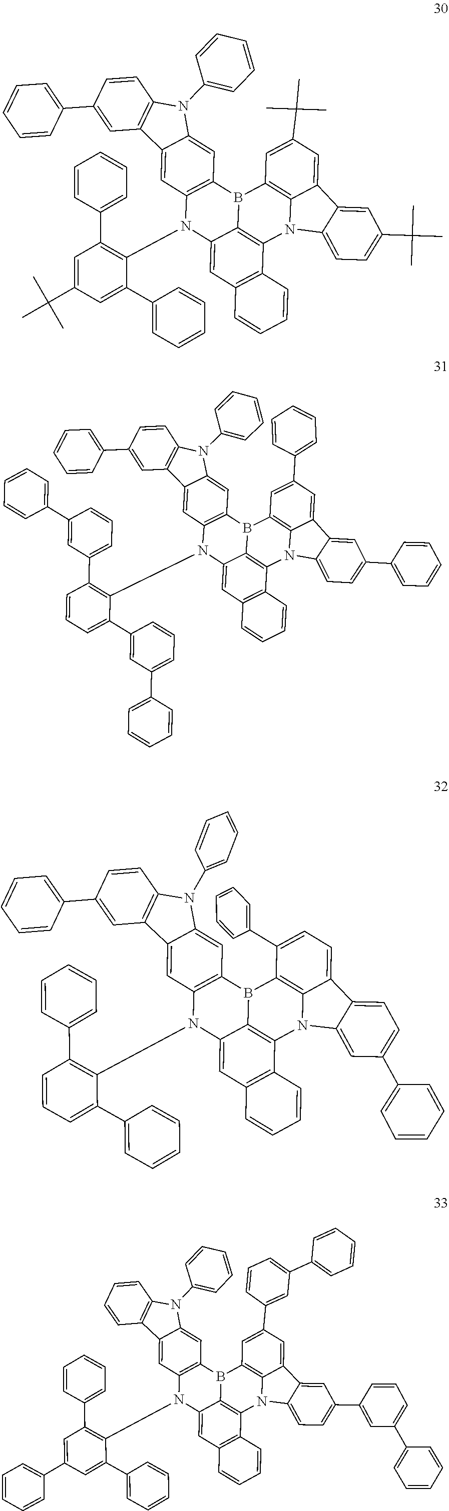

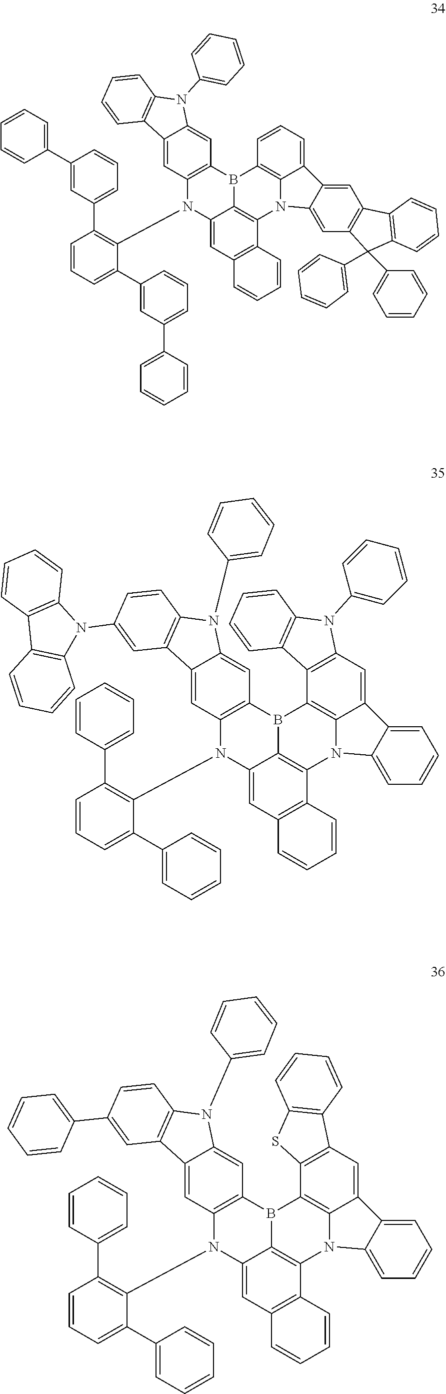 [SMILES: c1ccc(-c2cccc(-c3cccc(-c4cccc(-c5ccccc5)c4)c3N3c4cc5c6ccccc6n(-c6ccccc6)c5cc4B4c5c3cc3ccccc3c5-n3c5cc6c(cc5c5cccc4c53)-c3ccccc3C6(c3ccccc3)c3ccccc3)c2)cc1 ; c1ccc(-c2cccc(-c3ccccc3)c2N2c3cc4c5cc(-n6c7ccccc7c7ccccc76)ccc5n(-c5ccccc5)c4cc3B3c4c2cc2ccccc2c4-n2c4ccccc4c4cc5c(c3c42)c2ccccc2n5-c2ccccc2)cc1 ; c1ccc(-c2ccc3c(c2)c2cc4c(cc2n3-c2ccccc2)B2c3c(cc5ccccc5c3-n3c5ccccc5c5cc6c(sc7ccccc76)c2c53)N4c2c(-c3ccccc3)cccc2-c2ccccc2)cc1]

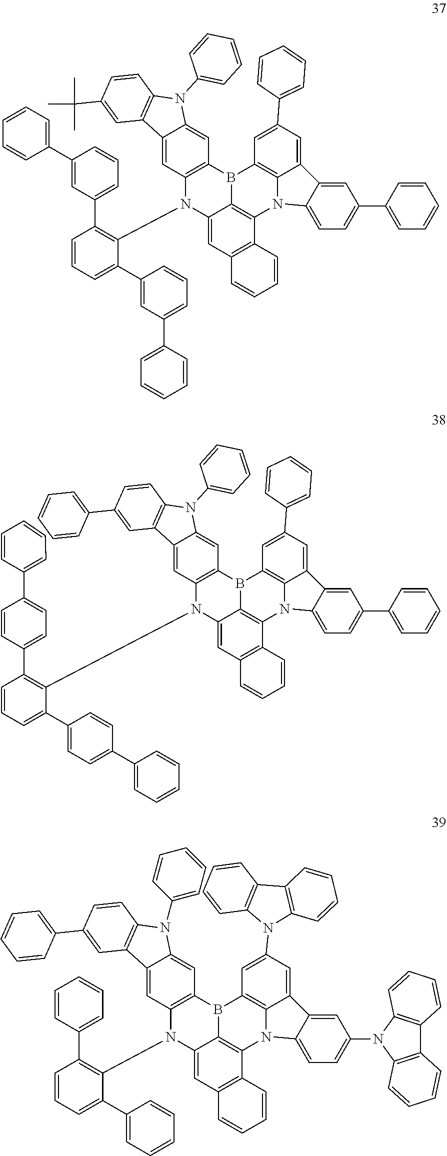 [SMILES: CC(C)(C)c1ccc2c(c1)c1cc3c(cc1n2-c1ccccc1)B1c2c(cc4ccccc4c2-n2c4ccc(-c5ccccc5)cc4c4cc(-c5ccccc5)cc1c42)N3c1c(-c2cccc(-c3ccccc3)c2)cccc1-c1cccc(-c2ccccc2)c1 ; c1ccc(-c2ccc(-c3cccc(-c4ccc(-c5ccccc5)cc4)c3N3c4cc5c6cc(-c7ccccc7)ccc6n(-c6ccccc6)c5cc4B4c5c3cc3ccccc3c5-n3c5ccc(-c6ccccc6)cc5c5cc(-c6ccccc6)cc4c53)cc2)cc1 ; c1ccc(-c2ccc3c(c2)c2cc4c(cc2n3-c2ccccc2)B2c3c(cc5ccccc5c3-n3c5ccc(-n6c7ccccc7c7ccccc76)cc5c5cc(-n6c7ccccc7c7ccccc76)cc2c53)N4c2c(-c3ccccc3)cccc2-c2ccccc2)cc1]

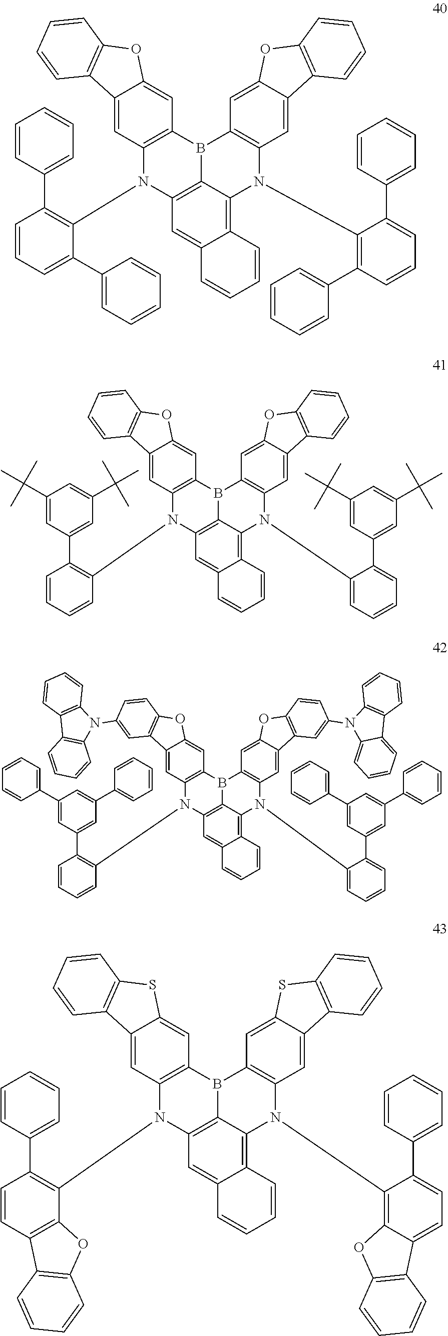

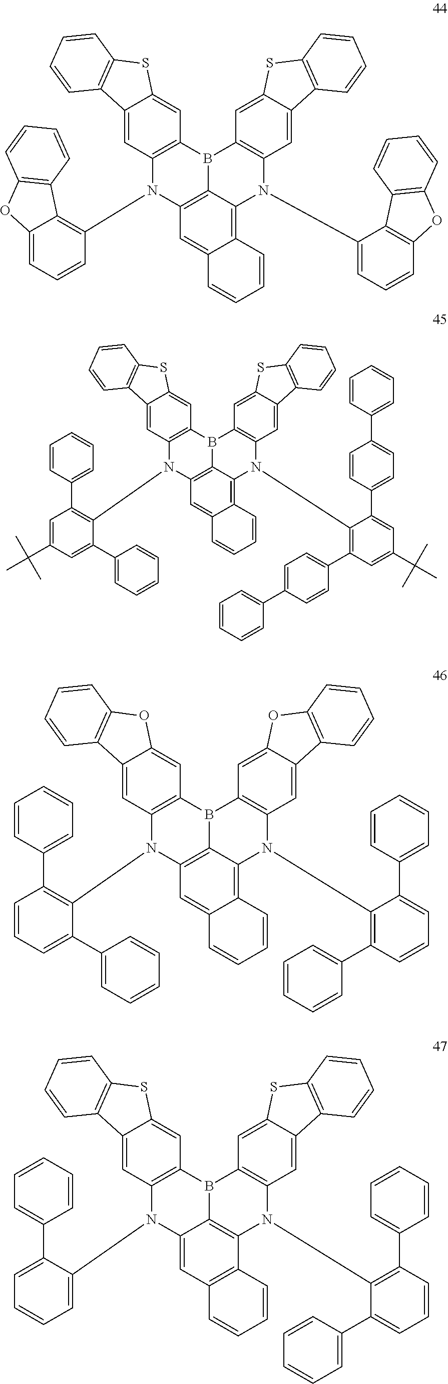

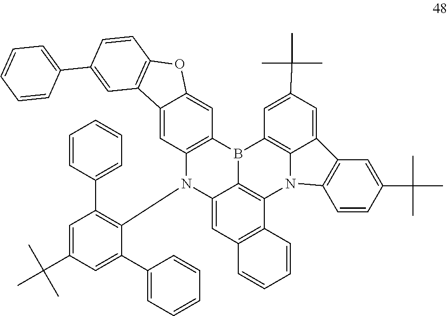 [SMILES: CC(C)(C)c1cc(-c2ccccc2)c(N2c3cc4c(cc3B3c5c2cc2ccccc2c5-n2c5ccc(C(C)(C)C)cc5c5cc(C(C)(C)C)cc3c52)oc2ccc(-c3ccccc3)cc24)c(-c2ccccc2)c1]

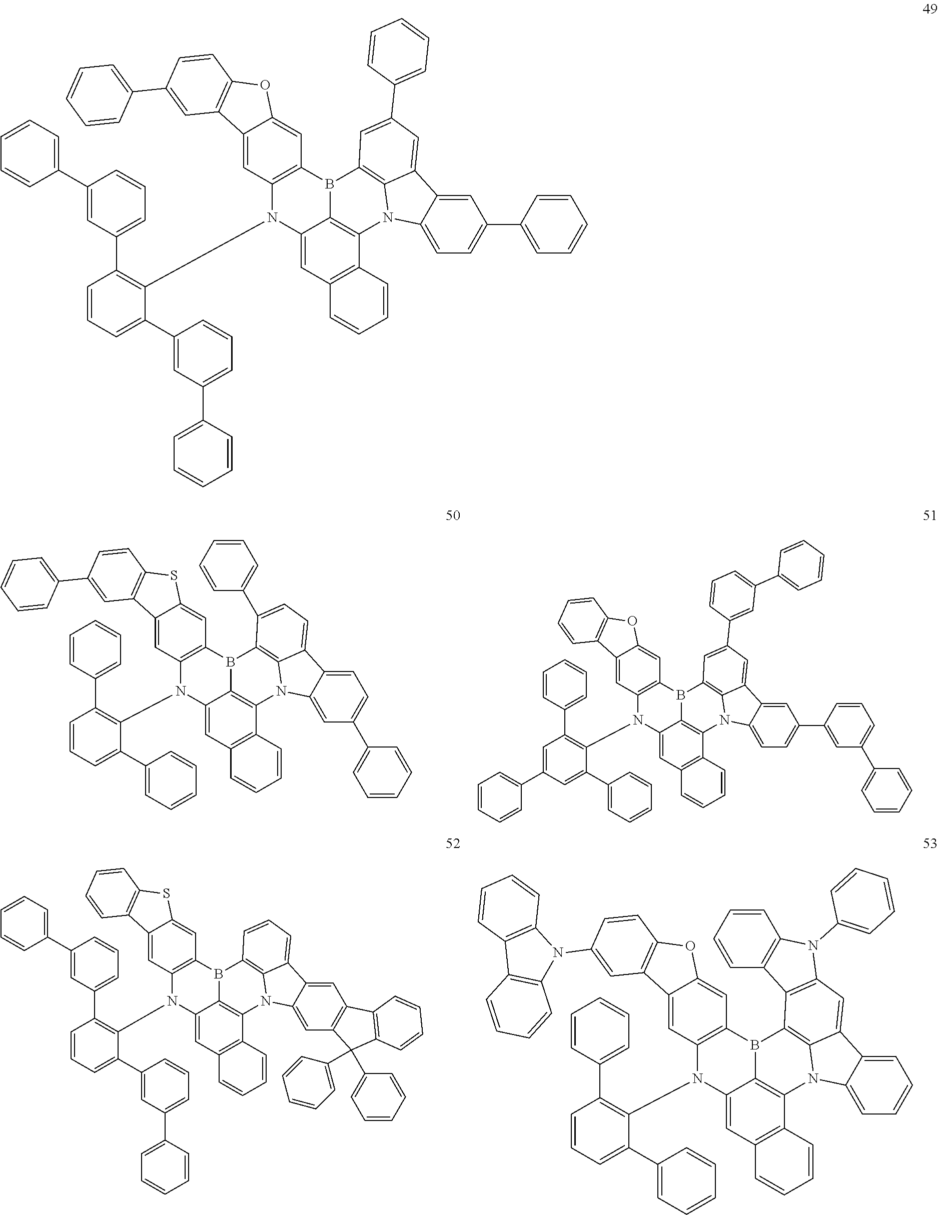

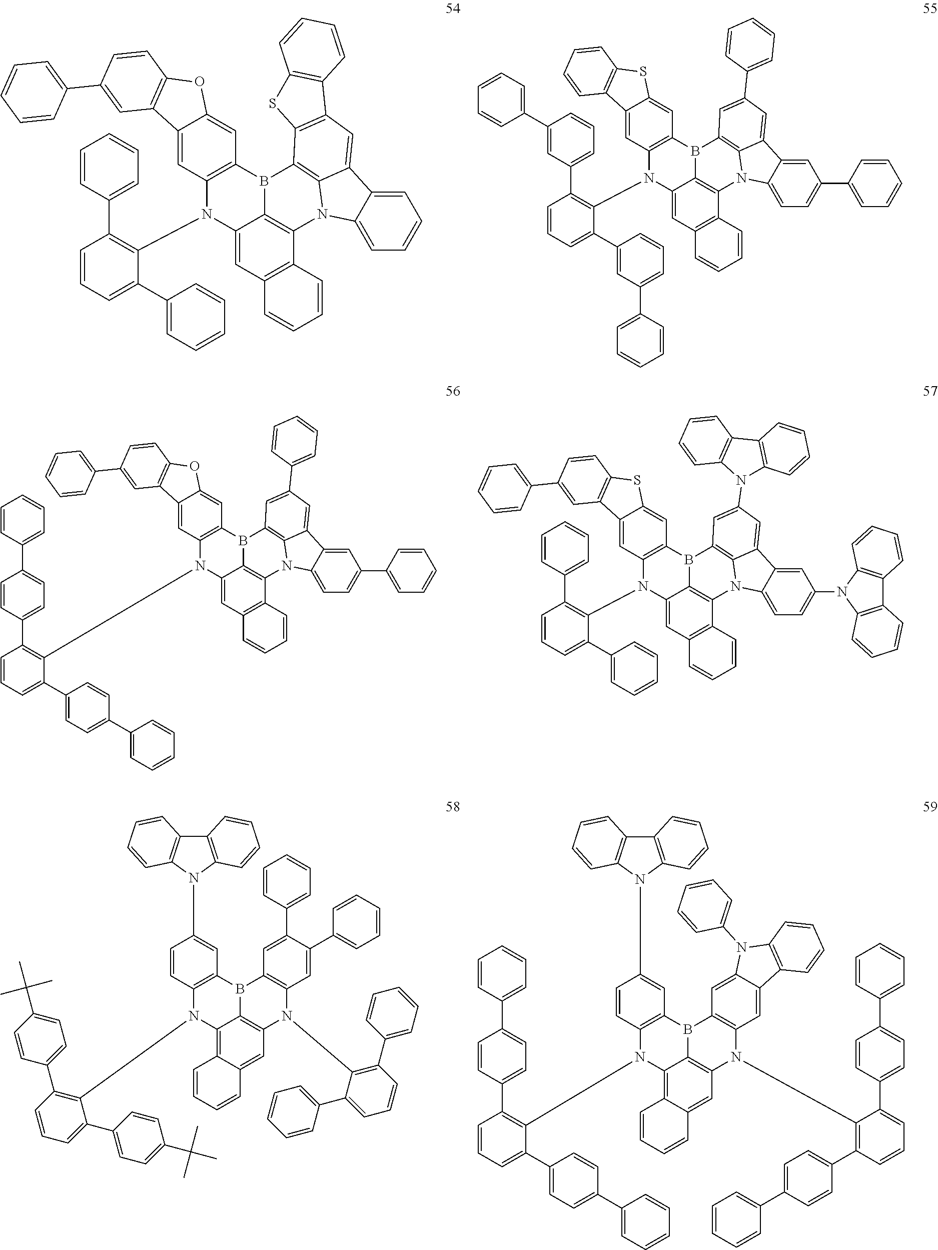

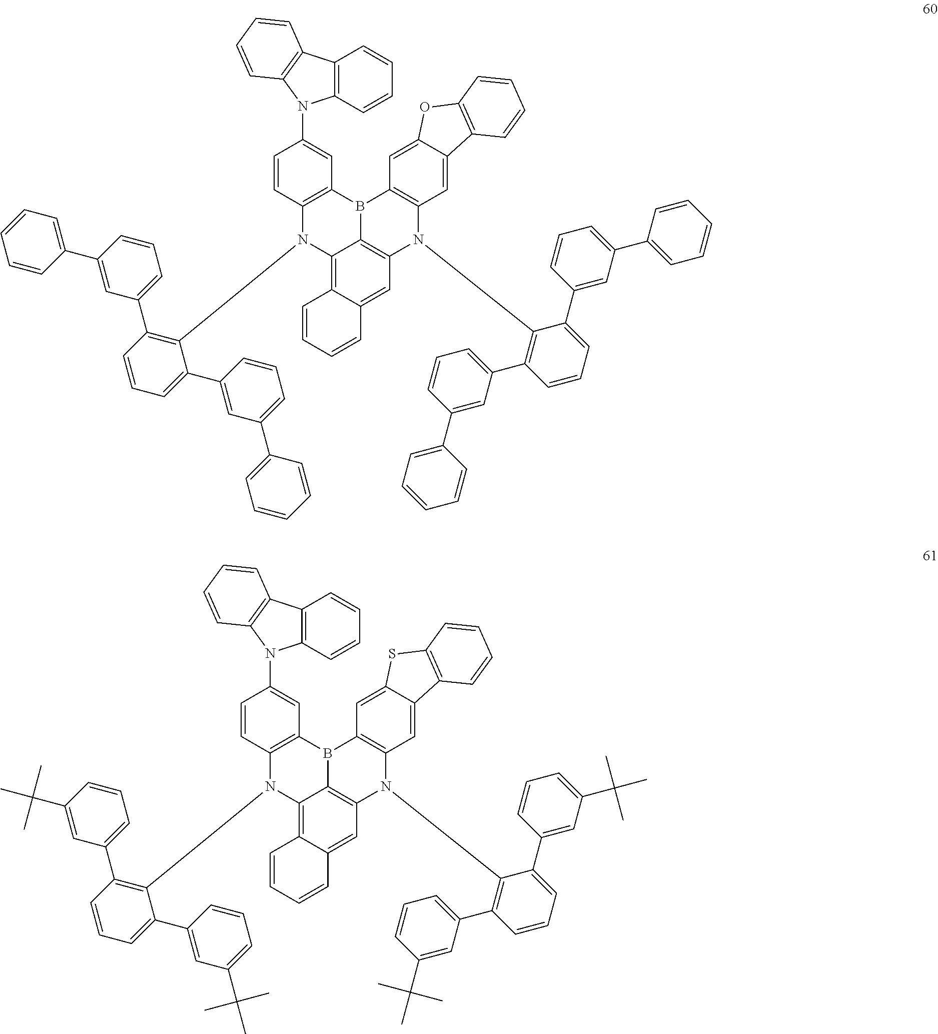 [SMILES: c1ccc(-c2cccc(-c3cccc(-c4cccc(-c5ccccc5)c4)c3N3c4cc5c(cc4B4c6cc(-n7c8ccccc8c8ccccc87)ccc6N(c6c(-c7cccc(-c8ccccc8)c7)cccc6-c6cccc(-c7ccccc7)c6)c6c4c3cc3ccccc63)oc3ccccc35)c2)cc1 ; CC(C)(C)c1cccc(-c2cccc(-c3cccc(C(C)(C)C)c3)c2N2c3cc4c(cc3B3c5cc(-n6c7ccccc7c7ccccc76)ccc5N(c5c(-c6cccc(C(C)(C)C)c6)cccc5-c5cccc(C(C)(C)C)c5)c5c3c2cc2ccccc52)sc2ccccc24)c1]

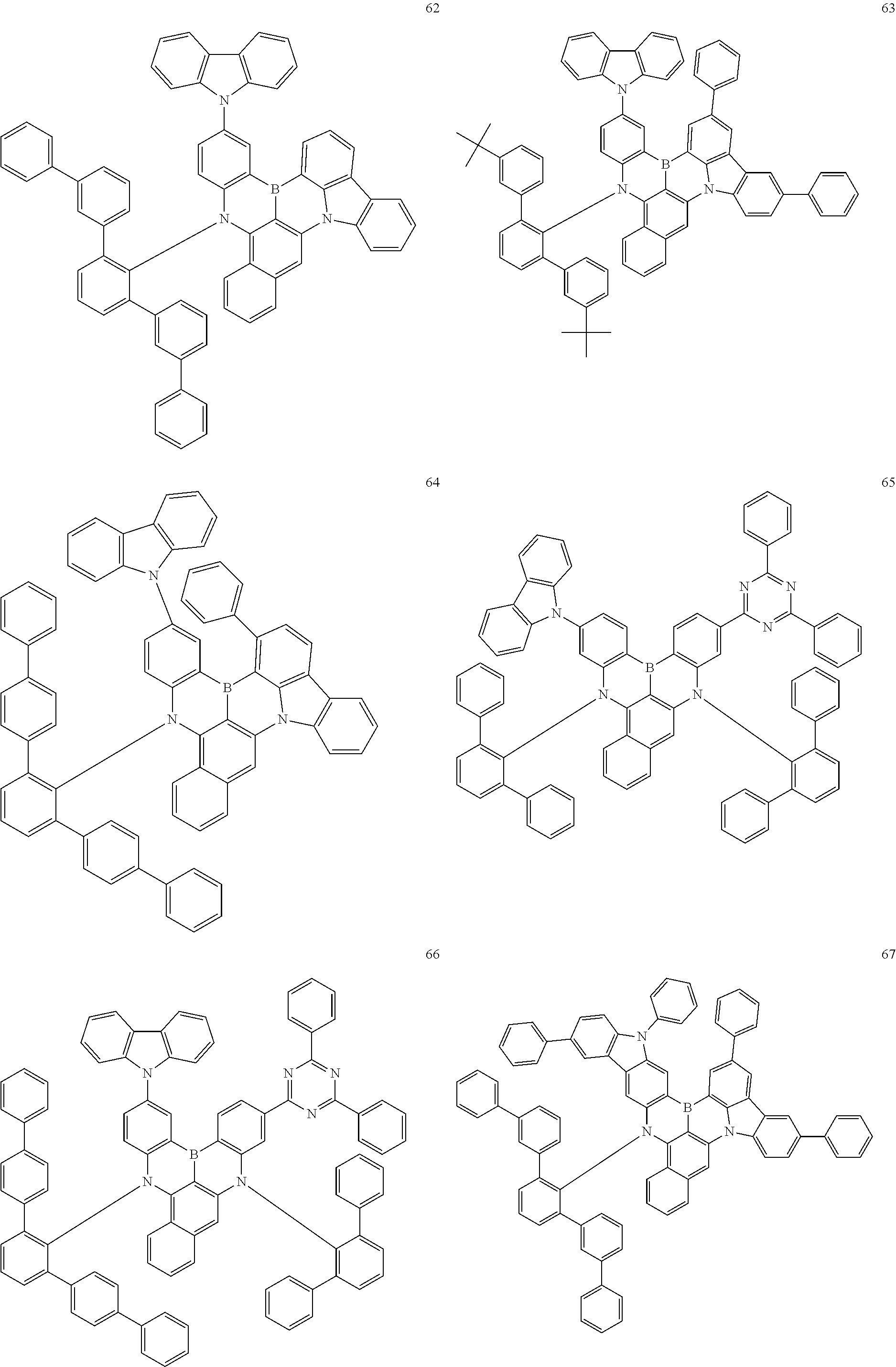

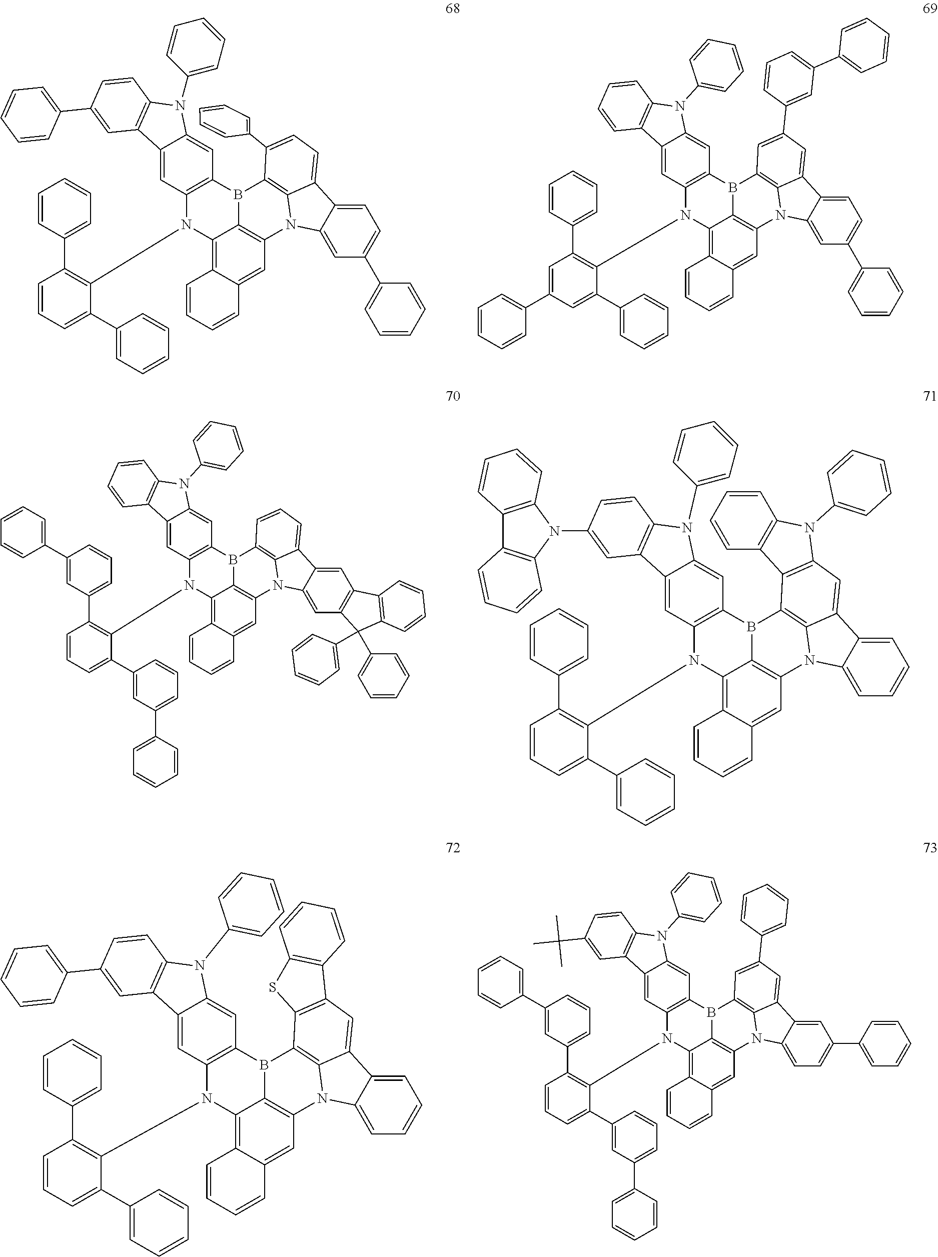

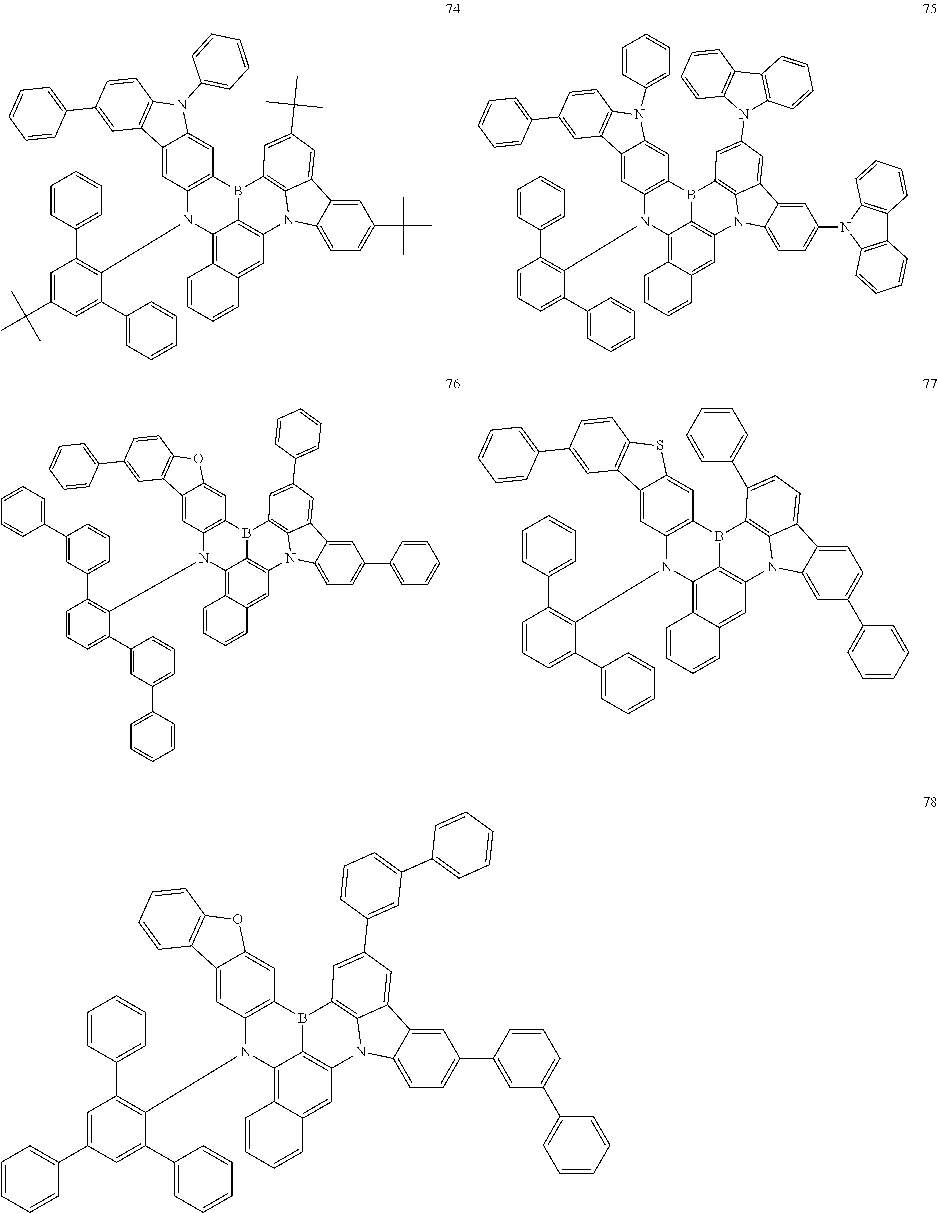

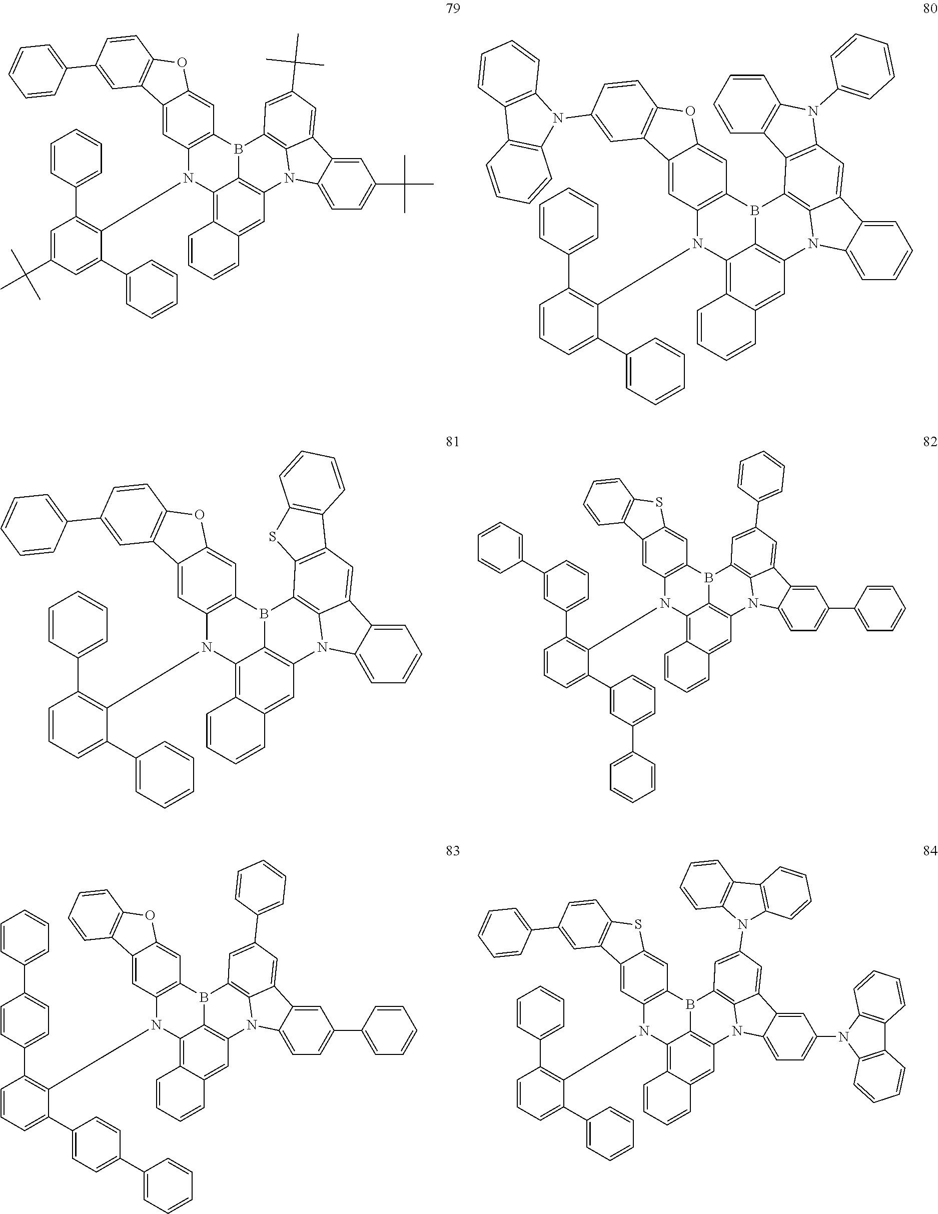

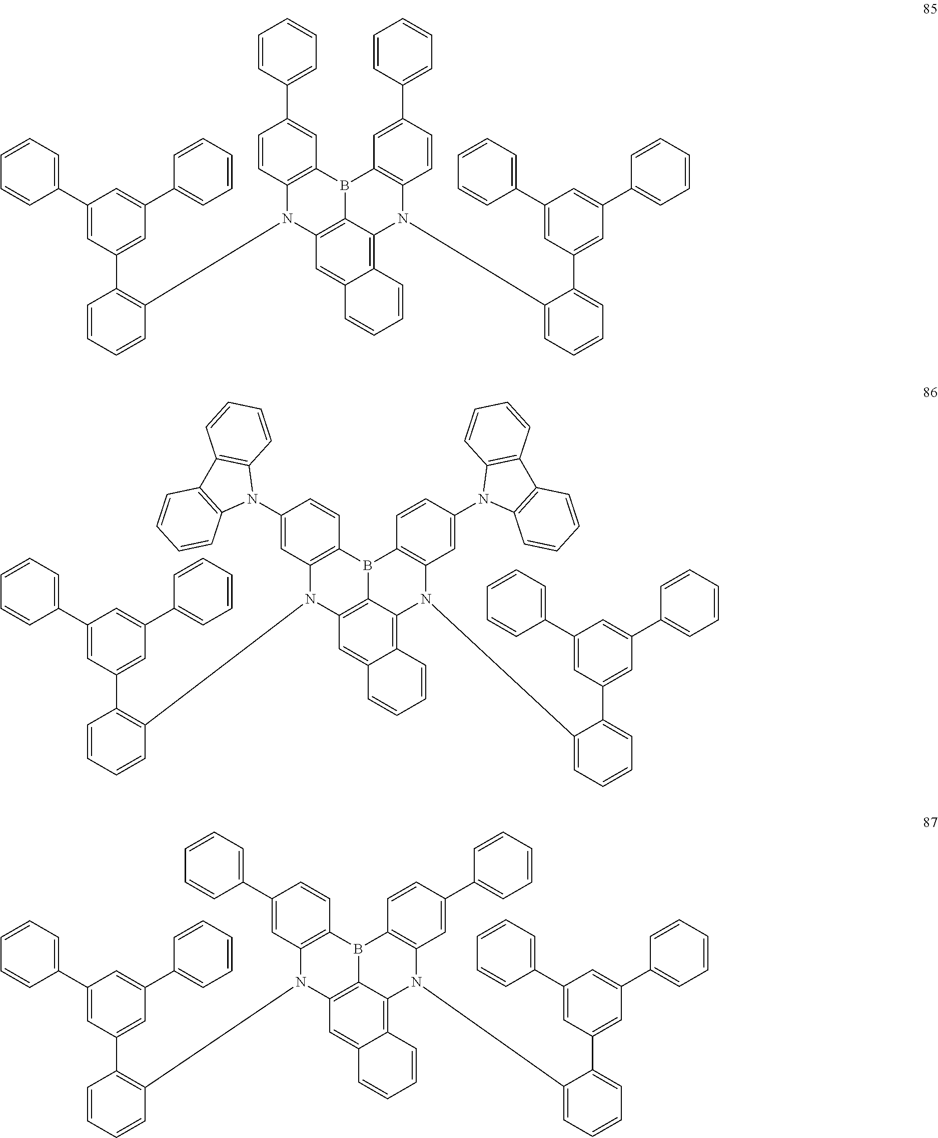 [SMILES: c1ccc(-c2cc(-c3ccccc3)cc(-c3ccccc3N3c4ccc(-c5ccccc5)cc4B4c5cc(-c6ccccc6)ccc5N(c5ccccc5-c5cc(-c6ccccc6)cc(-c6ccccc6)c5)c5c4c3cc3ccccc53)c2)cc1 ; c1ccc(-c2cc(-c3ccccc3)cc(-c3ccccc3N3c4cc(-n5c6ccccc6c6ccccc65)ccc4B4c5ccc(-n6c7ccccc7c7ccccc76)cc5N(c5ccccc5-c5cc(-c6ccccc6)cc(-c6ccccc6)c5)c5c4c3cc3ccccc53)c2)cc1 ; c1ccc(-c2cc(-c3ccccc3)cc(-c3ccccc3N3c4cc(-c5ccccc5)ccc4B4c5ccc(-c6ccccc6)cc5N(c5ccccc5-c5cc(-c6ccccc6)cc(-c6ccccc6)c5)c5c4c3cc3ccccc53)c2)cc1]

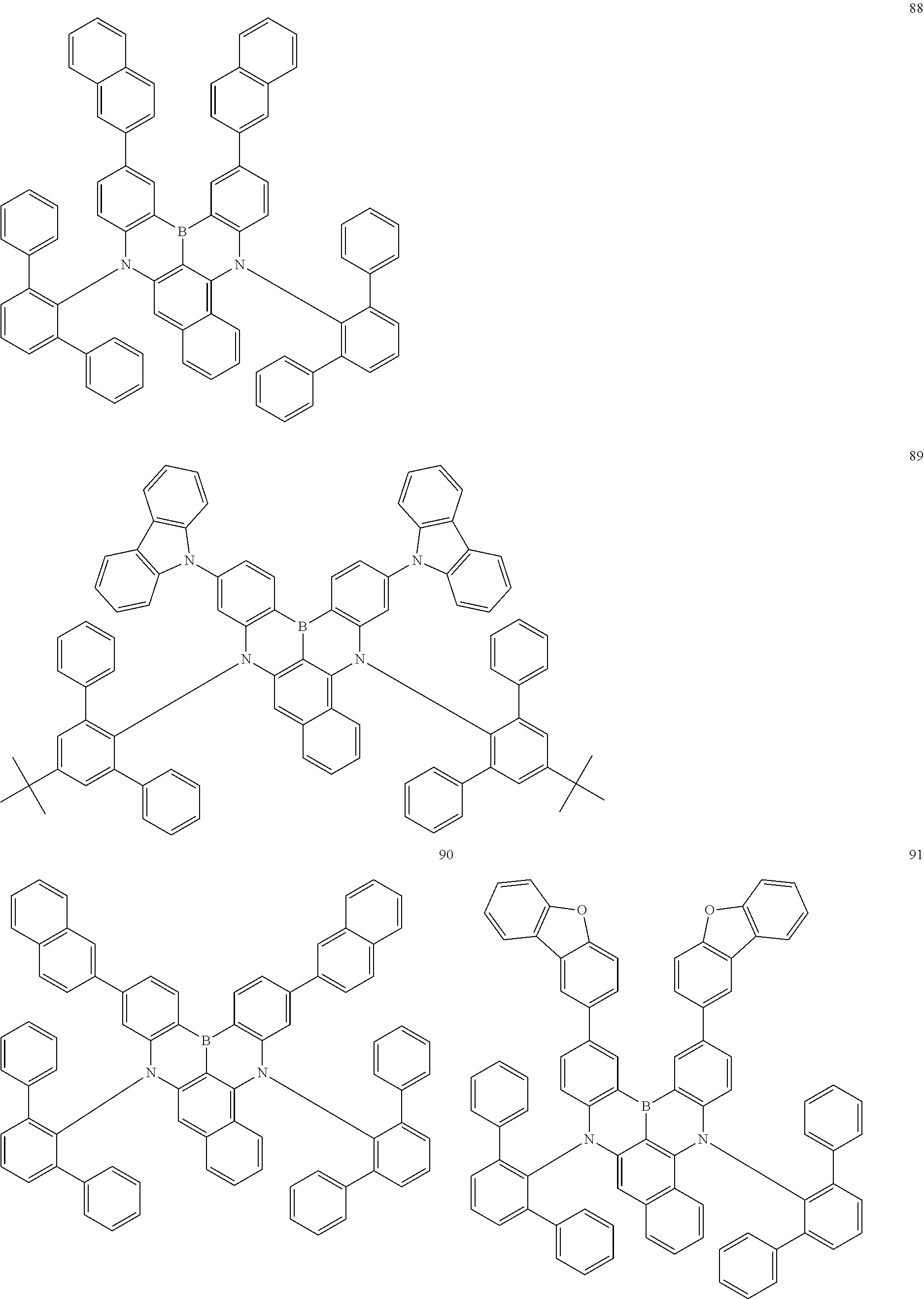

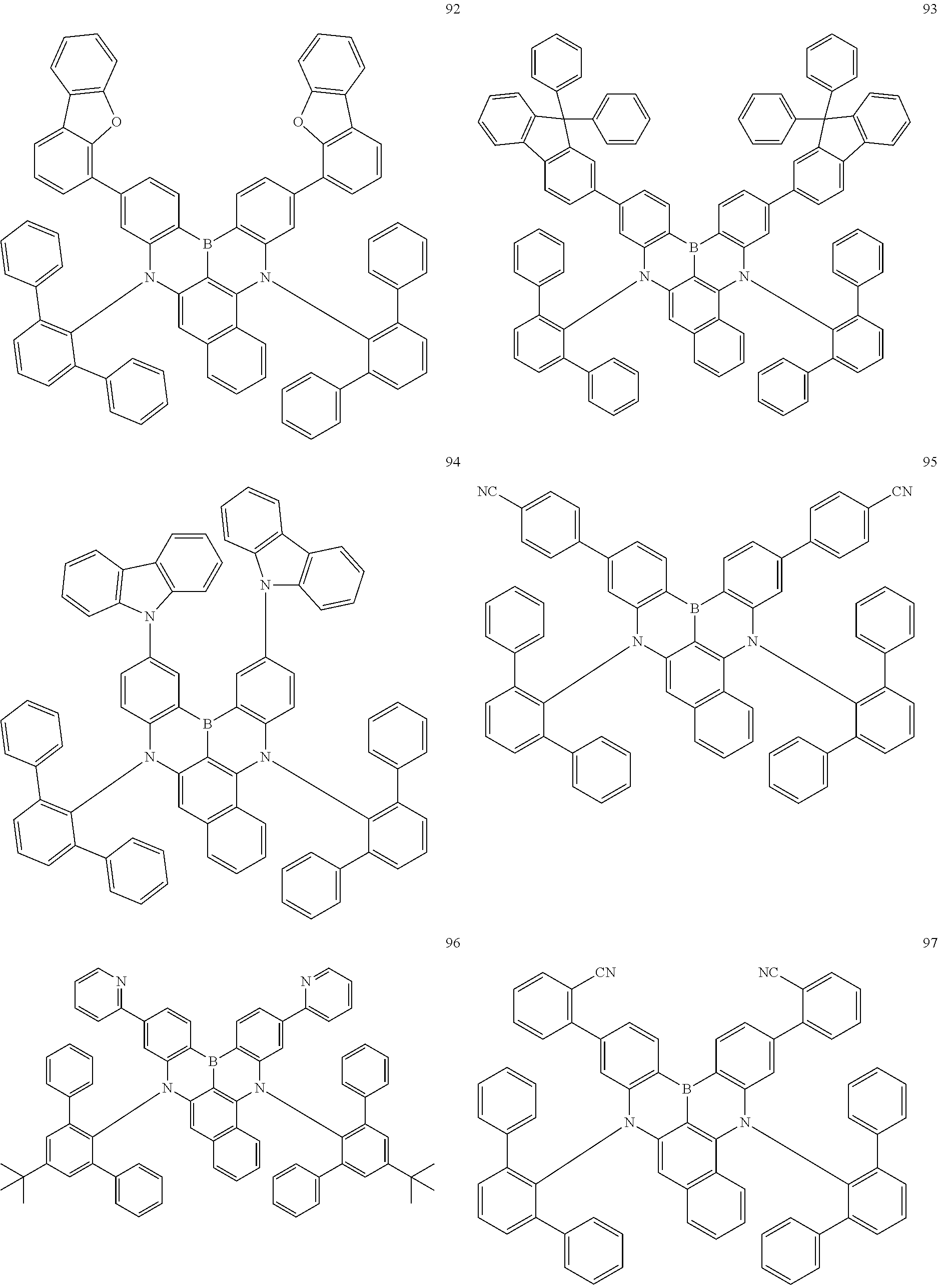

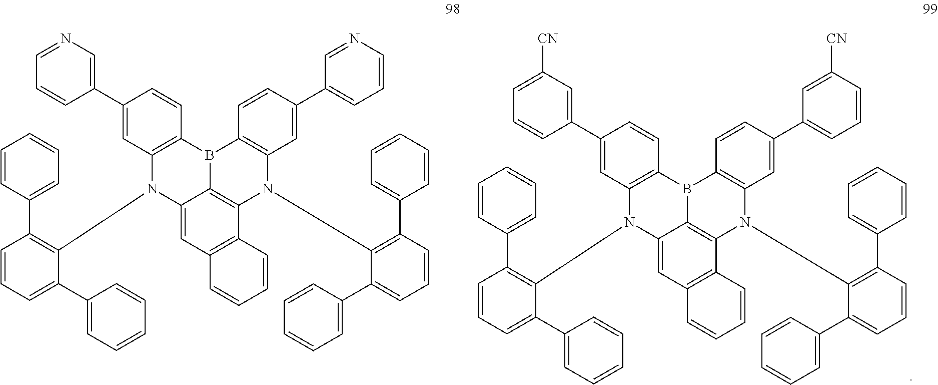 [SMILES: c1ccc(-c2cccc(-c3ccccc3)c2N2c3cc(-c4cccnc4)ccc3B3c4ccc(-c5cccnc5)cc4N(c4c(-c5ccccc5)cccc4-c4ccccc4)c4c3c2cc2ccccc42)cc1 ; N#Cc1cccc(-c2ccc3c(c2)N(c2c(-c4ccccc4)cccc2-c2ccccc2)c2cc4ccccc4c4c2B3c2ccc(-c3cccc(C#N)c3)cc2N4c2c(-c3ccccc3)cccc2-c2ccccc2)c1]

The fused polycyclic compound represented by Formula 1 has a structure in which a first aromatic hydrocarbon ring is fused with a first benzene ring, and thus, may contribute to high efficiency and long lifespan in a light emitting device.

The fused polycyclic compound includes a fused ring core in which five rings are fused with a boron atom, a first nitrogen atom, and a second nitrogen atom, thereby exhibiting multiple resonance in a wide plate-shaped skeleton, and thus, may readily separate states of highest occupied molecular orbital (HOMO) and lowest unoccupied molecular orbital (LUMO) in a molecule. Accordingly, the fused polycyclic compound may have a reduced difference (AEST) between a lowest triplet excitation energy level T1 level and a lowest singlet excitation energy level S1 level, and if used as a delayed fluorescence light emitting material, the luminous efficiency of a light emitting element may be further improved.

In the fused polycyclic compound according to an embodiment, the first aromatic hydrocarbon ring may be connected to a first benzene ring of the fused ring core to form an additional fused ring. In the fused polycyclic compound, the first aromatic hydrocarbon ring may be a substituted or unsubstituted benzene ring, and the benzene ring may be connected to the first benzene ring of the fused ring core to form a naphthalene ring. As the first aromatic hydrocarbon ring is connected to the fused ring core at a particular position to form the additional fused ring, the fused polycyclic compound may induce a red-shift of a molecule while maintaining high luminous efficiency and long lifespan properties.

The fused polycyclic compound has a structure to which the first aromatic hydrocarbon ring is fused, and thus, may adjust non-bonding molecular orbital properties and bonding molecular orbital properties in a molecule, and ultimately, has an advantage of simultaneously implementing a red-shift and high efficiency.

The fused polycyclic compound has a structure in which three benzene rings are fused with a boron atom having electron withdrawing properties, and has a structure in which two nitrogen atoms having electron donating properties are included as ring-forming atoms. Accordingly, the fused polycyclic compound may maintain, at the fused ring core thereof, non-bonding properties of multiple resonance in which HOMO and LUMO are distributed on an atomic nucleus. The fused polycyclic compound has a structure to which the first aromatic hydrocarbon ring is additionally fused, and thus, may induce a red-shift due to bonding molecular orbital properties of the first aromatic hydrocarbon ring. For example, although the fused ring core maintains non-bonding properties of multiple resonance in which HOMO and LUMO are distributed on an atomic nucleus, the additionally fused first aromatic hydrocarbon ring is a conjugation region, thereby exhibiting bonding properties, which may result in inducing a red-shift. Therefore, the fused polycyclic compound may induce a red-shift of a molecule while maintaining high efficiency and long lifespan properties. For example, the fused polycyclic compound may contribute to high element efficiency and improved lifespan properties in a green light wavelength region.

The fused polycyclic compound may effectively maintain a trigonal planar structure of a boron atom through a steric hindrance effect by the first and second substituents. A boron atom has electron-deficient properties due to an empty p-orbital, and thus, may form a bond with another nucleophile to convert into a tetrahedral structure, which may cause element deterioration. In the fused polycyclic compound according to an embodiment, first and second substituents are bonded to the fused ring core, thereby effectively protecting an empty p-orbital of a boron atom, so that deterioration of a light emitting element due to structural deformation of the boron atom may be prevented.

The fused polycyclic compound is capable of controlling the formation of excimers or exciplexes by suppressing intermolecular interaction through a steric hindrance effect due to the introduction of the first and second substituents, so that luminous efficiency may be increased. The fused polycyclic compound represented by Formula 1 has a bulky structure, and thus, may reduce Dexter energy transfer by increasing intermolecular distance, and accordingly, it is possible to suppress an increase in the concentration of triplet excitons of the fused polycyclic compound. A high concentration of triplet exciton may remain in an excited state for a long period of time, and thus, may cause compound decomposition, and may cause structural deterioration of surrounding compounds by inducing the generation of hot excitons having high energy generated through triplet-triplet annihilation (TTA). Triplet-triplet annihilation is a bimolecular reaction which rapidly consumes triplet excitons used for emitting light, and thus, may cause degradation in luminous efficiency as non-radiative transition. In the fused polycyclic compound, intermolecular distance is increased by the first and second substituents, which may suppress Dexter energy transfer, so that it is possible to suppress lifespan deterioration caused by an increase in triplet concentration. Therefore, if the fused polycyclic compound is applied to a light emitting layer EML of a light emitting element ED, luminous efficiency may be increased, and the lifespan of the element may also be improved.

The fused polycyclic compound of an embodiment represented by Formula 1 may be a light emitting material having a central wavelength lₘₐₓ equal to or greater than about 500 nm. For example, the fused polycyclic compound represented by Formula 1 may be a light emitting material having a central wavelength lₘₐₓ equal to or greater than about 500 nm. The fused polycyclic compound represented by Formula 1 may be a green dopant. In the specification, a central wavelength lₘₐₓ of the fused polycyclic compound may refer to a peak wavelength of an emission spectrum representing the maximum emission intensity in an emission spectrum measured in a toluene solution.

In the light emitting element ED, the light emitting layer EML may include a host and a dopant, and may include, as the dopant, the fused polycyclic compound as described above. For example, in the light emitting element ED, the light emitting layer EML may include a host and a dopant, and may include, as a dopant for delayed fluorescence emission, the fused polycyclic compound as described above. For example, the light emitting layer EML may include at least one compound selected from Compound Group 1 as shown above as a thermally activated delayed fluorescence (TADF) dopant.

The emission spectrum of the fused polycyclic compound represented by Formula 1 may have a full width at half maximum (FWHM) in a range of about 10 nm to about 50 nm. For example, the emission spectrum of the fused polycyclic compound represented by Formula 1 may have an FWHM in a range of about 20 nm to about 40 nm. The emission spectrum of the fused polycyclic compound represented by Formula 1 may have an FWHM in any of the ranges described above and thus, when applied to the light emitting element ED, luminous efficiency may be improved. When the fused polycyclic compound represented by Formula 1 is used as a green light emitting material for a light emitting element, the lifespan of the light emitting element may be improved.

In an embodiment, the fused polycyclic compound represented by Formula 1 may be a thermally activated delayed fluorescence (TADF) light emitting material. The fused polycyclic compound represented by Formula 1 may be a thermally activated delayed fluorescence dopant having a difference (AEST) between a lowest triplet excitation energy level T1 level and a lowest singlet excitation energy level S1 level equal to or less than about 0.6 eV. For example, the fused polycyclic compound represented by Formula 1 may be a thermally activated delayed fluorescence dopant having a difference (ΔE_{ST}) between a lowest triplet excitation energy level T1 level and a lowest singlet excitation energy level S1 level equal to or less than about 0.2 eV. However, embodiments are not limited thereto.

In the light emitting element ED, the light emitting layer EML may emit delayed fluorescence light. For example, the light emitting layer EML may emit thermally activated delayed fluorescence (TADF).

The light emitting layer EML of the light emitting element ED may emit green light. For example, the light emitting layer EML of the light emitting element ED may emit green light in a wavelength range equal to or greater than about 490 nm. However, embodiments are not limited thereto, and the light emitting layer EML may emit blue light or red light.

The fused polycyclic compound according to an embodiment may be included in the light emitting layer EML. The fused polycyclic compound may be included in the light emitting layer EML as a dopant material. The fused polycyclic compound may be a thermally activated delayed fluorescence light emitting material. The fused polycyclic compound may be used as a thermally activated delayed fluorescence dopant. For example, in the light emitting element ED, the light emitting layer EML may include at least one compound selected from Compound Group 1 as a thermally activated delayed fluorescence dopant. However, a use of the fused polycyclic compound is not limited thereto.

In an embodiment, the light emitting layer EML may include multiple compounds. The light emitting layer EML may include the fused polycyclic compound represented by Formula 1 as a first compound, and may further include at least one of a second compound represented by Formula HT-1, a third compound represented by Formula ET-1, and a fourth compound represented by Formula D-1.

In an embodiment, the light emitting layer EML may include the first compound represented by Formula 1, and may further include at least one of a second compound represented by Formula HT-1 and a third compound represented by Formula ET-1.

In an embodiment, the light emitting layer EML may further include a second compound represented by Formula HT-1. In an embodiment, the second compound may be used as a hole transport host material in a light emitting layer EML:

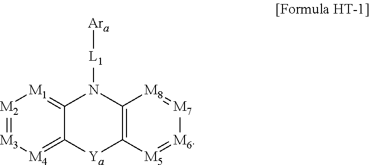

In Formula HT-1, M₁ to M₈ may each independently be N or C(R₅₁). For example, M₁ to M₈ may each independently be C(R₅₁). As another example, one of M₁ to M₈ may be N, and the remainder of M₁ to M₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom of Formula HT-1 may be connected to each other via a direct linkage,

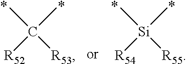

In Formula HT-1, if Yₐ is a direct linkage, the second compound represented by Formula HT-1 may include a carbazole moiety.

In Formula HT-1, Arₐ may be a substituted or unsubstituted aryl group having 6 to 30 ring-forming carbon atoms or a substituted or unsubstituted heteroaryl group having 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. As another example, R₅₁ to R₅₅ may each independently be an unsubstituted methyl group or an unsubstituted phenyl group.

In an embodiment, the second compound represented by Formula HT-1 may be selected from Compound Group 2. In an embodiment, in light emitting element ED, the second compound may include at least one compound selected from Compound Group 2:

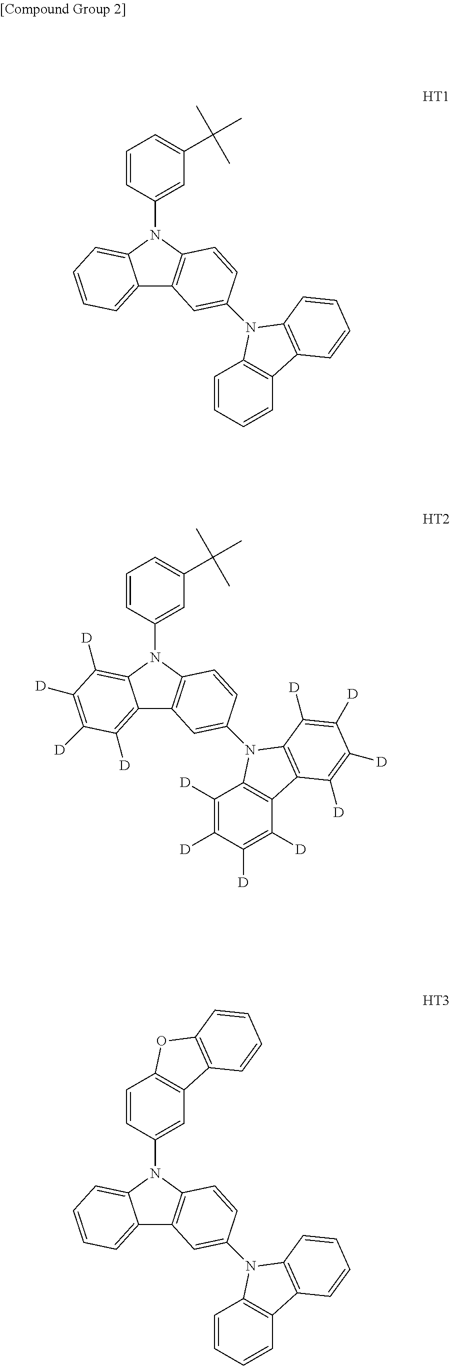 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

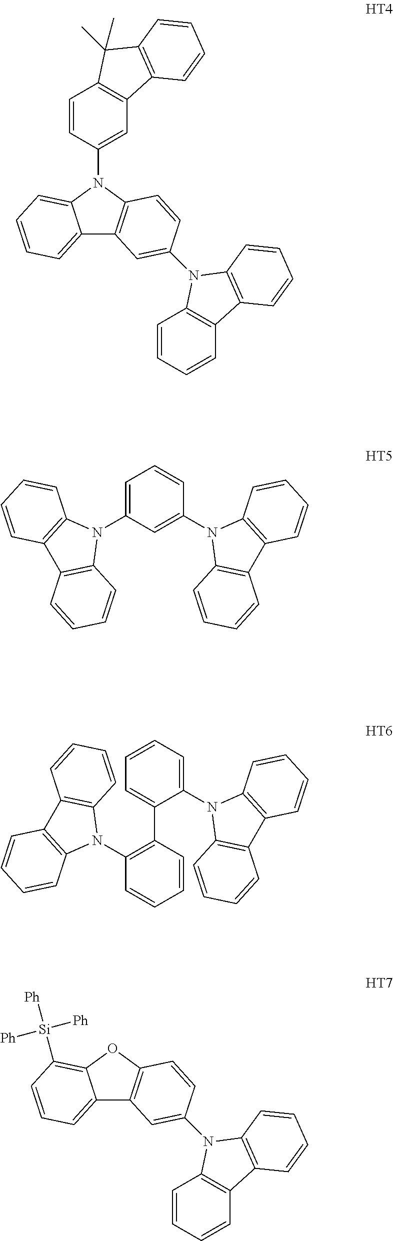 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

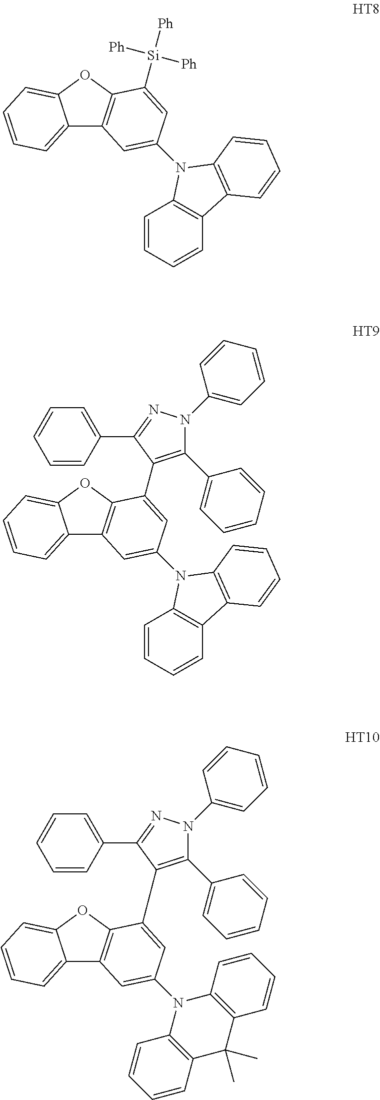 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

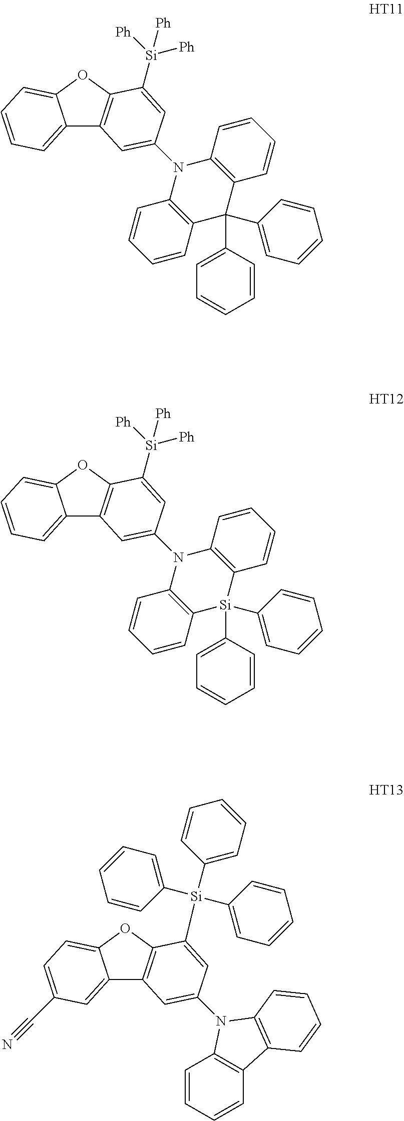 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

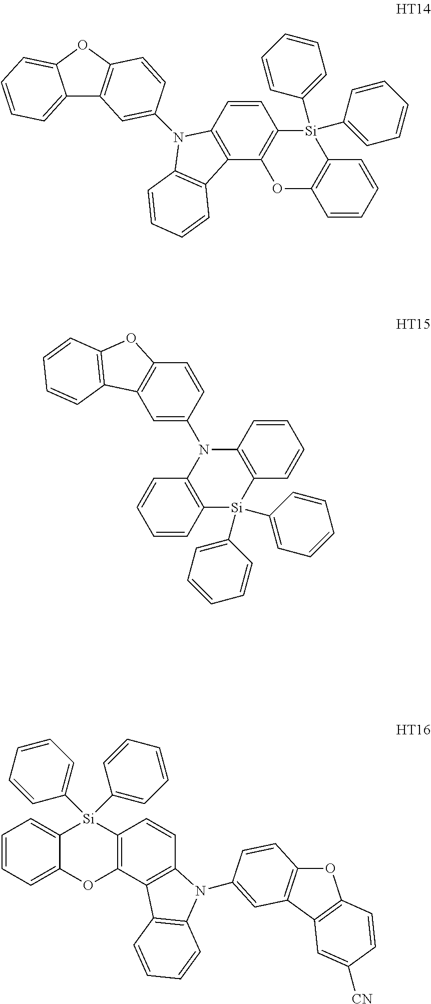 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

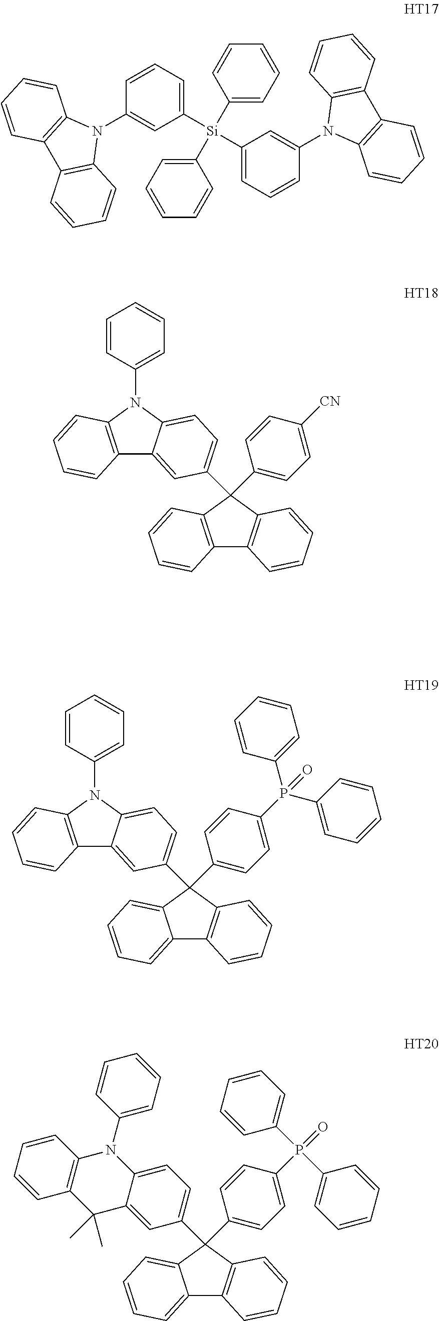 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

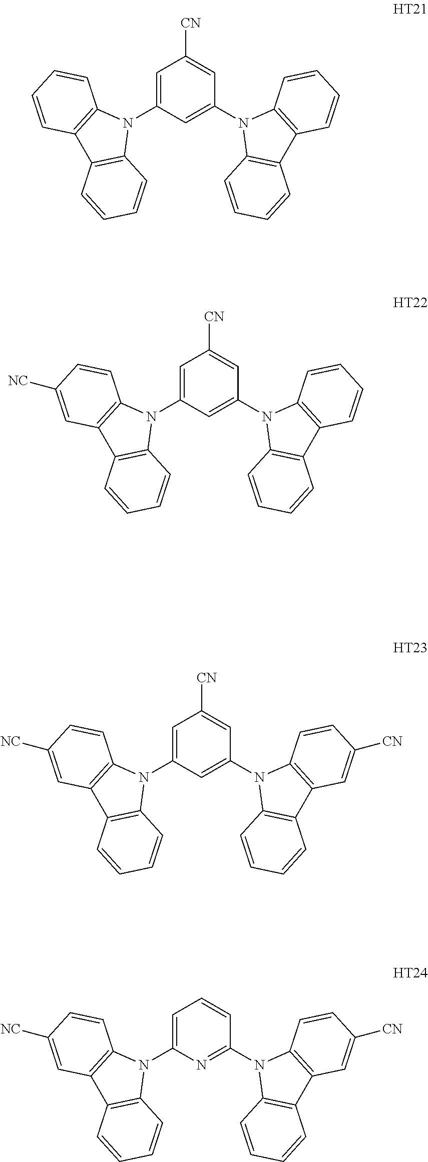 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

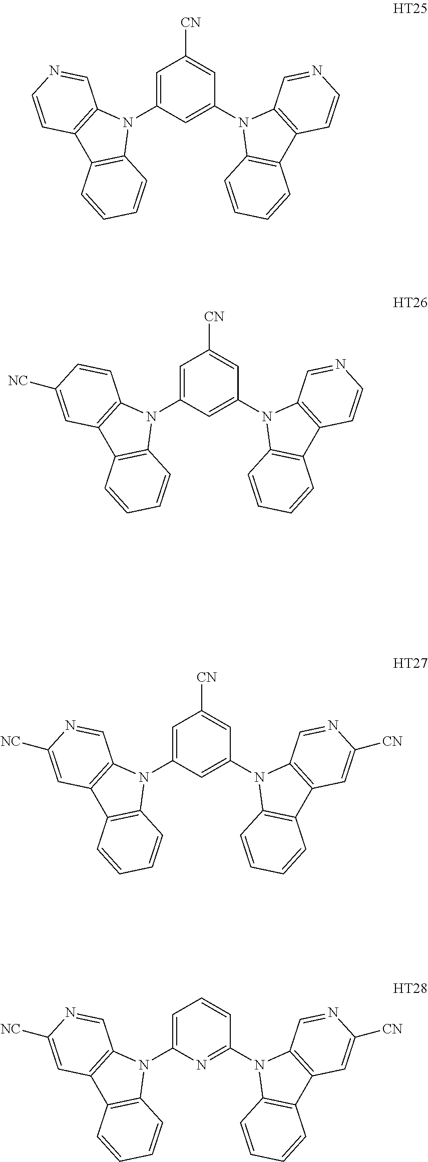 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

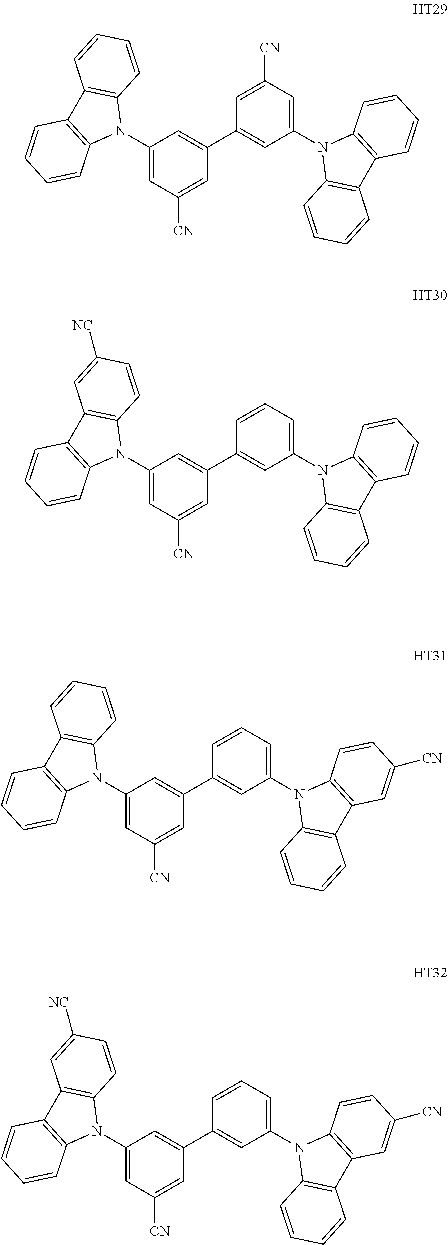 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

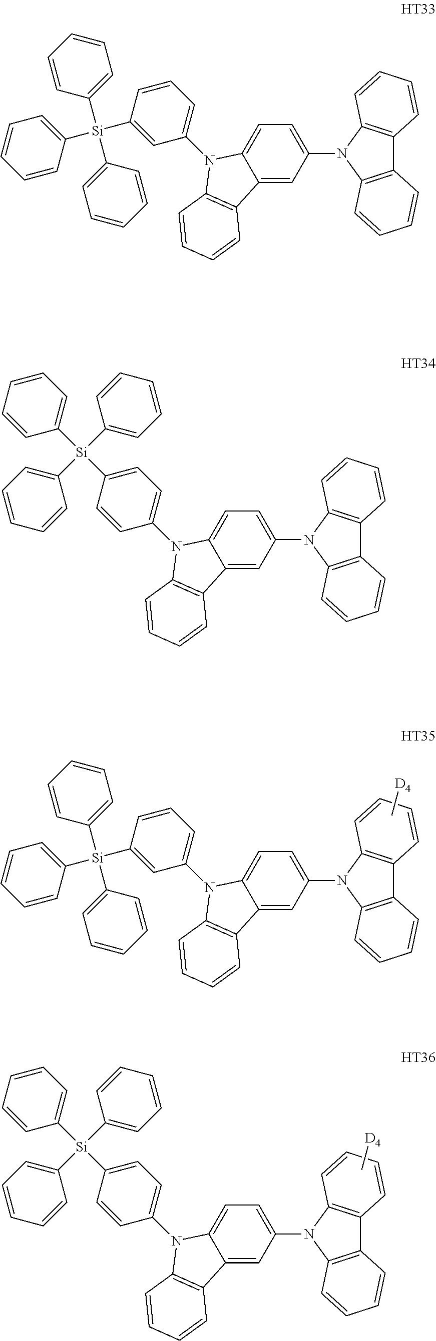

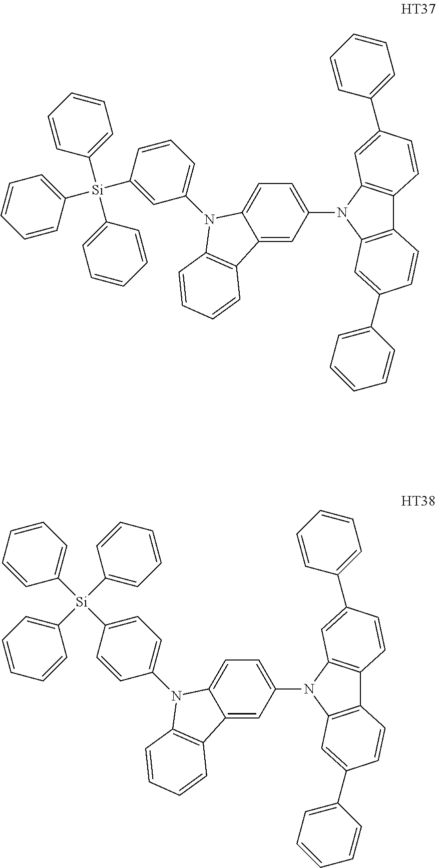 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

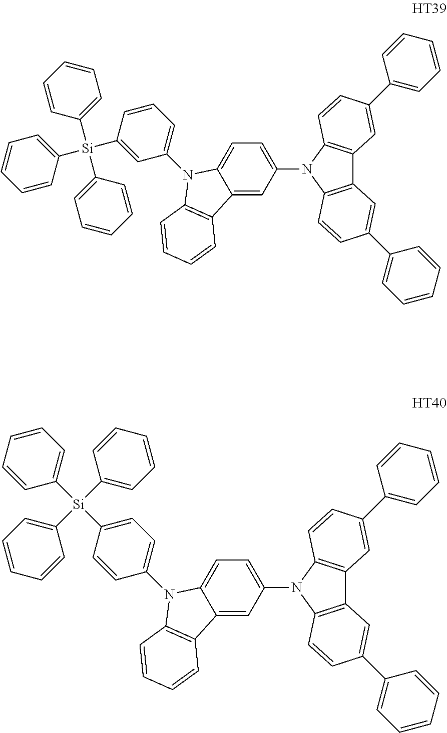 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

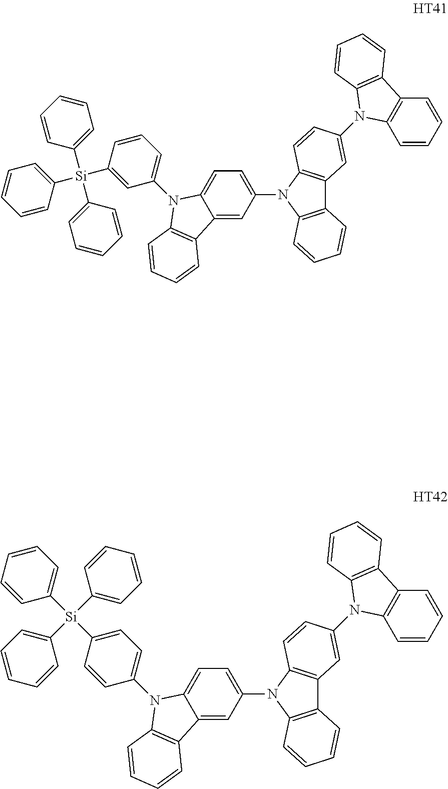 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

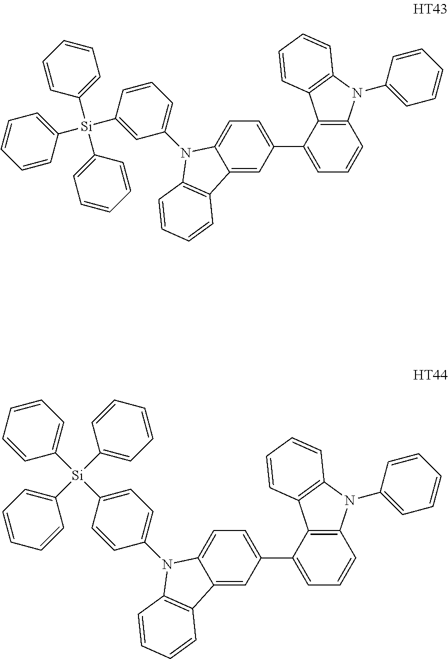 [SMILES: c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

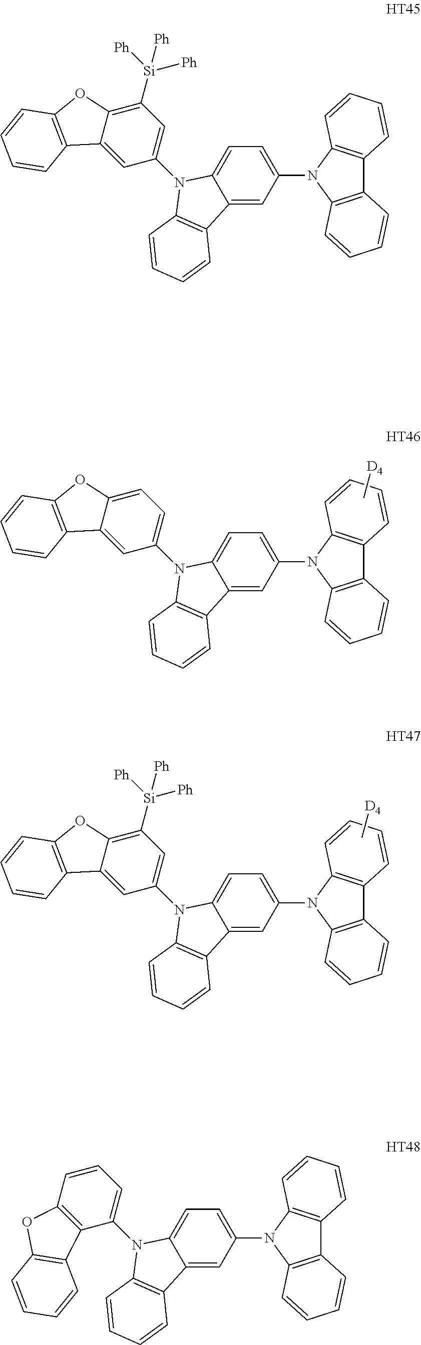

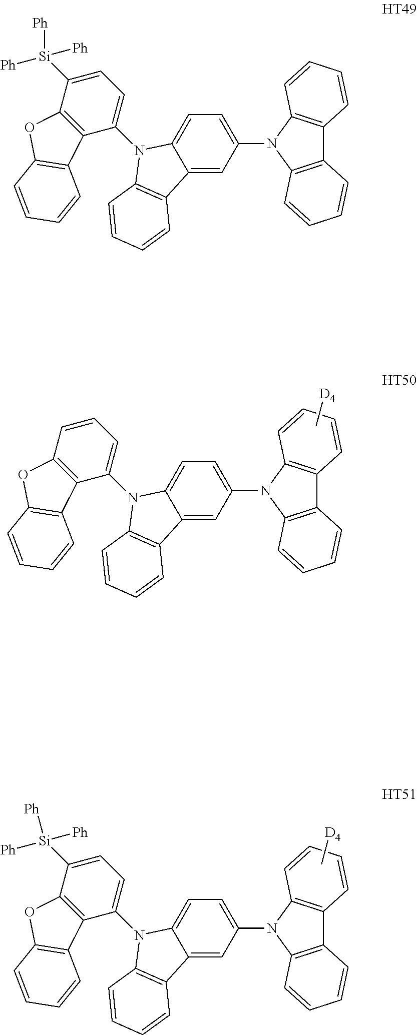

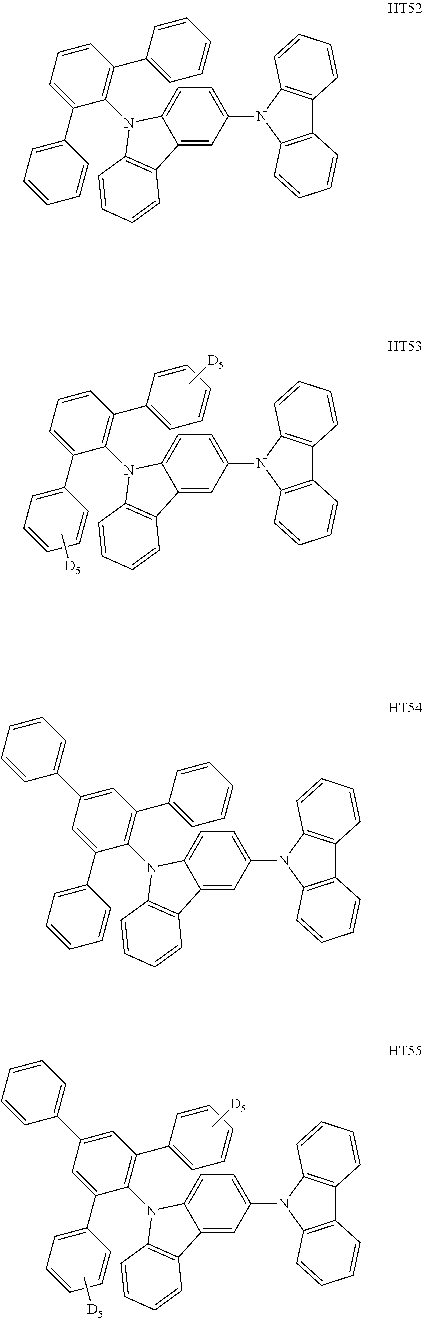

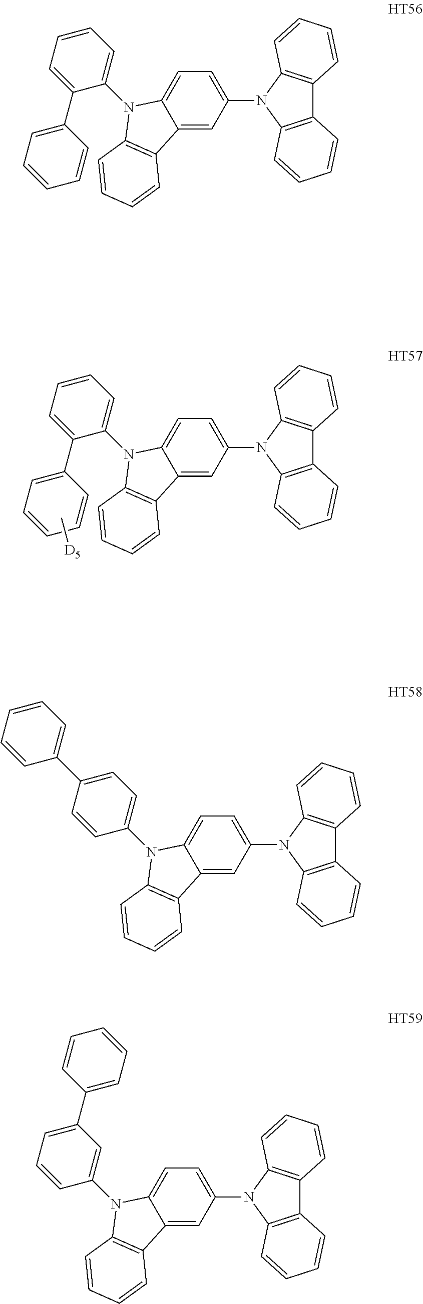

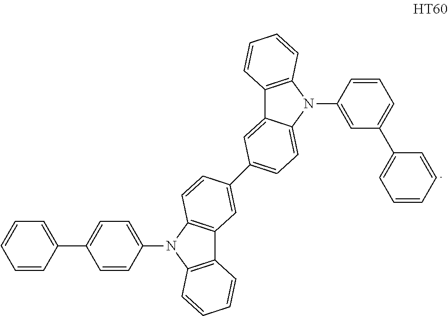 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the light emitting layer EML may further include a third compound represented by Formula ET-1. In an embodiment, the third compound may be used as an electron transport host material in the light emitting layer EML:

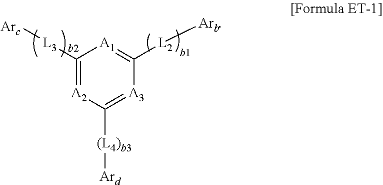

In Formula ET-1, at least one of A1 to A3 may each be N; and the remainder of A1 to A3 may each independently be C(R₅₆). For example, one of A1 to A3 may be N, and the remainder of A1 to A3 may each independently be C(R₅₆). Thus, the third compound represented by Formula ET-1 may include a pyridine moiety. As another example, two of A1 to A3 may each be N, and the remainder of A1 to A3 may be C(R₅₆). Thus, the third compound represented by Formula ET-1 may include a pyrimidine moiety. As yet another example, A1 to A3 may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. If b1 to b3 are each 2 or more, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

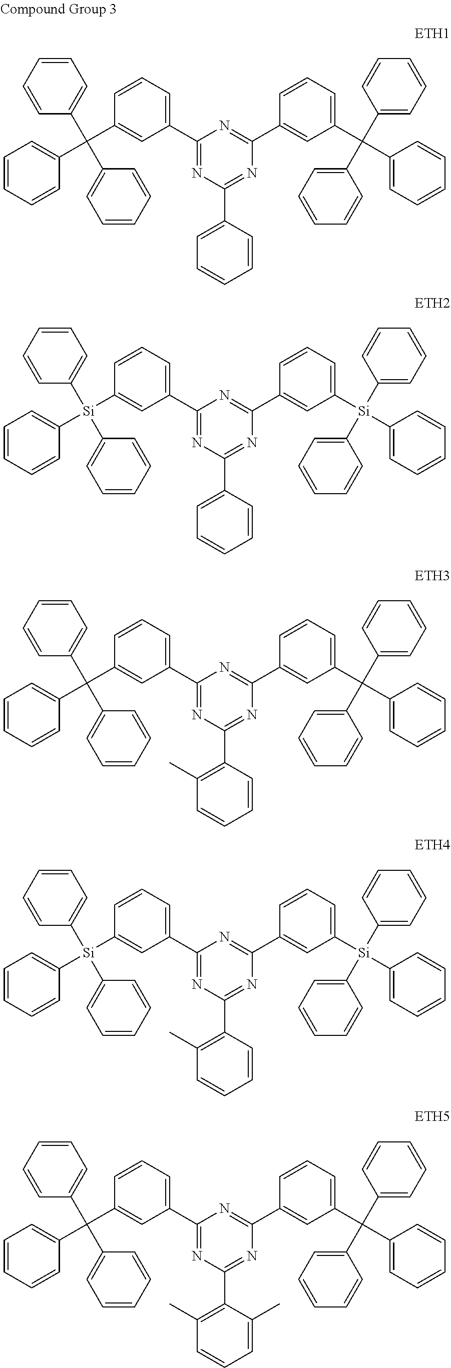

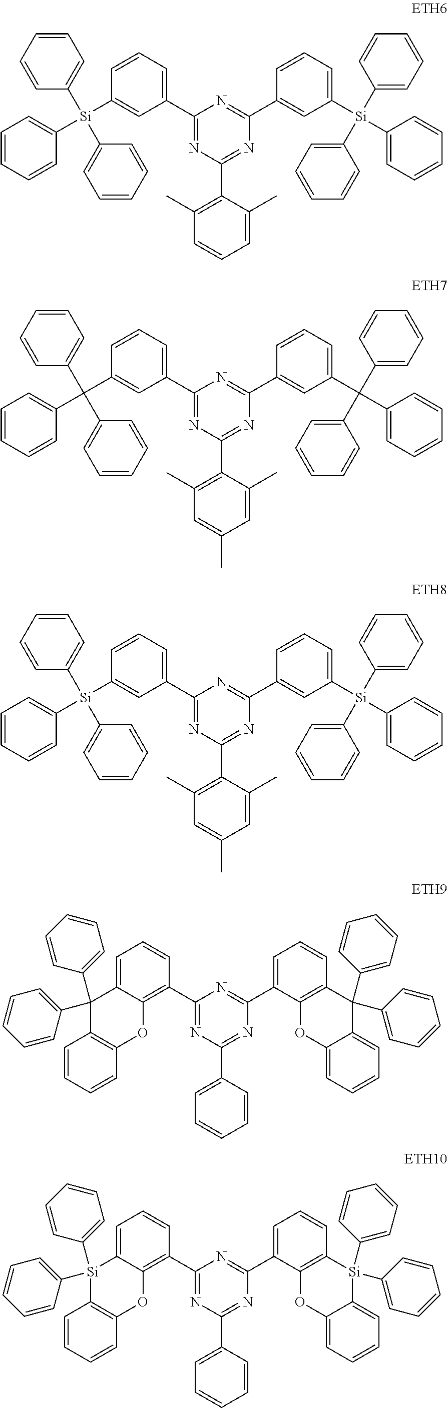

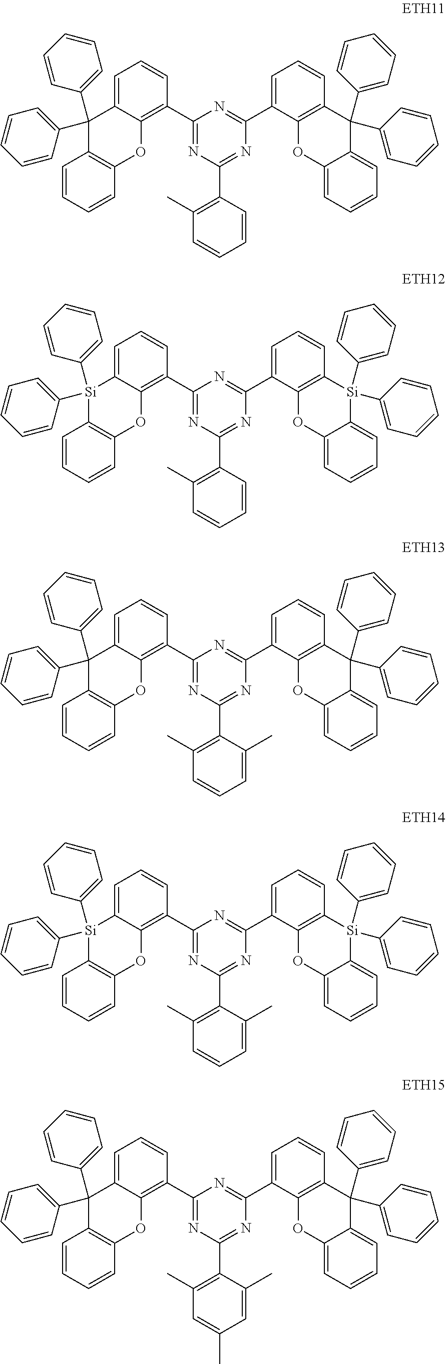

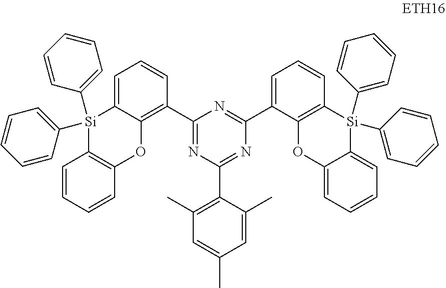 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

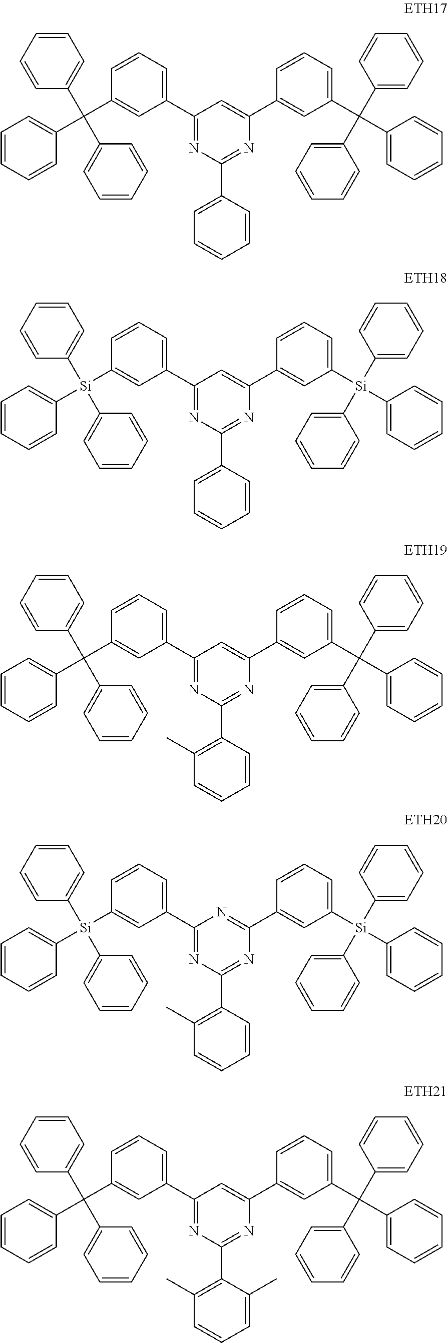

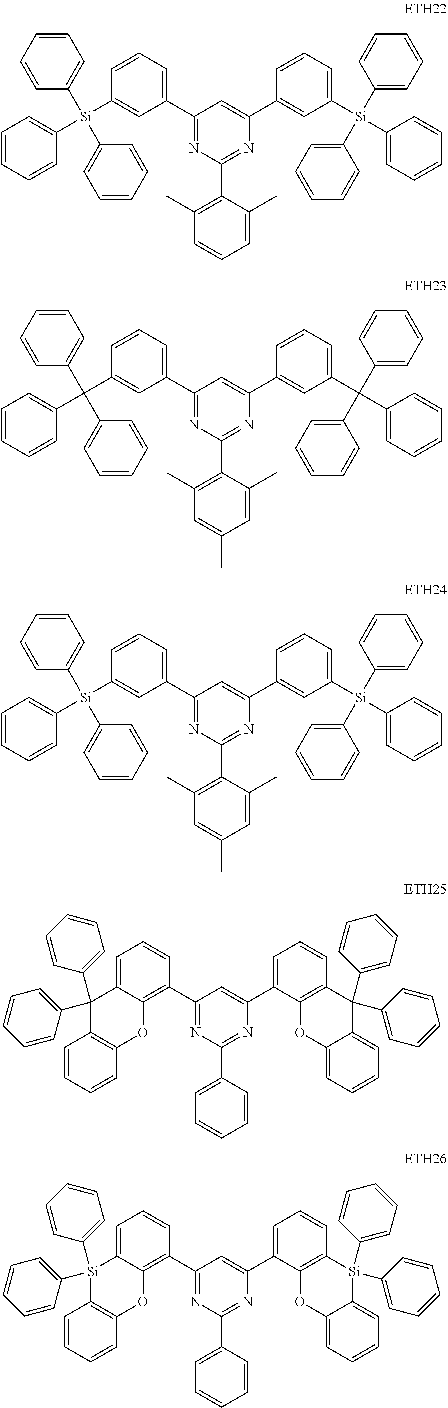

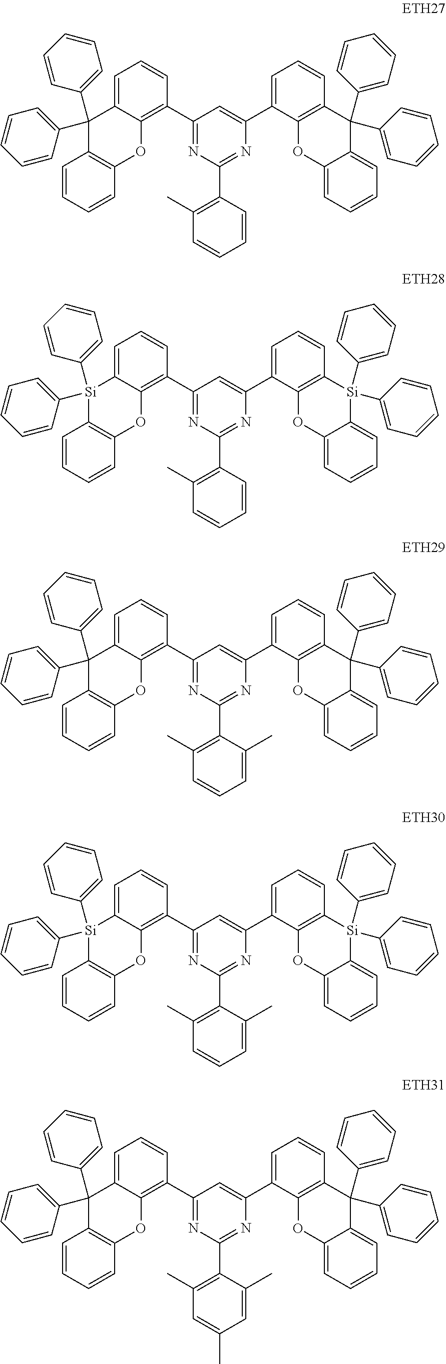

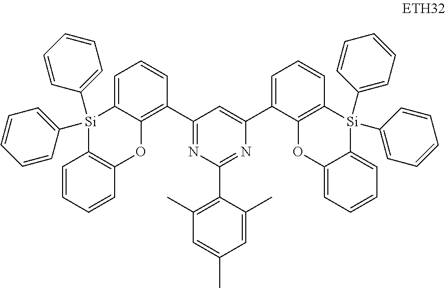 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

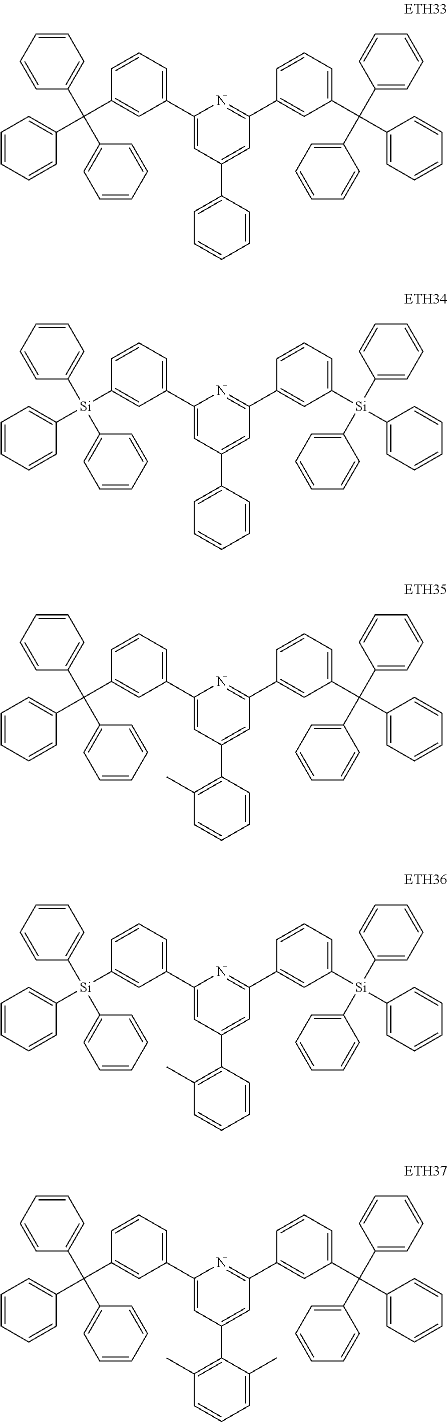

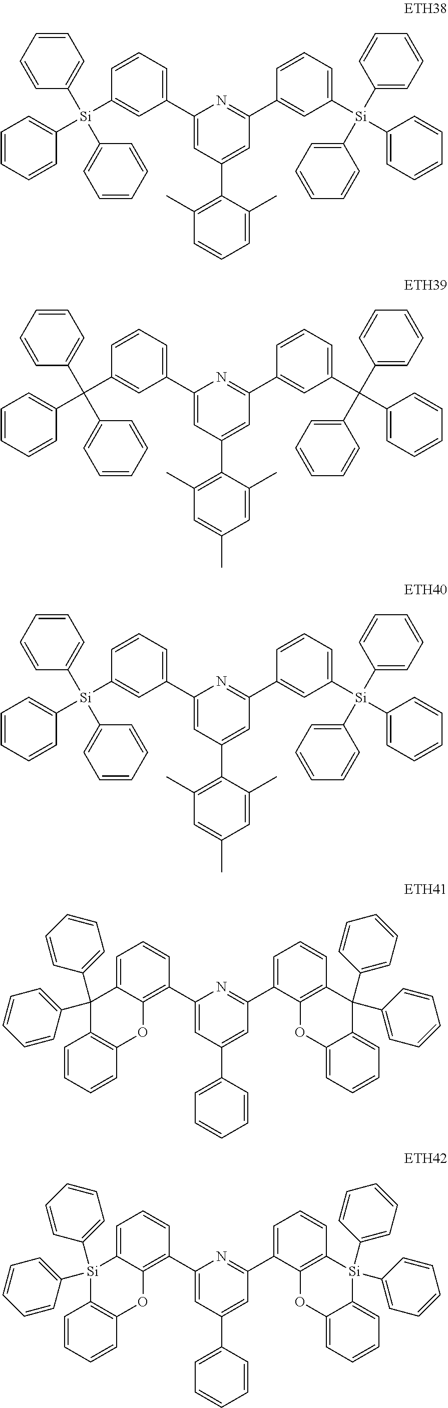

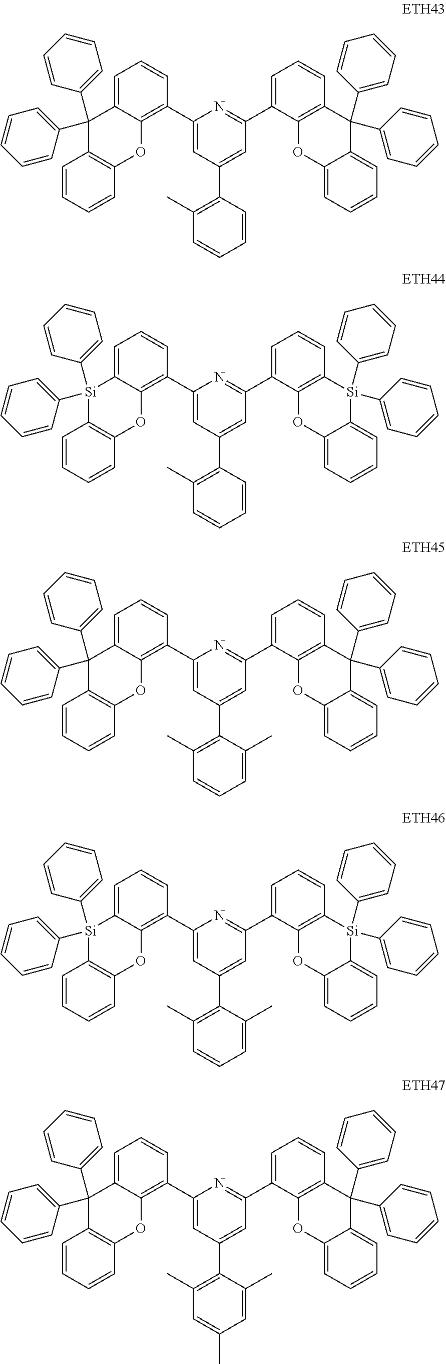

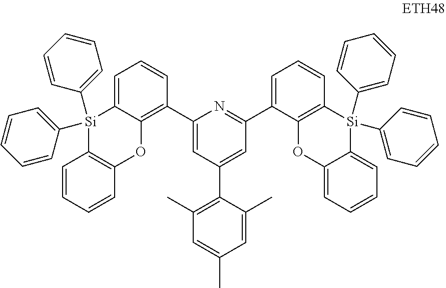 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

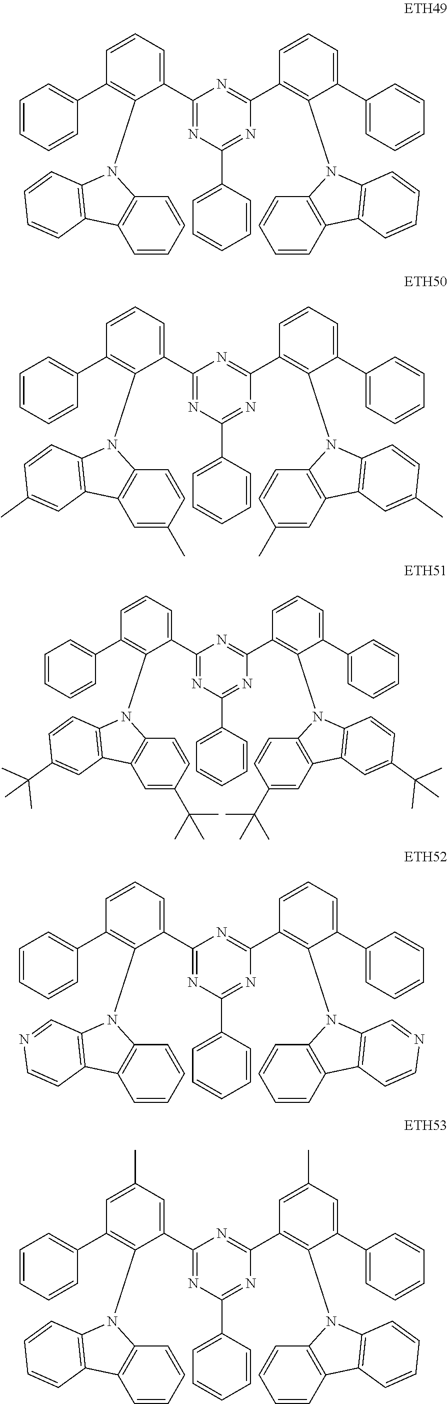

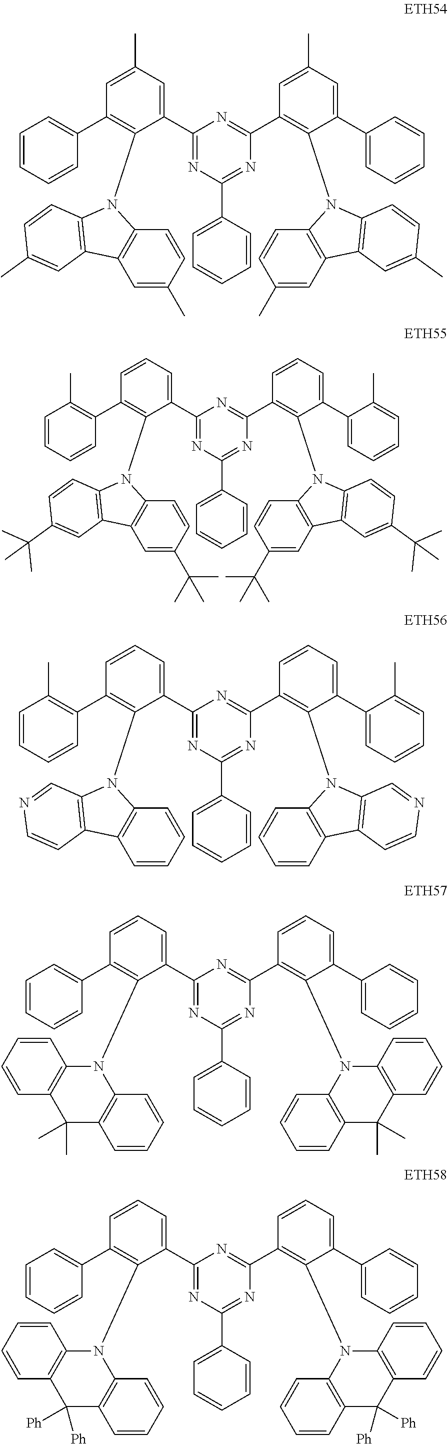

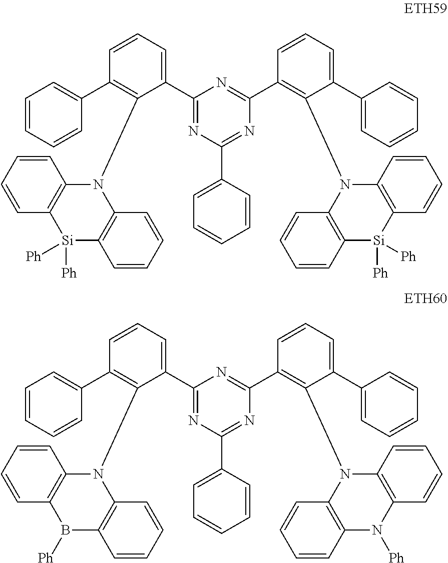 [SMILES: c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5N(c5ccccc5)c5ccccc54)n3)c3ccccc32)cc1]

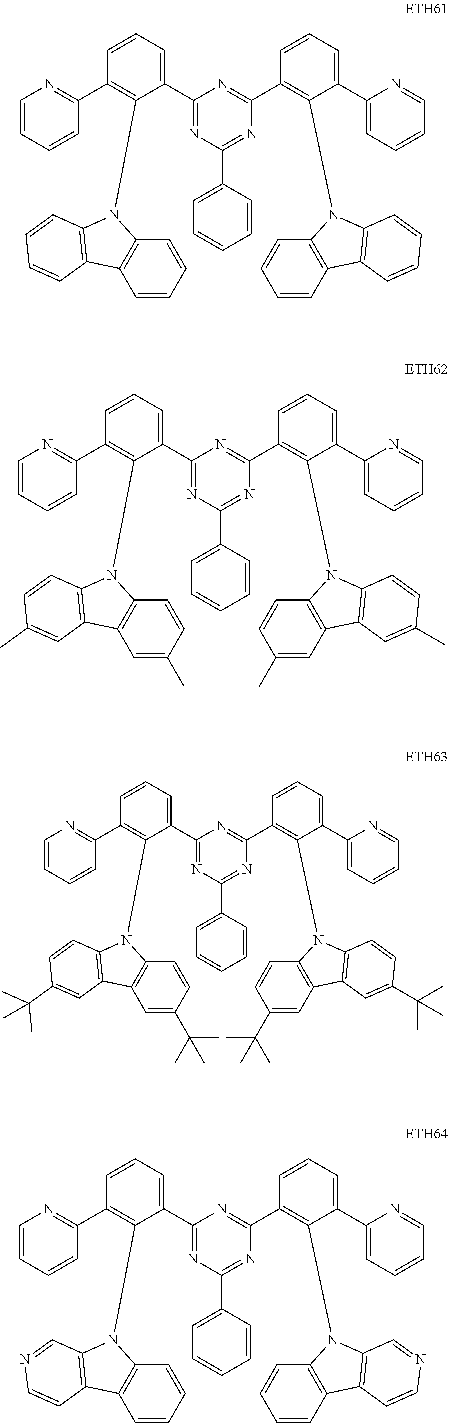

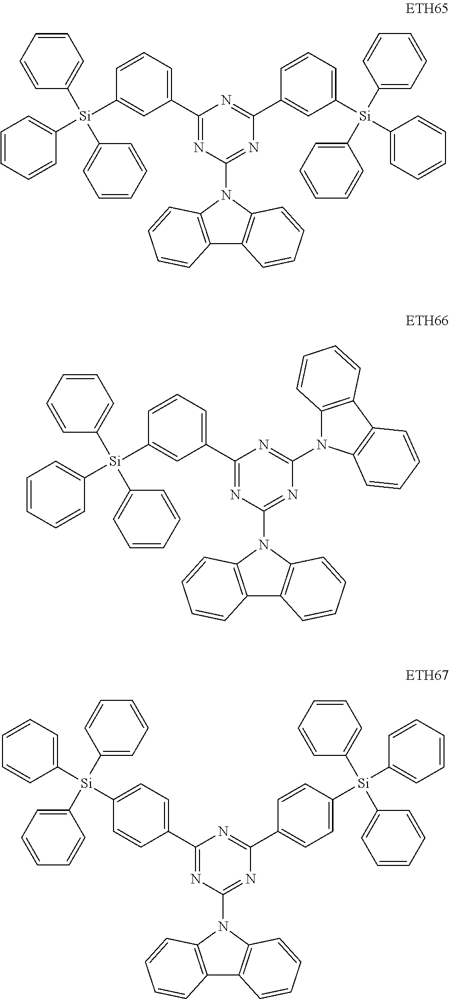 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

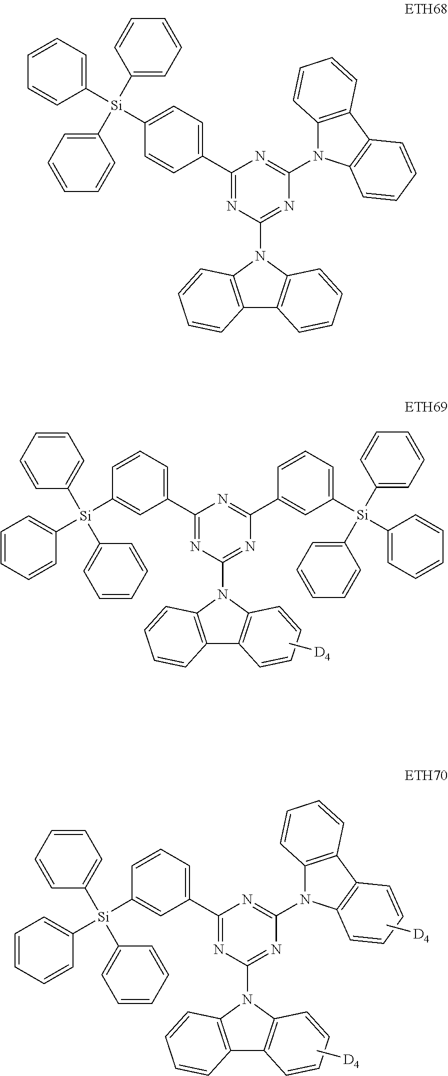

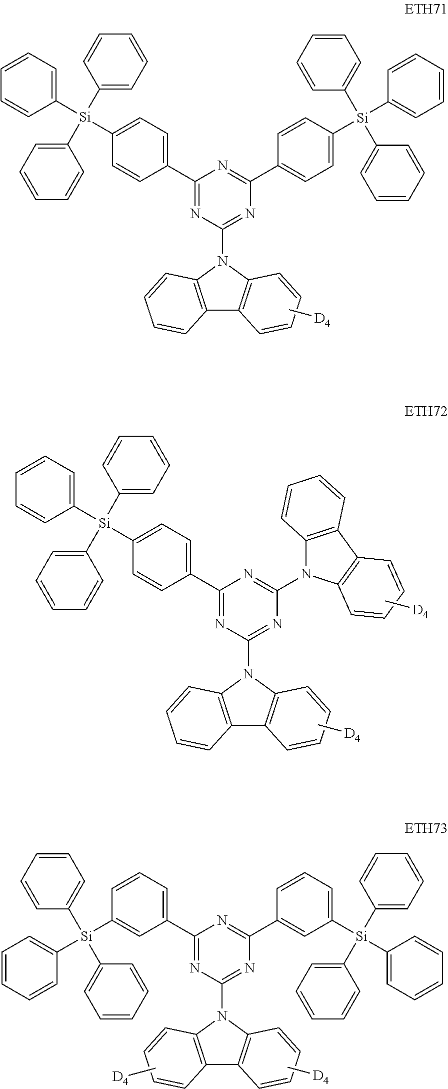

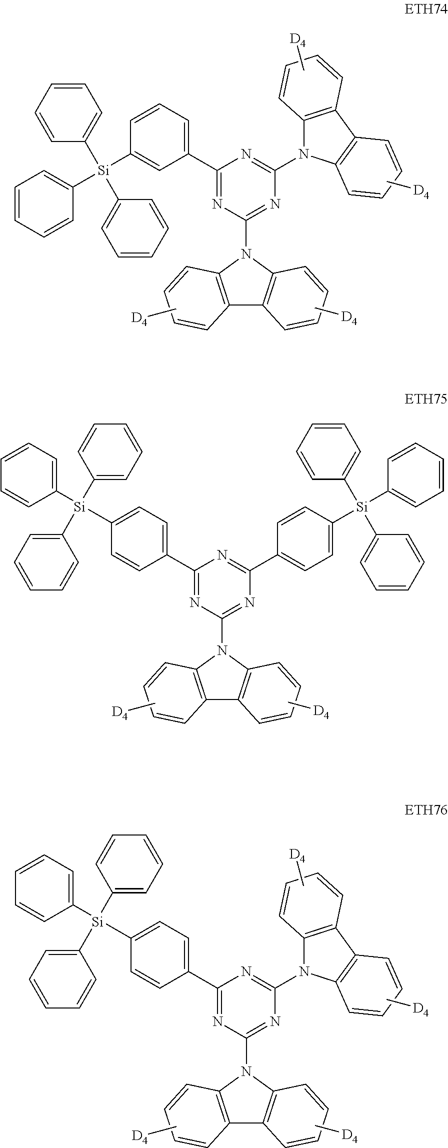

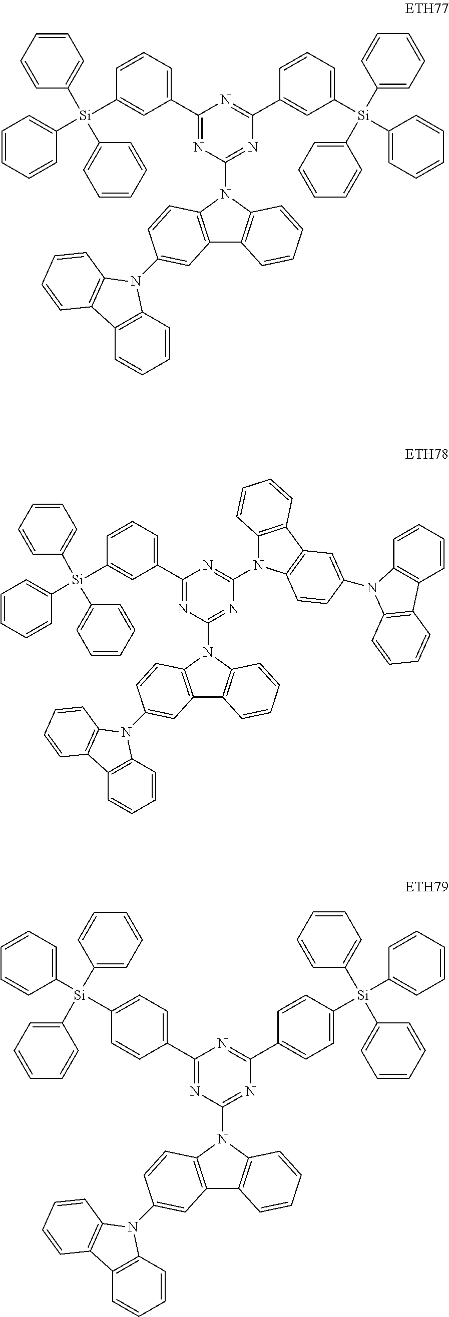 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

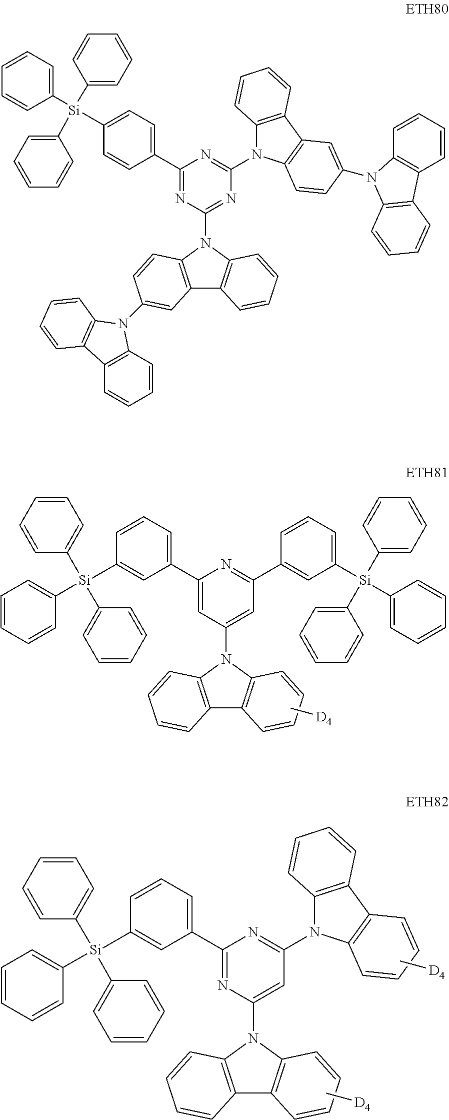

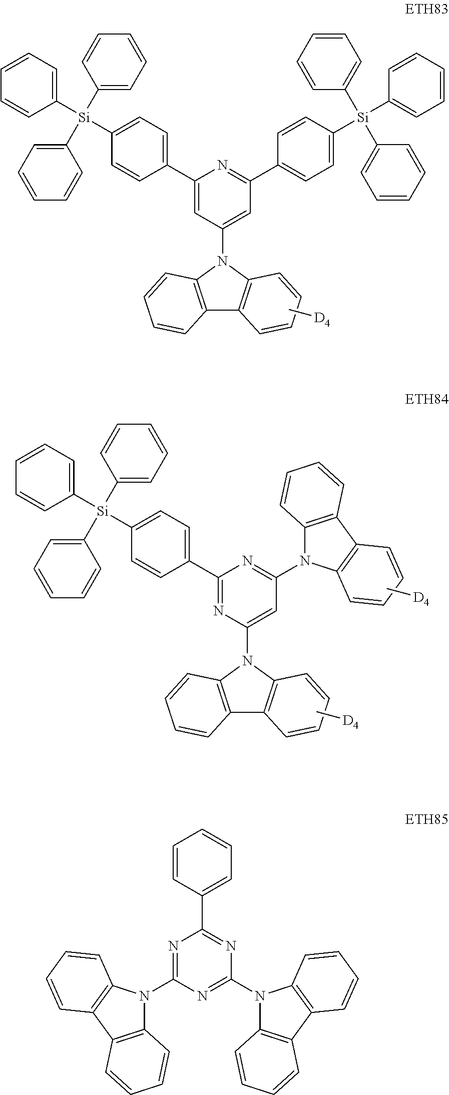

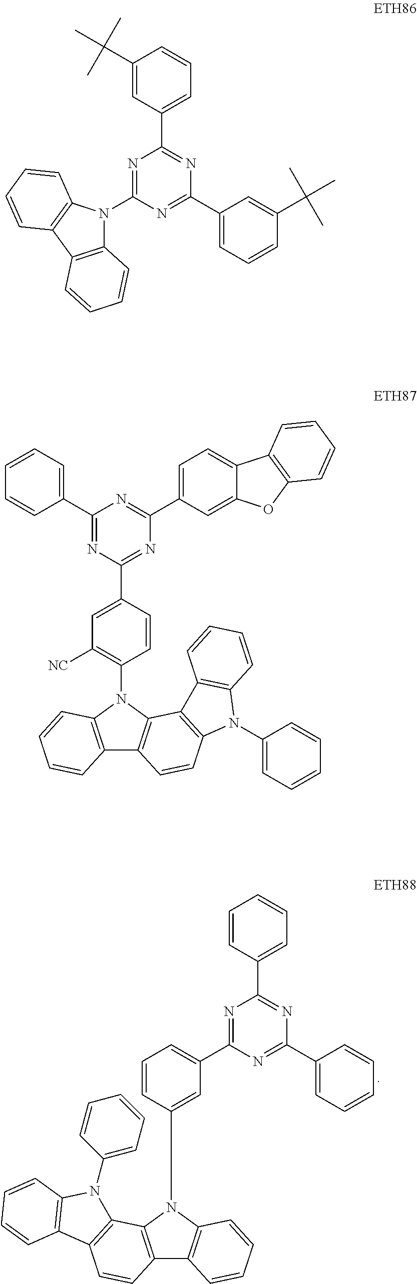 [SMILES: CC(C)(C)c1cccc(-c2nc(-c3cccc(C(C)(C)C)c3)nc(-n3c4ccccc4c4ccccc43)n2)c1 ; N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In Compound Group 3, D represents a deuterium atom, and Ph represents an unsubstituted phenyl group.

In an embodiment, the light emitting layer EML may include the second compound and the third compound, and the second compound and the third compound may form an exciplex. In the light emitting layer EML, an exciplex may be formed by a hole transport host and an electron transport host. A triplet energy of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transport host and the electron transport host.

In an embodiment, the light emitting layer EML may include a fourth compound, in addition to the first compound, the second compound, and the third compound. The fourth compound may be used as a phosphorescent sensitizer in a light emitting layer EML. Energy may be transferred from the fourth compound to the first compound, thereby implementing light emission.

In an embodiment, the light emitting layer EML may further include, as a fourth compound, an organometallic complex that includes platinum (Pt) as a central metal atom and ligands bonded to the central metal atom. In an embodiment, the light emitting layer EML may further include a fourth compound represented by Formula D-1:

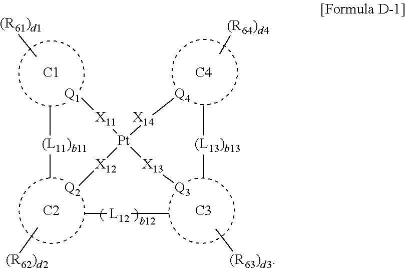

In Formula D-1, Q1 to Q4 may each independently be C or N.

In Formula D-1, Cy1 to Cy4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, X₁₁ to X₁₄ may each independently be a direct linkage, or

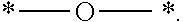

For example, one of X₁₁ to X₁₄ may be

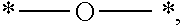

and the remainder of X₁₁ to X₁₄ may each be a direct linkage.

In Formula D-1, L₁ to L₁₃ may each independently be a direct linkage,

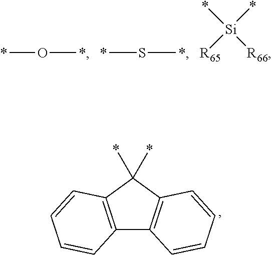

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃,

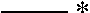

represents a bond to one of Cy1 to Cy4.

In Formula D-1, b11 to b13 may each independently be 0 or 1. If b11 is 0, Cy1 and Cy2 may not be directly bonded to each other. If b12 is 0, Cy2 and Cy3 may not be directly bonded to each other. If b3 is 0, Cy3 and Cy4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4, and four groups of each of R₆₁ to R₆₄ are all hydrogen atoms may be the same as a case where d1 to d4 are each 0. If d1 to d4 are each 2 or more, multiple groups of each of R₆₁ to R₆₄ may all be the same, or at least one thereof may be different from the remainder.

In an embodiment, in Formula D-1, Cy1 to Cy4 may each independently be a substituted or unsubstituted hydrocarbon ring or a substituted or unsubstituted heterocycle that is represented by one of Formula C-1 to Formula C-5:

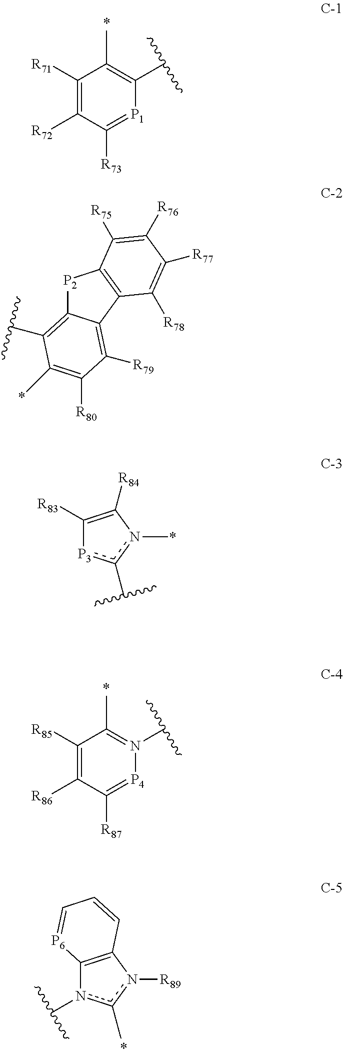

In Formula C-1 to Formula C-5, P₁ may be

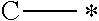

### or C(R₇₄); P2 may be

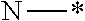 [SMILES: *N]

or N(R₈₁); P₃ may be

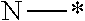 [SMILES: *N]

or N(R₈₂); P₄ may be

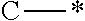 [SMILES: *C]

or C(R₈₈); and P₆ may be

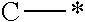 [SMILES: *C]

### or C(R₉₀).

In Formula C-1 to Formula C-5, R₇₁ to R₉₀ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-5,

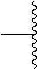

represents a bond to a central metal atom of Pt, and

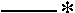 [SMILES: *C]

represents a bond to an adjacent ring group (Cy1 to Cy4) or to a linking moiety (L₁₁ to L₁₃).

In an embodiment, the light emitting layer EML may include the first compound represented by Formula 1, and at least one of the second compound, the third compound, and the fourth compound. In an embodiment, the light emitting layer EML may include the first compound, the second compound, and the third compound. In the light emitting layer EML, the second compound and the third compound may form an exciplex, and energy may be transferred from the exciplex to the first compound, thereby implementing light emission.

In another embodiment, the light emitting layer EML may include the first compound, the second compound, the third compound, and the fourth compound. In the light emitting layer EML, the second compound and the third compound may form an exciplex, and energy may be transferred from the exciplex to the fourth compound and to the first compound, thereby implementing light emission. In an embodiment, the fourth compound may be a sensitizer. In the light emitting element ED, the fourth compound included in the light emitting layer EML may serve as a sensitizer that transfers energy from a host (for example, an exciplex host) to the first compound, which is a light-emitting dopant. For example, the fourth compound, which serves as an auxiliary dopant, may accelerate energy transfer to the first compound, which is a light emitting dopant, thereby increasing a light emitting ratio of the first compound. Accordingly, the emission efficiency of the light emitting layer EML may be improved. If energy transfer to the first compound increases, excitons formed in the light emitting layer EML may not accumulate and may rapidly emit light, so that deterioration of a device may be reduced. Accordingly, the lifetime of the light emitting element ED may increase.

The light emitting element ED may include the first compound, the second compound, the third compound, and the fourth compound, and the light emitting layer EML may include a combination of two host materials and two dopant materials. In the light emitting element ED, the light emitting layer EML may include the second compound and the third compound, which are two different hosts, the first compound that emits delayed fluorescence, and the fourth compound that includes an organometallic complex, so that the light emitting element ED may exhibit excellent emission efficiency properties.

In an embodiment, the fourth compound represented by Formula D-1 may be selected from Compound Group 4. In an embodiment, in the light emitting element ED, the fourth compound may include at least one compound selected from Compound Group 4:

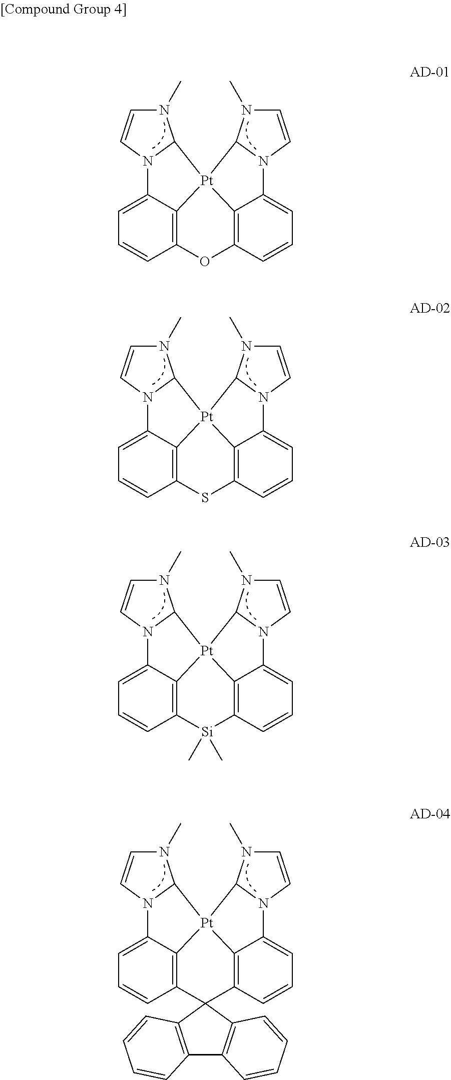

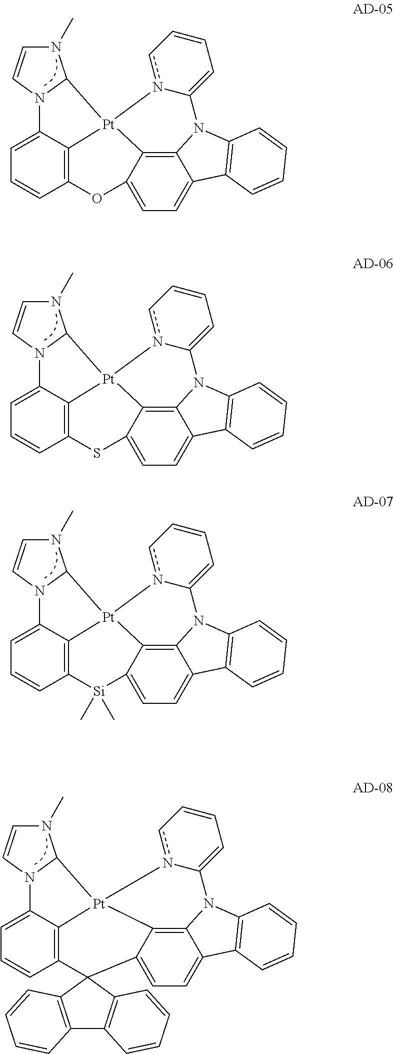

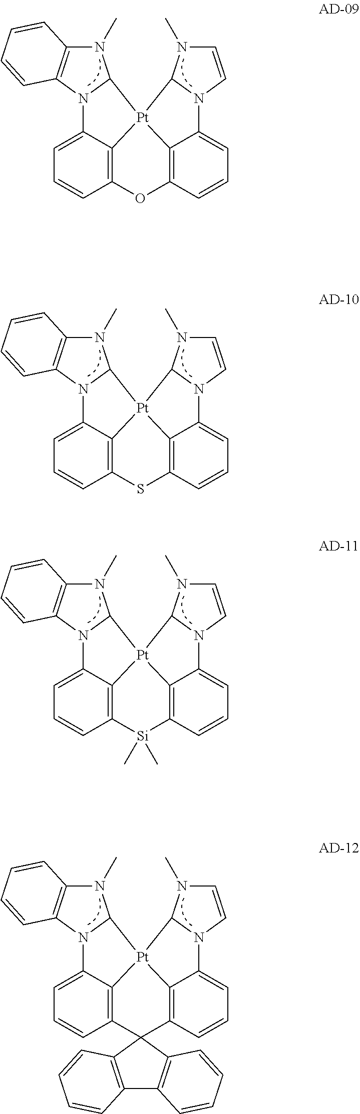

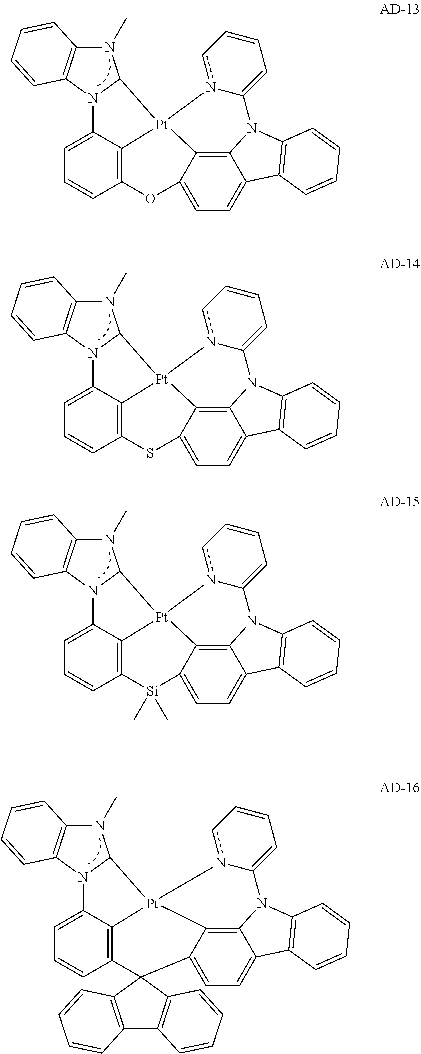

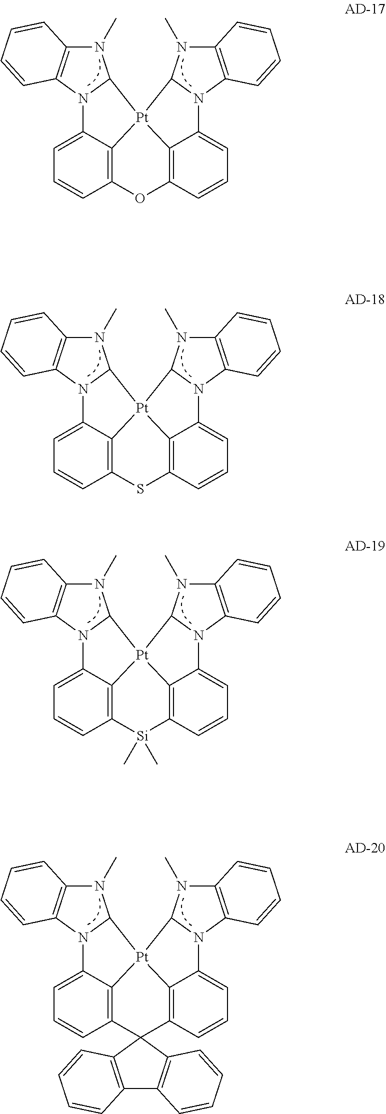

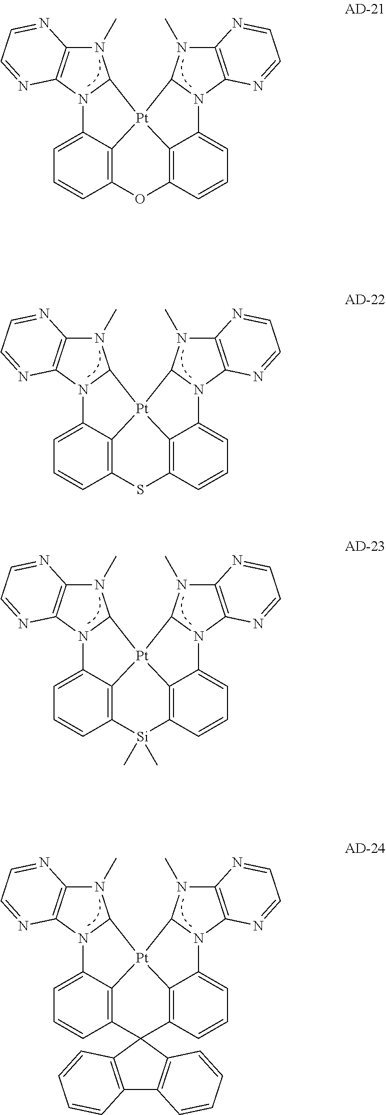

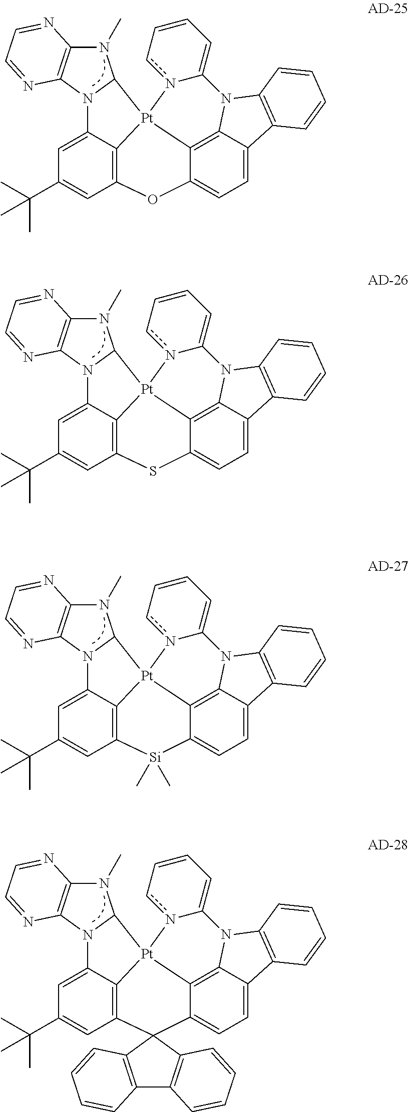

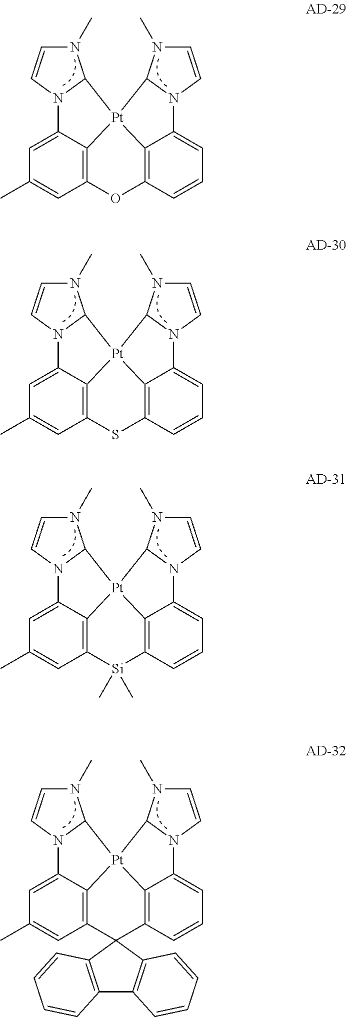

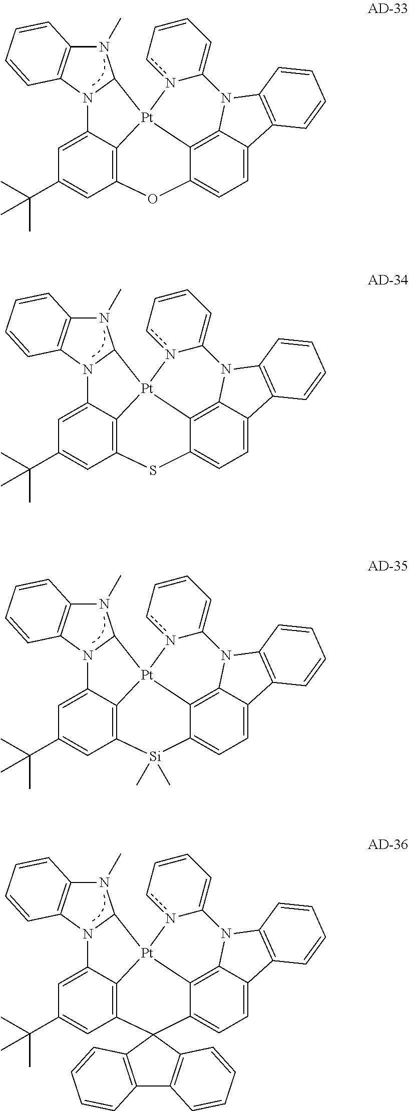

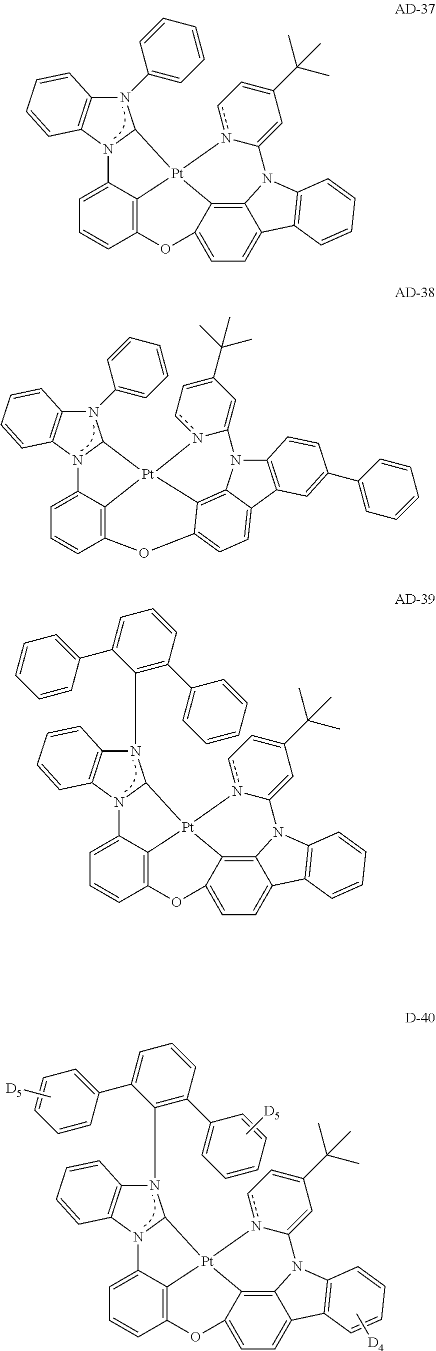

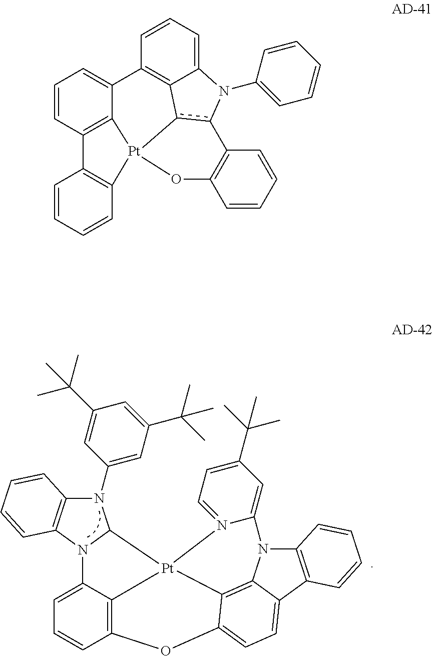

In Compound Group 4, D represents a deuterium atom.

In an embodiment, the light emitting element ED may include multiple light emitting layers. The multiple light emitting layers may be stacked between a first electrode and a second electrode, so that a light emitting element ED that includes multiple light emitting layers may emit white light. The light emitting element including multiple light emitting layers may be a light emitting element having a tandem structure. If the light emitting element ED includes multiple light emitting layers, at least one light emitting layer EML may include the first compound represented by Formula 1. If the light emitting element ED includes multiple light emitting layers, at least one light emitting layer EML may include the first compound, the second compound, the third compound, and the fourth compound.

In the light emitting element ED, if the light emitting layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the range described above, energy transfer from the second compound and the third compound to the first compound may increase, and accordingly, emission efficiency and device lifetime may increase.

In the light emitting layer EML, a total amount of the second compound and the third compound may be the remainder of the total weight of the first compound, the second compound, the third compound, and the fourth compound, excluding the amount of the first compound and the fourth compound. For example, a combined amount of the second compound and the third compound may be in a range of about 65 wt % to about 95 wt %, based on a total weight of the first compound, the second compound, the third compound, and the fourth compound.

Within the combined amount of the second compound and the third compound in the light emitting layer EML, a weight ratio of the second compound to the third compound may be in a range of about 3:7 to about 7:3.

If the amounts of the second compound and the third compound satisfy the above-described ranges and ratios, charge balance properties in the light emitting layer EML may be improved, and emission efficiency and device lifetime may be improved. If the amounts of the second compound and the third compound deviate from the above-described ranges and ratios, charge balance in the light emitting layer EML may not be achieved, so that emission efficiency may be reduced, and the element may readily deteriorate.

If the light emitting layer EML includes the fourth compound, an amount of the fourth compound may be in a range of about 4 wt % to 30 wt %, based on a total weight of the first compound, the second compound, the third compound, and the fourth compound in the light emitting layer EML. However, embodiments are not limited thereto. If an amount of the fourth compound satisfies the above-described range, energy transfer from a host (for example, an exciplex host) to the first compound, which is a light emitting dopant, may increase, so that an emission ratio may improve. Accordingly, the emission efficiency of the light emitting layer EML may be improved. If the amounts of the first compound, the second compound, the third compound, and the fourth compound included in the light emitting layer EML satisfy the above-described ranges and ratios, excellent emission efficiency and long lifetime may be achieved.

In the light emitting element ED of, the light emitting layer EML may further include an anthracene derivative, a pyrene derivative, a fluoranthene derivative, a chrysene derivative, a dihydrobenzanthracene derivative, or a triphenylene derivative. For example, the light emitting layer EML may include an anthracene derivative or a pyrene derivative.

In the light emitting element ED according to embodiments as shown in each of FIG. 3 to FIG. 6, the light emitting layer EML may further include hosts and dopants of the related art, in addition to the above-described host and dopant.

In an embodiment, the light emitting layer EML may include a compound represented by Formula E-1. The compound represented by Formula E-1 may be used as a fluorescence host material.

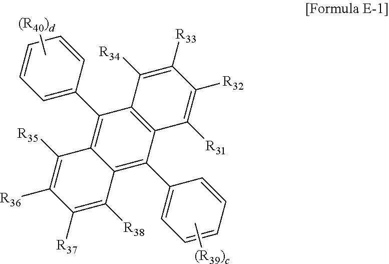

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E21:

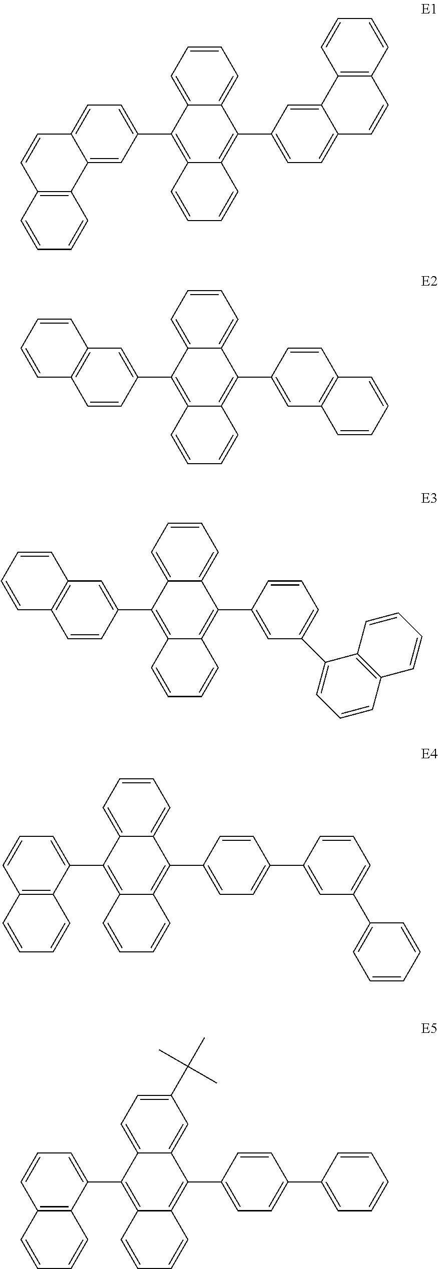

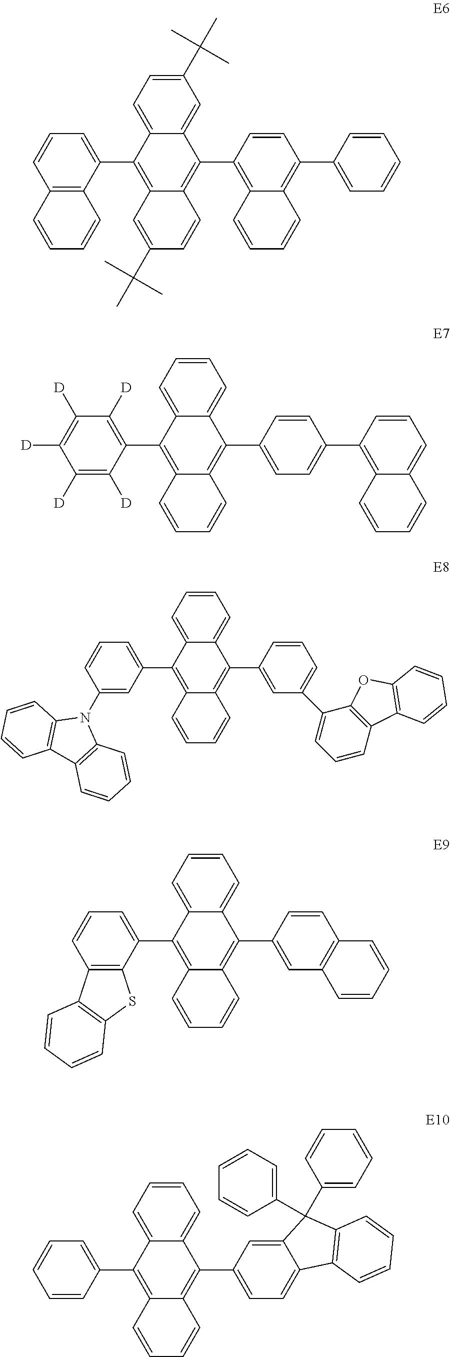

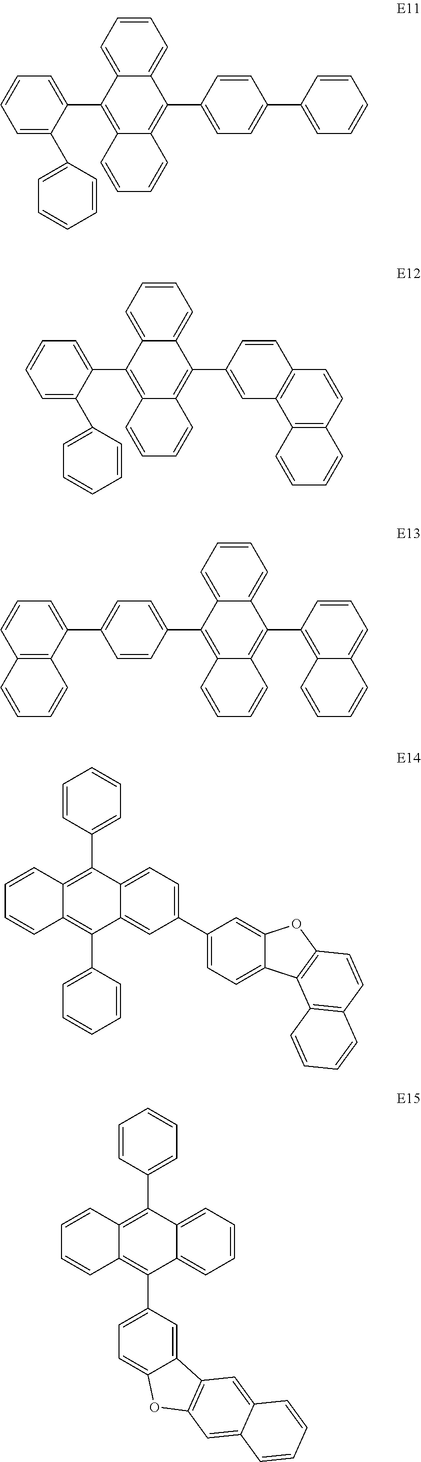

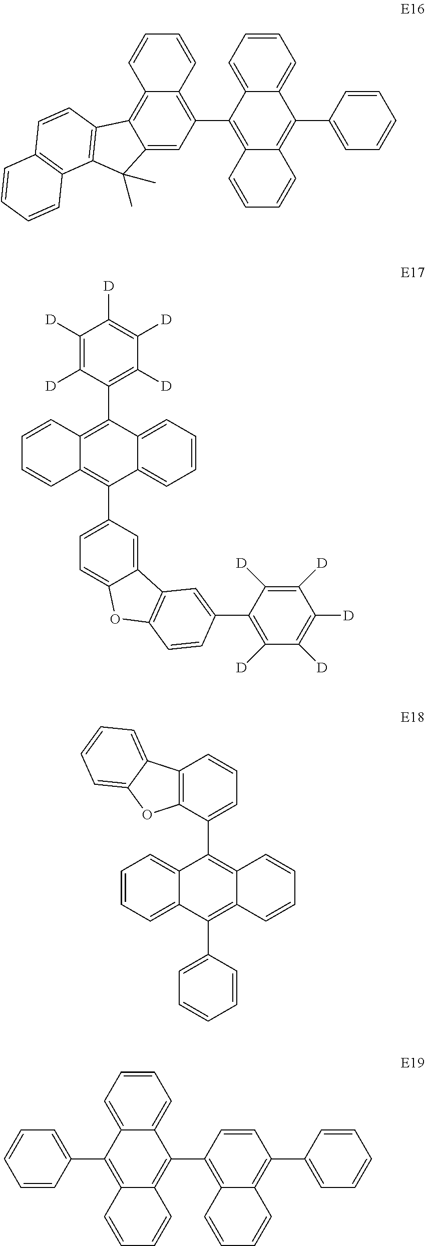

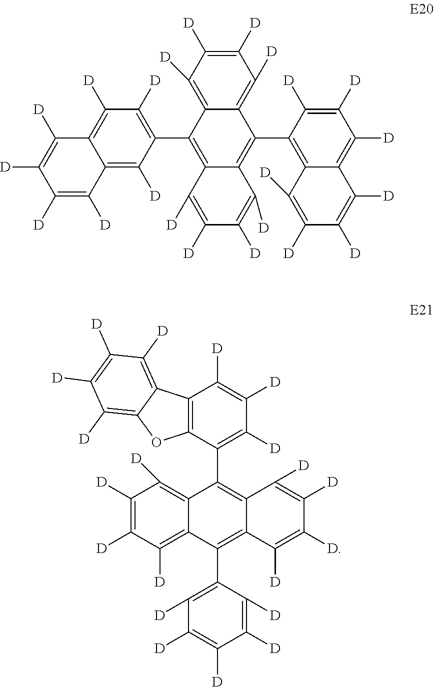

In an embodiment, the light emitting layer EML may include a compound represented by Formula E-2a or Formula E-2b. The compound represented by Formula E-2a or Formula E-2b may be used as a phosphorescence host material.

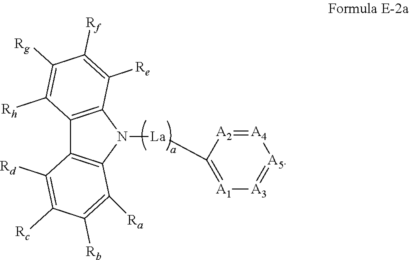

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. If a is 2 or more, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

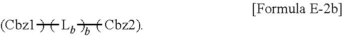

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. If b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2:

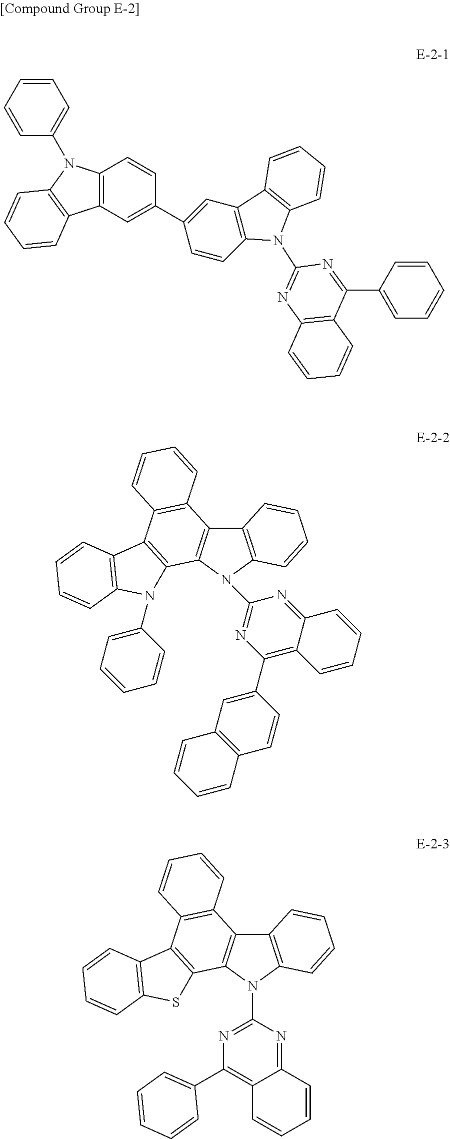 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

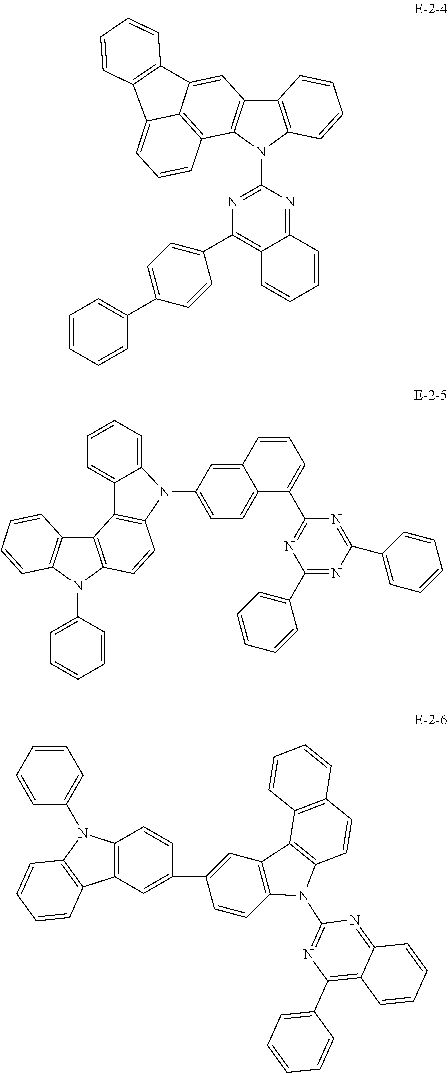 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

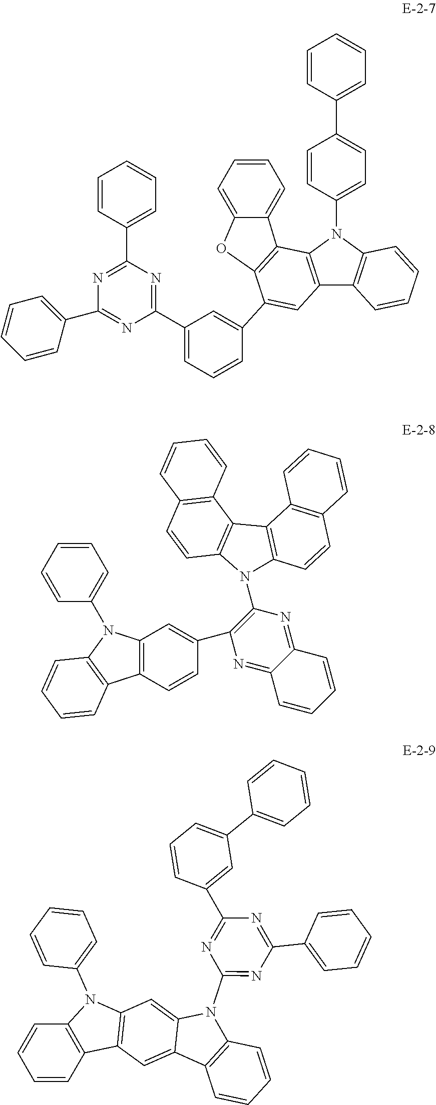 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

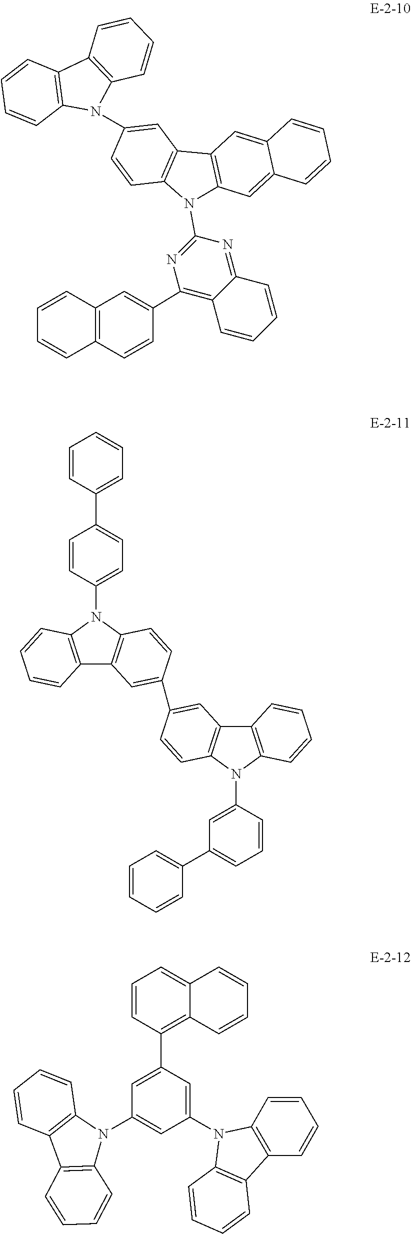 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

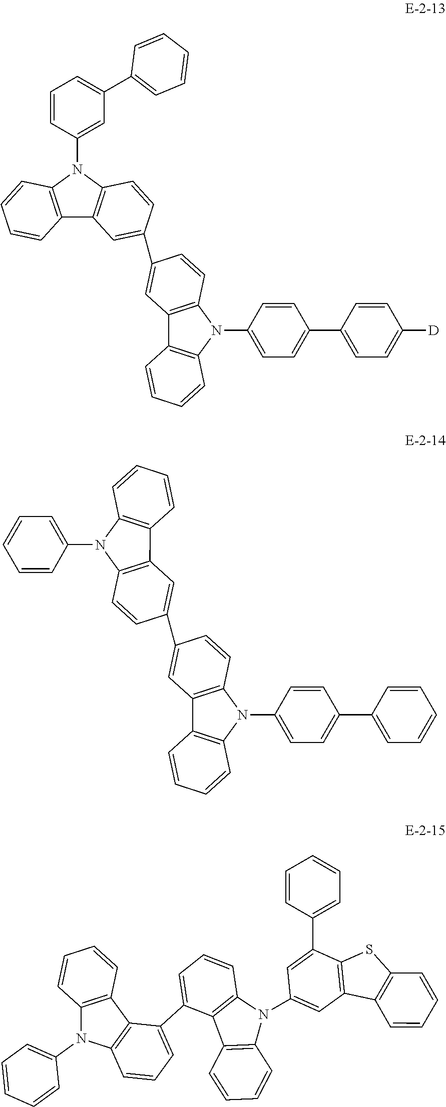 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

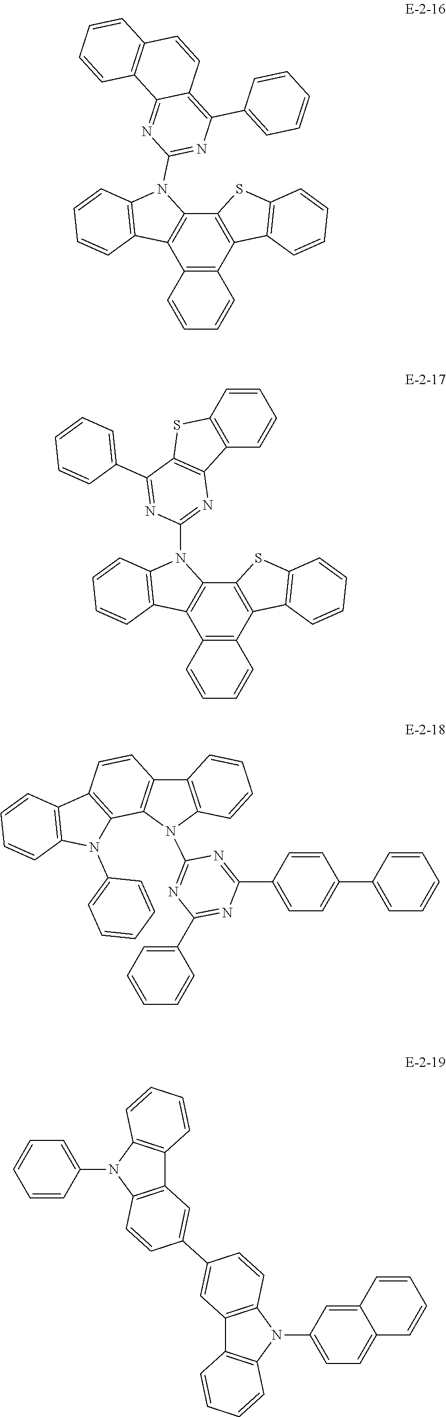 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

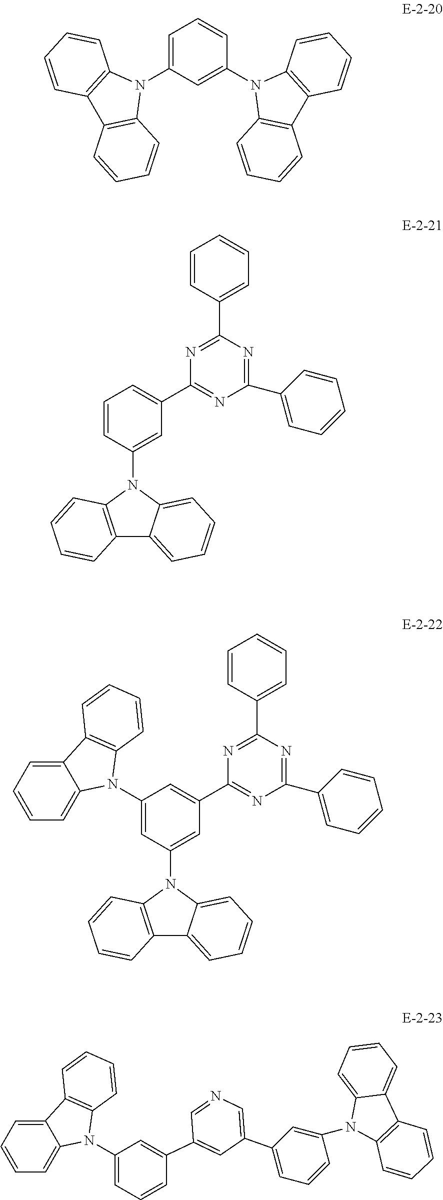 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

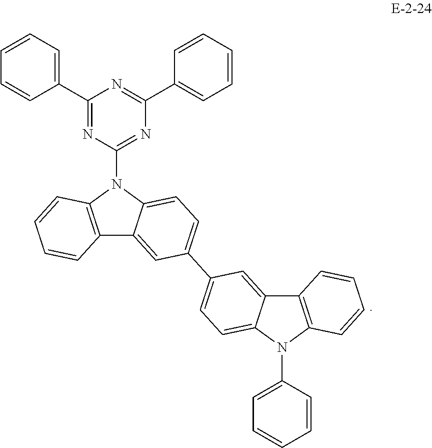 [SMILES: c1ccc(-c2nc(-c3ccccc3)nc(-n3c4ccccc4c4cc(-c5ccc6c(c5)c5ccccc5n6-c5ccccc5)ccc43)n2)cc1]

In an embodiment, the light emitting layer EML may further include a material of the related art as a host material. For example, the light emitting layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the light emitting layer EML may include a compound represented by Formula M-a. The compound represented by Formula M-a may be used as a phosphorescence dopant material.

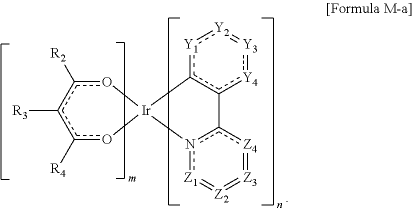

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, if m is 0, n may be 3, and if m is 1, n may be 2.

In an embodiment, the compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

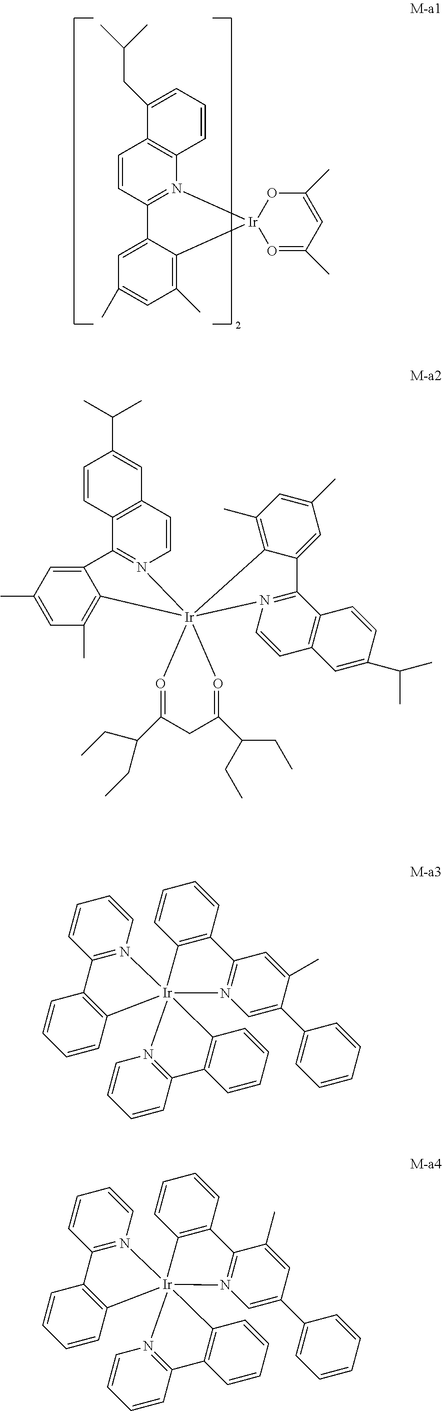

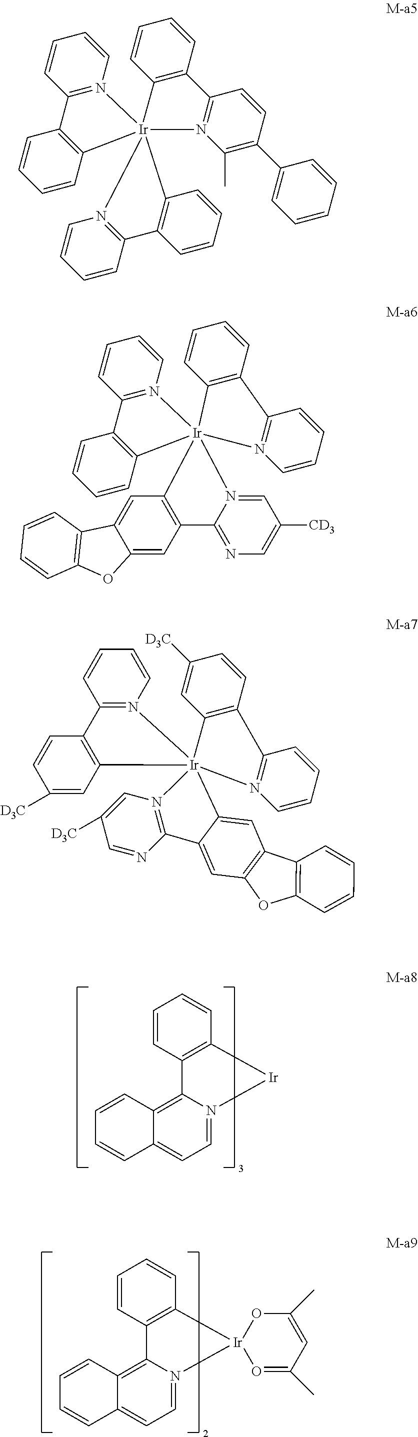

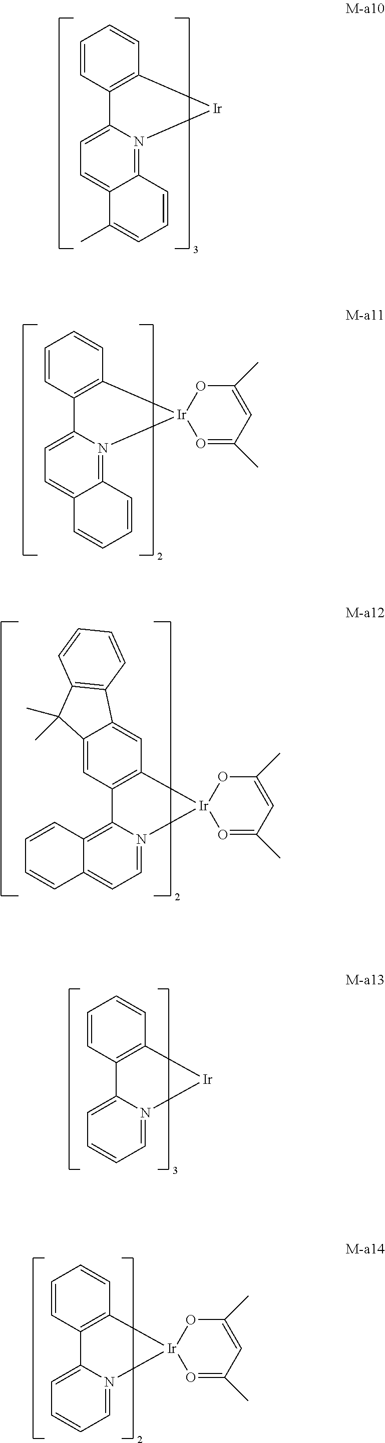

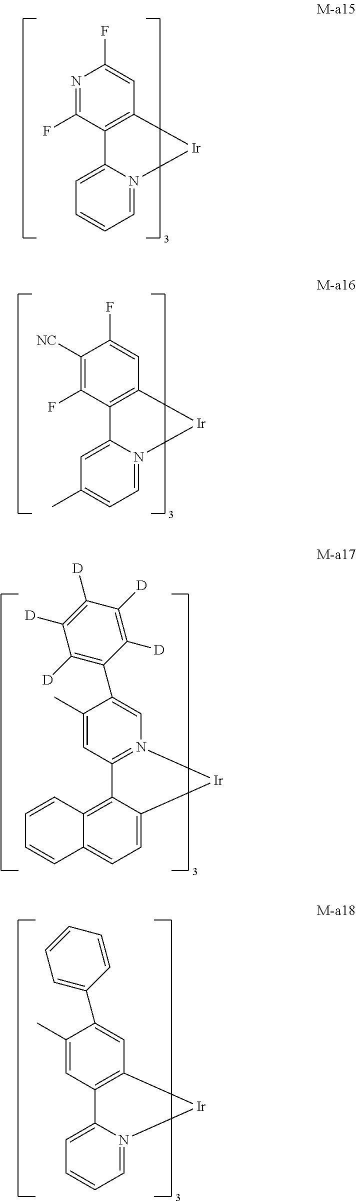

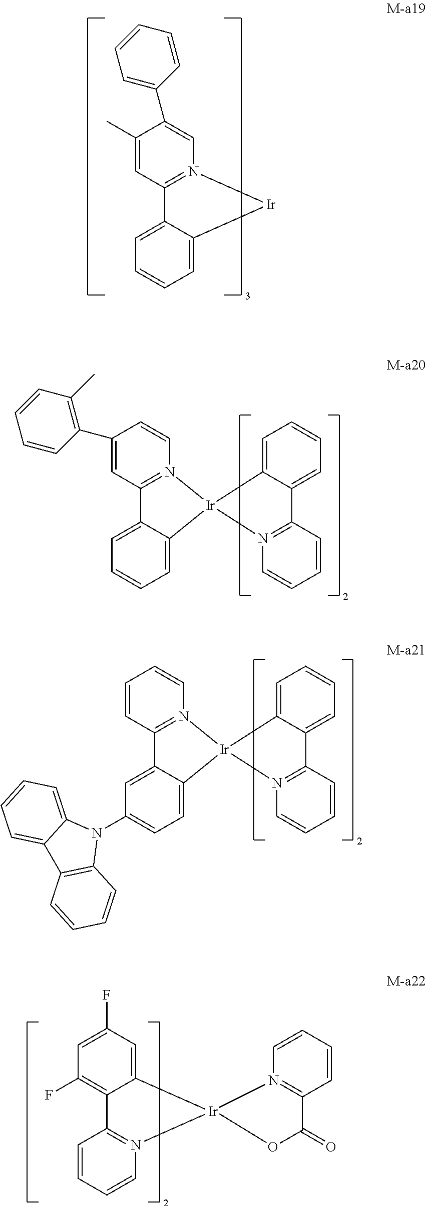

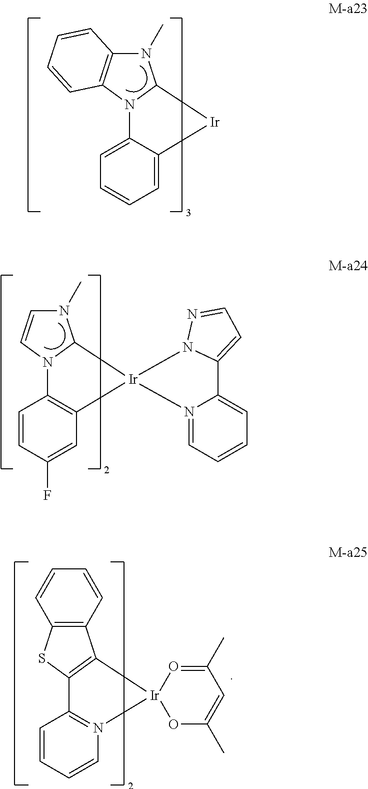

In an embodiment, the light emitting layer EML may further include a compound represented by one of Formula F-a to Formula F-c. The compounds represented by one of Formula F-a to Formula F-c may be used as fluorescence dopant materials.

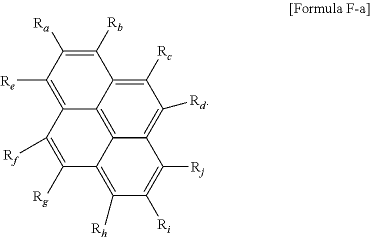

In Formula F-a, two of Rₐ to Rⱼ may each independently be substituted with a group represented by

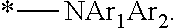

The remainder of Rₐ to Rⱼ that are not substituted with the group represented by

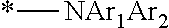

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

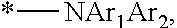

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group including O or S as a ring-forming atom.

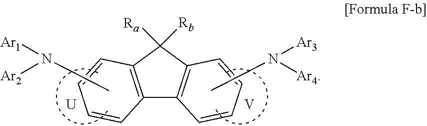

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at a portion respectively designated by U or V, and if the number of U or V is 0, a fused ring may not be present at the portion respectively designated by U or V. If the number of U is 0 and the number of V is 1, or if the number of U is 1 and the number of V is 0, a fused ring having a fluorene core of Formula F-b may be a cyclic compound with four rings. If the number of U and V is each 0, a fused ring having a fluorene core of Formula F-b may be a cyclic compound with three rings. If the number of U and V is each 1, a fused ring having a fluorene core of Formula F-b may be a cyclic compound with five rings.

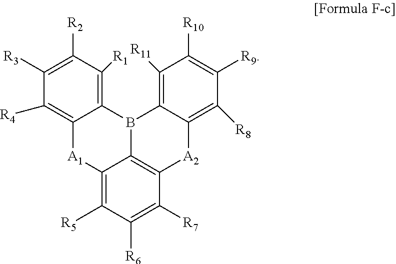

In Formula F-c, A1 and A2 may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, if A₁ and A₂ are each independently N(Rₘ), A₁ may be combined with R₄ or R₅ to form a ring, and/or A₂ may be combined with R₇ or R₈ to form a ring.

In an embodiment, the light emitting layer EML may include, as a dopant material of the related art, a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The light emitting layer EML may include a phosphorescence dopant material of the related art. For example, the phosphorescence dopant may include a metal complex that includes iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′) picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the light emitting layer may include a quantum dot.

In the specification, a quantum dot may be a crystal of a semiconductor compound. A quantum dot may emit light in various emission wavelengths according to a size of the crystal. A quantum dot may emit light in various emission wavelengths by adjusting an elemental ratio in the quantum dot compound.

A diameter of the quantum dot may be, for example, in a range of about 1 nm to about 10 nm.

The quantum dot may be synthesized by chemical bath deposition, metal organic chemical vapor deposition, molecular beam epitaxy, or a similar process therewith.

Chemical bath deposition is a method of mixing an organic solvent and a precursor material and growing a quantum dot particle crystal. While growing the crystal, the organic solvent may naturally serve as a dispersant that is coordinated on the surface of the quantum dot crystal and may control the growth of the crystal. Accordingly, chemical bath deposition is more advantageous as compared to a vapor deposition method such as metal organic chemical vapor deposition (MOCVD) and molecular beam epitaxy (MBE), and the growth of the quantum dot particle may be controlled through a low-cost process.

The quantum dot may include a Group II-VI compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof. In an embodiment, a Group II-VI compound may further include a Group I metal and/or a Group IV element. Examples of a Group I-II-VI compound may include CuSnS and CuZnS, and examples of a Group II-IV-VI compound may include ZnSnS and the like. Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃, and In₂Se₃; a ternary compound such as InGaS₃, and InGaSe₃; and any combination thereof.

Examples of a Group I-III-VI compound may include: a ternary compound such as AgInS, AgInS₂, CuInS, CuInS₂, AgGaS₂, CuGaS₂, CuGaO₂, AgGaO₂, AgAlO₂ and mixtures thereof; a quaternary compound such as AgInGaS₂ and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and mixtures thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (wherein x is a real number between 0 and 1).

In an embodiment, a quantum dot may have a core/shell structure in which a quantum dot surrounds another quantum dot. An interface between the core and the shell may have a concentration gradient in which the concentration of an element that is present in the shell decreases toward the center.

In embodiments, a quantum dot may have the above-described core-shell structure that includes a nanocrystal core and a shell that surrounds the core. The shell of a quantum dot may serve as a protection layer that prevents chemical deformation of the core to maintain semiconductor properties and/or may serve as a charging layer that imparts the quantum dot with electrophoretic properties. The shell may be single-layered or multilayered. Examples of a shell of a quantum dot may include a metal oxide, a non-metal oxide, a semiconductor compound, or a combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fc₂O₃, Fc₃O₄, CoO, Co₃O₄, and NiO, or a ternary compound such as MgAl₂O₄, CoFc₂O₄, NiFc₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have an FWHM of an emission wavelength spectrum equal to or less than about 40 nm. For example, the quantum dot may have an FWHM of an emission wavelength spectrum equal to or less than about 30 nm. Within any of the above ranges, color purity or color reproducibility may be improved. Light emitted through a quantum dot may be emitted in all directions, so that viewing angle properties may be improved.

The shape of a quantum dot may be any shape used in the related art, without specific limitation. For example, a quantum dot may have a spherical shape, a pyramidal shape, a multi-arm shape, or a cubic shape, or a quantum dot may be in the form of a nanoparticle, a nanotube, a nanowire, a nanofiber, a nanoplate particle, etc.

As a size of a quantum dot or an elemental ratio of a quantum dot compound is adjusted, an energy band gap may be accordingly controlled to obtain light of various wavelengths from a quantum dot light emitting layer. Therefore, by utilizing quantum dots as described above (using quantum dots of different sizes or having different element ratios in a quantum dot compound), a light emitting element may emit light of various wavelengths. For example, a size of a quantum dot or an elemental ratio of a quantum dot compound may be adjusted to emit red light, green light, and/or blue light. In an embodiment, quantum dots may be configured to emit white light by combining light of various colors.

In the light emitting elements ED according to embodiments, as shown in each of FIG. 3 to FIG. 6, the electron transport region ETR may be provided on the light emitting layer EML. The electron transport region ETR may include at least one of a hole blocking layer HBL, an electron transport layer ETL, and an electron injection layer EIL. However, embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material and an electron transport material. The electron transport region ETR may have a single-layered structure that includes different materials. In embodiments, the electron transport region ETR may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

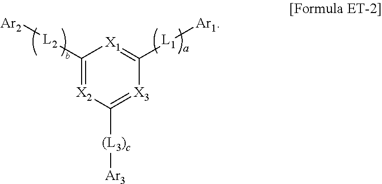

In Formula ET-2, at least one of X₁ to X₃ may each be N, and the remainder of X₁ to X₃ may each independently be C(Ra). In Formula ET-2, Rₐ may be a hydrogen atom, a deuterium atom, a substituted or unsubstituted alkyl of 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. If a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile) or a mixture thereof, without limitation.

In an embodiment, the electron transport region ETR may include a compound selected from Compound Group 3.

In an embodiment, the electron transport region ETR may include at least one compound selected from Compounds ET1 to ET36:

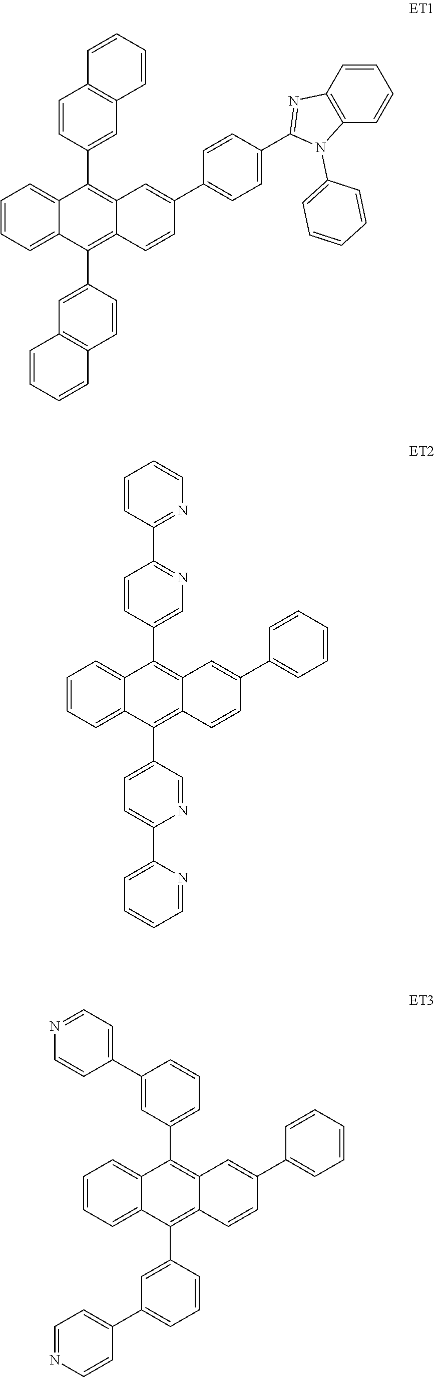 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

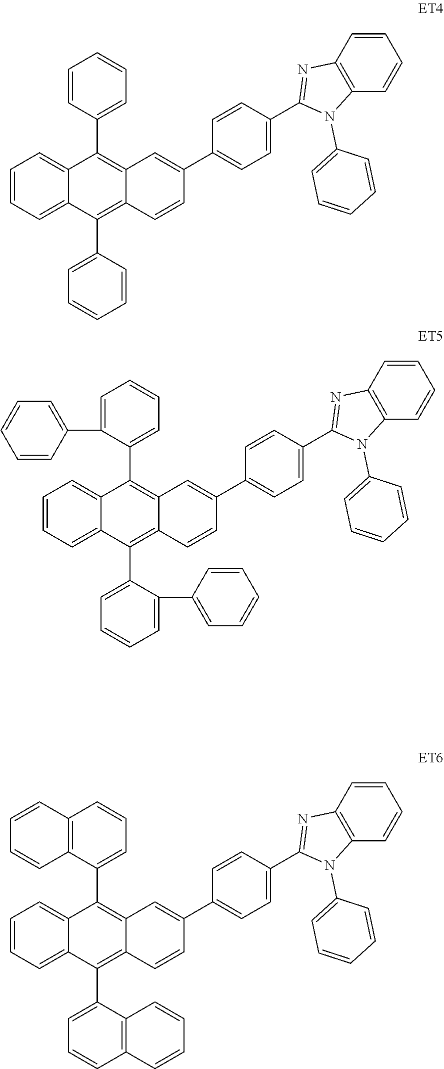 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

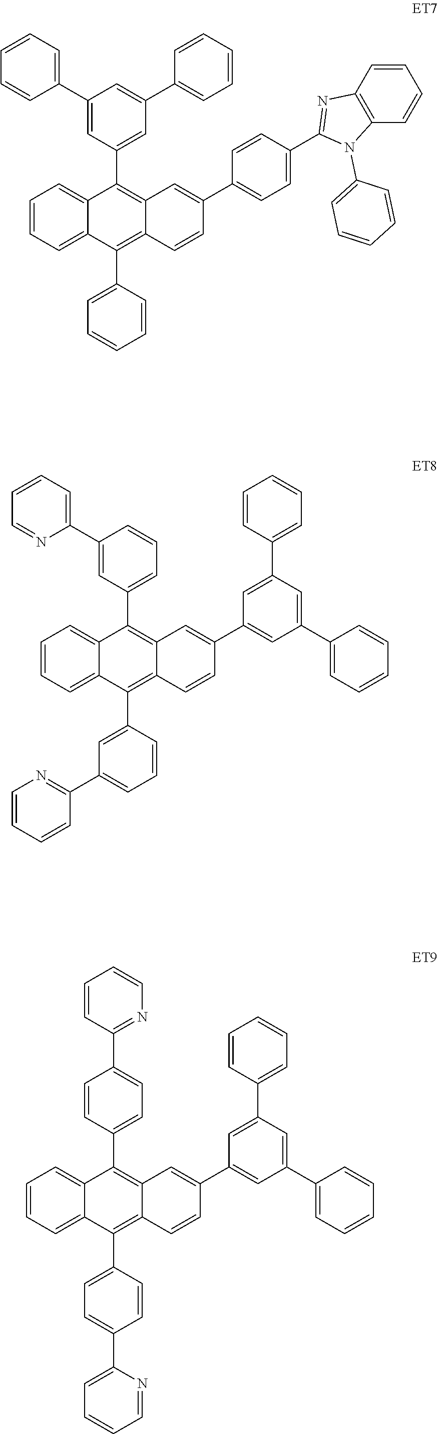 [SMILES: c1ccc(-c2cc(-c3ccccc3)cc(-c3c4ccccc4c(-c4ccccc4)c4ccc(-c5ccc(-c6nc7ccccc7n6-c6ccccc6)cc5)cc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

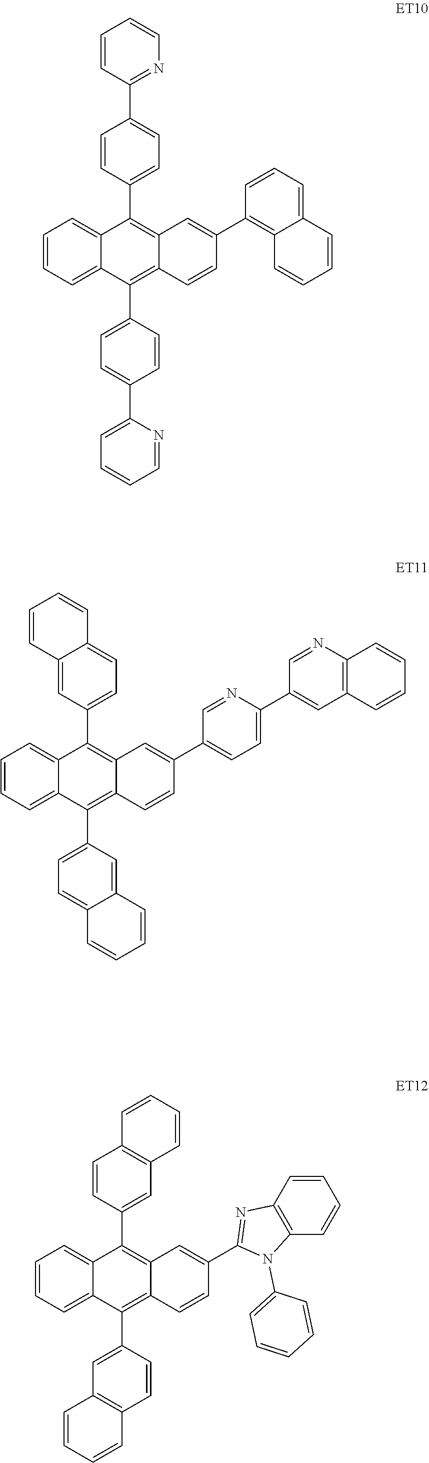 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

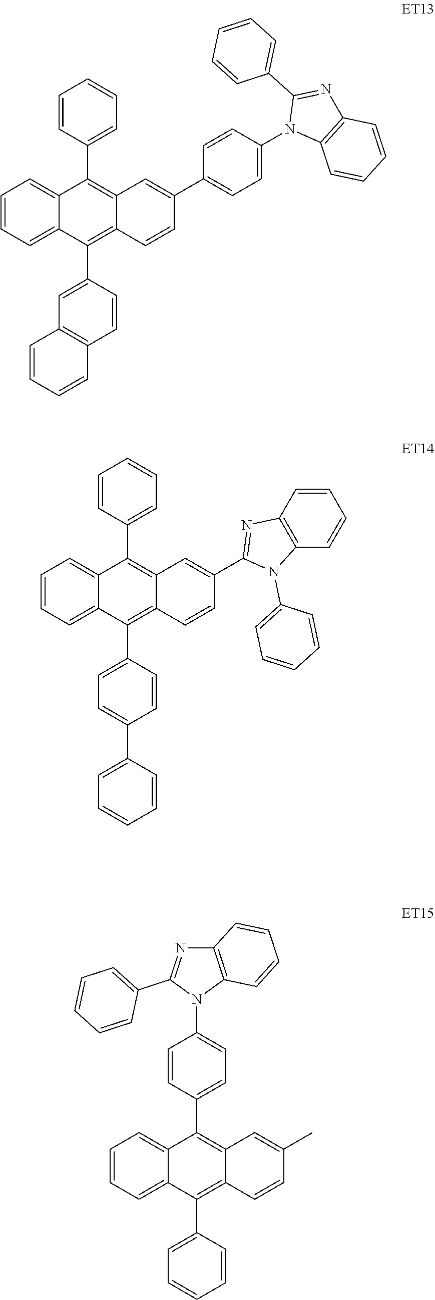 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

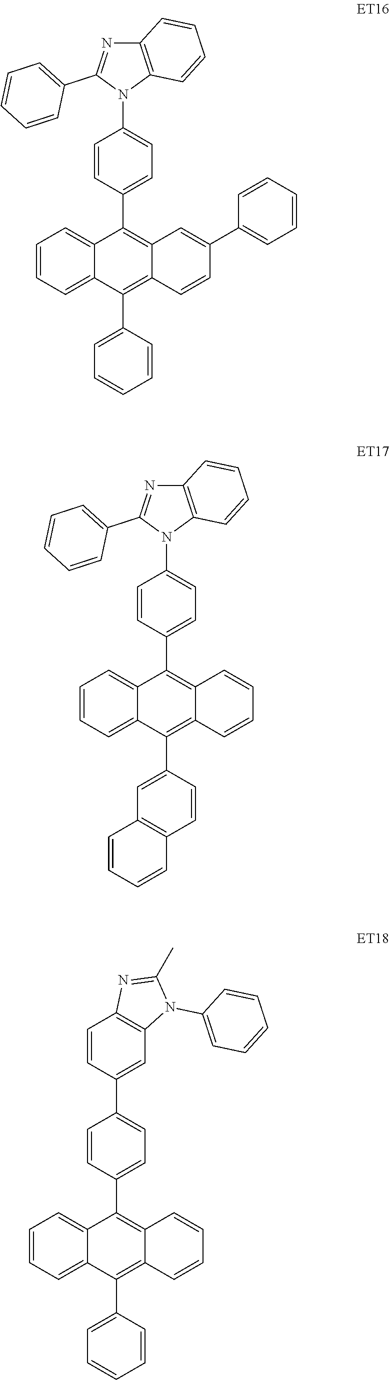 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

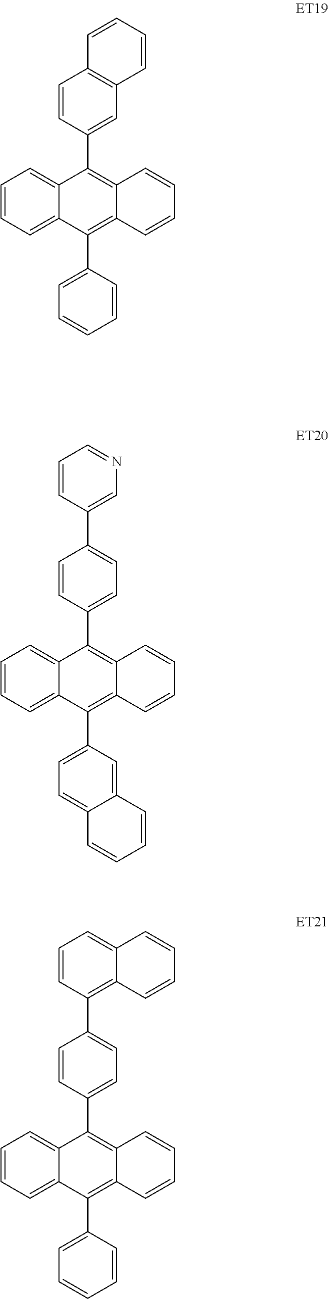

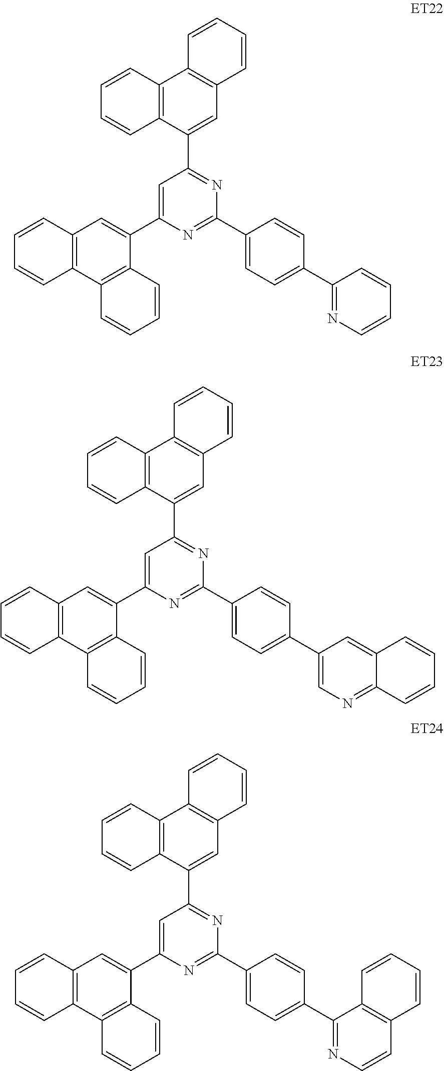 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5cc6ccccc6c6ccccc56)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

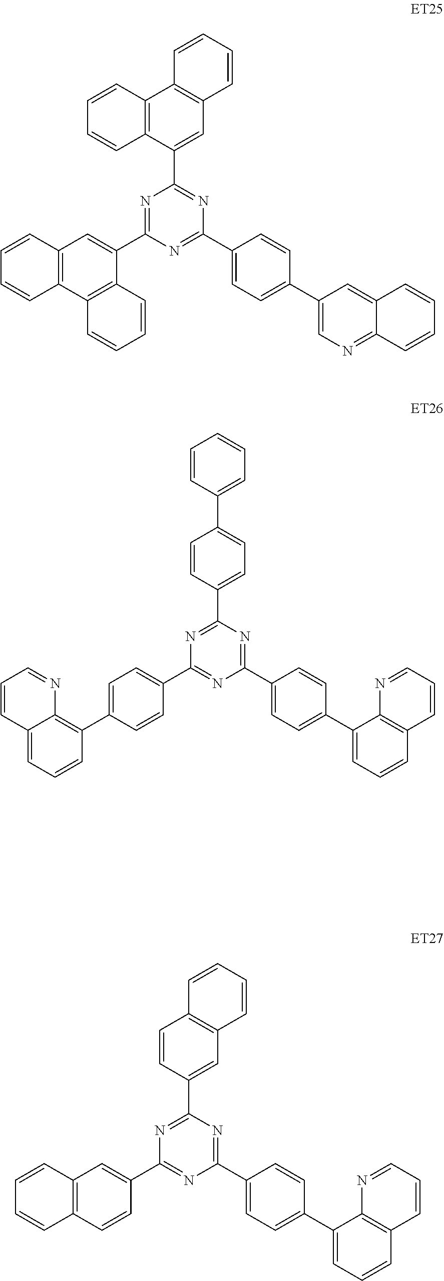 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

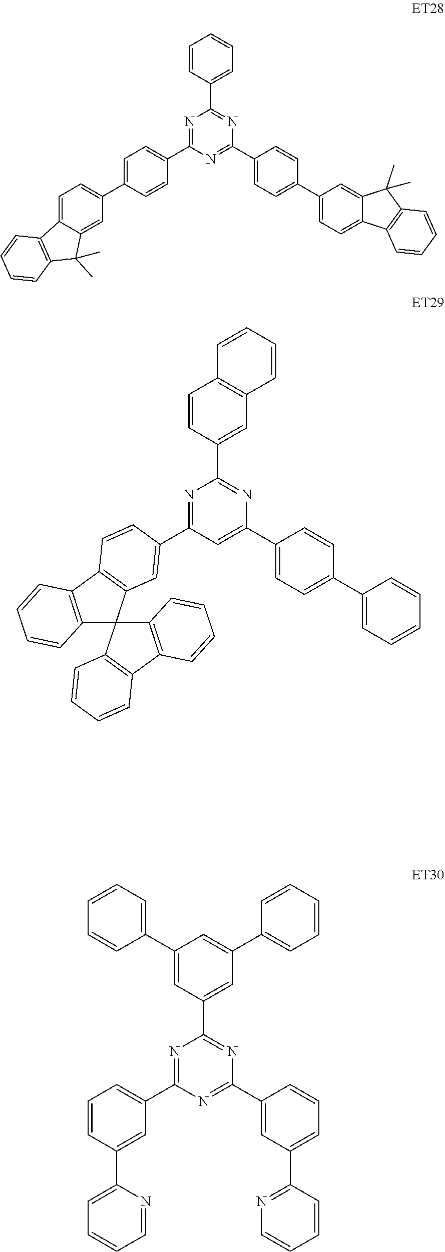 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

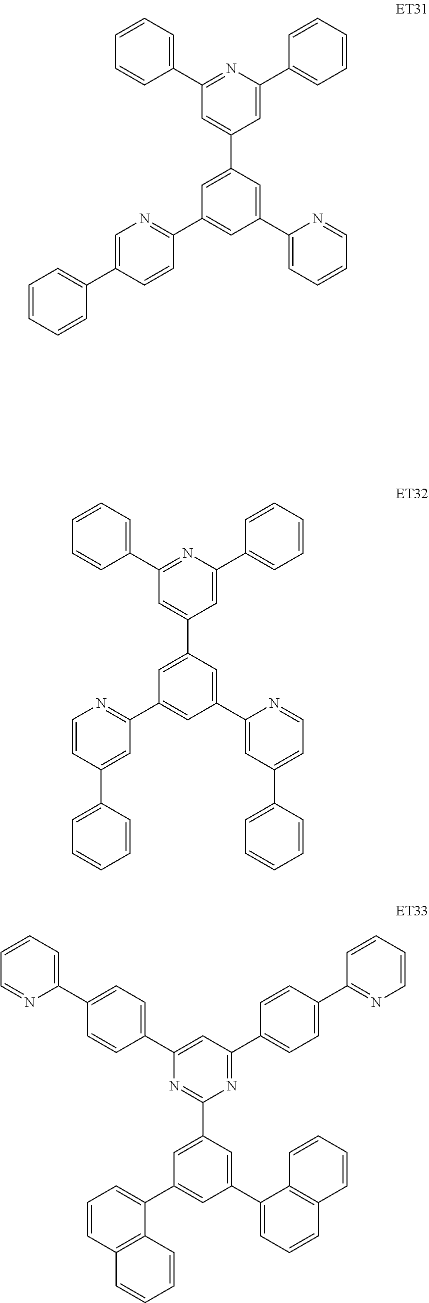 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

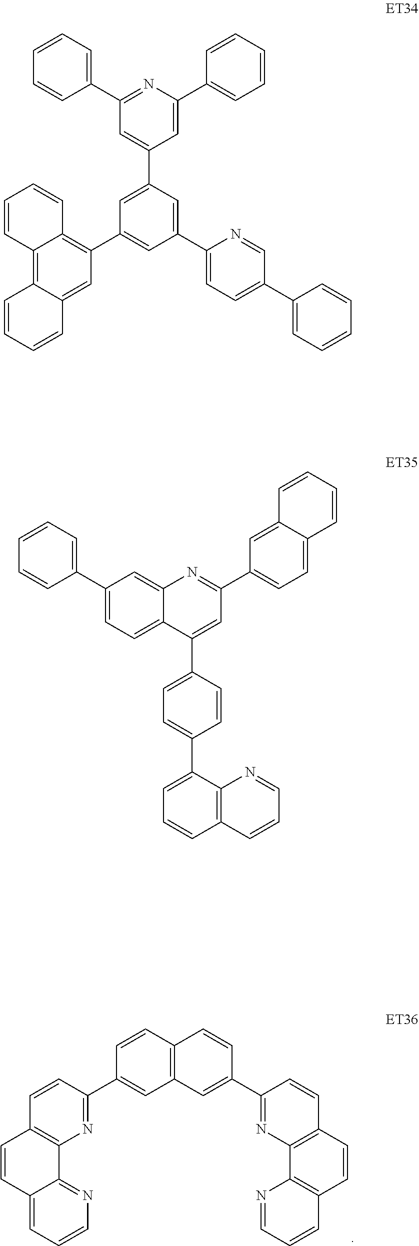 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more of the aforementioned metal materials, or oxides of the aforementioned metal materials.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), etc., or may include an epoxy resin, or an acrylate such as methacrylate. In an embodiment, a capping layer CPL may include at least one of Compounds P1 to P5, but embodiments are not limited thereto.

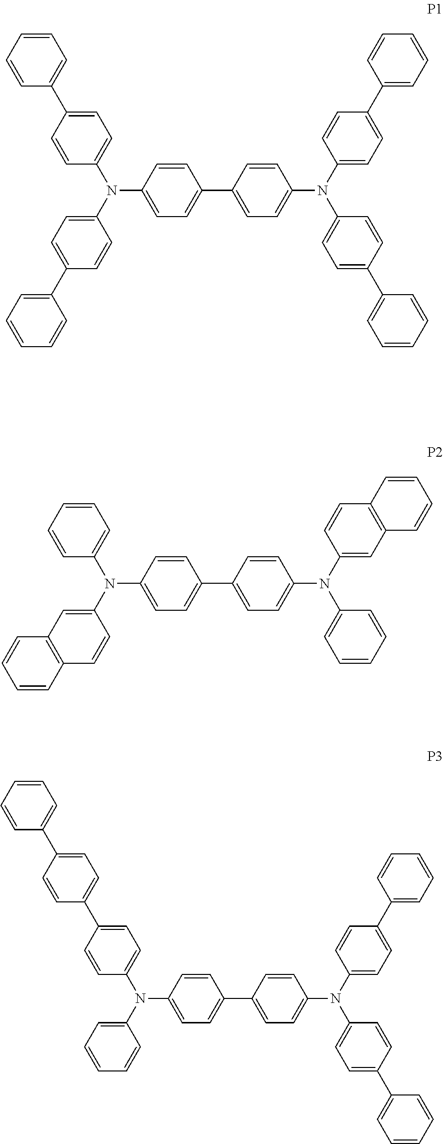 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

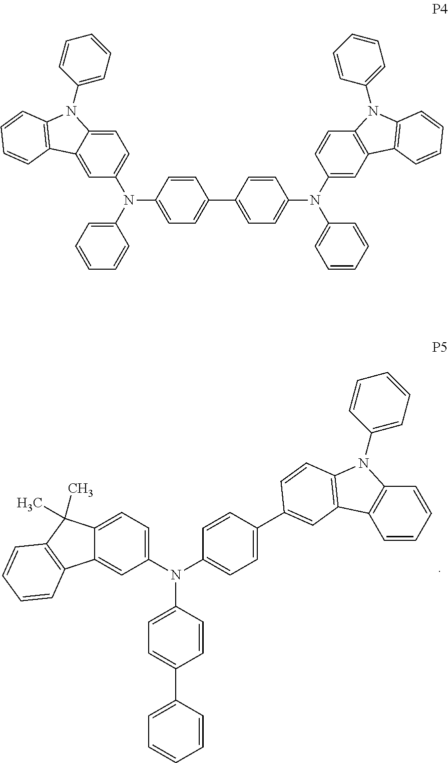 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

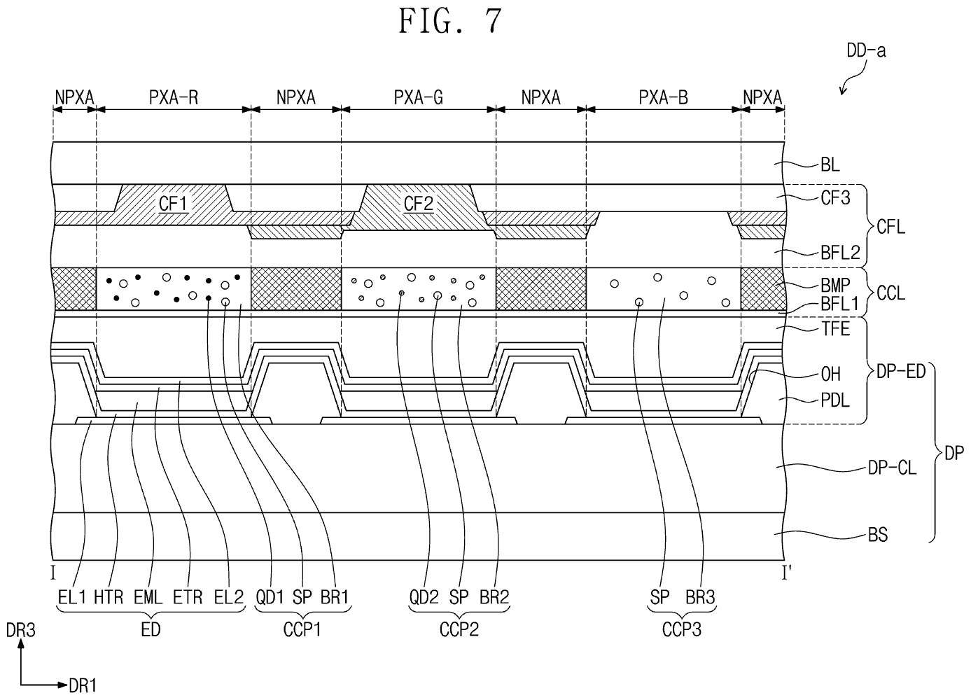

FIG. 7 to FIG. 10 are each a schematic cross-sectional view of a display device according to embodiments. In the explanation on the display devices according to embodiments as shown in FIG. 7 to FIG. 10, the features that have been described above with respect to FIG. 1 to FIG. 6 will not be explained again, and the differing features will be explained.

Referring to FIG. 7, the display device DD-a according to an embodiment may include a display panel DP including a display device layer DP-ED, a light controlling layer CCL disposed on the display panel DP, and a color filter layer CFL. In an embodiment shown in FIG. 7, the display panel DP includes a base layer BS, a circuit layer DP-CL provided on the base layer BS, and a display device layer DP-ED, and the display device layer DP-ED may include a light emitting element ED.

The light emitting element ED may include a first electrode EL1, a hole transport region HTR disposed on the first electrode EL1, a light emitting layer EML disposed on the hole transport region HTR, an electron transport region ETR disposed on the light emitting layer EML, and a second electrode EL2 disposed on the electron transport region ETR. In embodiments, a structure of the light emitting element ED shown in FIG. 7 may be the same as a structure of a light emitting element according to one of FIG. 3 to FIG. 6 as described above.

The light emitting layer EML of the light emitting element ED included in the display device DD-a according to an embodiment may include the fused polycyclic compound according to an embodiment as described above.

Referring to FIG. 7, the light emitting layer EML may be disposed in an opening OH defined in a pixel defining film PDL. For example, the light emitting layer EML, which is separated by the pixel defining film PDL and provided to correspond to each of the light emitting regions PXA-R, PXA-G, and PXA-B, may emit light in a same wavelength region. In the display device DD-a, the light emitting layer EML may emit blue light. Although not shown in the drawings, in an embodiment, the light emitting layer EML may be provided as a common layer for all of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light provided and emit the resulting light. For example, the light controlling layer CCL may be a layer that includes a quantum dot or a layer that includes a phosphor.

The light controlling layer CCL may include light controlling parts CCP1, CCP2, and CCP3. The light controlling parts CCP1, CCP2, and CCP3 may be spaced apart from each other.

Referring to FIG. 7, a partition pattern BMP may be disposed between the separated light controlling parts CCP1, CCP2, and CCP3, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light. In an embodiment, the first light controlling part CCP1 may provide red light, which is the second color light, and the second light controlling part CCP2 may provide green light, which is the third color light. The third color controlling part CCP3 may provide blue light by transmitting the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are mediums in which the quantum dots QD1 and QD2 and the scatterer SP are dispersed, and may include various resin compositions which may be referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. In an embodiment, a color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide and silicon oxynitride, and a metal thin film that secures light transmittance. The barrier layers BFL1 and BFL2 may each independently further include an organic layer. The barrier layers BFL1 and BFL2 may be composed of a single layer or of multiple layers.

In the display device DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include filters CF1, CF2, and CF3. The first to third filters CF1, CF2, and CF3 may be disposed so that they respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and nay not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

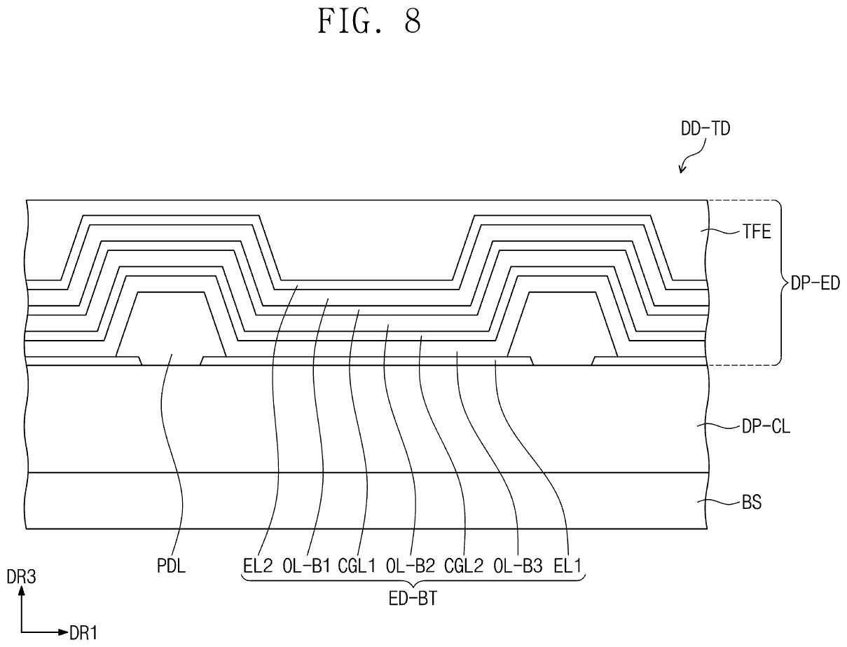

FIG. 8 is a schematic cross-sectional view of a portion of a display device according to an embodiment. In a display device DD-TD according to an embodiment, a light emitting element ED-BT may include light emitting structures OL-B1, OL-B2, and OL-B3. The light emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, a light emitting layer EML (FIG. 7), and an electron transport region ETR, which may be disposed in that order between the first electrode EL1 and the second electrode EL2.

For example, the light emitting element ED-BT included in the display device DD-TD may be a light emitting element having a tandem structure that includes multiple light emitting layers.

In an embodiment shown in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light emitting element ED-BT that includes the light emitting structures OL-B1, OL-B2, and OL-B3, which emit light in different wavelength regions, may emit white light.

Charge generating layers CGL1 and CGL2 may each be disposed between two adjacent light emitting structures among the light emitting structures OL-B1, OL-B2, and OL-B3. The charge generating layers CGL1 and CGL2 may each independently include a p-type charge generating layer and/or an n-type charge generating layer.

The fused polycyclic compound according to an embodiment as described above may be included in at least one of the light emitting structures OL-B1, OL-B2, and OL-B3 included in the display device DD-TD. For example, at least one of the light emitting layers included in the light emitting element ED-BT may include the fused polycyclic compound according to an embodiment.

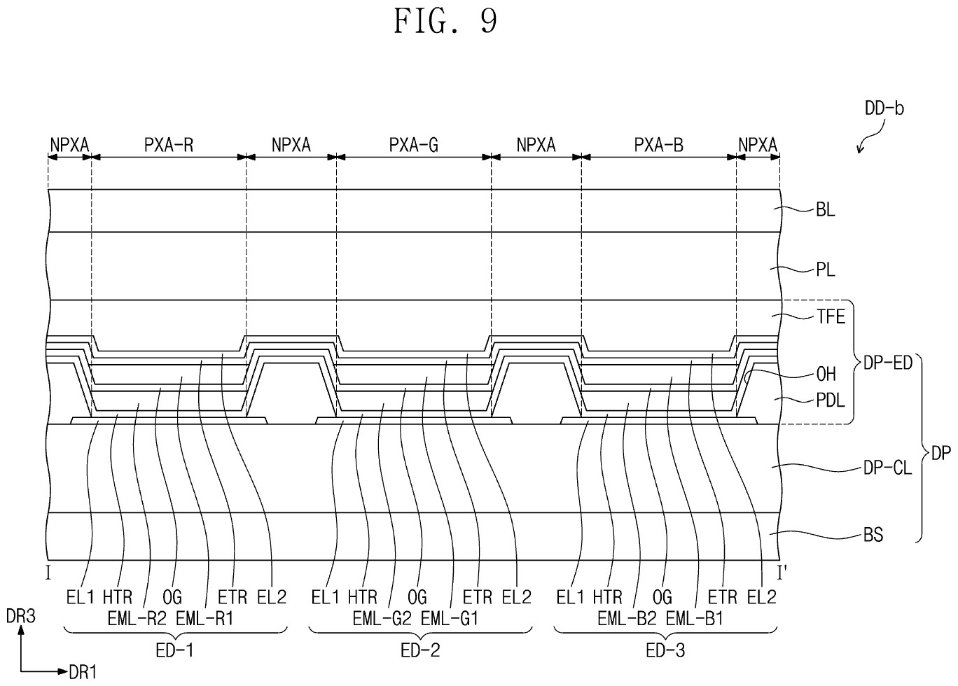

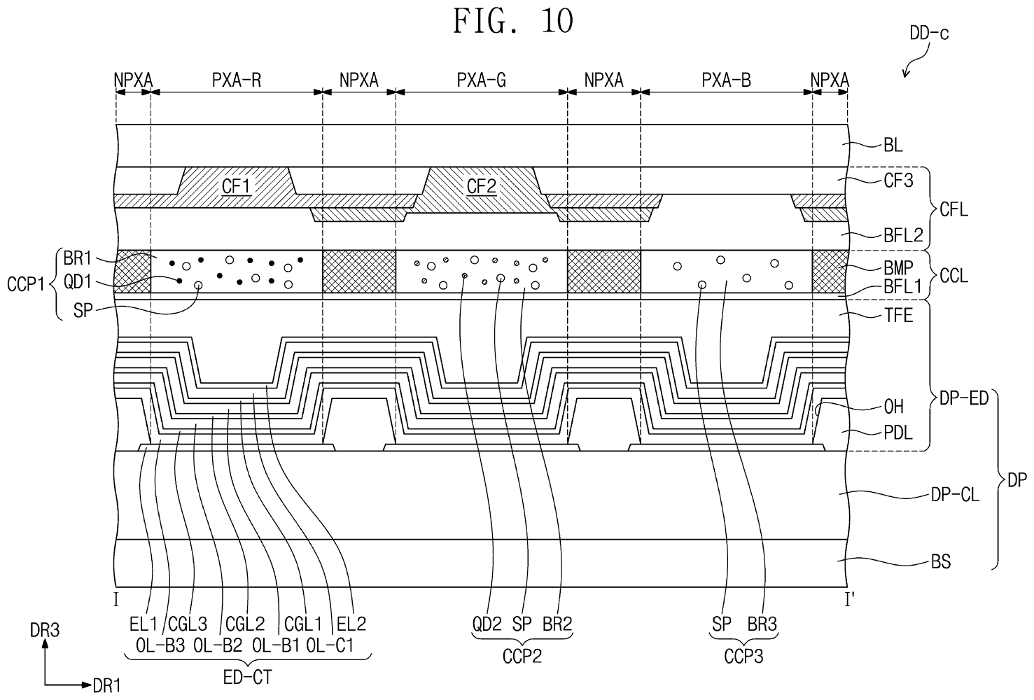

FIG. 9 is a schematic cross-sectional view of a display device DD-b according to an embodiment. FIG. 10 is a schematic cross-sectional view of a display device DD-c according to an embodiment.

Referring to FIG. 9, a display device DD-b according to an embodiment may include light emitting elements ED-1, ED-2, and ED-3, in which two light emitting layers are stacked. In comparison to the display device DD shown in FIG. 2, the embodiment shown in FIG. 9 is different at least in that the first to third light emitting elements ED-1, ED-2, and ED-3 each include two light emitting layers that are stacked in a thickness direction. In the first to third light emitting elements ED-1, ED-2, and ED-3, the two light emitting layers may emit light in a same wavelength region.

The first light emitting element ED-1 may include a first red light emitting layer EML-R1 and a second red light emitting layer EML-R2. The second light emitting element ED-2 may include a first green light emitting layer EML-G1 and a second green light emitting layer EML-G2. The third light emitting element ED-3 may include a first blue light emitting layer EML-B1 and a second blue light emitting layer EML-B2. An emission auxiliary part OG may be disposed between the first red light emitting layer EML-R1 and the second red light emitting layer EML-R2, between the first green light emitting layer EML-G1 and the second green light emitting layer EML-G2, and between the first blue light emitting layer EML-B1 and the second blue light emitting layer EML-B2.

The emission auxiliary part OG may have a single-layered structure or a multilayered structure. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for the first to third light emitting elements ED-1, ED-2, and ED-3. However, embodiments are not limited thereto, and the emission auxiliary part OG may be provided by being patterned within the openings OH defined in a pixel definition layer PDL.

The first red light emitting layer EML-R1, the first green light emitting layer EML-G1, and the first blue light emitting layer EML-B1 may each be disposed between the electron transport region ETR and the emission auxiliary part OG. The second red light emitting layer EML-R2, the second green light emitting layer EML-G2, and the second blue light emitting layer EML-B2 may each be disposed between the emission auxiliary part OG and the hole transport region HTR.

The first light emitting element ED-1 may include a first electrode EL1, a hole transport region HTR, a second red light emitting layer EML-R2, an emission auxiliary part OG, a first red light emitting layer EML-R1, an electron transport region ETR, and a second electrode EL2, which are stacked in that order. The second light emitting element ED-2 may include a first electrode EL1, a hole transport region HTR, a second green light emitting layer EML-G2, an emission auxiliary part OG, a first green light emitting layer EML-G1, an electron transport region ETR, and a second electrode EL2, which are stacked in that order. The third light emitting element ED-3 may include a first electrode EL1, a hole transport region HTR, a second blue light emitting layer EML-B2, an emission auxiliary part OG, a first blue light emitting layer EML-B1, an electron transport region ETR, and a second electrode EL2, which are stacked in that order.

An optical auxiliary layer PL may be disposed on a display device layer DP-ED. The optical auxiliary layer PL may include a polarization layer. The optical auxiliary layer PL may be disposed on a display panel DP and may control light that is reflected at the display panel DP from an external light. Although not shown in the drawings, in an embodiment, the optical auxiliary layer PL may be omitted from the display device DD-b.

At least one light emitting layer included in the display device DD-b illustrated in FIG. 9 may include the fused polycyclic compound according to an embodiment as described above. For example, in an embodiment, at least one of the first blue light emitting layer EML-B1 and the second blue light emitting layer EML-B2 may include the fused polycyclic compound according to an embodiment.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in that order in a thickness direction between the first electrode EL1 and the second electrode EL2.

Charge generating layers CGL1, CGL2, and CGL3 may each be disposed between two adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1, a second charge generating layer CGL2 may be disposed between the first light emitting structure OL-B1 and the second light emitting structure OL-B2, and a third charge generating layer CGL3 may be disposed between the second light emitting structure OL-B2 and the third light emitting structure OL-B3. The charge generating layers CGL1, CGL2, and CGL3 may each independently include a p-type charge generating layer and/or an n-type charge generating layer.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The fused polycyclic compound according to an embodiment as described above may be included in at least one of the light emitting structures OL-B1, OL-B2, OL-B3, and OL-C1 included in the display device DD-c. For example, in an embodiment, at least one of the first to third light emitting structures OL-B1, OL-B2, and OL-B3 may each independently include the fused polycyclic compound.

The light emitting element ED according to an embodiment includes the fused polycyclic compound represented by Formula 1 as described above in at least one functional layer disposed between the first electrode EL1 and the second electrode EL2, and thus, may exhibit excellent luminous efficiency and improved lifespan properties. For example, the fused polycyclic compound according to an embodiment may be included in a light emitting layer EML of the light emitting element ED, and the light emitting element ED may exhibit long lifespan properties.

In an embodiment, an electronic apparatus may include a display device that includes multiple light emitting elements, and a control part that controls the display device. The electronic apparatus may be an apparatus that is activated according to electrical signals. The electronic apparatus may include display devices according to various embodiments. Examples of an electronic apparatus may include large, medium-sized, and small electronic devices, such as a television, a monitor, a billboard, a personal computer, a laptop computer, a personal digital terminal, a display device for a vehicle, a game console, a portable electronic device, and a camera.

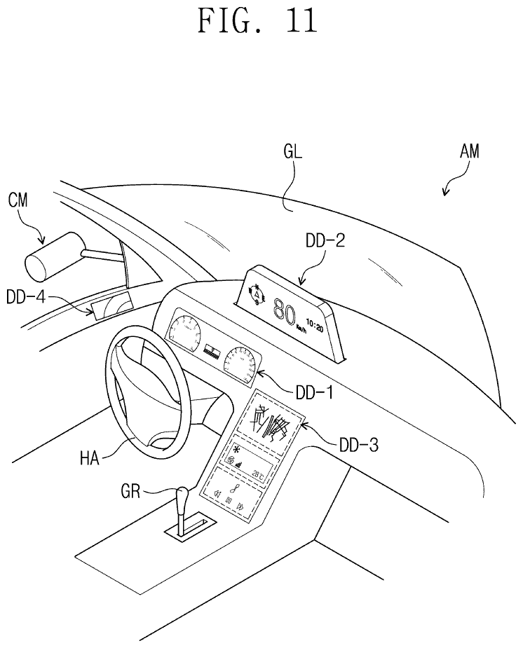

FIG. 11 is a schematic diagram of a vehicle AM that includes first to fourth display devices DD-1, DD-2, DD-3 and DD-4. At least one of the first to fourth display devices DD-1, DD-2, DD-3 and DD-4 may have a structure according to one of display devices DD, DD-TD, DD-a, DD-b, and DD-c, as described above with reference to FIGS. 1, 2, and 7 to 10.

In FIG. 11, an automobile is shown as a vehicle AM, but this is only an example, and the first to fourth display devices DD-1, DD-2, DD-3 and DD-4 may be disposed in various transport means such as a bicycle, a motorcycle, a train, a ship, and an airplane. In an embodiment, at least one of the first to fourth display devices DD-1, DD-2, DD-3 and DD-4 having a structure according to one of display devices DD, DD-TD, DD-a, DD-b, and DD-c may be included in a personal computer, a laptop computer, a personal digital terminal, a game console, a portable electronic device, a television, a monitor, a billboard, or the like. However, these are merely provided as examples, and the display device may be included in other electronic devices.

At least one of the first to fourth display devices DD-1, DD-2, DD-3, and DD-4 may each independently include a light emitting element ED according to an embodiment as described with reference to any of FIGS. 3 to 6. The light emitting element ED may include a fused polycyclic compound according to an embodiment. At least one of the first to fourth display devices DD-1, DD-2, DD-3, and DD-4 may include a light emitting element ED that includes a fused polycyclic compound according to an embodiment, thereby improving display service life.

Referring to FIG. 11, the vehicle AM may include a steering wheel HA for operating the vehicle AM and a gearshift GR. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), and images that represent a fuel gauge. The first scale and the second scale may each be represented by digital images.

A second display device DD-2 may be disposed in a second region facing a driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed of the vehicle AM, and may further include information such as the current time. Although not shown in the drawings, in an embodiment, the second information of the second display device DD-2 may be displayed by being projected on the front window GL.

A third display device DD-3 may be disposed in a third region that is adjacent to the gearshift GR. For example, the third display device DD-3 may be a center information display (CID) for a vehicle that is disposed between a driver's seat and a passenger seat and which displays third information. The passenger seat may be a seat that is spaced apart from the driver's seat, and the gearshift GR may be disposed between the driver's seat and the passenger seat. The third information may include information about traffic conditions (for example, navigation information), about music or radio that is playing, about a video (or image) that is displayed, about temperatures in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3 and DD-4 may further display information on the interior and exterior of the vehicle AM. The first to fourth information may include information that is different from each other. However, embodiments are not limited thereto, and a portion of the first to fourth information may include a same information.

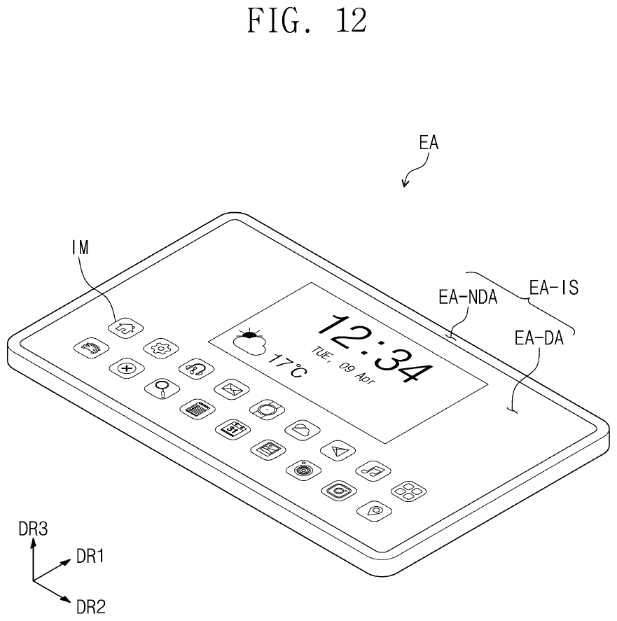

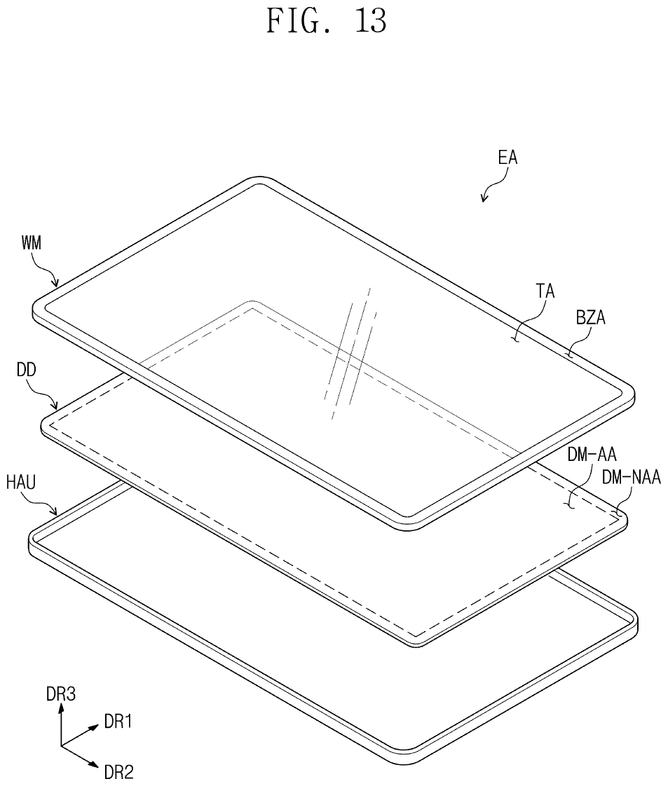

FIG. 12 is a schematic perspective view of an electronic apparatus according to an embodiment. FIG. 13 is an exploded perspective view of an electronic apparatus according to an embodiment.

An electronic apparatus EA may display an image IM through a display surface EA-IS. The image IM may be a dynamic image or a static image. The display surface EA-IS may be parallel to a plane defined by a first direction axis DR1 and a second direction axis DR2. FIG. 12 shows to electronic apparatus EA as having a flat display surface EA-IS, but embodiments are not limited thereto. For example, the electronic apparatus EA may have a curved display surface or a three-dimensional display surface. The three-dimensional display surface may include multiple display areas that face different directions.

The display surface EA-IS may include a display area EA-DA and a non-display area EA-NDA. The electronic apparatus EA may display an image IM through the display area EA-DA.

The non-display area EA-NDA may have a selected or given color. The non-display area EA-NDA may be adjacent to the display area EA-DA. The non-display area EA-NDA may surround the display area EA-DA. Accordingly, the shape of the display area EA-DA may be substantially defined by the non-display area EA-NDA. However, FIG. 12 is only shown as an example, and the non-display area EA-NDA may be disposed adjacent to only one side of the display area EA-DA, or it may be omitted.

Referring to FIG. 13, the electronic apparatus EA may include a display device DD. The electronic apparatus EA may further include a window member WM and a housing HAU.

The window member WM may cover an entire outer surface of the electronic apparatus EA. The window member WM may include a transparent area TA and a bezel area BZA. The front surface of the window member WM, which includes the transparent area TA and the bezel area BZA, may correspond to the front surface of the electronic apparatus EA. The transparent area TA may correspond to the display area EA-DA of the electronic apparatus EA shown in FIG. 12, and the bezel area BZA may correspond to the non-display area EA-NDA of the electronic apparatus EA shown in FIG. 12.

The transparent area TA may be an optically transparent area. The bezel area BZA may be an area having a relatively low light transmittance as compared to the transparent area TA. The bezel area BZA may have a selected or given color. The bezel area BZA may be adjacent to the transparent area TA and may surround the transparent area TA. The bezel area BZA may define the shape of the transparent area TA. However, embodiments are not limited thereto, and the bezel area BZA may be disposed adjacent to only one side of the transparent area TA, or a portion of the bezel area BZA may be omitted.

The housing HAU may include a material having relatively high rigidity. For example, the housing HAU may include a frame and/or a plate made of glass, plastic, or metal. The frames and/or plates may be provided in multiple pieces. The housing HAU may provide an enclosure. The display device DD may be seated in the enclosure and protected from external impact.

The display device DD may have a structure according to one of display devices DD, DD-TD, DD-a, DD-b, and DD-c, as described above with reference to FIGS. 1, 2, and 7 to 10. The display device DD may include a light emitting element ED according to an embodiment as described with reference to any of FIGS. 3 to 6. Accordingly, the electronic apparatus EA including the display device DD according to an embodiment may exhibit excellent reliability.

An active area DM-AA and a peripheral area DM-NAA may be defined in the display device DD. The active area DM-AA may overlap the display area EA-DA illustrated in FIG. 12, and the peripheral area DM-NAA may overlap the non-display area EA-NDA illustrated in FIG. 12.

The active area DM-AA may be an area that is activated according to an electrical signal. The peripheral area DM-NAA may be an area that is positioned adjacent to at least one side of the active area DM-AA. The active area DM-AA may include the non-light emitting area NPXA and light emitting areas PXA-R, PXA-G and PXA-B as shown in FIG. 1. The peripheral area DM-NAA may surround the active area DM-AA. However, embodiments are not limited thereto. Although not shown in the drawings, some portions of the peripheral areas DM-NAA may be omitted. A driving circuit or a driving wiring for driving the active area DM-AA may be disposed in the peripheral area DM-NAA.

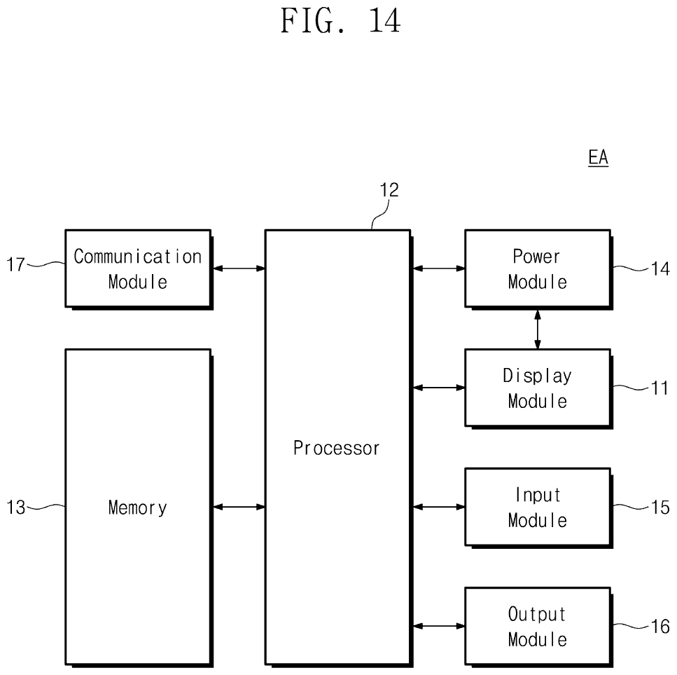

The electronic apparatus EA according to an embodiment includes the display device DD as described above, and may further include a module or device having an additional function, in addition to the display device DD. FIG. 14 is a block diagram of an electronic apparatus according to an embodiment. Referring to FIG. 14, an electronic apparatus EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. Data that is used for the operation of the processor 12 or the display module 11 may be stored in the memory 13. If the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts the power supplied by the power supply module to generate power for the operation of the electronic apparatus EA.

The display module 11 may have a configuration according to at least one of the display devices DD, DD-TD, DD-a, DD-b, and DD-c, as described above with reference to FIGS. 1, 2, and 7 to 10. For example, the display module 11 may include a base layer BS, a circuit layer DP-CL, and a display element layer DP-ED among the configurations of the display devices DD, DD-TD, DD-a, DD-b, and DD-c, as described above with reference to FIGS. 1, 2, and 7 to 10. In embodiments, the display module 11 may further include at least one of an optical layer PP (FIG. 2), a light control layer CCL (FIGS. 7 and 10), a color filter layer CFL (FIGS. 7 and 10), and an optical auxiliary layer PL (FIG. 10).

The electronic apparatus EA may further include an input module 15, a non-image output module 16, and/or a communication module 17.

The input module 15 may provide input information to the processor 12 and/or the display module 11. The input module 15 may include various sensor modules as well as physical buttons, a keyboard, and a microphone. Examples of a sensor module may include touch sensors, pressure sensors, distance sensors, position sensors, digitizers, motion recognition sensors, camera sensors, photodetector, photoelectric conversion sensors, temperature sensors, and biosensors such as blood pressure sensors, blood sugar sensors, electrocardiogram sensors, and heart rate sensors.

The non-image output module 16 may receive information other than images transmitted from the processor 12 and provide the information to the user. Examples of a non-image output module 16 may include an audio module, a haptic module, a light emitting module, and the like, and may include other electronic device-specific functional modules (e.g., a cooling module of a refrigerator, and the like).

The communication module 17 is a module that transmits and receives information between the electronic apparatus EA and an external device, and may include a receiving part and a transmitting part. The communication module 17 may include various wireless communication modules such as a mobile communication module, a Wi-Fi module, and a Bluetooth module, or various wired communication modules.

At least one module of the electronic apparatus EA as described above may be included in the display device as described above (for example, at least one of DD, DD-TD, DD-a, DD-b, and DD-c, FIGS. 1, 2, and 7 to 10) according to an embodiment. In embodiments, some individual components that are functionally included in a module may be included in the display device, and other modules may be provided separately from the display device. For example, the display device may include the display module 11, and the processor 12, the memory 13, and the power module 14 may be provided in other devices within the electronic apparatus EA other than the display device.

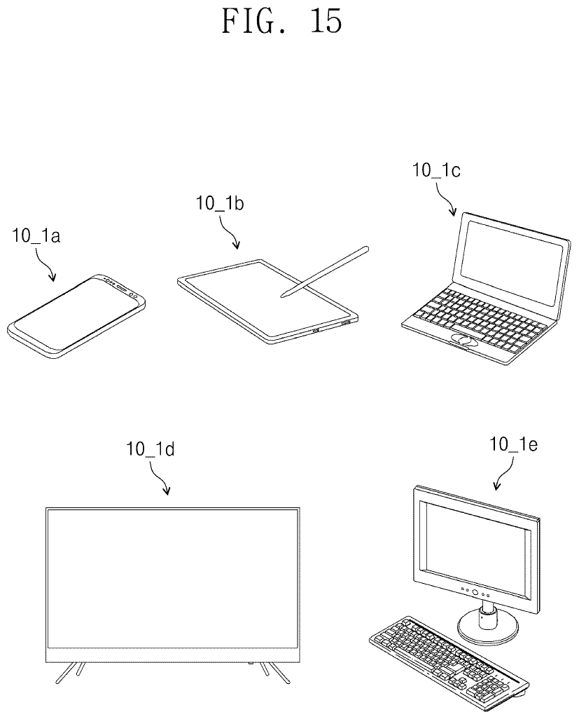

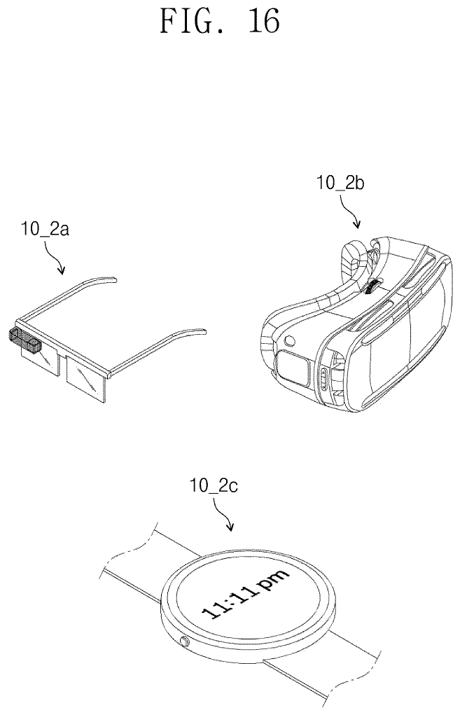

FIGS. 15 and 16 show schematic diagrams of electronic apparatuses according to various embodiments. Referring to FIGS. 15 and 16, examples of electronic apparatuses that include a display device according to an embodiment (for example, at least one of DD, DD-TD, DD-a, DD-b, and DD-c, FIGS. 1, 2, and 7 to 10) may include image display electronic apparatuses such as a smartphone 10_1a, a tablet computer 10_1b, a laptop computer 10_1c, a television 10_1d, and a desktop monitor 10_1e. Further examples of electronic apparatuses that include a display device according to an embodiment may include wearable electronic apparatuses that include display modules such as smart glasses 10_2a, a head-mounted display 10_2b, and a smart watch 10_2c. However, these are only shown as examples, and the electronic apparatus according to an embodiment is not limited thereto.

Hereinafter, a fused polycyclic compound according to an embodiment and a light emitting element according to an embodiment will be described in detail with reference to the Examples and the Comparative Examples. The Examples shown below are only provided to facilitate in understanding the disclosure, and the scope thereof is not limited thereto.

### EXAMPLES

### 1. Synthesis of Fused Polycyclic Compound

A method for synthesizing a fused polycyclic compound according to an embodiment will be described in detail by describing synthesis methods for Compounds 12, 40, 83, 87, 92, 94, and 96. In the following descriptions, a method for synthesizing a fused polycyclic compound is only provided as an example, and the method for synthesizing a fused polycyclic compound according to an embodiment is not limited to the Examples.

### (1) Synthesis of Compound 12

Compound 12 according to an embodiment may be synthesized by, for example, the following reaction.

### (Synthesis of Intermediate 12-1)

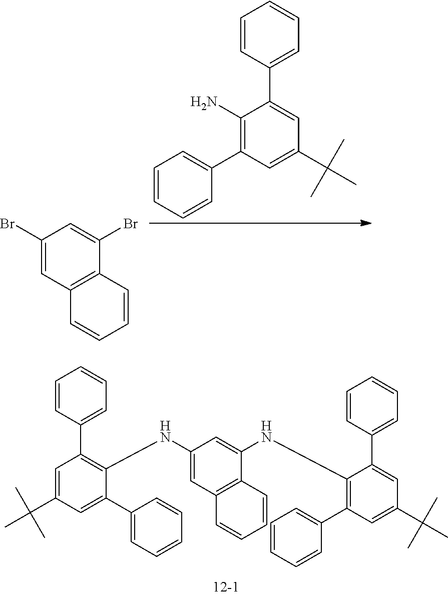

1,3-dibromonaphthalene (1 eq), 5′-(tert-butyl)-[1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in o-xylene, and stirred at 140 degrees Celsius for 12 hours. The mixture was cooled, and washed with ethyl acetate and water, and separated to obtain an organic layer, which was dried with MgSO₄ and dried under reduced pressure. Intermediate 12-1 was obtained by purification by column chromatography using methylene chloride (MC) and n-hexane. (Yield: 78%)

### (Synthesis of Intermediate 12-2)

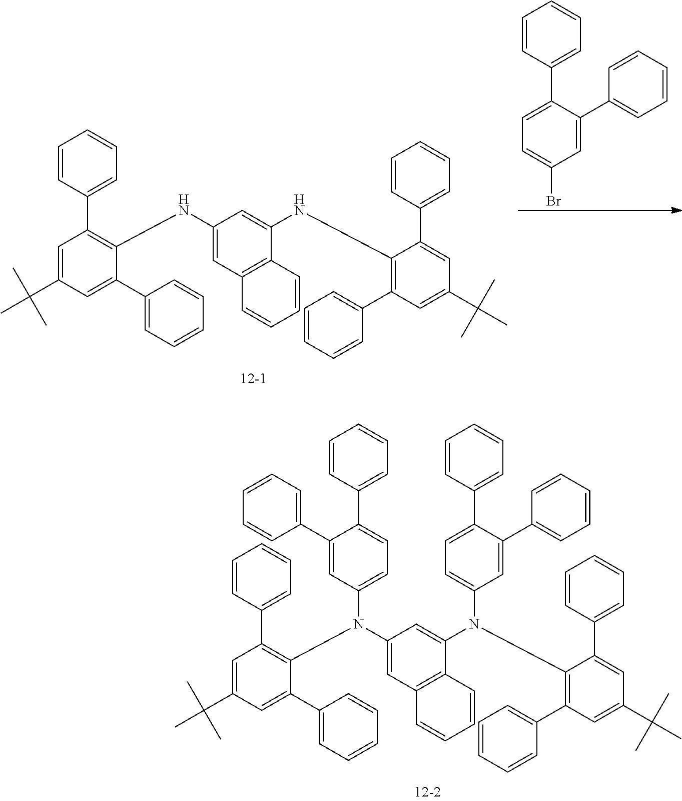

Intermediate 12-1 (1 eq), 4′-bromo-1,1′: 2′,1″-terphenyl (4 eq), tris(dibenzylideneacetone)dipalladium(0) (0.15 eq), tri-tert-butylphosphine (0.3 eq), and sodium tert-butoxide (5 eq) were dissolved in o-xylene, and stirred at 140 degrees Celsius for 60 hours. The mixture was cooled, and washed with ethyl acetate and water, and separated to obtain an organic layer, which was dried with MgSO₄ and dried under reduced pressure. Intermediate 12-2 was obtained by purification by column chromatography using MC and n-hexane. (Yield: 36%)

### (Synthesis of Compound 12)

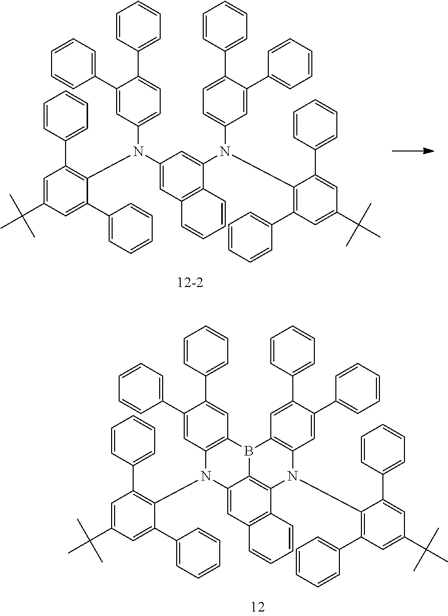

Intermediate 12-2 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 12. (Yield: 18%)

### (2) Synthesis of Compound 40

Compound 40 according to an embodiment may be synthesized by, for example, the following reaction.

### (Synthesis of Intermediate 40-1)

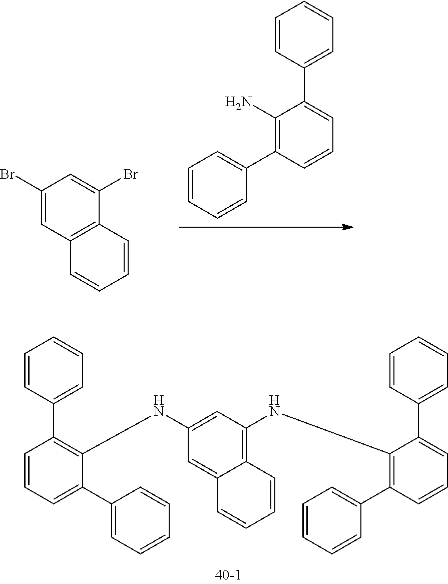 [SMILES: Brc1cc(Br)c2ccccc2c1 ; Nc1c(-c2ccccc2)cccc1-c1ccccc1 ; c1ccc(-c2cccc(-c3ccccc3)c2Nc2cc(Nc3c(-c4ccccc4)cccc3-c3ccccc3)c3ccccc3c2)cc1]

1,3-dibromonaphthalene (1 eq), [1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in o-xylene, and stirred at 140 degrees Celsius for 12 hours. The mixture was cooled, and washed with ethyl acetate and water, and separated to obtain an organic layer, which was dried with MgSO₄ and dried under reduced pressure. Intermediate 40-1 was obtained by purification by column chromatography using MC and n-hexane. (Yield: 81%)

### (Synthesis of Intermediate 40-2)

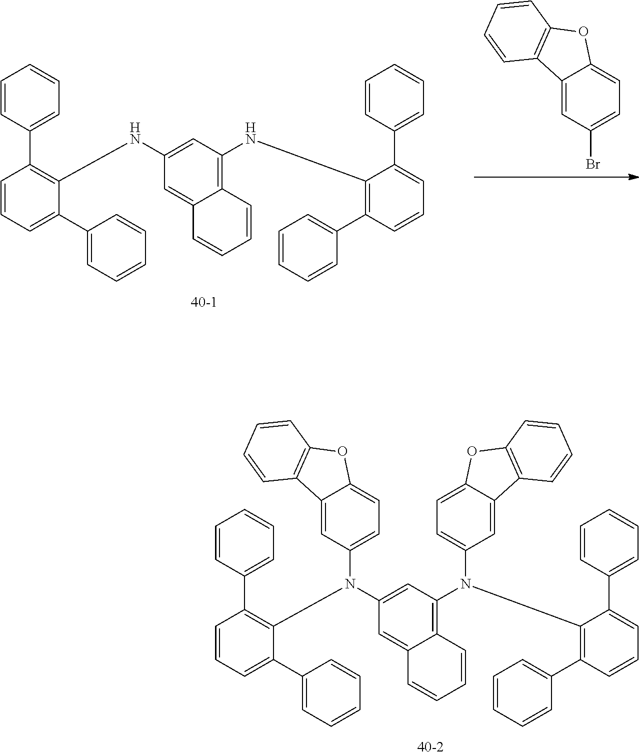 [SMILES: c1ccc(-c2cccc(-c3ccccc3)c2Nc2cc(Nc3c(-c4ccccc4)cccc3-c3ccccc3)c3ccccc3c2)cc1 ; Brc1ccc2oc3ccccc3c2c1 ; c1ccc(-c2cccc(-c3ccccc3)c2N(c2cc(N(c3ccc4oc5ccccc5c4c3)c3c(-c4ccccc4)cccc3-c3ccccc3)c3ccccc3c2)c2ccc3oc4ccccc4c3c2)cc1]

Intermediate 40-1 (1 eq), 2-bromodibenzo[b,d]furan (4 eq), tris(dibenzylideneacetone)dipalladium(0) (0.15 eq), tri-tert-butylphosphine (0.3 eq), and sodium tert-butoxide (5 eq) were dissolved in o-xylene, and stirred at 140 degrees Celsius for 60 hours. The mixture was cooled, and washed with ethyl acetate and water, and separated to obtain an organic layer, which was dried with MgSO₄ and dried under reduced pressure. Intermediate 40-2 was obtained by purification by column chromatography using MC and n-hexane. (Yield: 42%)

### (Synthesis of Compound 40)

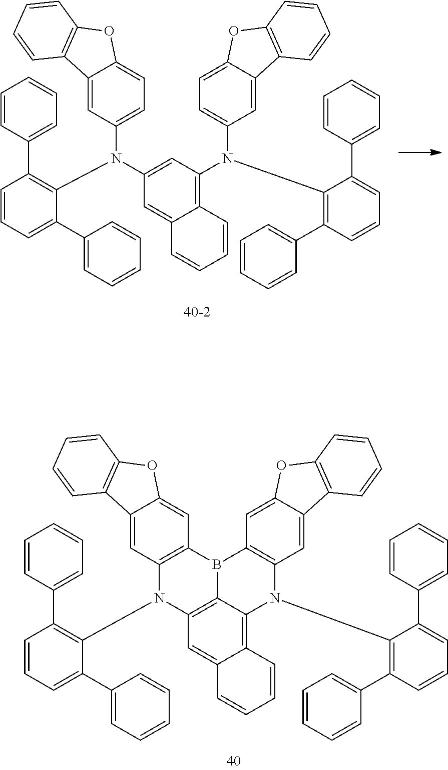 [SMILES: c1ccc(-c2cccc(-c3ccccc3)c2N(c2cc(N(c3ccc4oc5ccccc5c4c3)c3c(-c4ccccc4)cccc3-c3ccccc3)c3ccccc3c2)c2ccc3oc4ccccc4c3c2)cc1 ; c1ccc(-c2cccc(-c3ccccc3)c2N2c3cc4c(cc3B3c5cc6oc7ccccc7c6cc5N(c5c(-c6ccccc6)cccc5-c5ccccc5)c5c3c2cc2ccccc52)oc2ccccc24)cc1]

Intermediate 40-2 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 40. (Yield: 15%)

### (3) Synthesis of Compound 83

Compound 83 according to an embodiment may be synthesized by, for example, the following reaction.

### (Synthesis of Intermediate 83-1)

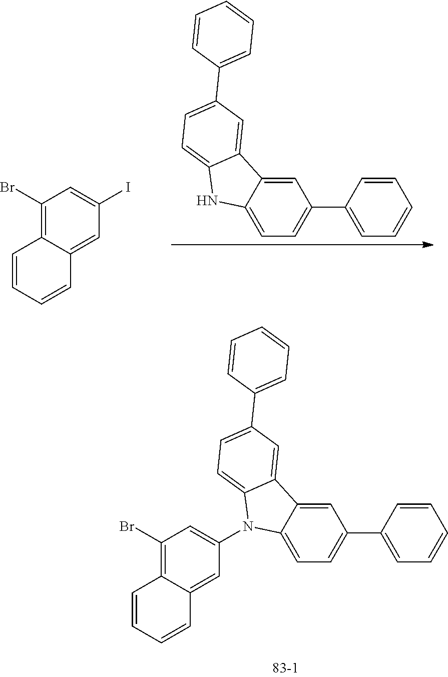 [SMILES: Brc1cc(I)cc2ccccc12 ; c1ccc(-c2ccc3[nH]c4ccc(-c5ccccc5)cc4c3c2)cc1 ; Brc1cc(-n2c3ccc(-c4ccccc4)cc3c3cc(-c4ccccc4)ccc32)cc2ccccc12]

1-bromo-3-iodonaphthalene (1 eq), 3,6-diphenyl-9H-carbazole (1 eq), tris(dibenzylideneacetone)dipalladium(0) (0.1 eq), tri-tert-butylphosphine (0.2 eq), and sodium tert-butoxide (3 eq) were dissolved in toluene, and stirred at 80 degrees Celsius for 6 hours. The mixture was cooled, and washed with ethyl acetate and water, and separated to obtain an organic layer, which was dried with MgSO₄ and dried under reduced pressure. Intermediate 83-1 was obtained by purification by column chromatography using MC and n-hexane. (Yield: 54%)

### (Synthesis of Intermediate 83-2)

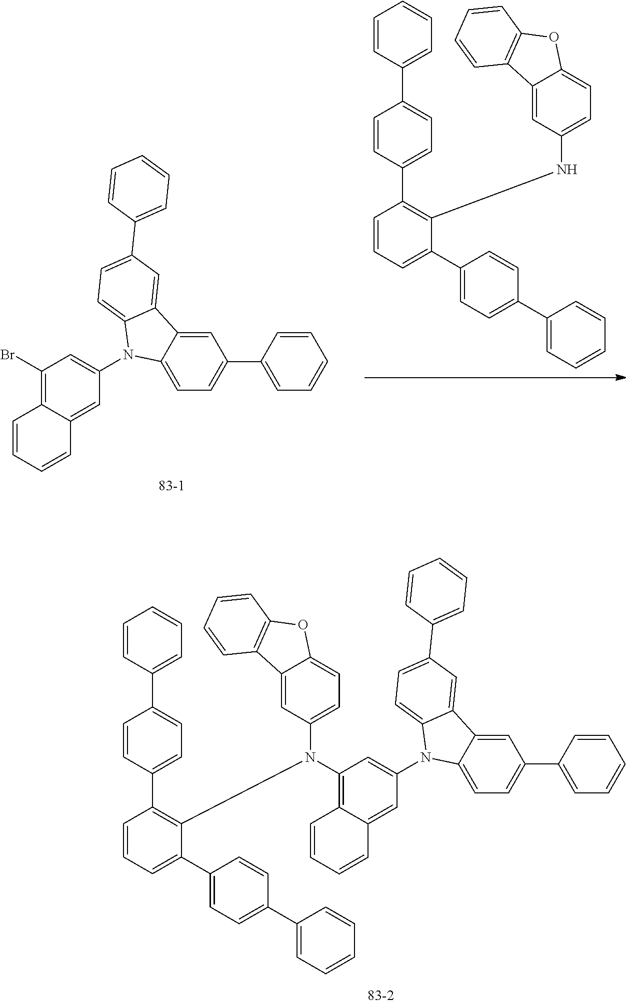 [SMILES: Brc1cc(-n2c3ccc(-c4ccccc4)cc3c3cc(-c4ccccc4)ccc32)cc2ccccc12 ; c1ccc(-c2ccc(-c3cccc(-c4ccc(-c5ccccc5)cc4)c3Nc3ccc4oc5ccccc5c4c3)cc2)cc1 ; c1ccc(-c2ccc(-c3cccc(-c4ccc(-c5ccccc5)cc4)c3N(c3ccc4oc5ccccc5c4c3)c3cc(-n4c5ccc(-c6ccccc6)cc5c5cc(-c6ccccc6)ccc54)cc4ccccc34)cc2)cc1]

Intermediate 83-1 (1 eq), N-([1,1′:4′,1″:3″,1′″:4′″,1″″-quinquephenyl]-2″-yl)dibenzo[b,d]furan-2-amine (2 eq), tris(dibenzylideneacetone)dipalladium(0) (0.15 eq), tri-tert-butylphosphine (0.3 eq), and sodium tert-butoxide (5 eq) were dissolved in o-xylene, and stirred at 140 degrees Celsius for 60 hours. The mixture was cooled, and washed with ethyl acetate and water, and separated to obtain an organic layer, which was dried with MgSO₄ and dried under reduced pressure. Intermediate 83-2 was obtained by purification by column chromatography using MC and n-hexane. (Yield: 36%)

### (Synthesis of Compound 83)

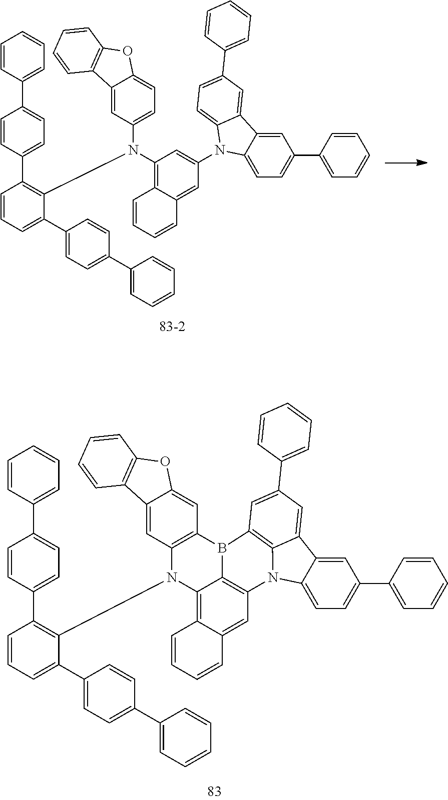 [SMILES: c1ccc(-c2ccc(-c3cccc(-c4ccc(-c5ccccc5)cc4)c3N(c3ccc4oc5ccccc5c4c3)c3cc(-n4c5ccc(-c6ccccc6)cc5c5cc(-c6ccccc6)ccc54)cc4ccccc34)cc2)cc1 ; c1ccc(-c2ccc(-c3cccc(-c4ccc(-c5ccccc5)cc4)c3N3c4cc5c(cc4B4c6c(cc7ccccc7c63)-n3c6ccc(-c7ccccc7)cc6c6cc(-c7ccccc7)cc4c63)oc3ccccc35)cc2)cc1]

Intermediate 83-2 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 83. (Yield: 13%)

### (4) Synthesis of Compound 87

### (Synthesis of Intermediate 87-1)

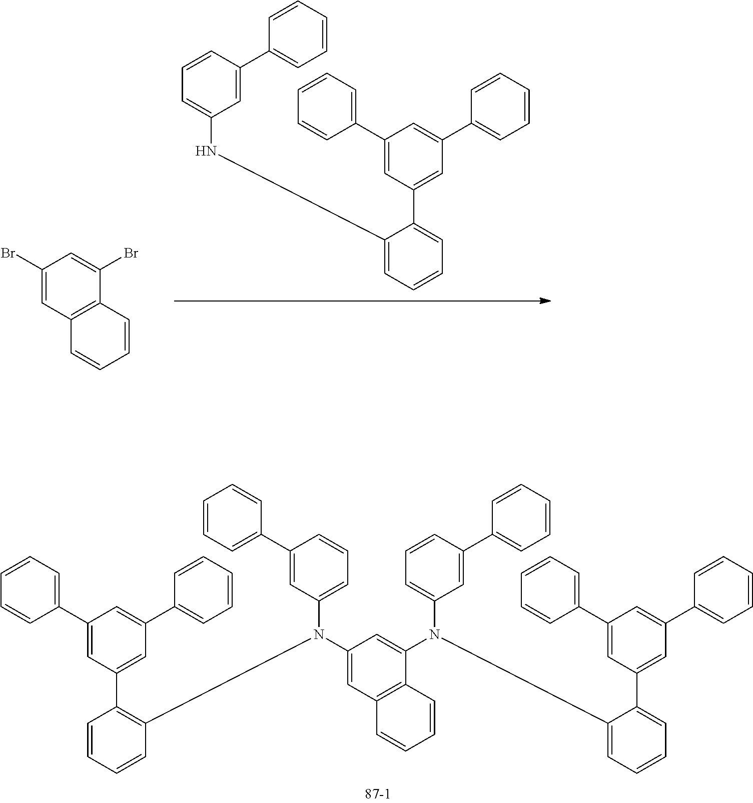 [SMILES: Brc1cc(Br)c2ccccc2c1 ; c1ccc(-c2cccc(Nc3ccccc3-c3cc(-c4ccccc4)cc(-c4ccccc4)c3)c2)cc1 ; c1ccc(-c2cc(-c3ccccc3)cc(-c3ccccc3N(c3cccc(-c4ccccc4)c3)c3cc(N(c4cccc(-c5ccccc5)c4)c4ccccc4-c4cc(-c5ccccc5)cc(-c5ccccc5)c4)c4ccccc4c3)c2)cc1]

1,3-dibromonaphthalene (1 eq), N-([1,1′-biphenyl]-3-yl)-5′-phenyl-[1,1′:3′,1″-terphenyl]-2-amine (2 eq), tris(dibenzylideneacetone)dipalladium(0) (0.05 eq), tri-tert-butylphosphine (0.1 eq), and sodium tert-butoxide (3 eq) were dissolved in toluene, and stirred at 110 degrees Celsius for 12 hours. The mixture was cooled, and washed with ethyl acetate and water 3 times, and separated to obtain an organic layer, which was dried with MgSO₄ and dried under reduced pressure. Intermediate 87-1 was obtained by purification by column chromatography using MC and n-hexane. (Yield: 69%)

### (Synthesis of Compound 87)

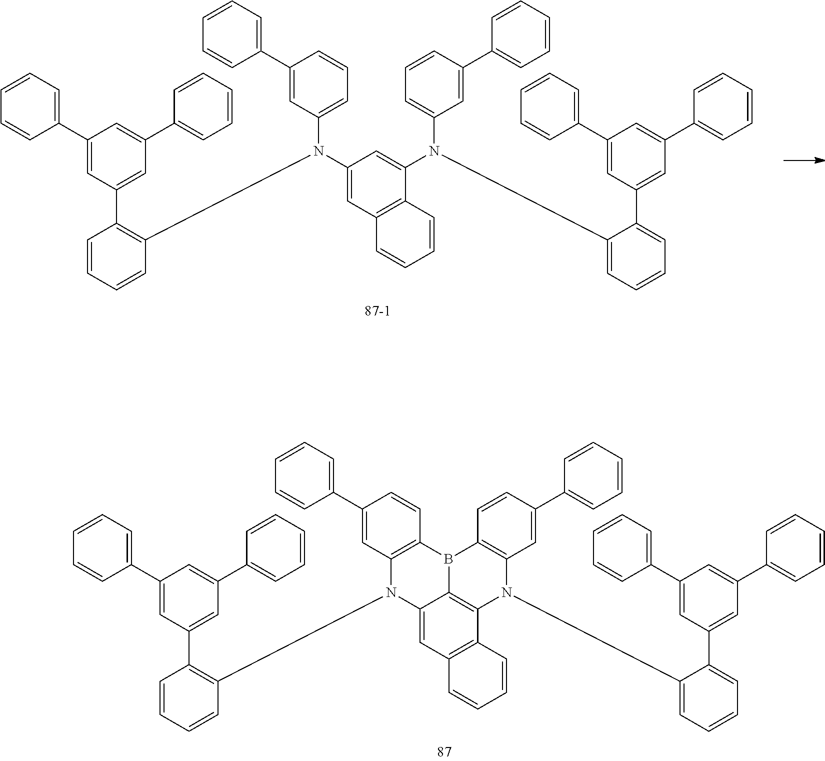 [SMILES: c1ccc(-c2cc(-c3ccccc3)cc(-c3ccccc3N(c3cccc(-c4ccccc4)c3)c3cc(N(c4cccc(-c5ccccc5)c4)c4ccccc4-c4cc(-c5ccccc5)cc(-c5ccccc5)c4)c4ccccc4c3)c2)cc1 ; c1ccc(-c2cc(-c3ccccc3)cc(-c3ccccc3N3c4cc(-c5ccccc5)ccc4B4c5ccc(-c6ccccc6)cc5N(c5ccccc5-c5cc(-c6ccccc6)cc(-c6ccccc6)c5)c5c4c3cc3ccccc53)c2)cc1]

Intermediate 87-1 (1 eq) was dissolved in ortho dichlorobenzene, and cooled to 0 degrees Celsius, and BBr-3 (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 87. (Yield: 12%)

### (5) Synthesis of Compound 92

### (Synthesis of Intermediate 92-1)

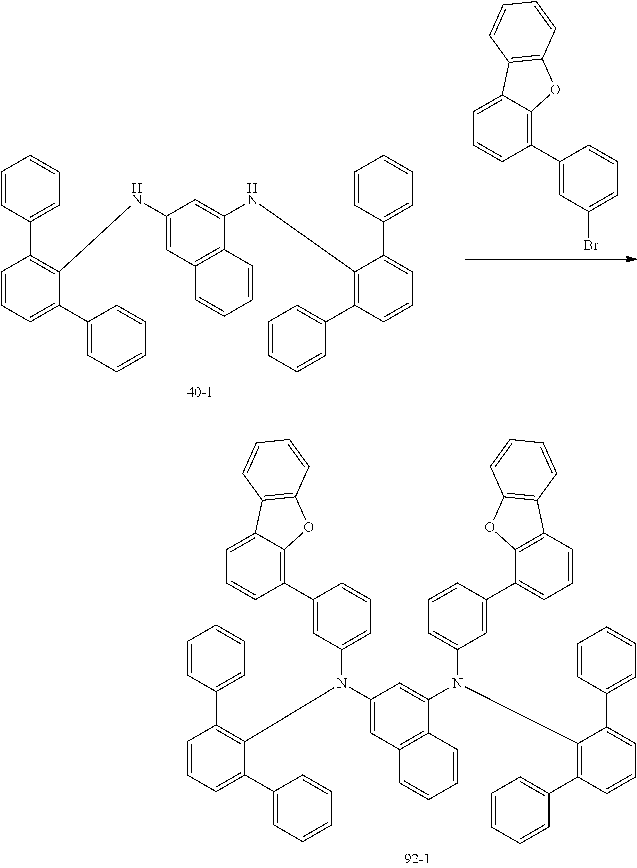 [SMILES: c1ccc(-c2cccc(-c3ccccc3)c2Nc2cc(Nc3c(-c4ccccc4)cccc3-c3ccccc3)c3ccccc3c2)cc1 ; Brc1cccc(-c2cccc3c2oc2ccccc23)c1 ; c1ccc(-c2cccc(-c3ccccc3)c2N(c2cccc(-c3cccc4c3oc3ccccc34)c2)c2cc(N(c3cccc(-c4cccc5c4oc4ccccc45)c3)c3c(-c4ccccc4)cccc3-c3ccccc3)c3ccccc3c2)cc1]

Intermediate 40-1 (1 eq), 4-(3-bromophenyl)dibenzo[b,d]furan (3 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150 degrees Celsius for 60 hours. The mixture was cooled, and washed with ethyl acetate and water 3 times, and separated to obtain an organic layer, which was dried with MgSO₄ and dried under reduced pressure. Intermediate 92-1 was obtained by purification by column chromatography using MC and n-hexane. (Yield: 42%)

### (Synthesis of Compound 92)

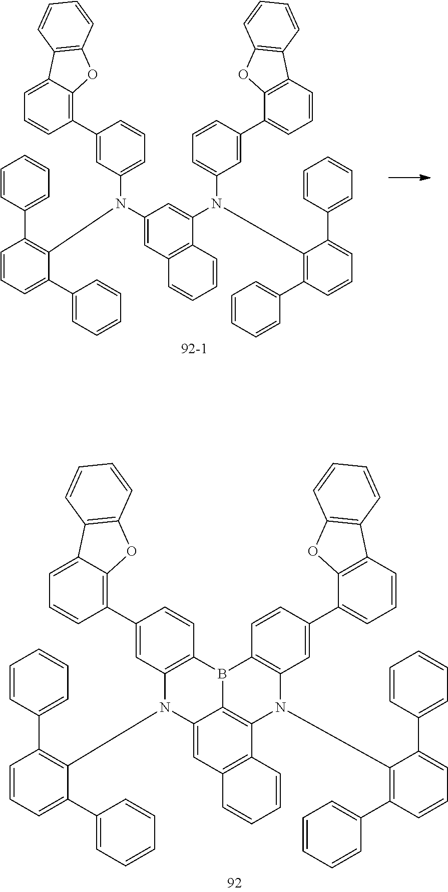 [SMILES: c1ccc(-c2cccc(-c3ccccc3)c2N(c2cccc(-c3cccc4c3oc3ccccc34)c2)c2cc(N(c3cccc(-c4cccc5c4oc4ccccc45)c3)c3c(-c4ccccc4)cccc3-c3ccccc3)c3ccccc3c2)cc1 ; c1ccc(-c2cccc(-c3ccccc3)c2N2c3cc(-c4cccc5c4oc4ccccc45)ccc3B3c4ccc(-c5cccc6c5oc5ccccc56)cc4N(c4c(-c5ccccc5)cccc4-c4ccccc4)c4c3c2cc2ccccc42)cc1]

Intermediate 92-1 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 92. (Yield: 13%)

### (6) Synthesis of Compound 94

### (Synthesis of Intermediate 94-1)

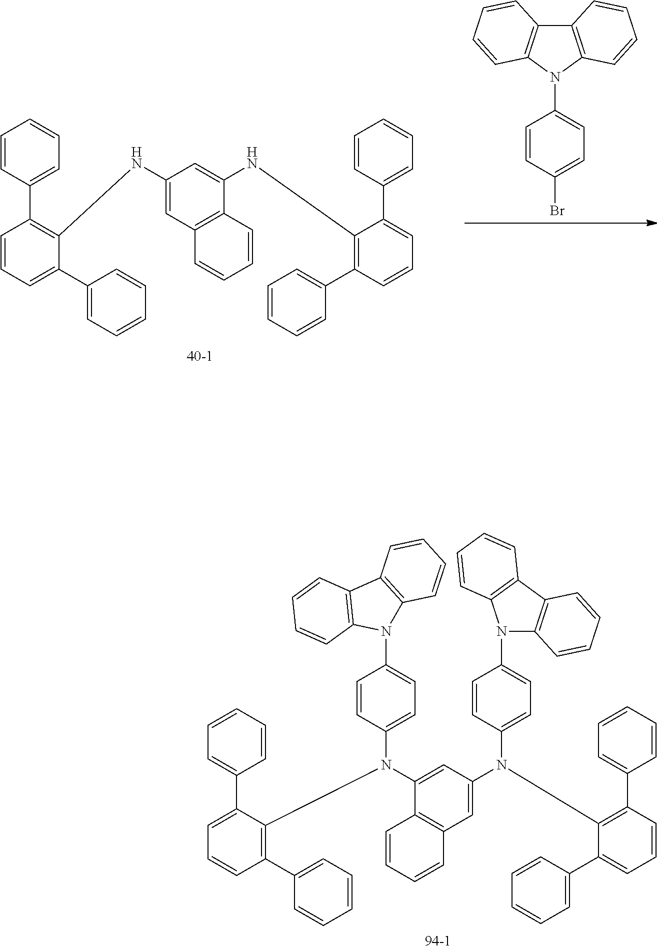 [SMILES: c1ccc(-c2cccc(-c3ccccc3)c2Nc2cc(Nc3c(-c4ccccc4)cccc3-c3ccccc3)c3ccccc3c2)cc1 ; Brc1ccc(-n2c3ccccc3c3ccccc32)cc1 ; c1ccc(-c2cccc(-c3ccccc3)c2N(c2ccc(-n3c4ccccc4c4ccccc43)cc2)c2cc(N(c3ccc(-n4c5ccccc5c5ccccc54)cc3)c3c(-c4ccccc4)cccc3-c3ccccc3)c3ccccc3c2)cc1]

Intermediate 40-1 (1 eq), 9-(4-bromophenyl)-9H-carbazole (3 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150 degrees Celsius for 60 hours. The mixture was cooled, and washed with ethyl acetate and water 3 times, and separated to obtain an organic layer, which was dried with MgSO₄ and dried under reduced pressure. Intermediate 94-1 was obtained by purification by column chromatography using MC and n-hexane. (Yield: 36%)

### (Synthesis of Compound 94)

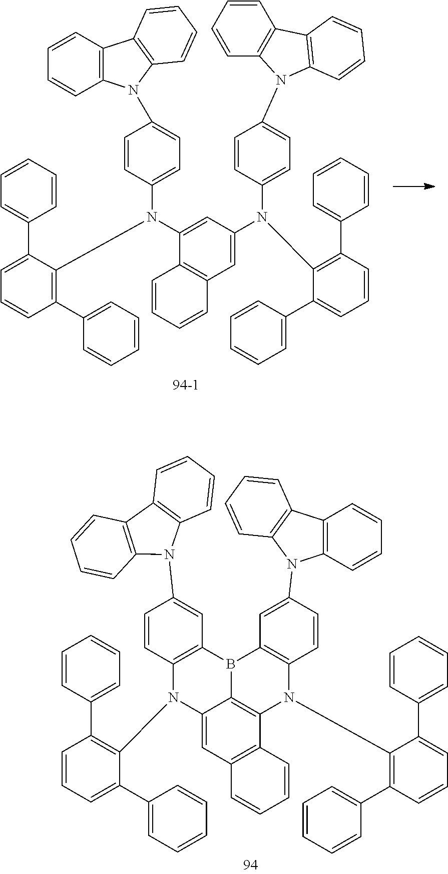 [SMILES: c1ccc(-c2cccc(-c3ccccc3)c2N(c2ccc(-n3c4ccccc4c4ccccc43)cc2)c2cc(N(c3ccc(-n4c5ccccc5c5ccccc54)cc3)c3c(-c4ccccc4)cccc3-c3ccccc3)c3ccccc3c2)cc1 ; c1ccc(-c2cccc(-c3ccccc3)c2N2c3ccc(-n4c5ccccc5c5ccccc54)cc3B3c4cc(-n5c6ccccc6c6ccccc65)ccc4N(c4c(-c5ccccc5)cccc4-c4ccccc4)c4c3c2cc2ccccc42)cc1]

Intermediate 94-1 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Compound 94. (Yield: 10%)

### (7) Synthesis of Compound 96

### (Synthesis of Intermediate 96-1)

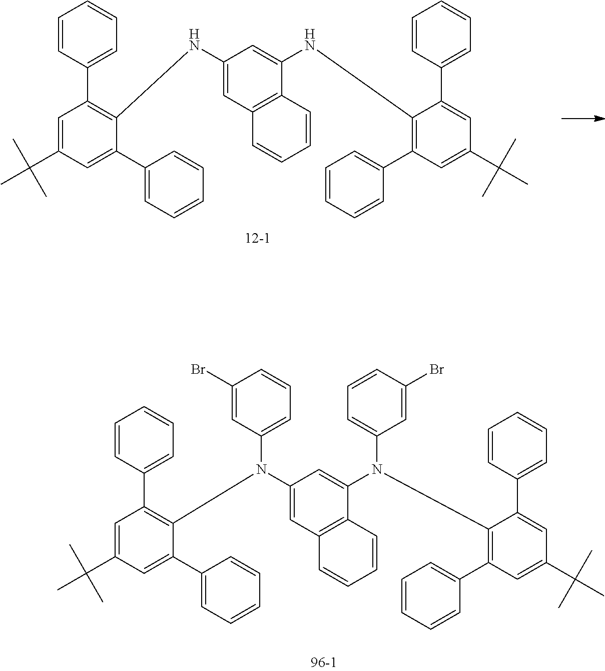

Intermediate 12-1 (1 eq), 1-bromo-3-iodobenzene (4 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150 degrees Celsius for 60 hours. The mixture was cooled, and washed with ethyl acetate and water 3 times, and separated to obtain an organic layer, which was dried with MgSO₄ and dried under reduced pressure. Intermediate 96-1 was obtained by purification by column chromatography using MC and n-hexane. (Yield: 49%)

### (Synthesis of Intermediate 96-2)

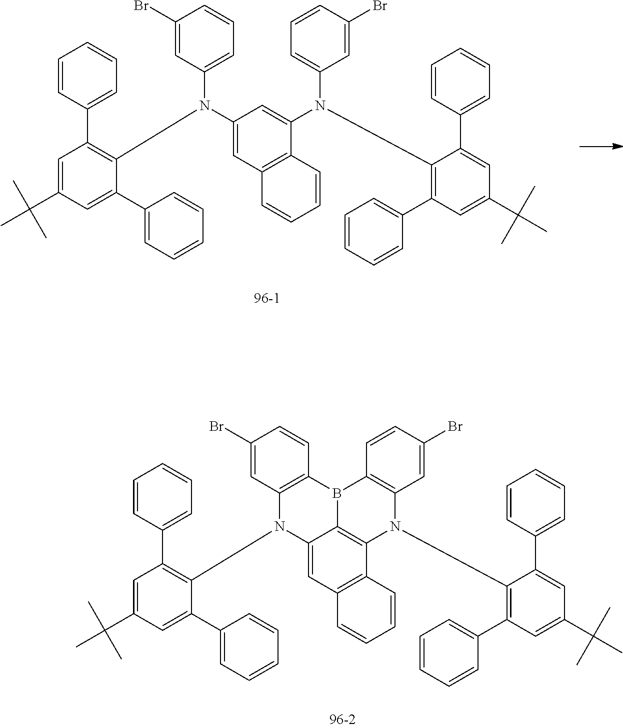

Intermediate 96-1 (1 eq) was dissolved in ortho dichlorobenzene, and cooled to 0 degrees Celsius, and BBr₃ (3 eq) was slowly injected thereto in a nitrogen atmosphere. After the completion of the dropping, the temperature was raised to 180 degrees Celsius and stirring was performed for 24 hours. After cooling, triethylamine was slowly dropped into a flask containing the reactant to terminate the reaction, and ethyl alcohol was added to the reactant to perform precipitation and filtering to obtain a reactant. The obtained solids were purified by column chromatography using MC and n-hexane, and recrystallized using toluene and acetone to obtain Intermediate 96-2. (Yield: 14%)

### (Synthesis of Compound 96)

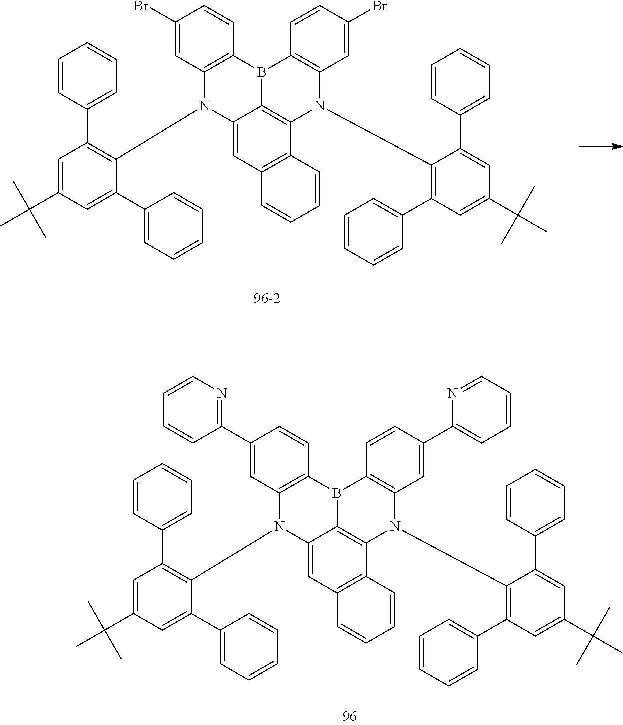

Intermediate 96-2 (1 eq), pyridin-2-ylboronic acid (3 eq), Pd(PPh₃)₄ (0.05 eq), and K₂CO₃ (3 eq) were dissolved in a mixed solution in which water and THF has a volume ratio of 2:1, and stirred at 80 degrees Celsius for 48 hours. The mixture was cooled, and washed with ethyl acetate and water 3 times, and separated to obtain an organic layer, which was dried with MgSO₄ and dried under reduced pressure. Purification by column chromatography was performed using MC and n-hexane to obtain Compound 96. (Yield: 52%)

### 2. Manufacturing and Evaluation of Light Emitting Element

A light emitting element including the fused polycyclic compound according to an embodiment in a light emitting layer was manufactured in the following manner. Light emitting elements of Example 1 to Example 7 were manufactured by respectively using Compounds 12, 40, 83, 87, 92, 94, and 96, which are the above-described Example Compounds, as light emitting layer dopant materials. Comparative Example 1 to Comparative Example 3 respectively correspond to light emitting elements manufactured by respectively using Comparative Example Compound X1 to Comparative Example Compound X3 as light emitting layer dopant materials.

### Example Compounds

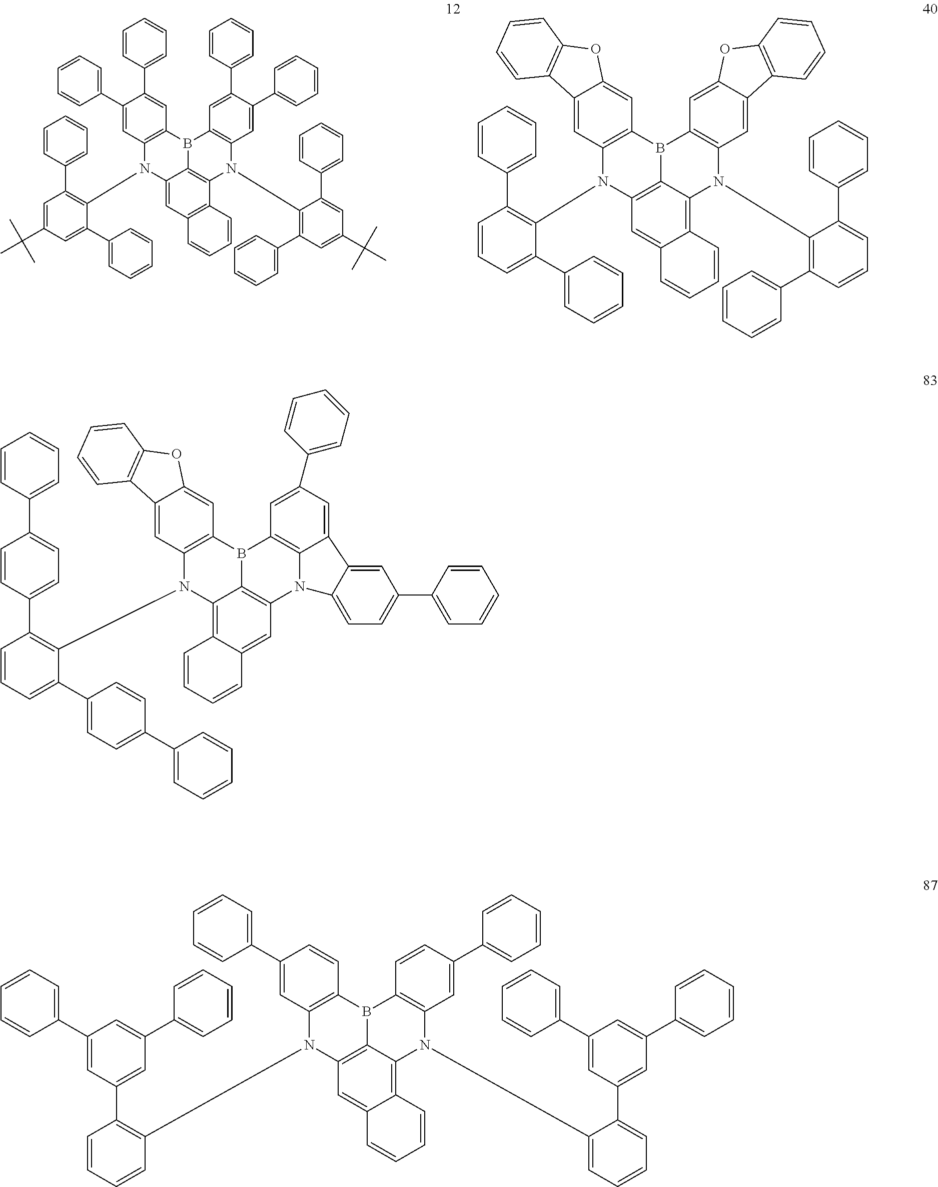

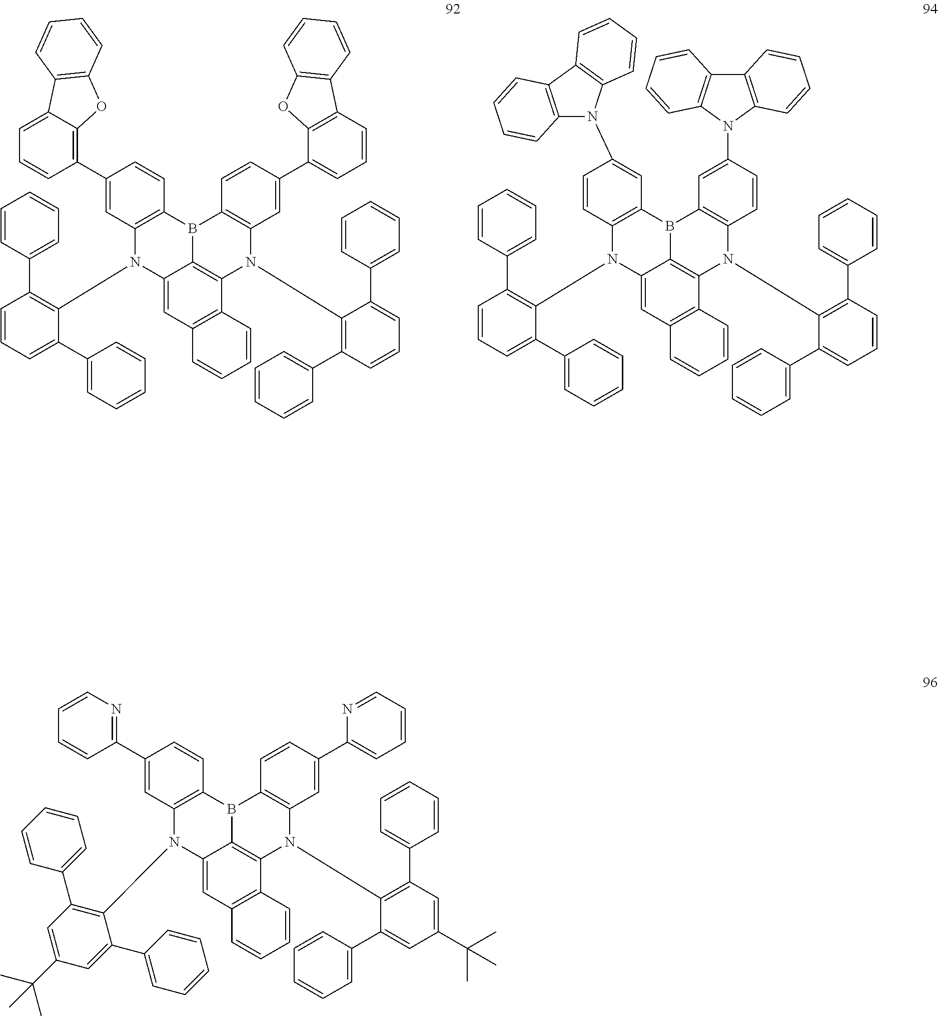

### Comparative Example Compounds

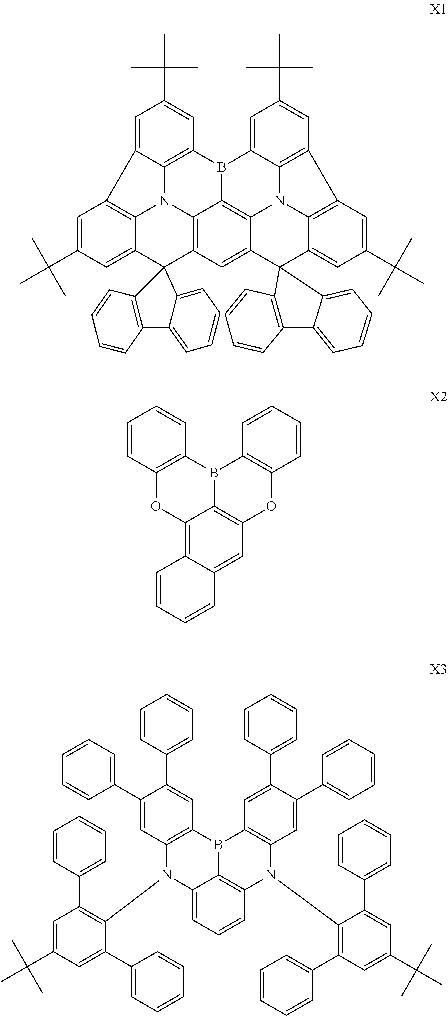

### Physical Properties Evaluation of Example and Comparative Example Compounds

Table 1 below shows the evaluation of physical properties of Compounds 12, 40, 83, 87, 92, 94, and 96, which are Example Compounds, and Comparative Example Compounds X1 to Comparative Example Compounds X3, which are Comparative Example Compounds. Table 1 below shows the measurement of photoluminescence (PL) emission wavelengths of Example Compounds and Comparative Example Compounds in a toluene solution. In Table 1, the PL emission wavelengths correspond to values respectively measured after dissolving Example Compounds and Comparative Example Compounds in the toluene solution at a concentration of 10E-6 M.

TABLE 1

| Compound | PL emission wavelength (nm) |
|---|---|
| Compound 12 | 519 |
| Compound 40 | 534 |
| Compound 83 | 525 |
| Compound 87 | 518 |
| Compound 92 | 521 |
| Compound 94 | 520 |
| Compound 96 | 517 |
| Comparative Example | 457 |
| Compound X1 | |
| Comparative Example | 530 |
| Compound X2 | |
| Comparative Example | 465 |
| Compound X3 | |

### (Manufacturing of Light Emitting Element)

In the light emitting elements of the Examples and the Comparative Examples, a glass substrate (manufactured by Corning Co., Ltd.) having an ITO electrode of 15 Ω/cm² (1,200 Å) as an anode was cut to a size of 50 mm×50 mm×0.7 mm, ultrasonically cleaned for 5 minutes using isopropyl alcohol and pure water, irradiated with ultraviolet rays for 30 minutes and exposed to ozone to be cleaned, and mounted on a vacuum deposition apparatus.

On an upper portion of the above-described anode, Compound HT-1-1 was deposited to provide a hole transport layer having a thickness of 200 Å, and Compound H-1-20 was deposited on an upper portion of the hole transport layer to provide an electron blocking layer having a thickness of 100 Å.

A mixed host in which a second compound and a third compound according to embodiments were mixed at a ratio of 1:1, the fourth compound, and an Example Compound or a Comparative Example Compound were co-deposited at a weight ratio of 85:14:1 to provide a light emitting layer having 300 Å thickness, and Compound ET37 was deposited on an upper portion of the light emitting layer to provide a hole blocking layer having a thickness of 50 Å.

On an upper portion of the hole blocking layer, a mixture in which Compound ET38 and LiQ were mixed at a ratio of 5:5 was deposited to provide an electron transport layer having a thickness of 300 Å, and LiQ was deposited on an upper portion of the electron transport layer to provide an electron injection layer having a thickness of 10 Å. A second electrode was provided at a thickness of 1,000 Å by using A1.

Each layer was formed by vacuum deposition. Among the compounds of Compound Group 2 as described above, Compound HT60 was used as the second compound, and among the compounds of Compound Group 3 as described above, Compound ETH88 was used as the third compound, and among the compounds of Compound Group 4 as described above, Compound AD-41 was used as the fourth compound.

The compounds used in the manufacture of the light emitting elements of the Examples and the Comparative Examples are disclosed below. The following materials were obtained by performing purification by sublimation on commercial products, and were used in the manufacture of the elements.

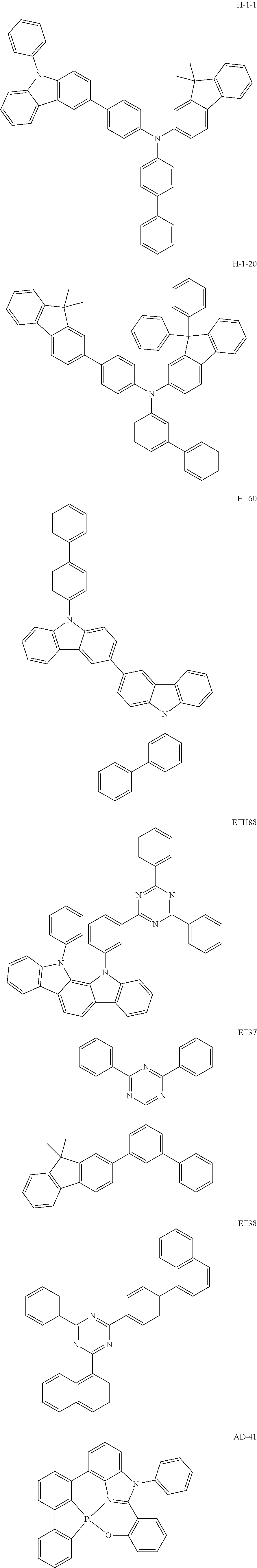

### (Evaluation of Properties of Light Emitting Element)

The driving voltage, element efficiency, emission wavelength, and element lifespan of the light emitting elements manufactured using the above-described Example Compounds 12, 40, 83, 87, 92, 94, and 96 and Comparative Example Compounds X1 to X3 were evaluated. Table 2 shows evaluation results of the light emitting elements of Example 1 to Example 7, and Comparative Example 1 to Comparative Example 3. In the results of evaluating properties of

Examples and Comparative Examples shown in Table 2, the driving voltage and the current density were measured using the V7000 OLED IVL Test System, (Polaronix). In order to evaluate the properties of the light emitting elements manufactured in Examples 1 to 7 and Comparative Examples 1 to 3, the driving voltage and efficiency (cd/A) at a current density of 10 mA/cm² were measured, and in Table 2, the driving voltage is shown using a value as a relative driving voltage, the value obtained by comparison with Comparative Example 1. Lifetime T95 was evaluated using a value as a relative element lifespan, the value obtained by comparing the time taken for an initial value to decrease to 95% luminance deterioration during a continuous driving at a current density of 10 mA/cm² with that of Comparative Example 1.

TABLE 2

| | Host | | | | | | |
|---|---|---|---|---|---|---|---|
| | (Second | | | | | Light | Lifespan |
| | compound:third | | | Driving | | emission | ratio |
| | compound = | Fourth | | voltage | Efficiency | wavelength | (%) |
| | 5:5) | compound | First compound | (%) | (cd/A) | (nm) | (T95) |
| Example 1 | HT60/EHT88 | AD-41 | Compound 12 | 94 | 146 | 525 | 203 |
| Example 2 | HT60/EHT88 | AD-41 | Compound 40 | 97 | 138 | 536 | 221 |
| Example 3 | HT60/EHT88 | AD-41 | Compound 83 | 98 | 134 | 527 | 195 |
| Example 4 | HT60/EHT88 | AD-41 | Compound 87 | 99 | 126 | 524 | 144 |
| Example 5 | HT60/EHT88 | AD-41 | Compound 92 | 98 | 131 | 525 | 177 |
| Example 6 | HT60/EHT88 | AD-41 | Compound 94 | 96 | 137 | 523 | 184 |
| Example 7 | HT60/EHT88 | AD-41 | Compound 96 | 96 | 125 | 526 | 132 |
| Comparative | HT60/EHT88 | AD-41 | Comparative Example | 100 | 106 | 532 | 100 |
| Example 1 | | | Compound X1 | | | | |
| Comparative | HT60/EHT88 | AD-41 | Comparative Example | 163 | 94 | 528 | 35 |
| Example 2 | | | Compound X2 | | | | |
| Comparative | HT60/EHT88 | AD-41 | Comparative Example | 144 | 21 | 528 | 11 |
| Example 3 | | | Compound X3 | | | | |

Referring to the results of Table 1, it can be confirmed that the light emitting elements of the Examples in which the fused polycyclic compound according to an embodiment was used as a light emitting material all emit light in a green wavelength region. It can be confirmed that Example 1 to Example 7 have both improved luminous efficiency and improved lifespan properties as compared to Comparative Example 1 to Comparative Example 3. Therefore, it can be seen that the fused polycyclic compound according to an embodiment may be used as a dopant material for a light emitting layer which emits light in a green wavelength region, and exhibits excellent lifespan properties with improved luminous efficiency compared to when a typical dopant material is used. The fused polycyclic compound according to an embodiment has a structure in which the first aromatic hydrocarbon ring is fused at a specific position of the fused ring core, and thus, may achieve high efficiency and long lifespan. The Example Compounds include the first and second substituents, so that boron atoms may be effectively protected, and inter-molecular interaction is suppressed, thereby controlling the formation of excimers or exciplexes, so that luminous efficiency and lifespan may be increased. The Example Compounds are capable of suppressing Dexter energy transfer by increasing the distance between adjacent molecules due to the first and second substituents, and thus, may suppress lifespan deterioration caused by the increase in triplet concentration.

Comparative Example 1 showed a result in which element lifespan and efficiency were degraded, as compared to the Examples. Comparative Example Compound X1 included in Comparative Example 1 includes a fused ring core centered on a boron atom and two nitrogen atoms, but has a structure in which the first aromatic hydrocarbon ring according to an embodiment is not additionally fused to the fused ring core, so that it has been confirmed that when applied to an element, luminous efficiency and lifespan are poor, as compared to the Examples.

Comparative Example 2 showed a result in which element lifespan and efficiency were degraded, as compared to the Examples. Comparative Example Compound X2 included in Comparative Example 2 differs from the compounds of the Examples in that it includes oxygen atoms instead of nitrogen atoms as constituent atoms of a fused ring core. As in the case of Comparative Example Compound X2, if only oxygen atoms instead of nitrogen atoms, are included as heteroatoms constituting a fused ring core, delayed fluorescence properties may be degraded. In comparison to Example Compounds, Comparative Example Compound X2 does not include a structure in which the first substituent according to an embodiment, which is a steric hindrance substituent connected to a nitrogen atom, is connected. As a result, compared to the Example Compounds, Comparative Example Compound X2 does not sufficiently have an effect of three-dimensionally protecting a fused ring core, so that effects such as suppressing intermolecular interaction or suppressing Dexter energy transfer, which may be expected in Examples, may be degraded.

Comparative Example 3 showed a result in which element lifespan and efficiency were degraded, as compared to the Examples. Comparing Example 1 and Comparative Example 3, Comparative Example Compound X3 included in Comparative Example 3 differs from Compound 12 included in Example 1 in that the first aromatic hydrocarbon ring is not additionally fused. Referring to Table 1 and Table 2 together, the molecular emission wavelength of Comparative Example Compound X3 is 465 nm, which is formed in a short wavelength region compared to Compound 12, and as a result, it was difficult to transfer energy from the host material in the element, which led to degradation in luminous efficiency and lifespan properties. It can be confirmed that the emission wavelength value of the light emitting element of Comparative Example 3 is longer than the molecular emission wavelength value of Comparative Example Compound X3, and this is determined to be caused by phosphorescence from the fourth compound due to energy transfer from Comparative Example Compound X3 to the fourth compound, which is a phosphorescence sensitizer. As a result, it is determined that Comparative Example Compound X3 is disadvantageous in terms of triplet exciton lifespan as compared to the phosphorescent sensitizer, and instead served as a sensitizer, not as a light emitting dopant, in the element, so that the lifespan sharply decreased. In comparison, the Example Compounds include a structure in which the first aromatic hydrocarbon ring is additionally fused, so that an effect of making a molecular emission wavelength longer may be achieved, and accordingly, when the Example Compounds are used as a thermally activated delayed fluorescent dopant, energy transfer efficiency from a host material is improved, making it possible to expect an effect of increasing luminous efficiency.

The light emitting element according to an embodiment includes the fused polycyclic compound according to an embodiment as a light emitting dopant of a thermally activated delayed fluorescence (TADF) light emitting element, and thus, may implement high element efficiency and improved lifespan properties in a green light wavelength region.

A light emitting element according to an embodiment may exhibit improved element properties with high efficiency and long lifespan.

A fused polycyclic compound according to an embodiment may contribute to high efficiency and long lifespan of a light emitting element by being included in a light emitting layer of the light emitting element.

A display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
a light emitting layer disposed between the first electrode and the second electrode, and including a first compound represented by Formula 1: 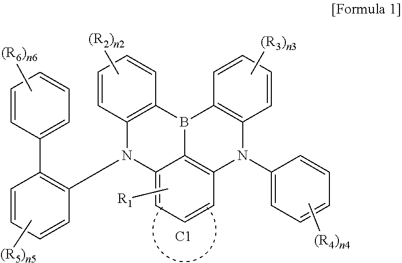
wherein in Formula 1,
C1 is a substituted or unsubstituted aromatic hydrocarbon ring having 6 to 30 ring-forming carbon atoms,
R₁ to R₆ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n2, n3, and n5 are each independently an integer from 0 to 4, and
n4 and n6 are each independently an integer from 0 to 5.

2. The light emitting element of claim 1, wherein the first compound is represented by Formula 2-1 or Formula 2-2: 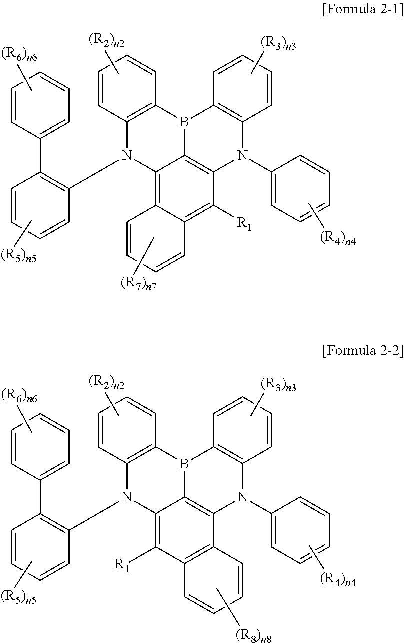
wherein in Formula 2-1 and Formula 2-2,
R₇ and R₈ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n7 and n8 are each independently an integer from 0 to 4, and
R₁ to R₆ and n2 to n6 are the same as defined in Formula 1.

3. The light emitting element of claim 1, wherein the first compound is represented by one of Formula 3-1 to Formula 3-6: 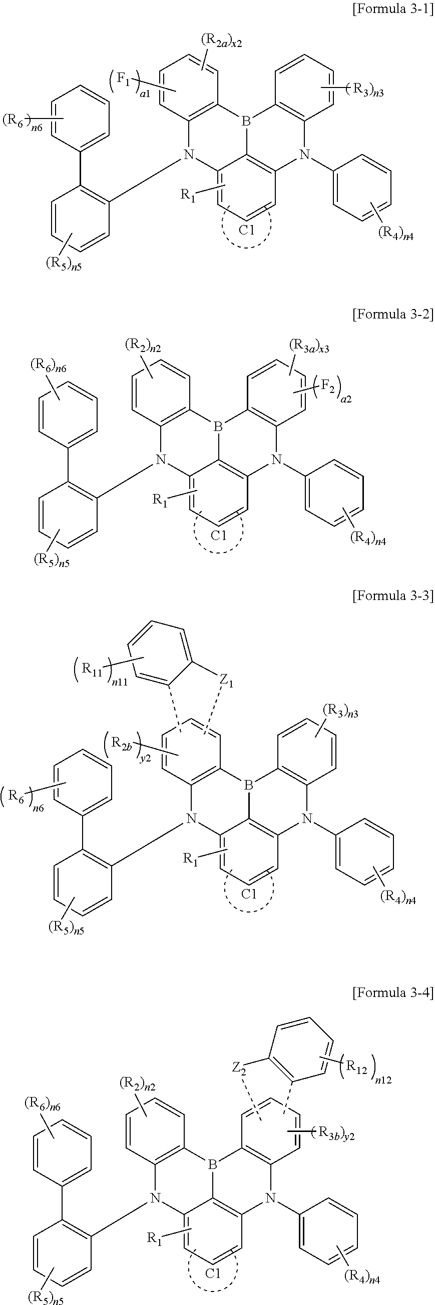 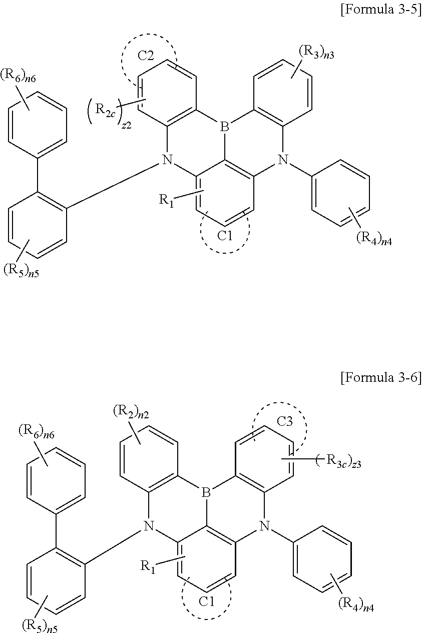
wherein in Formula 3-1 to Formula 3-6,
F₁ and F₂ are each independently a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
Z₁ and Z₂ are each independently O, S, N(R₁₃), or C(R₁₄)(R₁₅),
R₂ₐ, R₃ₐ, R_{2b}, R_{3b}, R_{2c}, R_{3c}, and R₁₁ to R₁₅ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
C2 and C3 are each independently a substituted or unsubstituted aromatic hydrocarbon ring having 6 to 30 ring-forming carbon atoms,
a1 and a2 are each independently 1 or 2,
x2 is an integer from 0 to (4-a1),
x3 is an integer from 0 to (4-a2),
y2, y3, z2, and z3 are each independently an integer from 0 to 2,
n11 and n12 are each independently an integer from 0 to 4, and
C1, R₁ to R₆, and n2 to n6 are the same as defined in Formula 1.

4. The light emitting element of claim 3, wherein in Formula 3-1 and Formula 3-2, F₁ and F₂ are each independently a substituted or unsubstituted diphenylamine group, a substituted or unsubstituted phenyl group, a substituted or unsubstituted biphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or bonded to an adjacent group to form a ring.

5. The light emitting element of claim 1, wherein the first compound is represented by one of Formula 4-1 to Formula 4-6: 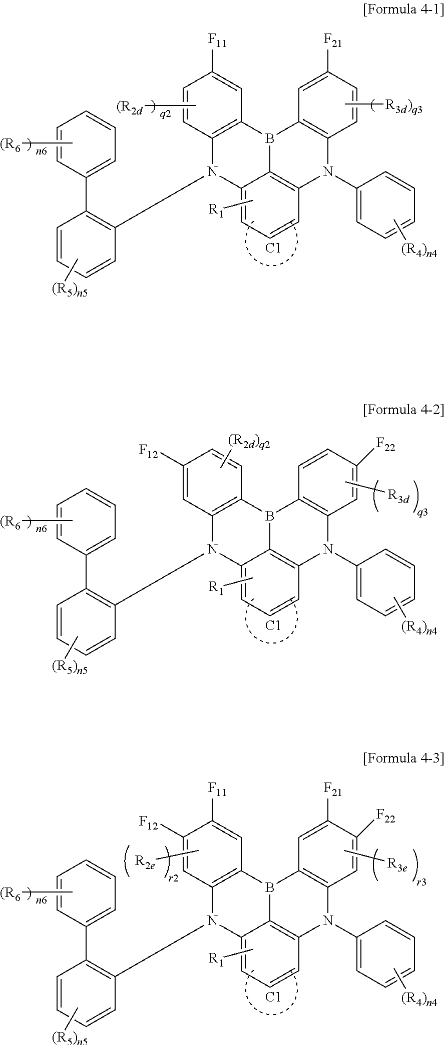 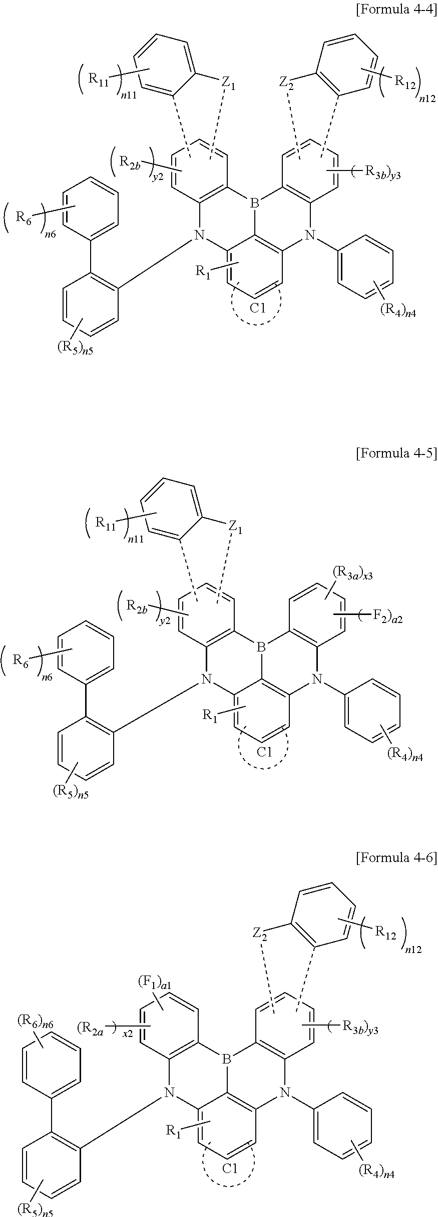
wherein in Formula 4-1 to Formula 4-6,
F₁, F₂, F₁₁, F₁₂, F₂₁, and F₂₂ are each independently a substituted or unsubstituted amine group, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
Z₁ and Z₂ are each independently O, S, N(R₁₃), or C(R₁₄)(R₁₅),
R₂ₐ, R₃ₐ, R_{2b}, R_{3b}, R_{2d}, R_{3d}, R₂ₑ, R₃ₑ, and R₁₁ to R₁₅ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
a1 and a2 are each independently 1 or 2,
x2 is an integer from 0 to (4-a1),
x3 is an integer from 0 to (4-a2),
q2 and q3 are each independently an integer from 0 to 3,
y2, y3, r2, and r3 are each independently an integer from 0 to 2,
n11 and n12 are each independently an integer from 0 to 4, and
C1, R₁, R₄ to R₆, and n4 to n6 are the same as defined in Formula 1.

6. The light emitting element of claim 1, wherein the first compound is represented by one of Formula 5-1 to Formula 5-3: 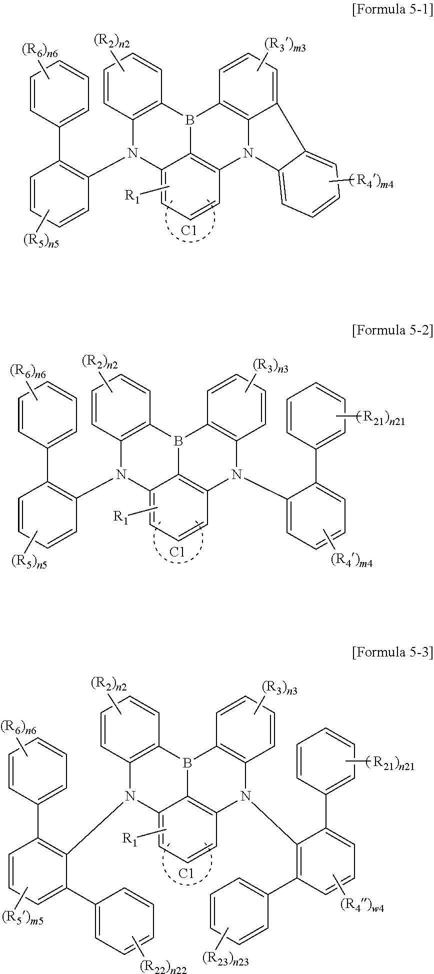
wherein in Formula 5-1 to Formula 5-3,
R₃′, R₄′, R₄″, R₅′, and R₂₁ to R₂₃ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
m4 is an integer from 0 to 4,
m3, w4, and m5 are each independently an integer from 0 to 3,
n21 to n23 are each independently an integer from 0 to 5, and
C1, R₁ to R₃, R₅, R₆, n2, n3, n5, and no are the same as defined in Formula 1.

7. The light emitting element of claim 1, wherein the first compound is represented by Formula 6-1 or Formula 6-2: 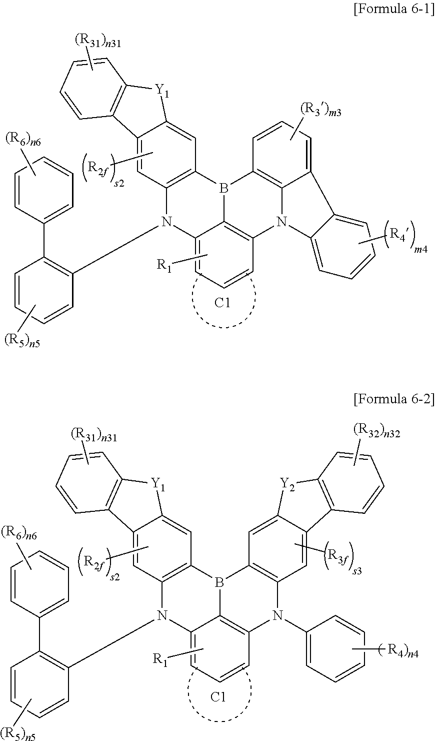
wherein in Formula 6-1 and Formula 6-2,
Y₁ and Y₂ are each independently O, S, N(R₃₃), or C(R₃₄)(R₃₅),
R₃′, R₄′, R_{2f}, R_{3f}, and R₃₁ to R₃₅ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
m4 is an integer from 0 to 4,
m3 is an integer from 0 to 3,
s2 and s3 are each independently an integer from 0 to 2,
n31 and n32 are each independently an integer from 0 to 4, and
C1, R₁, R₃, R₄, R₅, R₆, n3, n4, n5, and n6 are the same as defined in Formula 1.

8. The light emitting element of claim 1, wherein the first compound comprises at least one compound selected from Compound Group 1:

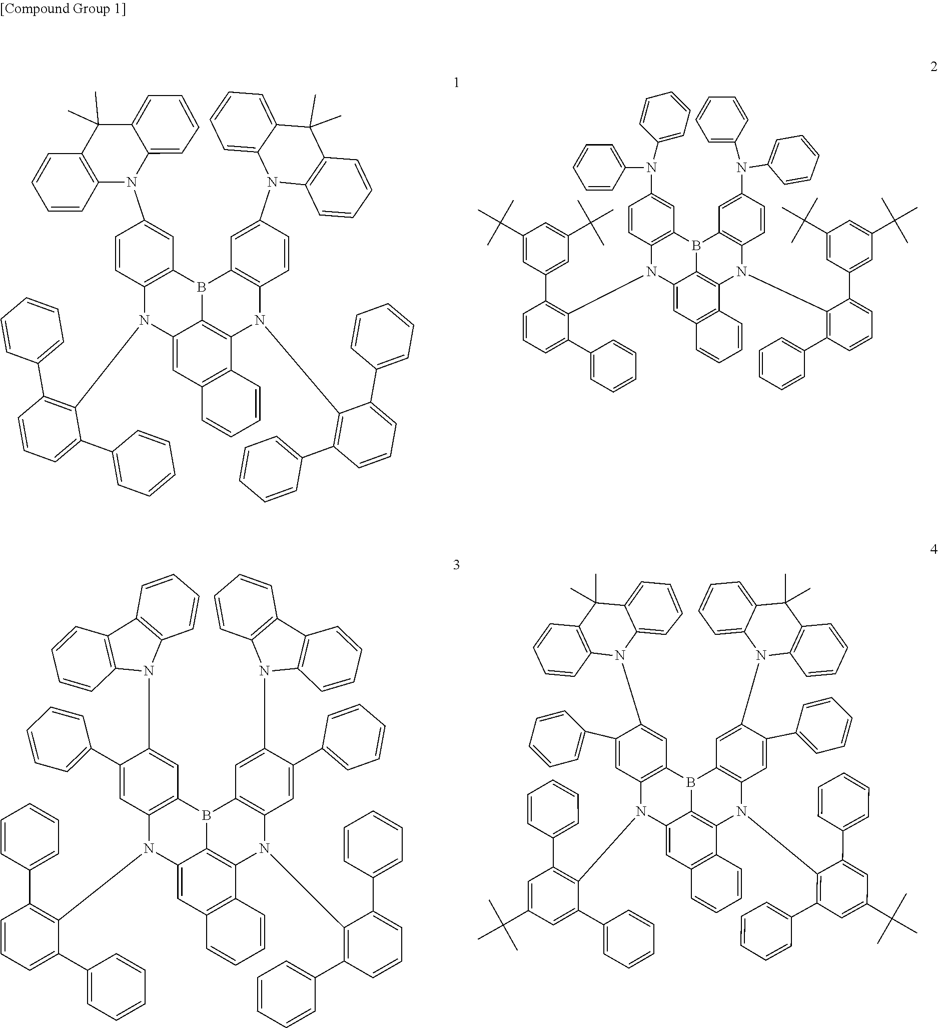

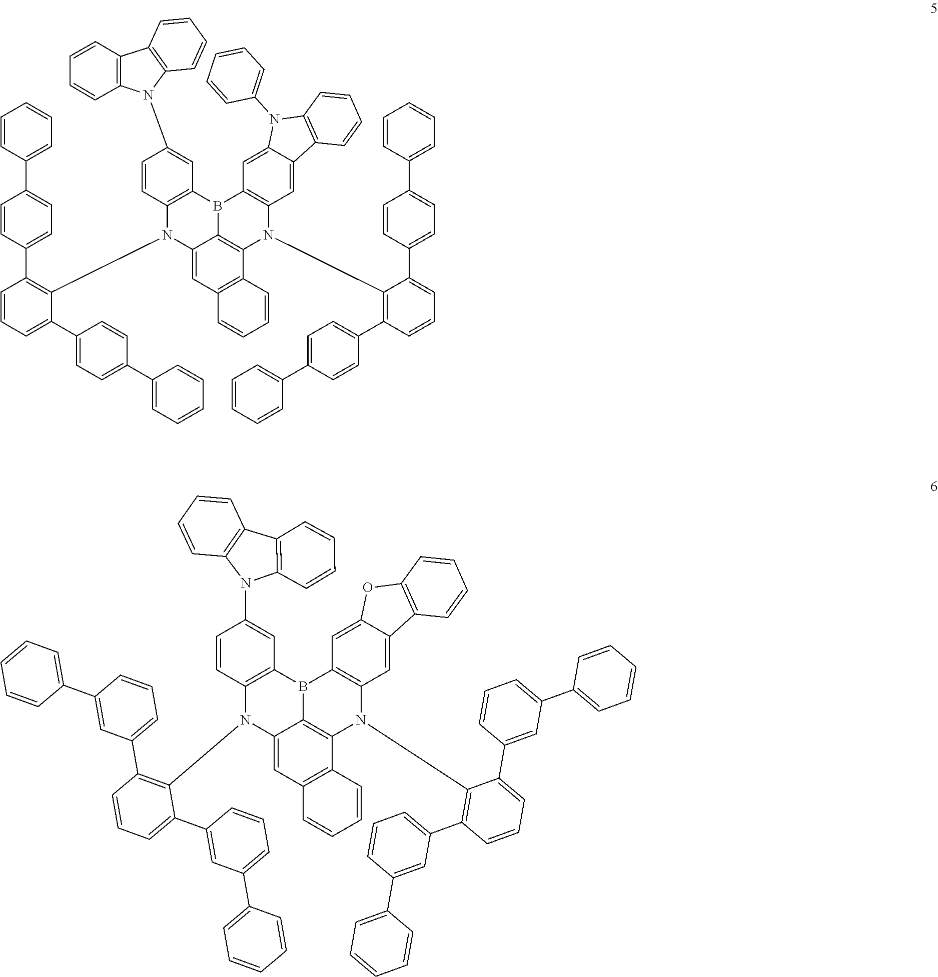 [SMILES: c1ccc(-c2ccc(-c3cccc(-c4ccc(-c5ccccc5)cc4)c3N3c4ccc(-n5c6ccccc6c6ccccc65)cc4B4c5cc6c(cc5N(c5c(-c7ccc(-c8ccccc8)cc7)cccc5-c5ccc(-c7ccccc7)cc5)c5c4c3cc3ccccc53)c3ccccc3n6-c3ccccc3)cc2)cc1 ; c1ccc(-c2cccc(-c3cccc(-c4cccc(-c5ccccc5)c4)c3N3c4ccc(-n5c6ccccc6c6ccccc65)cc4B4c5cc6oc7ccccc7c6cc5N(c5c(-c6cccc(-c7ccccc7)c6)cccc5-c5cccc(-c6ccccc6)c5)c5c4c3cc3ccccc53)c2)cc1]

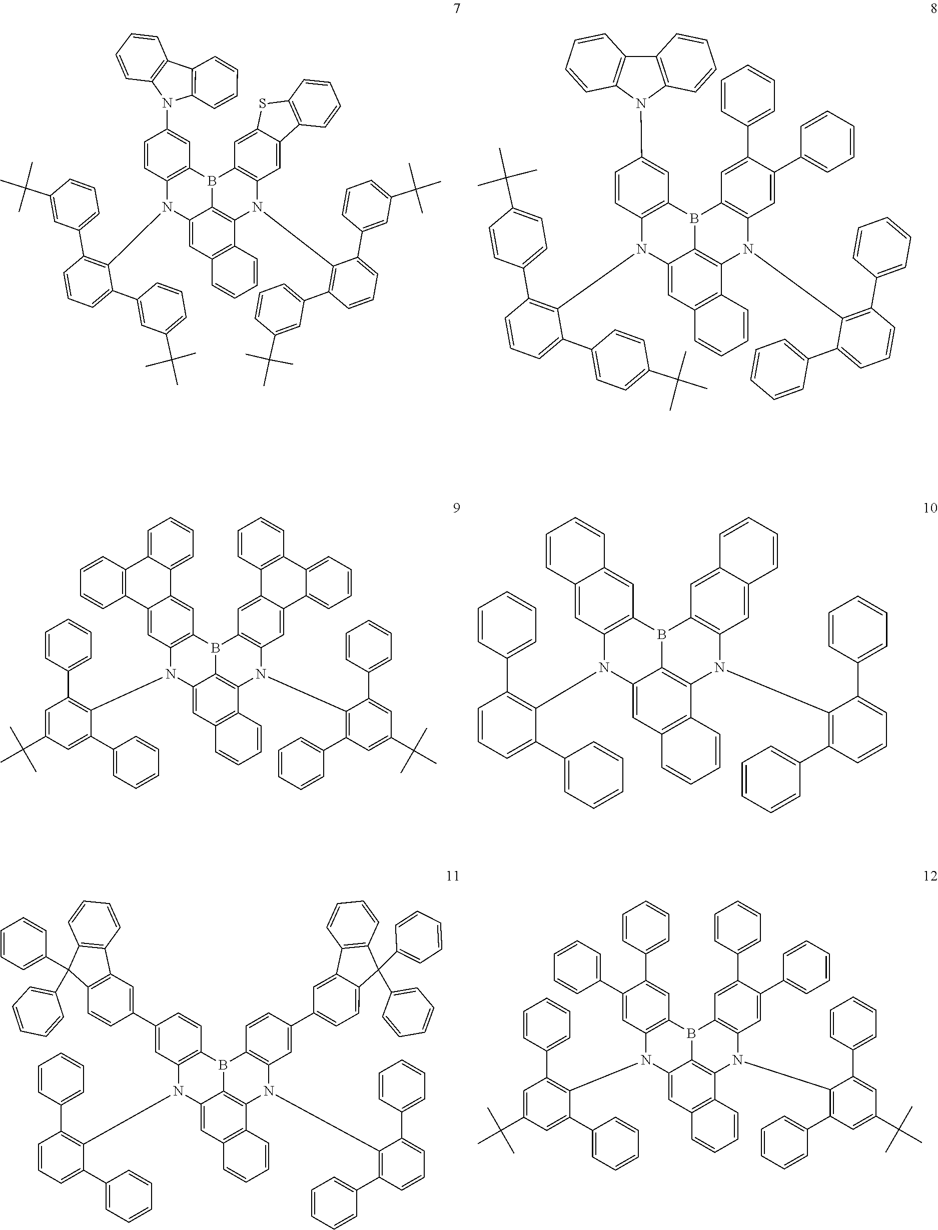

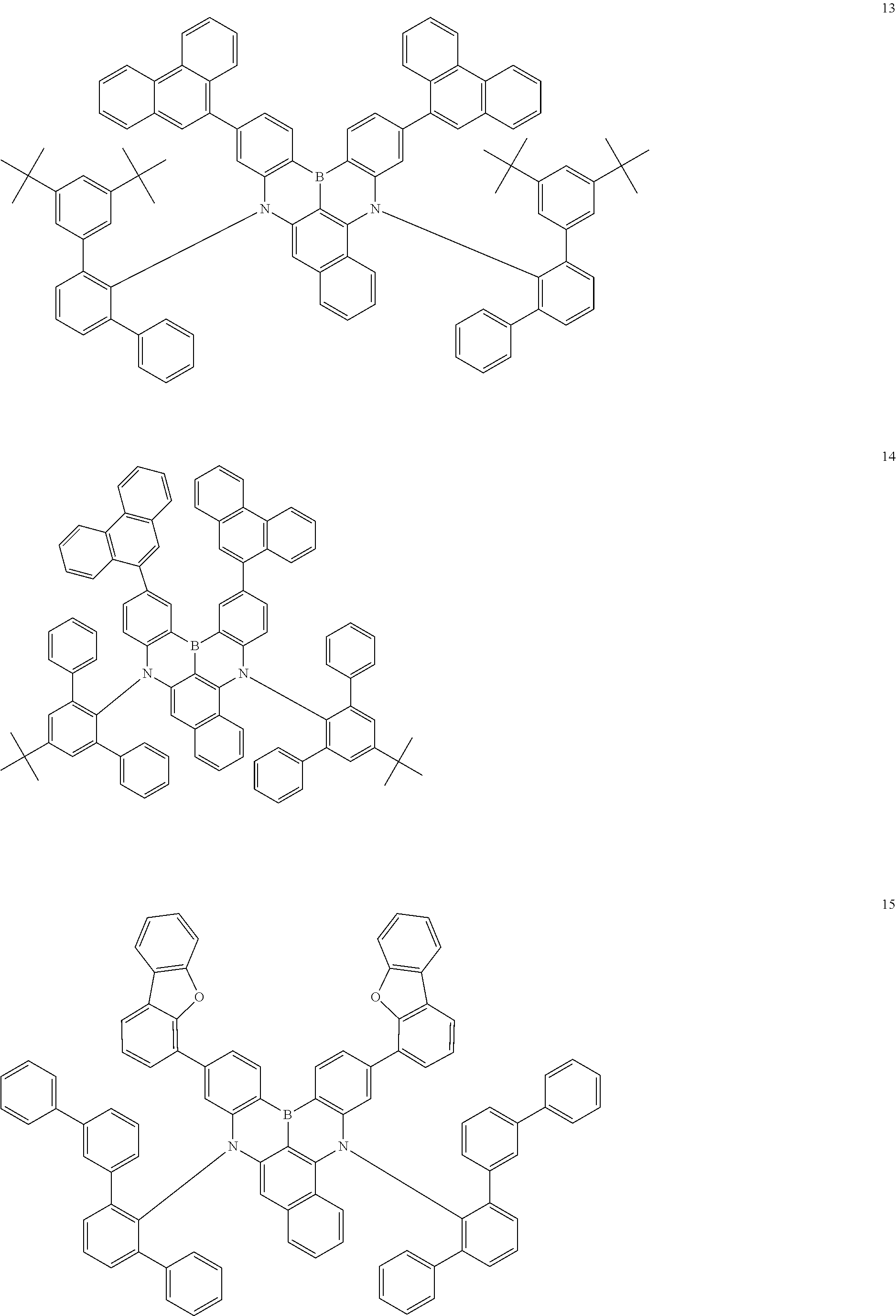

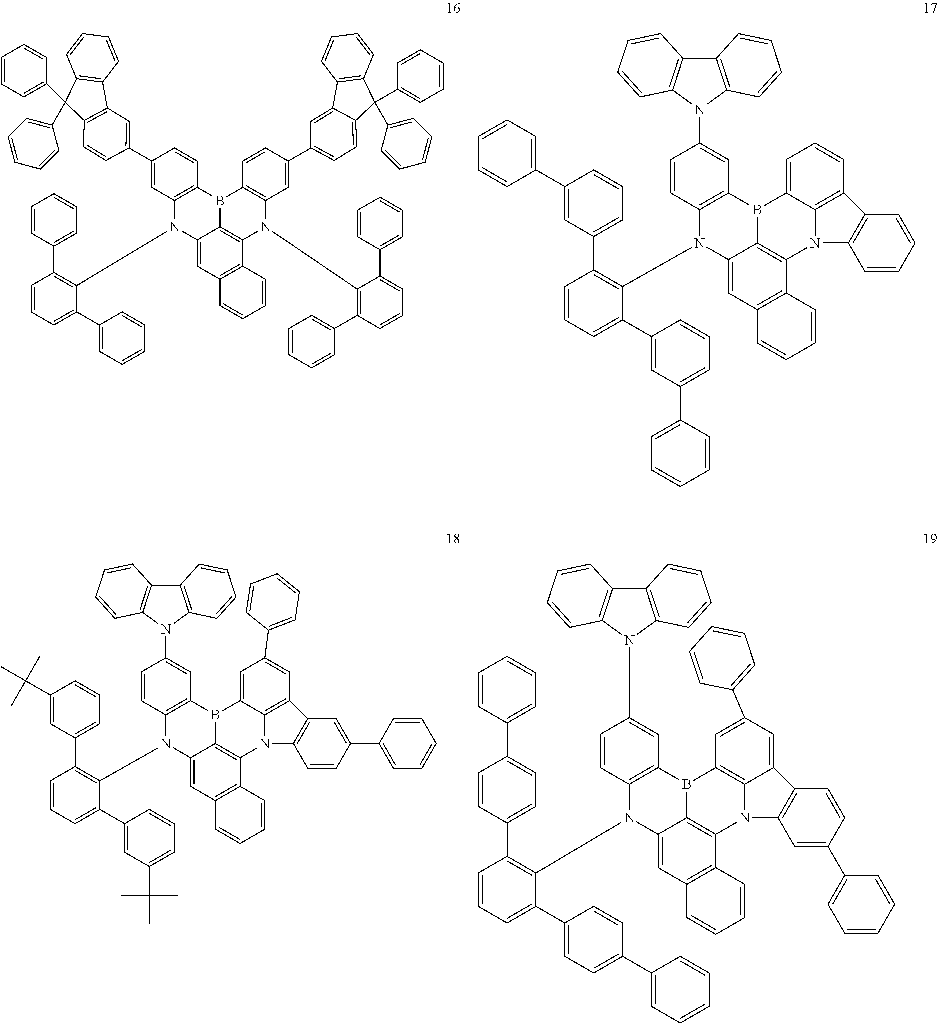

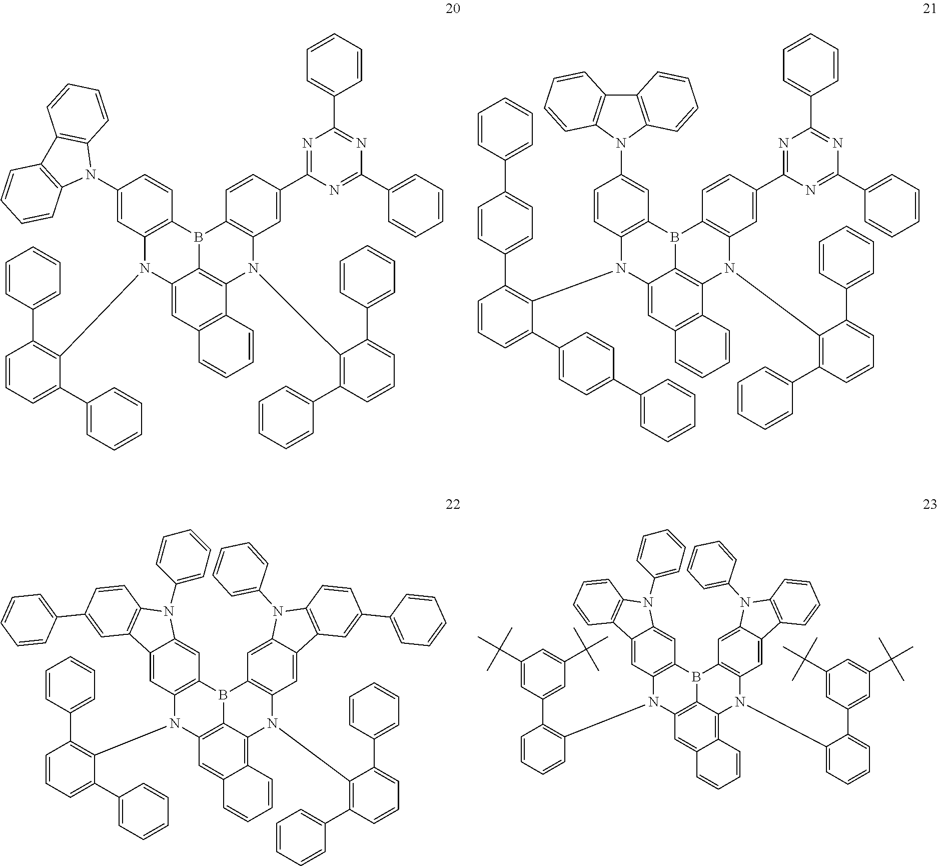

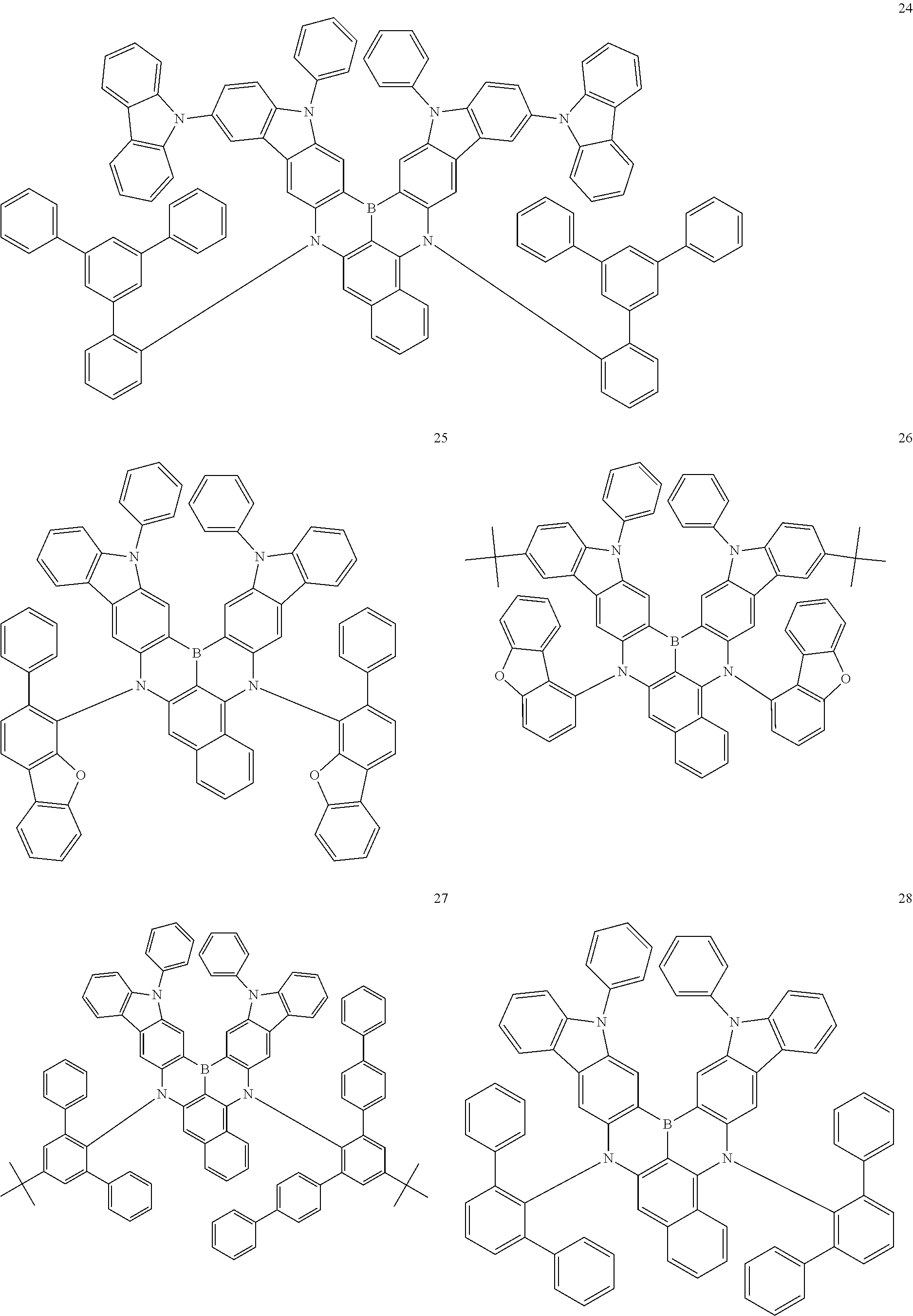

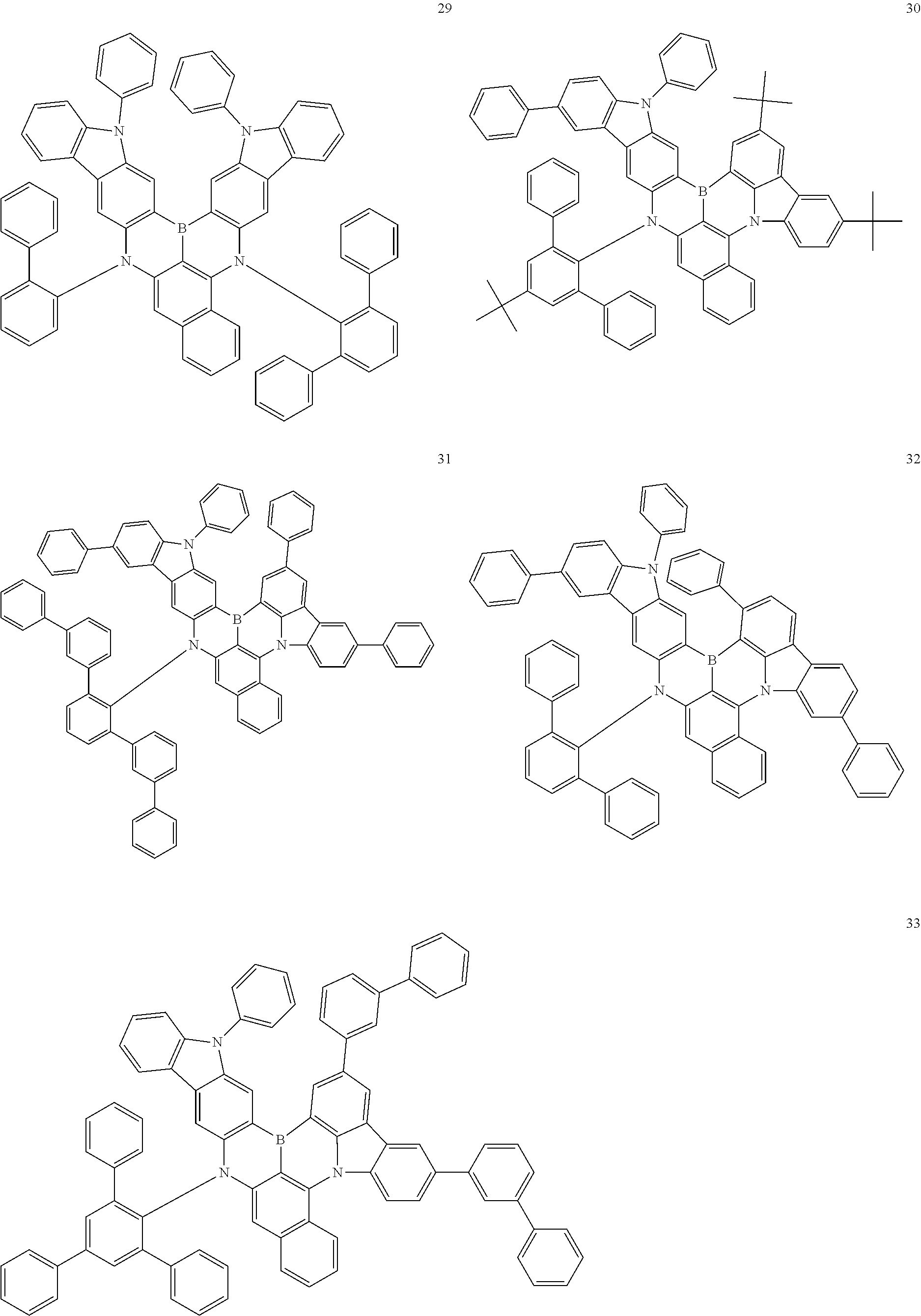

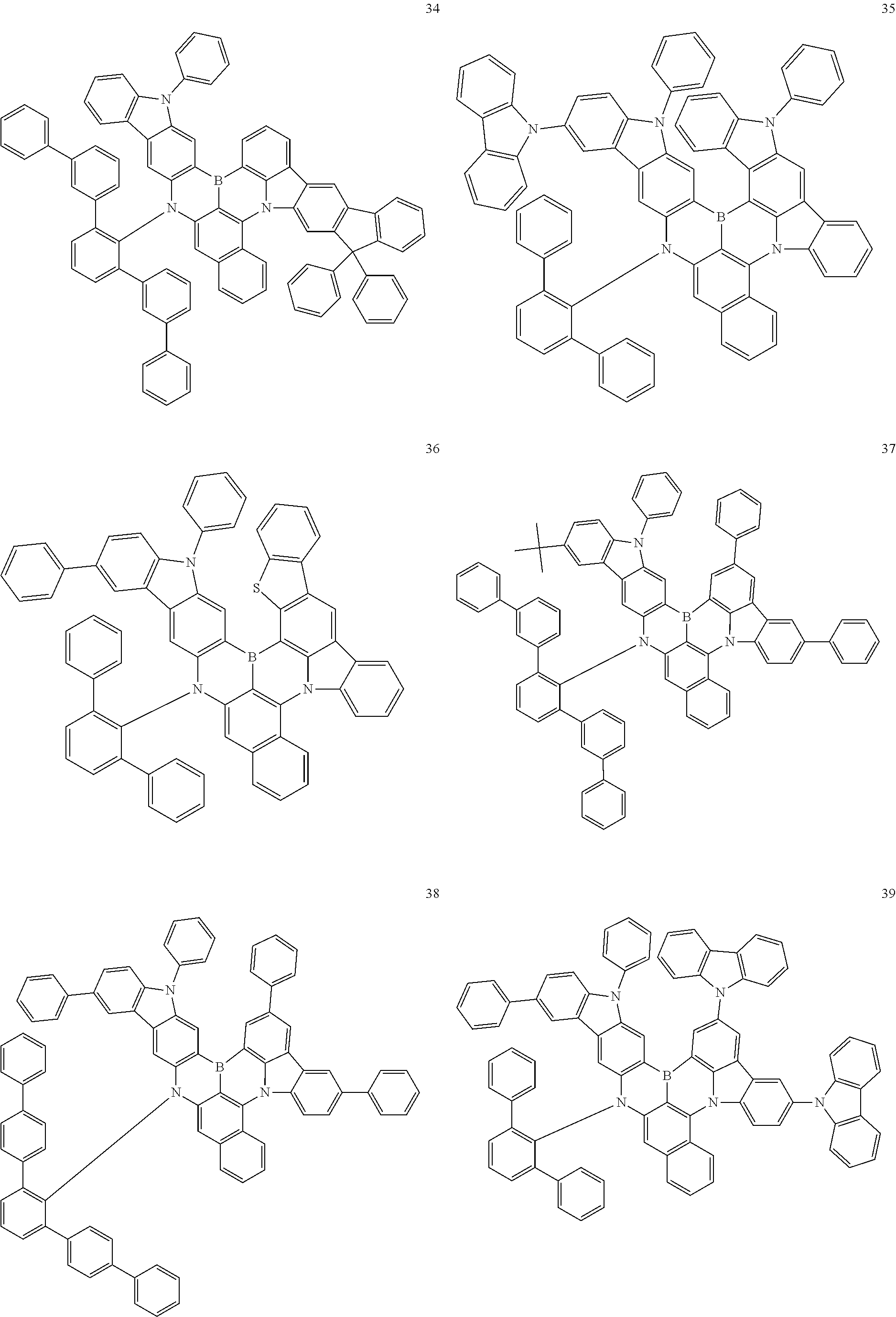

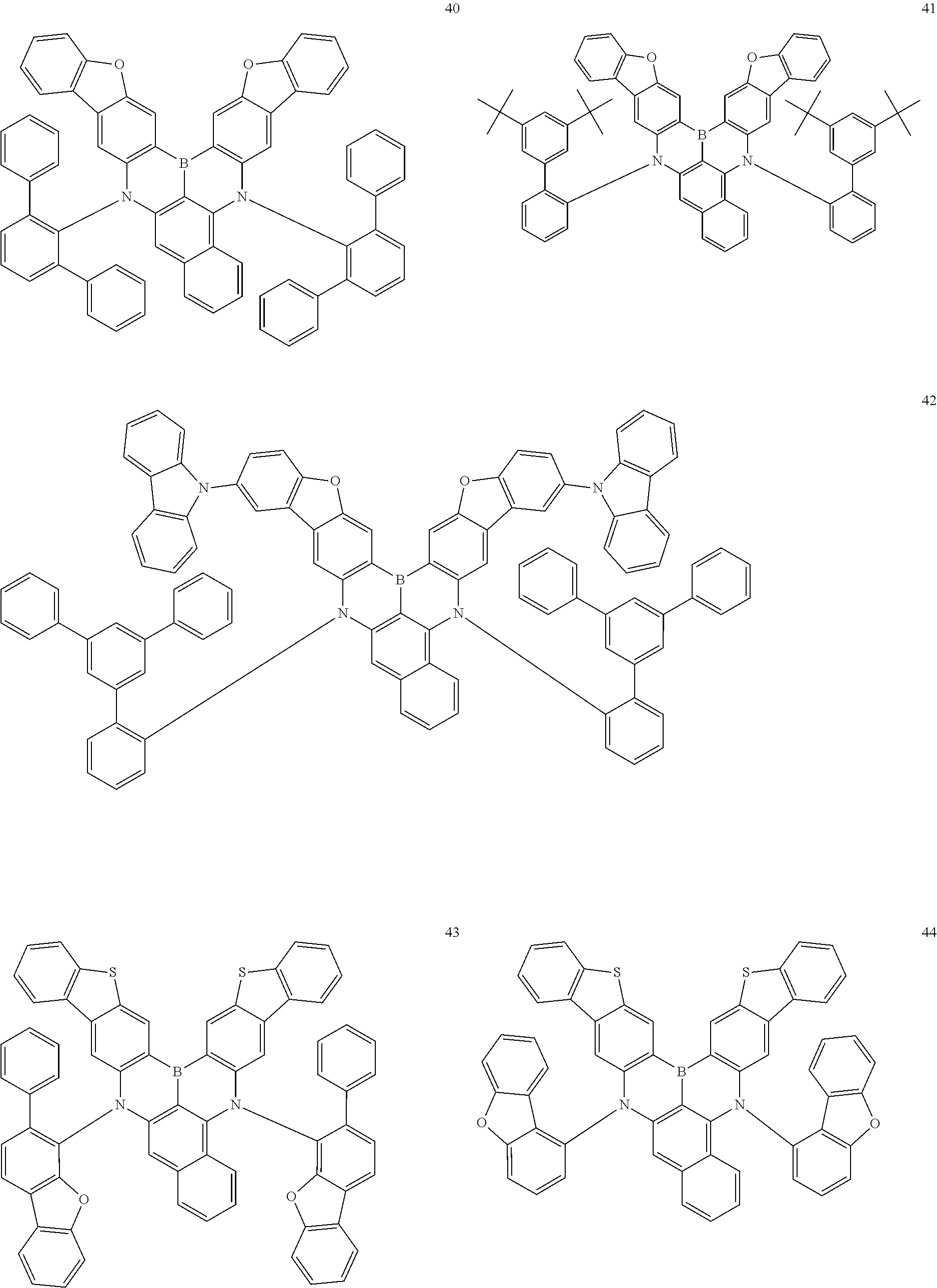

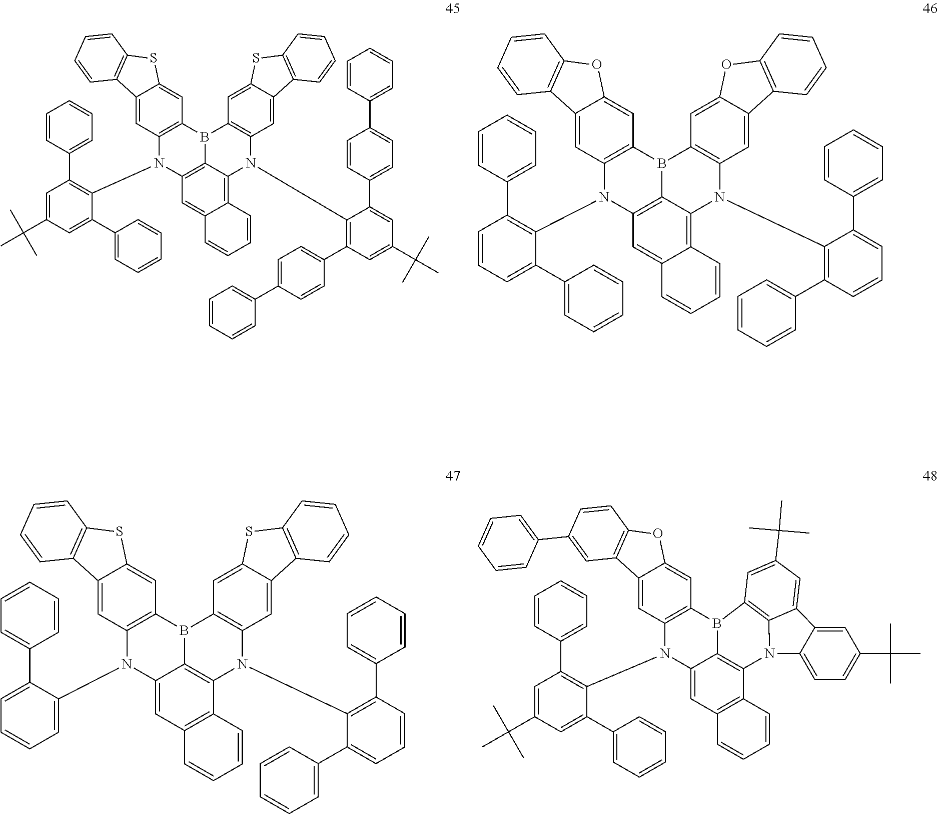

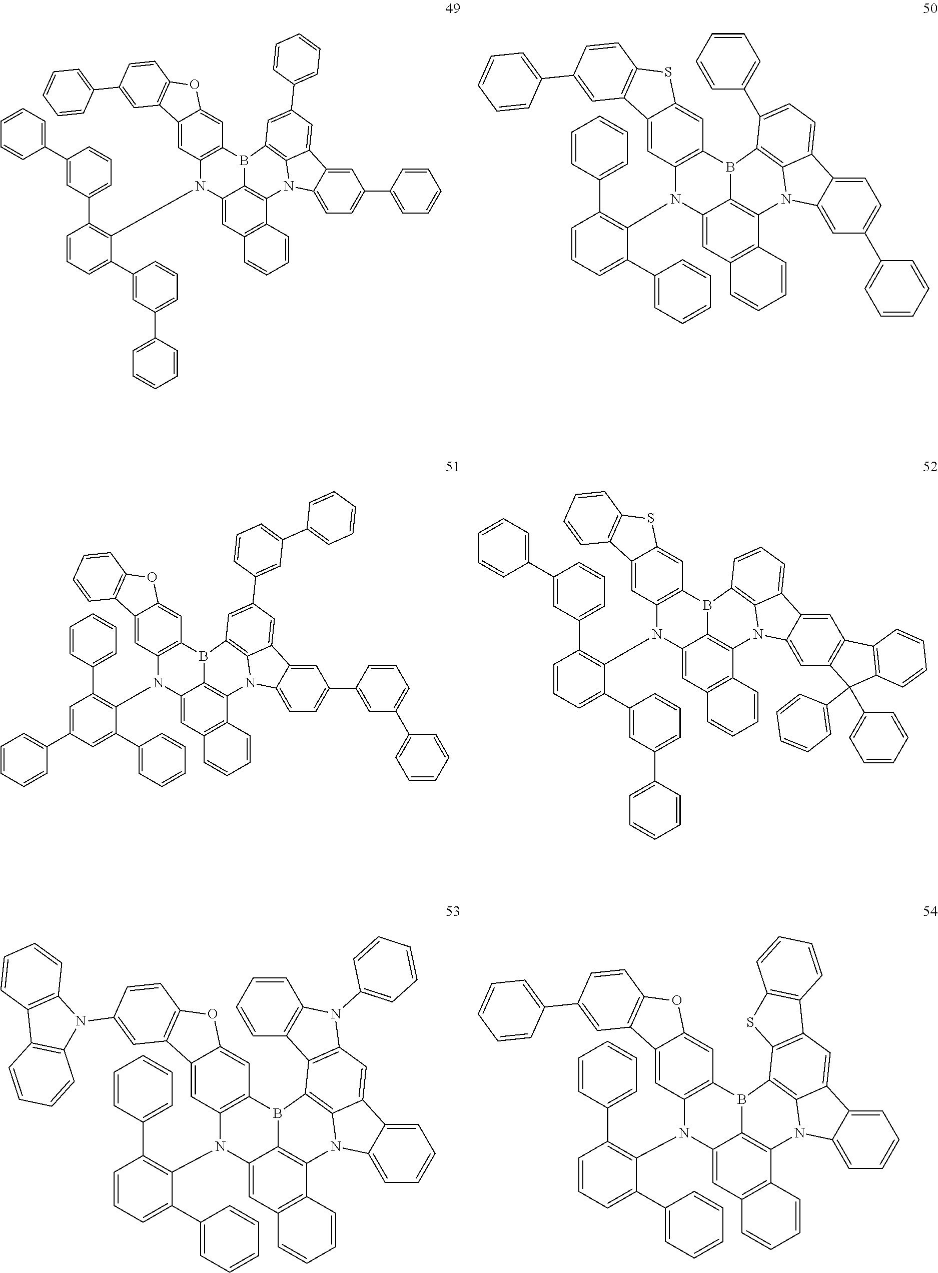

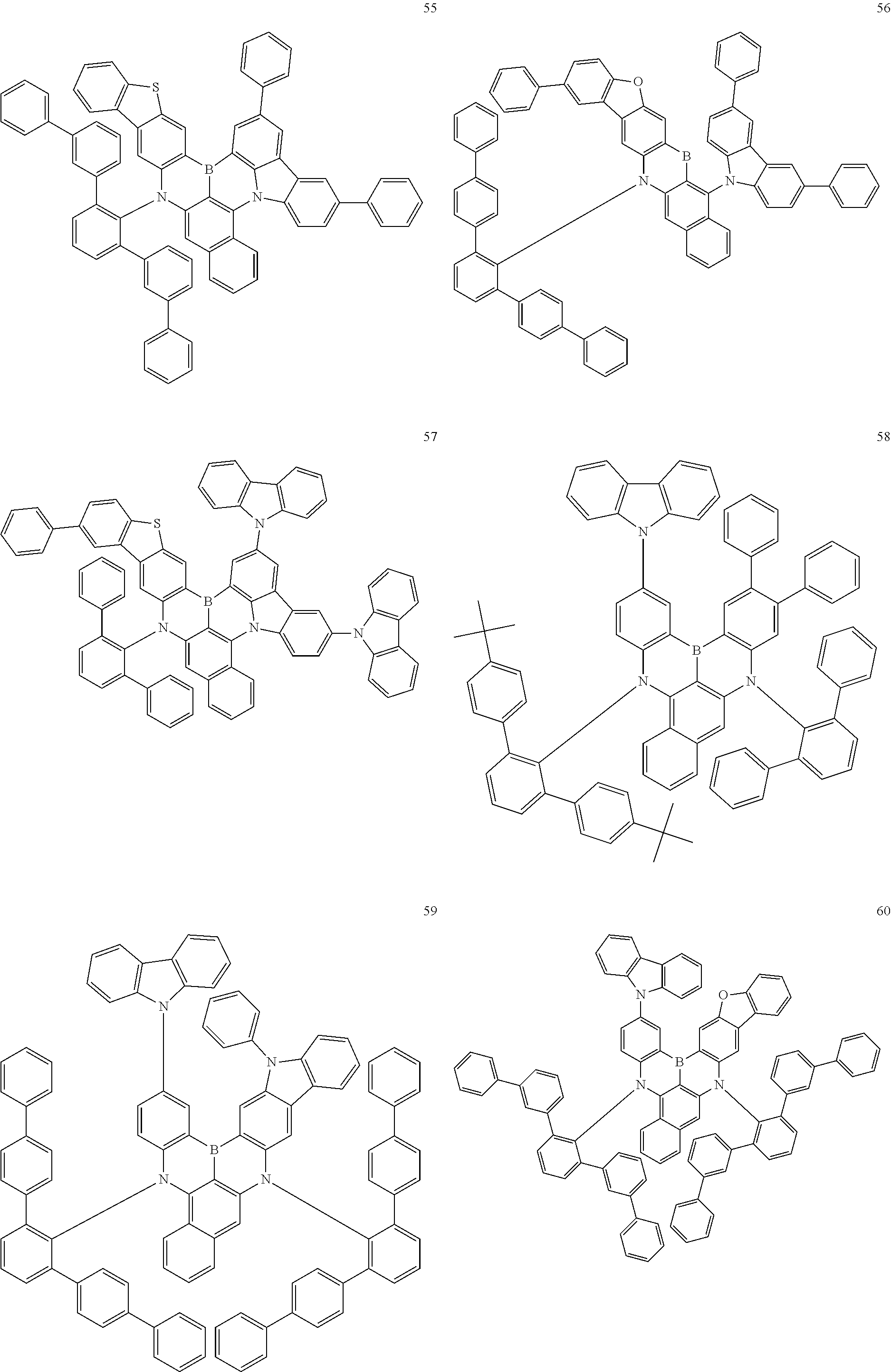

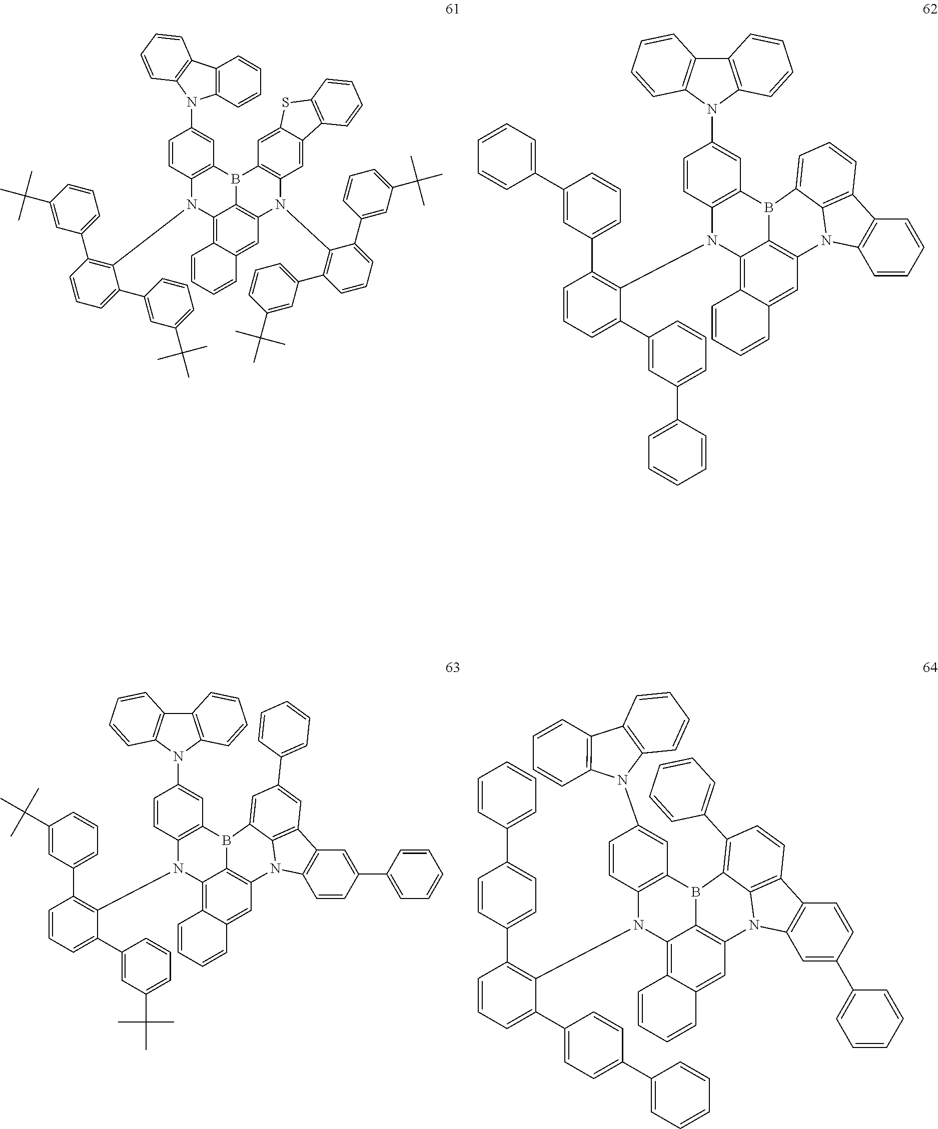

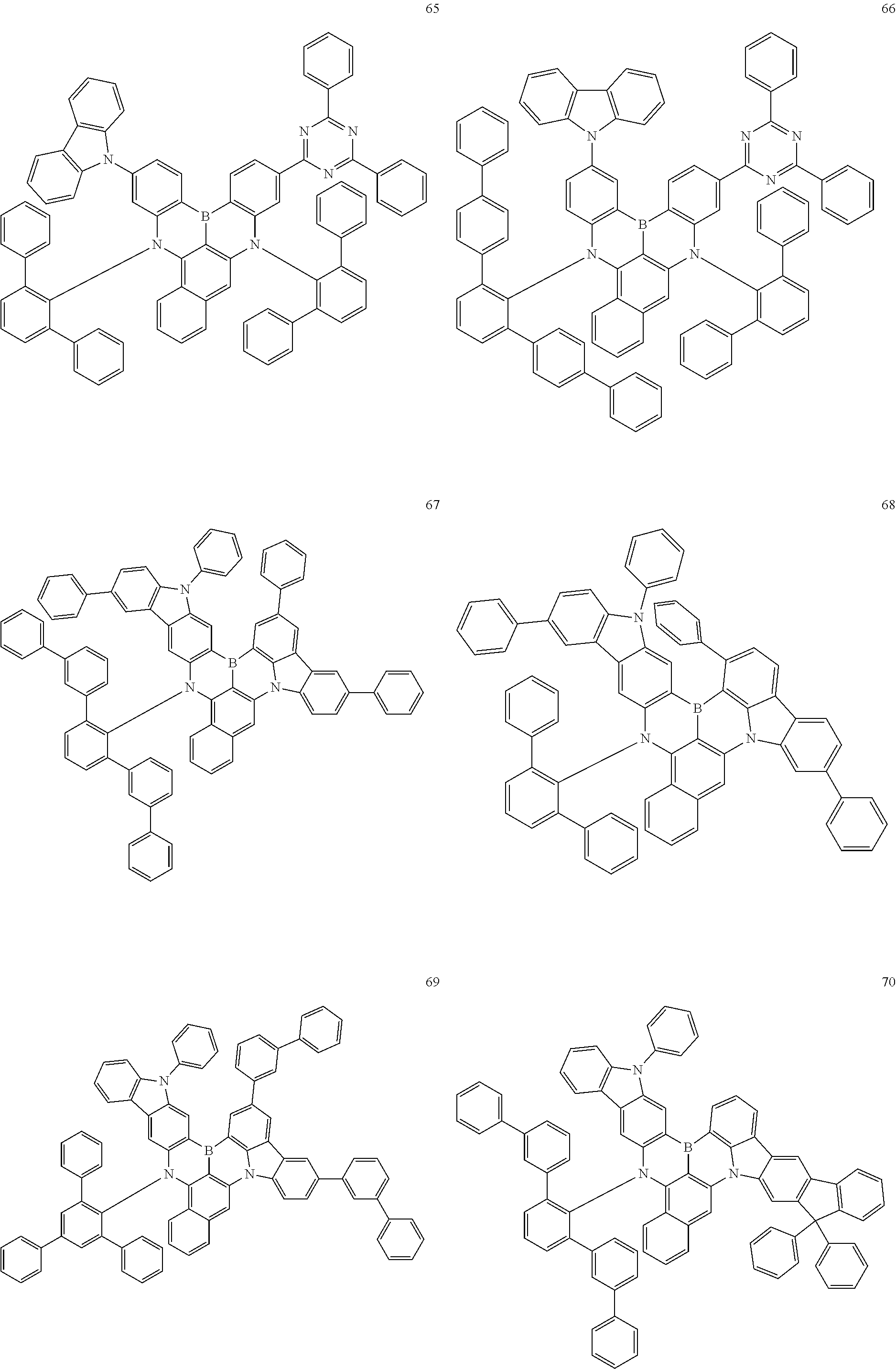

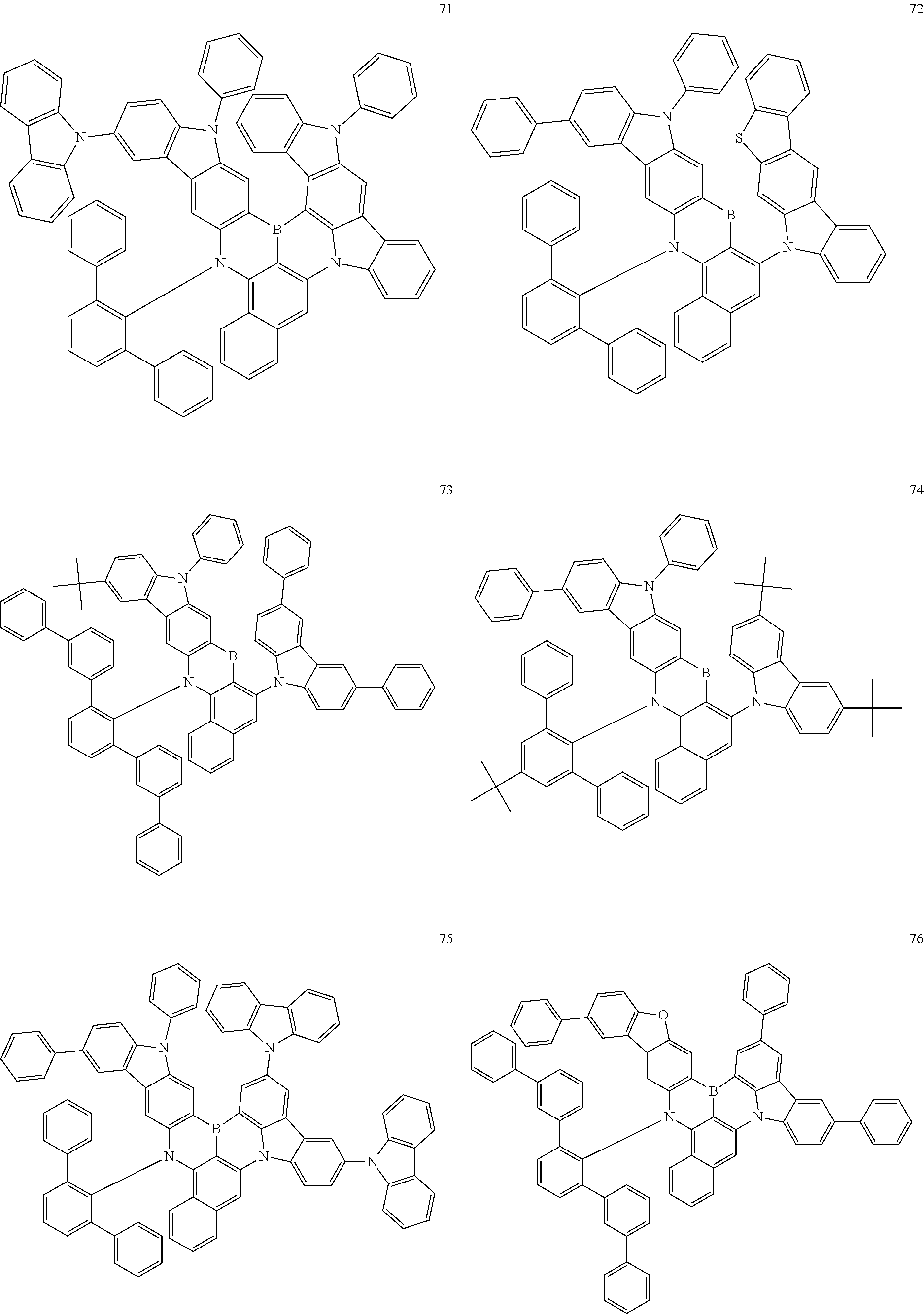

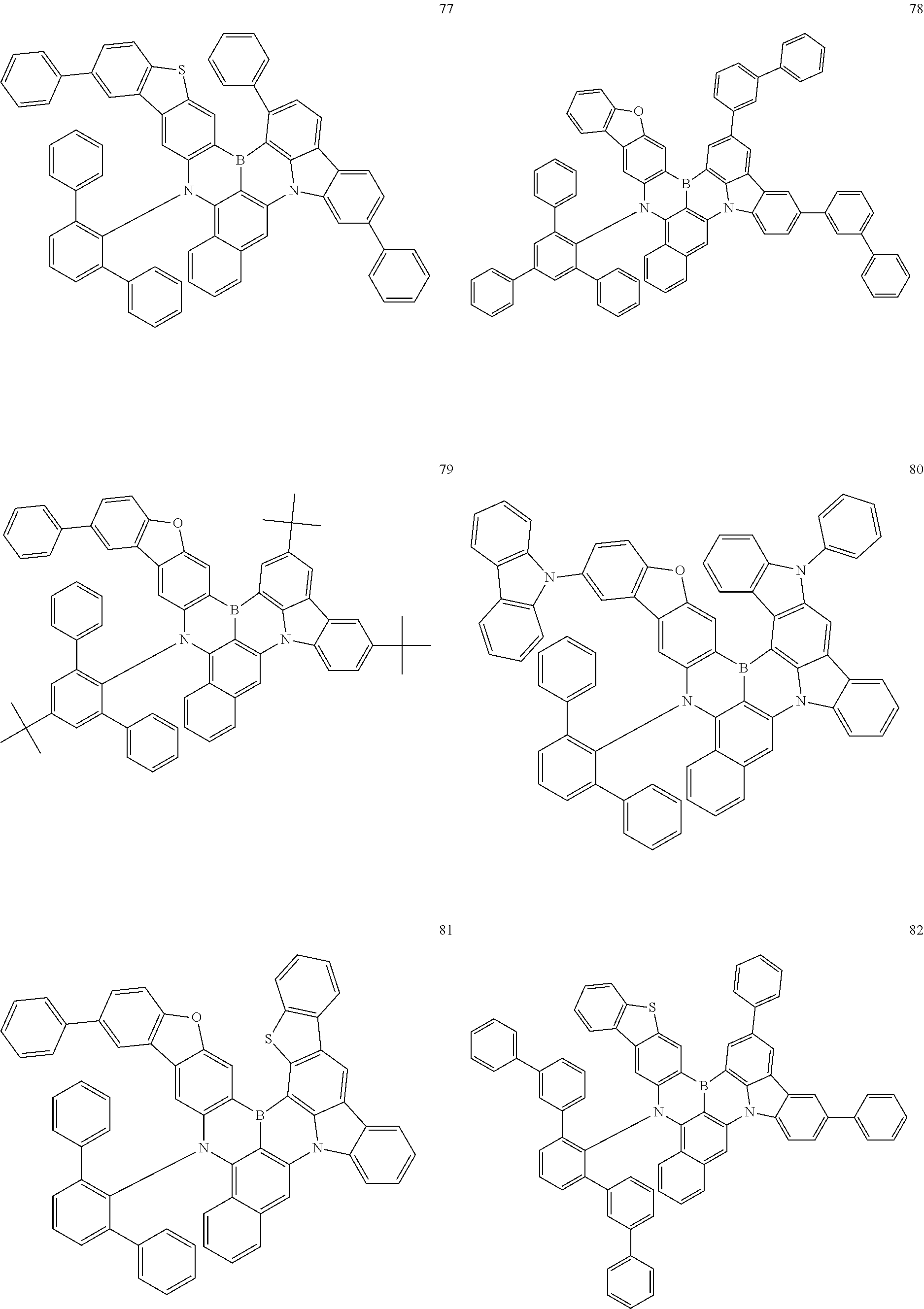

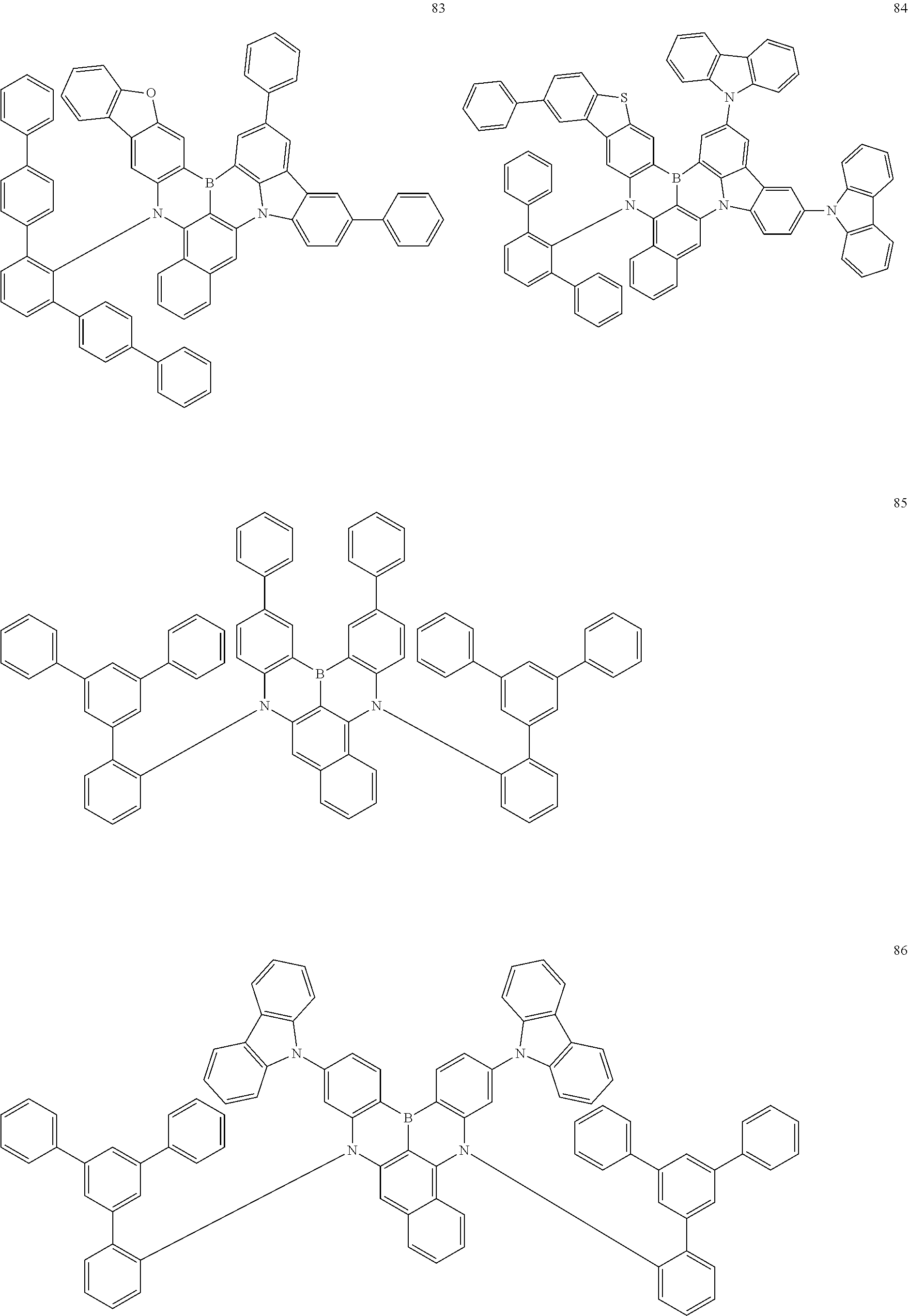

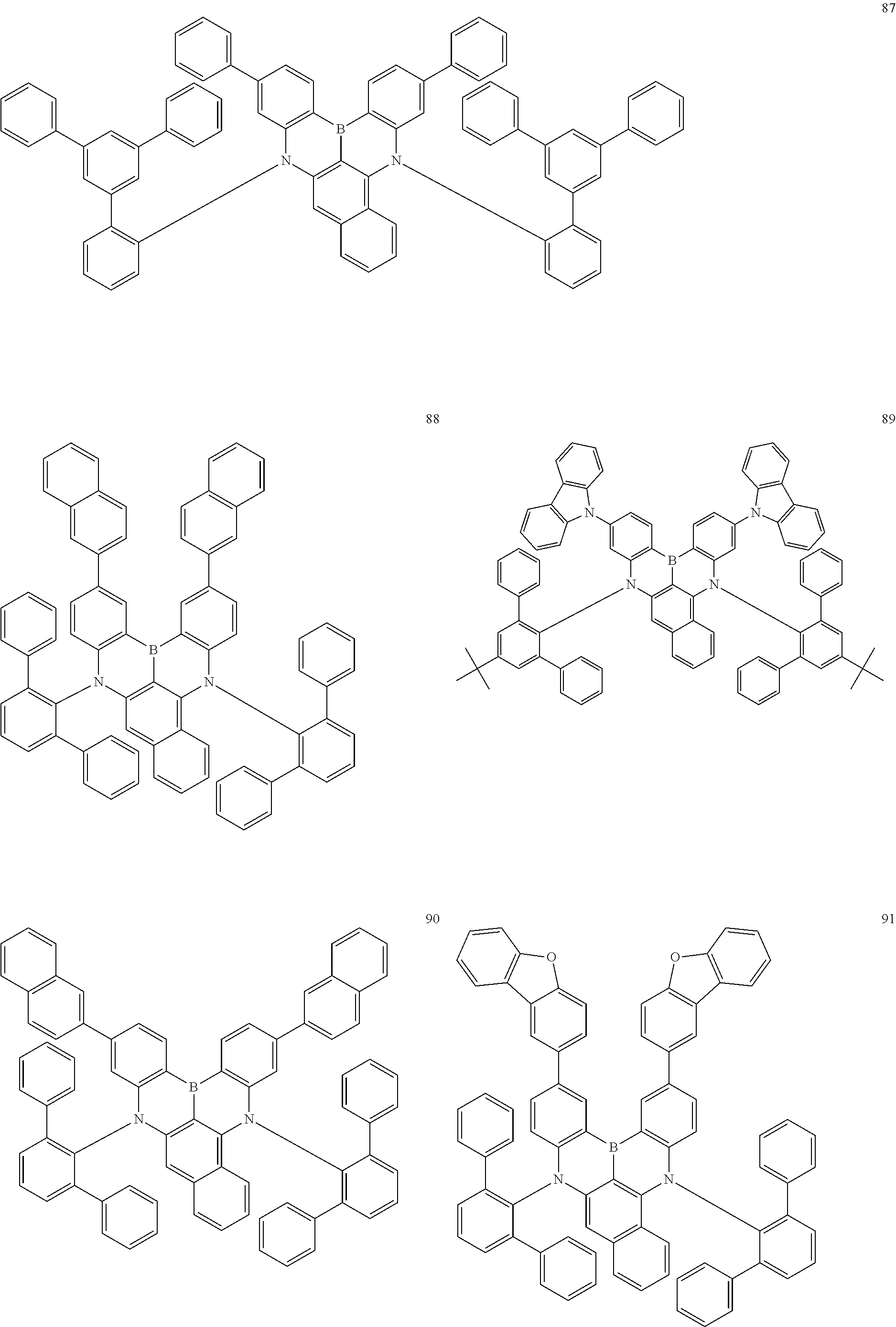

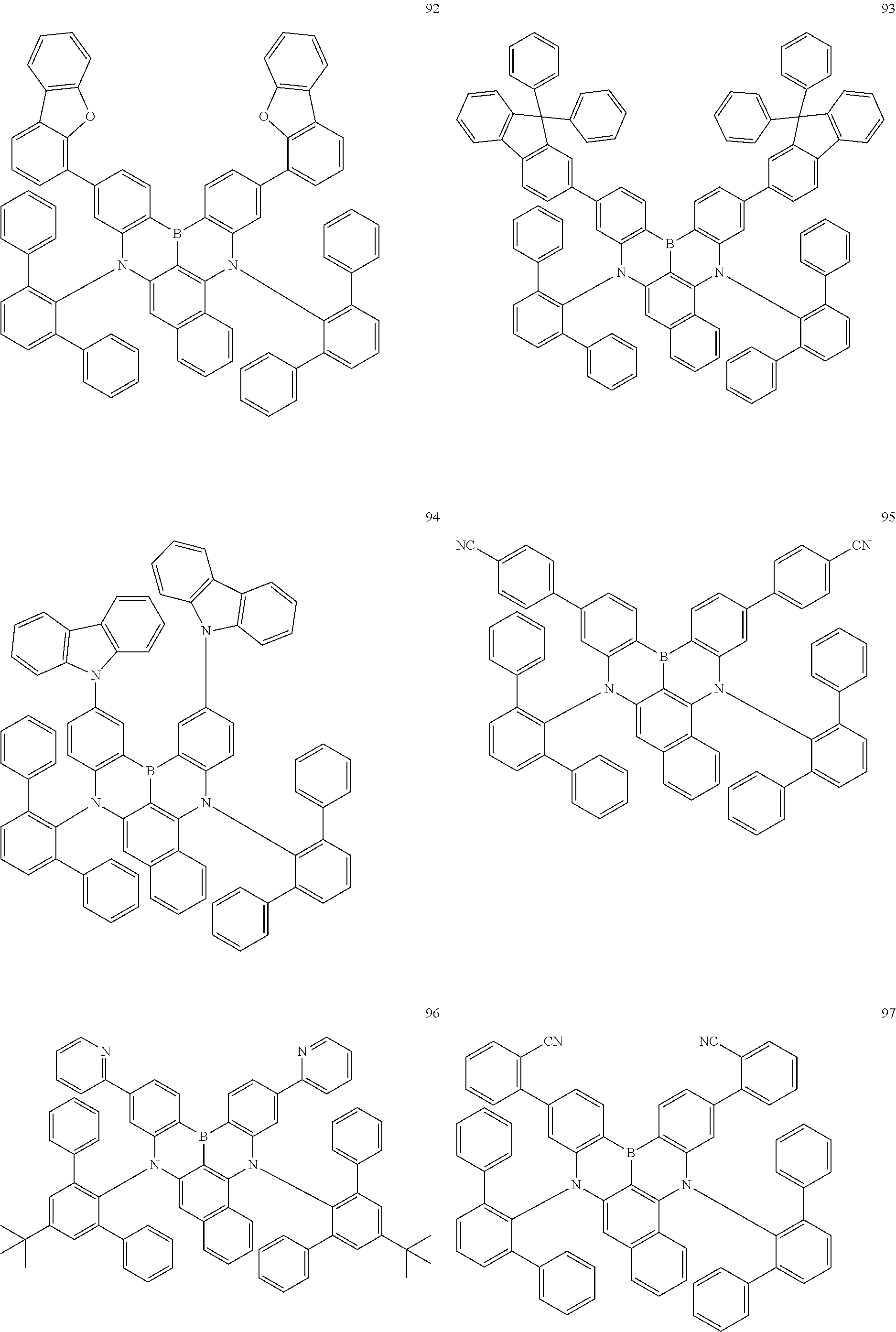

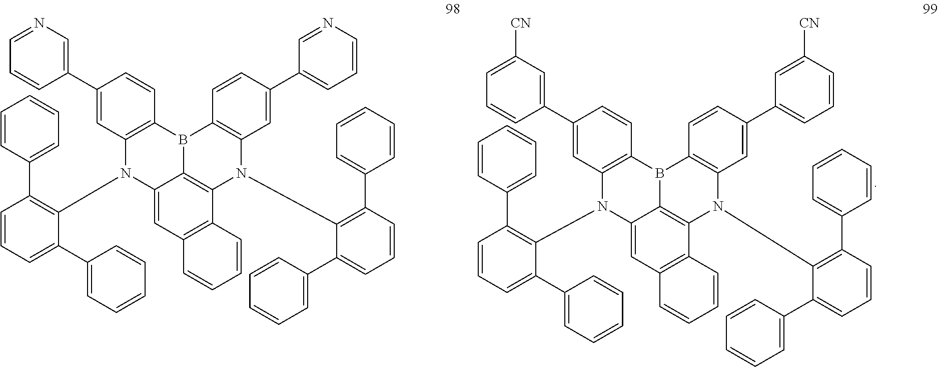 [SMILES: c1ccc(-c2cccc(-c3ccccc3)c2N2c3cc(-c4cccnc4)ccc3B3c4ccc(-c5cccnc5)cc4N(c4c(-c5ccccc5)cccc4-c4ccccc4)c4c3c2cc2ccccc42)cc1 ; N#Cc1cccc(-c2ccc3c(c2)N(c2c(-c4ccccc4)cccc2-c2ccccc2)c2cc4ccccc4c4c2B3c2ccc(-c3cccc(C#N)c3)cc2N4c2c(-c3ccccc3)cccc2-c2ccccc2)c1]

9. The light emitting element of claim 1, wherein the light emitting layer emits green light.

10. The light emitting element of claim 1, wherein the light emitting layer further comprises at least one of a second compound represented by Formula HT-1, a third compound represented by Formula ET-1, and a fourth compound represented by Formula D-1: 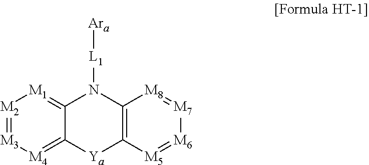
wherein in Formula HT-1,
M₁ to M₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Arₐ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 which 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; 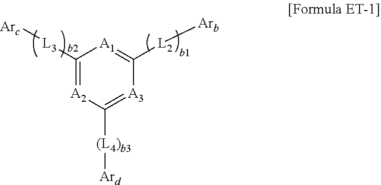
wherein in Formula ET-1,
at least one of A₁ to A₃ is each N,
the remainder A₁ to A₃ is each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 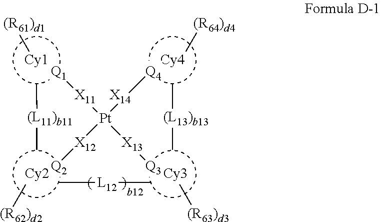
wherein in Formula D-1,
Q₁ to Q₄ are each independently C or N,
Cy1 to Cy4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms,
X₁₁ to X₁₄ are each independently a direct linkage or 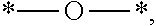
L₁₁ to L₁₃ are each independently a direct linkage, 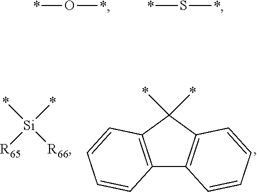
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

11. An electronic apparatus comprising:
a circuit layer disposed on a base layer; and
a display element layer disposed on the circuit layer, and including a light emitting element, wherein
the light emitting element includes:
a first electrode;
a second electrode disposed on the first electrode; and
a light emitting layer disposed between the first electrode and the second electrode, and
the light emitting layer includes a first compound represented by Formula 1: 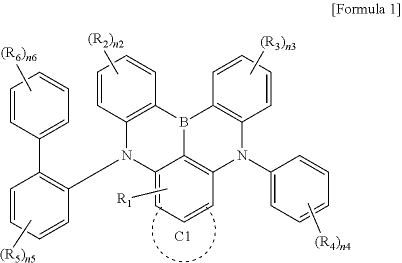
wherein in Formula 1,
C1 is a substituted or unsubstituted aromatic hydrocarbon ring having 6 to 30 ring-forming carbon atoms,
R₁ to R₆ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n2, n3, and n5 are each independently an integer from 0 to 4, and
n4 and n6 are each independently an integer from 0 to 5.

12. The electronic apparatus of claim 11, wherein
the light emitting element further comprises a capping layer disposed on the second electrode, and
the capping layer has a refractive index equal to or greater than about 1.6, with respect to light in a wavelength range of about 550 nm to about 660 nm.

13. The electronic apparatus of claim 11, further comprising:
a light control layer disposed on the display element layer and including a quantum dot, wherein
the light emitting element emits a first color light, and
the light control layer includes:
a first light control unit including a first quantum dot that converts the first color light into a second color light having a longer wavelength range than the first color light;
a second light control unit including a second quantum dot that converts the first color light into a third color light having a longer wavelength range than the first color light and the second color light; and
a third light control unit that transmits the first color light.

14. The electronic apparatus of claim 13, further comprising:
a color filter layer disposed on the light control layer, wherein
the color filter layer includes:
a first filter that transmits the second color light;
a second filter that transmits the third color light; and
a third filter that transmits the first color light.

15. A fused polycyclic compound represented by Formula 1: 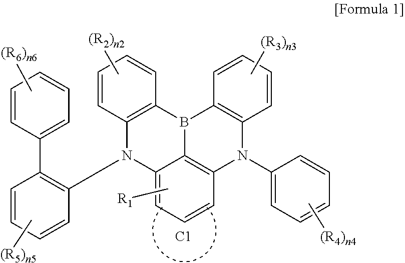
wherein in Formula 1,
C1 is a substituted or unsubstituted aromatic hydrocarbon ring having 6 to 30 ring-forming carbon atoms,
R₁ to R₆ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n2, n3, and n5 are each independently an integer from 0 to 4, and
n4 and n6 are each independently an integer from 0 to 5.

16. The fused polycyclic compound of claim 15, wherein the fused polycyclic compound is represented by Formula 2-1 or Formula 2-2: 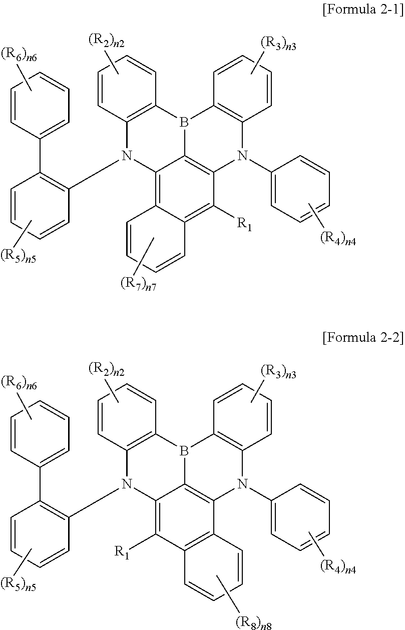
wherein in Formula 2-1 and Formula 2-2,
R₇ and R₈ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n7 and n8 are each independently an integer of 0 to 4, and
R₁ to R₆ and n2 to n6 are the same as defined in Formula 1.

17. The fused polycyclic compound of claim 15, wherein the fused polycyclic compound is represented by one of Formula 3-1 to Formula 3-6: 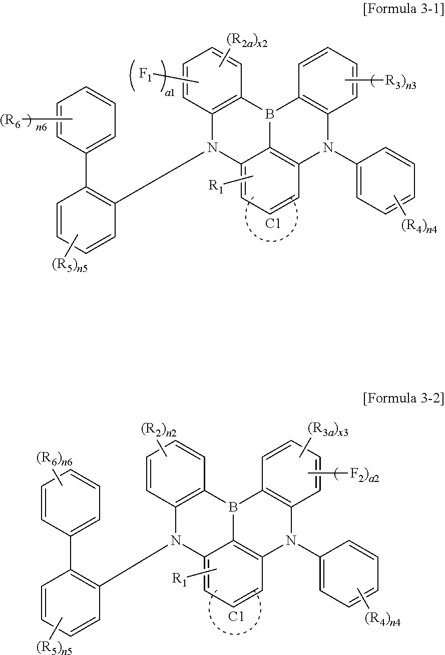 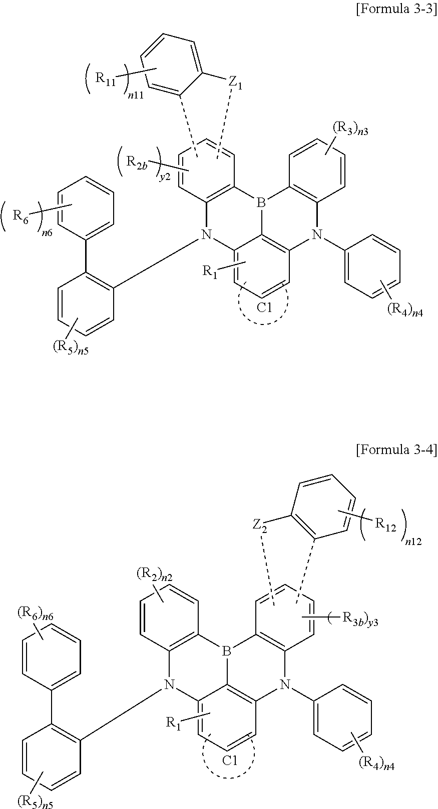 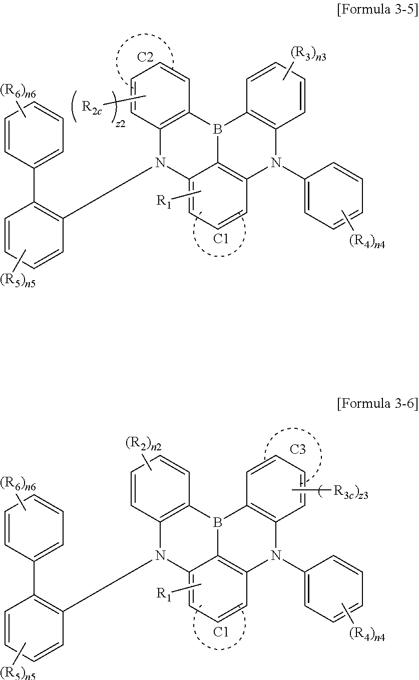
wherein in Formula 3-1 to Formula 3-6,
F₁ and F₂ are each independently a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
Z₁ and Z₂ are each independently O, S, N(R₁₃), or C(R₁₄)(R₁₅),
R₂ₐ, R₃ₐ, R_{2b}, R_{3b}, R_{2c}, R_{3c}, and R₁₁ to R₁₅ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
C2 and C3 are each independently a substituted or unsubstituted aromatic hydrocarbon ring having 6 to 30 ring-forming carbon atoms,
a1 and a2 are each independently 1 or 2,
x2 is an integer from 0 to (4-a1),
x3 is an integer from 0 to (4-a2),
y2, y3, z2, and z3 are each independently an integer from 0 to 2,
n11 and n12 are each independently an integer from 0 to 4, and
C1, R₁ to R₆, and n2 to n6 are the same as defined in Formula 1.

18. The fused polycyclic compound of claim 17, wherein in Formula 3-1 and Formula 3-2, F₁ and F₂ are each independently a substituted or unsubstituted diphenylamine group, a substituted or unsubstituted phenyl group, a substituted or unsubstituted biphenyl group, a substituted or unsubstituted naphthyl group, a substituted or unsubstituted phenanthrene group, a substituted or unsubstituted pyridine group, a substituted or unsubstituted triazine group, a substituted or unsubstituted dihydroacridine group, a substituted or unsubstituted fluorene group, a substituted or unsubstituted carbazole group, a substituted or unsubstituted dibenzofuran group, or a substituted or unsubstituted dibenzothiophene group, or bonded to an adjacent group to form a ring.

19. The fused polycyclic compound of claim 15, wherein the fused polycyclic compound is represented by one of Formula 5-1 to Formula 5-3: 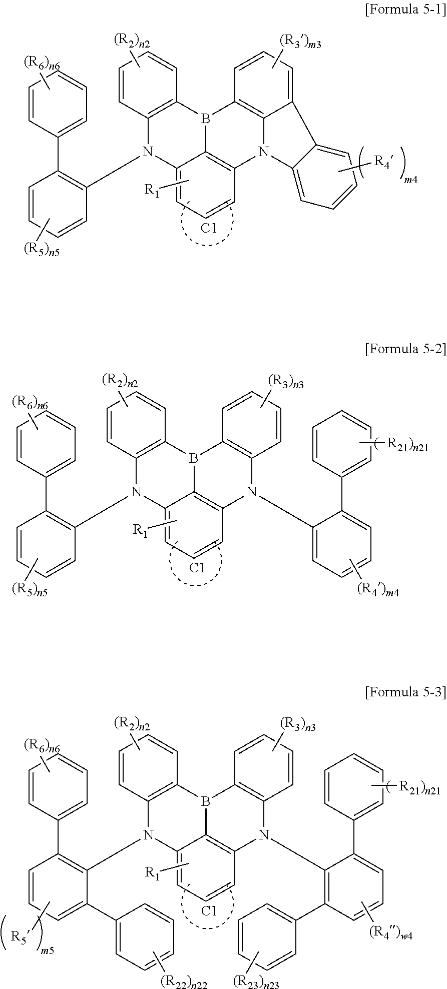
wherein in Formula 5-1 to Formula 5-3,
R₃′, R₄′, R₄″, R₅′, and R₂₁ to R₂₃ are each independently a hydrogen atom, a deuterium atom, a halogen atom, a cyano group, a hydroxy group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
m4 is an integer from 0 to 4,
m3, w4, and m5 are each independently an integer from 0 to 3,
n21 to n23 are each independently an integer from 0 to 5, and
C1, R₁ to R₃, R₅, R₆, n2, n3, n5, and n6 are the same as defined in Formula 1.

20. The fused polycyclic compound of claim 15, wherein the fused polycyclic compound is selected from Compound Group 1: 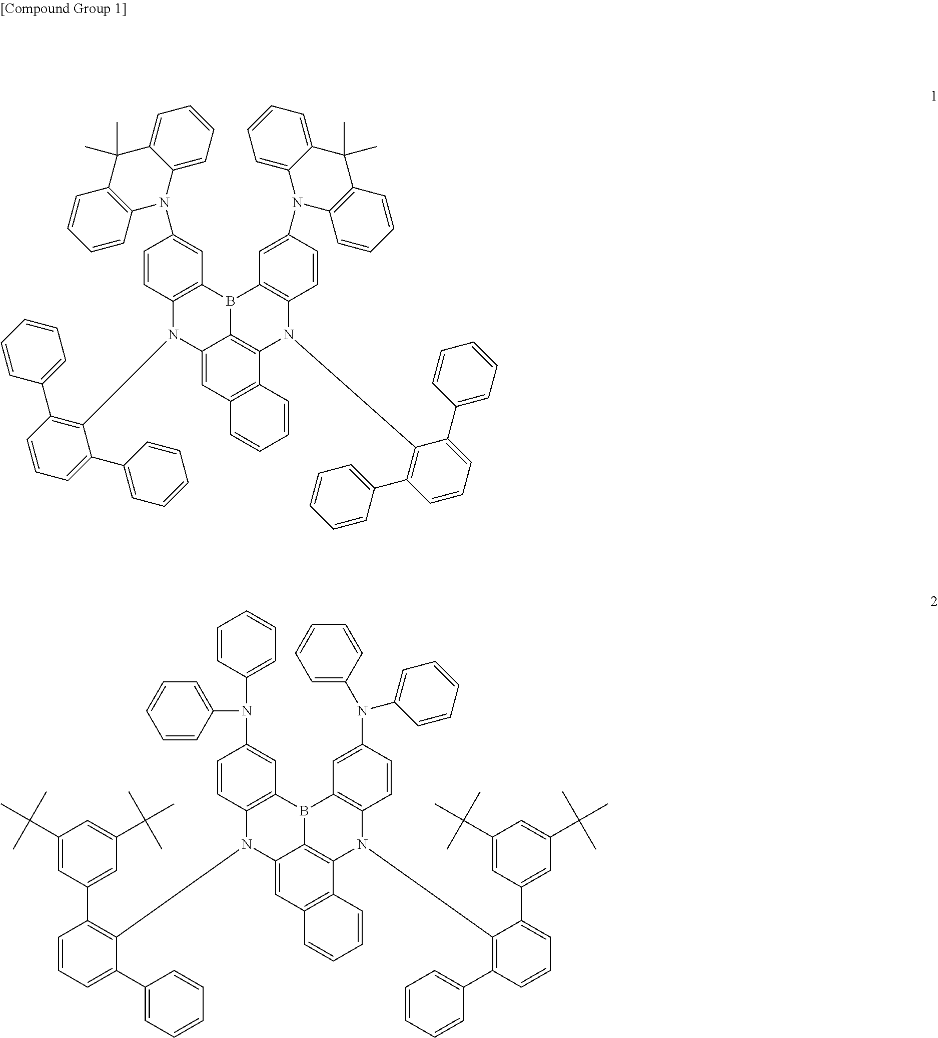 [SMILES: CC1(C)c2ccccc2N(c2ccc3c(c2)B2c4cc(N5c6ccccc6C(C)(C)c6ccccc65)ccc4N(c4c(-c5ccccc5)cccc4-c4ccccc4)c4c2c(cc2ccccc42)N3c2c(-c3ccccc3)cccc2-c2ccccc2)c2ccccc21 ; CC(C)(C)c1cc(-c2cccc(-c3ccccc3)c2N2c3ccc(N(c4ccccc4)c4ccccc4)cc3B3c4cc(N(c5ccccc5)c5ccccc5)ccc4N(c4c(-c5ccccc5)cccc4-c4cc(C(C)(C)C)cc(C(C)(C)C)c4)c4c3c2cc2ccccc42)cc(C(C)(C)C)c1] 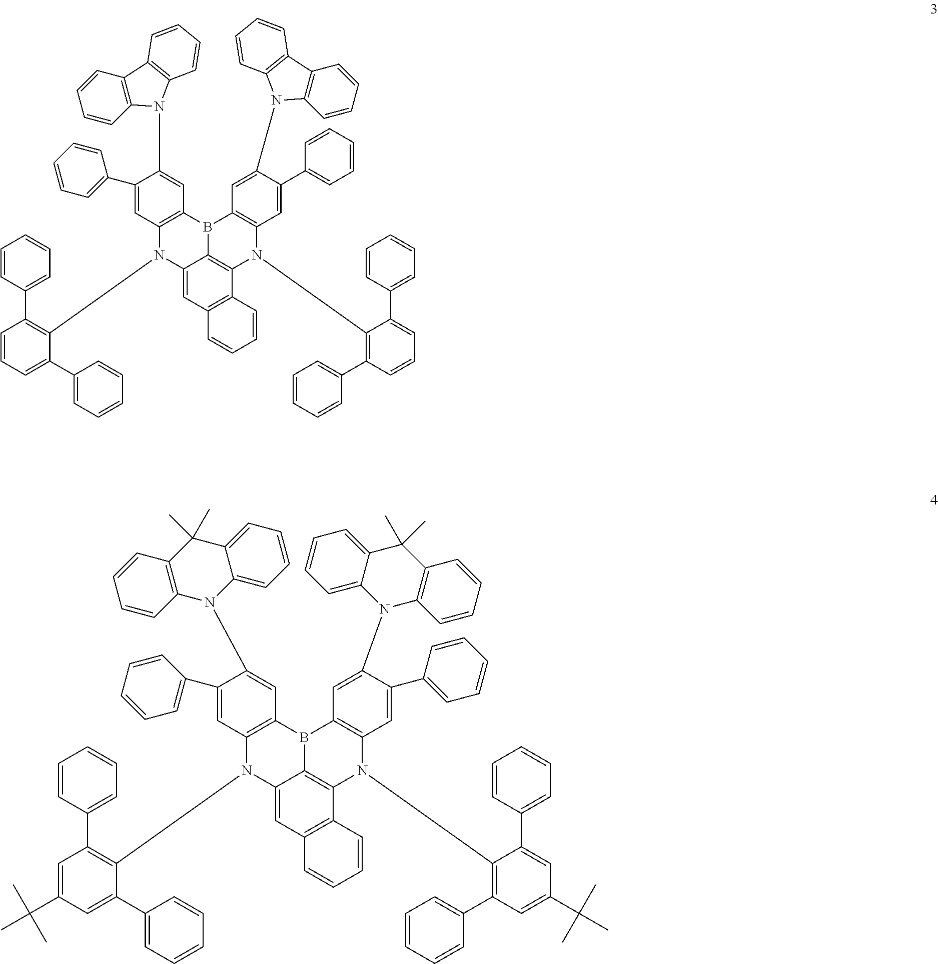 [SMILES: c1ccc(-c2cc3c(cc2-n2c4ccccc4c4ccccc42)B2c4cc(-n5c6ccccc6c6ccccc65)c(-c5ccccc5)cc4N(c4c(-c5ccccc5)cccc4-c4ccccc4)c4c2c(cc2ccccc42)N3c2c(-c3ccccc3)cccc2-c2ccccc2)cc1 ; CC(C)(C)c1cc(-c2ccccc2)c(N2c3cc(-c4ccccc4)c(N4c5ccccc5C(C)(C)c5ccccc54)cc3B3c4cc(N5c6ccccc6C(C)(C)c6ccccc65)c(-c5ccccc5)cc4N(c4c(-c5ccccc5)cc(C(C)(C)C)cc4-c4ccccc4)c4c3c2cc2ccccc42)c(-c2ccccc2)c1] 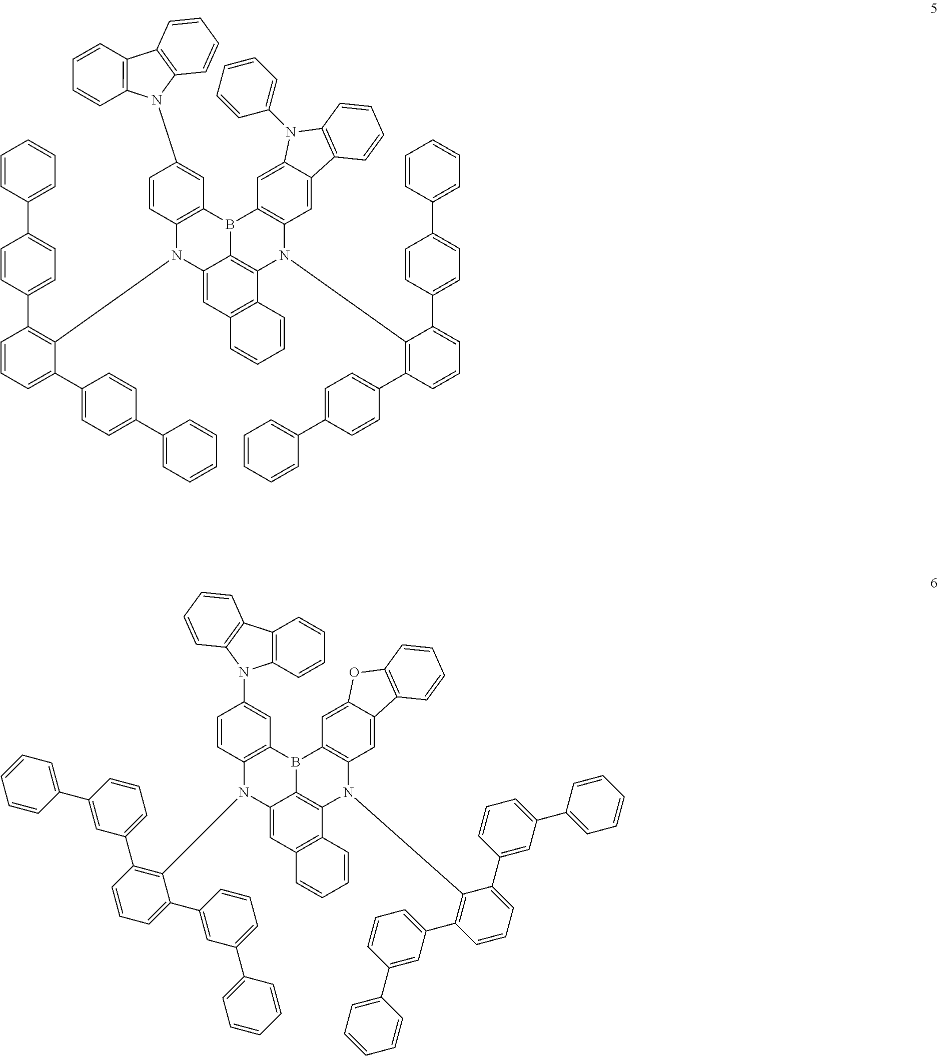 [SMILES: c1ccc(-c2ccc(-c3cccc(-c4ccc(-c5ccccc5)cc4)c3N3c4ccc(-n5c6ccccc6c6ccccc65)cc4B4c5cc6c(cc5N(c5c(-c7ccc(-c8ccccc8)cc7)cccc5-c5ccc(-c7ccccc7)cc5)c5c4c3cc3ccccc53)c3ccccc3n6-c3ccccc3)cc2)cc1 ; c1ccc(-c2cccc(-c3cccc(-c4cccc(-c5ccccc5)c4)c3N3c4ccc(-n5c6ccccc6c6ccccc65)cc4B4c5cc6oc7ccccc7c6cc5N(c5c(-c6cccc(-c7ccccc7)c6)cccc5-c5cccc(-c6ccccc6)c5)c5c4c3cc3ccccc53)c2)cc1] 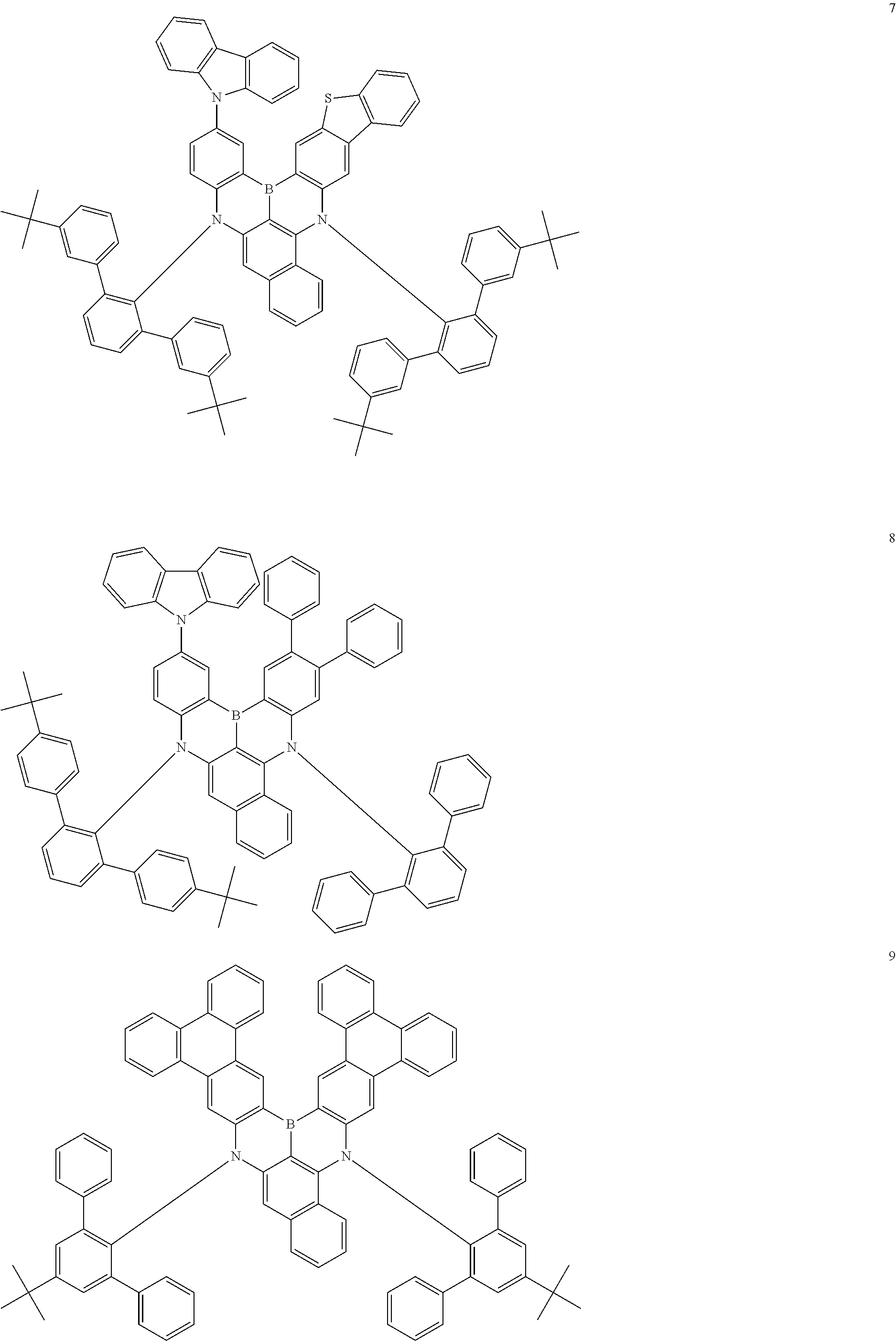 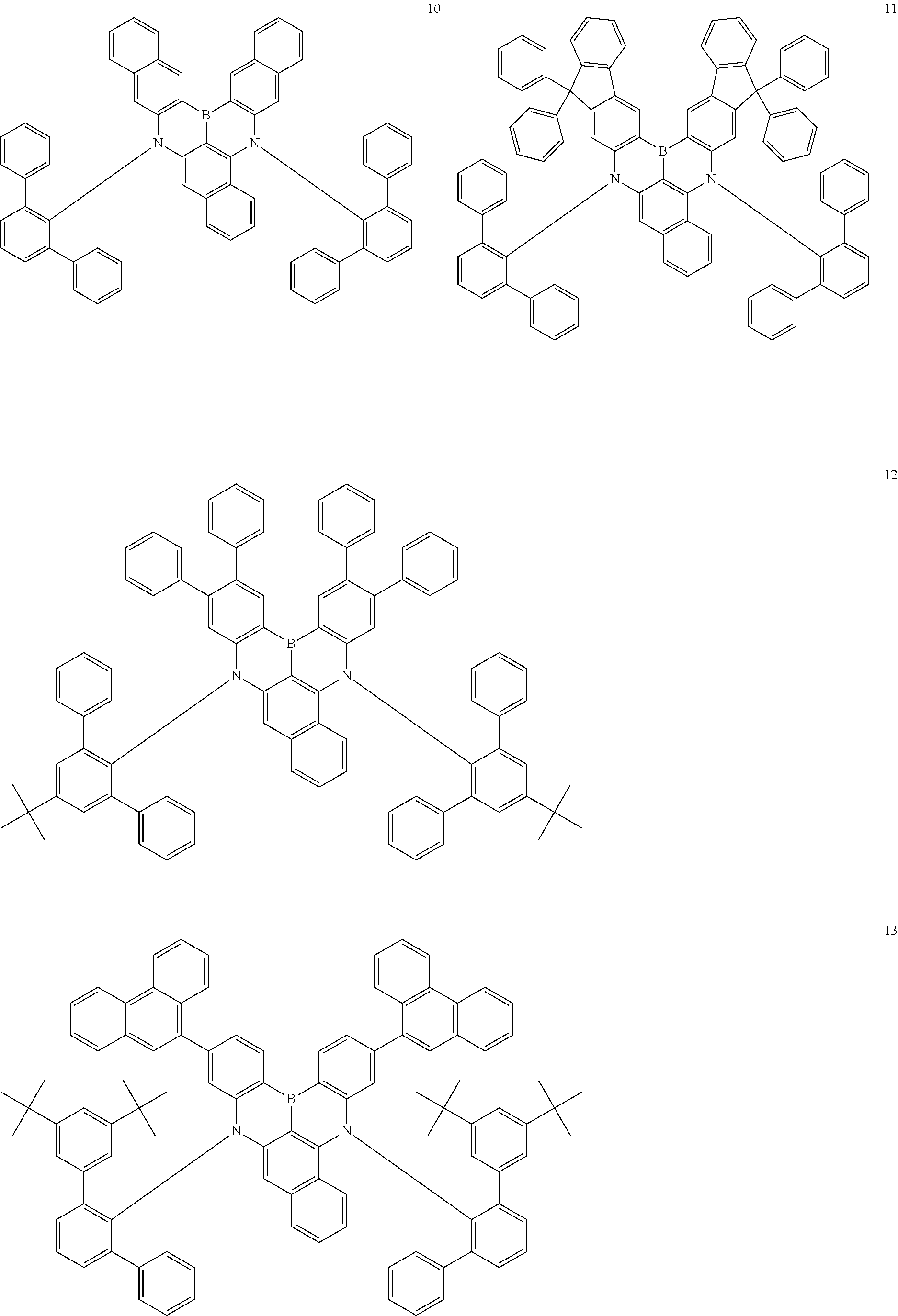 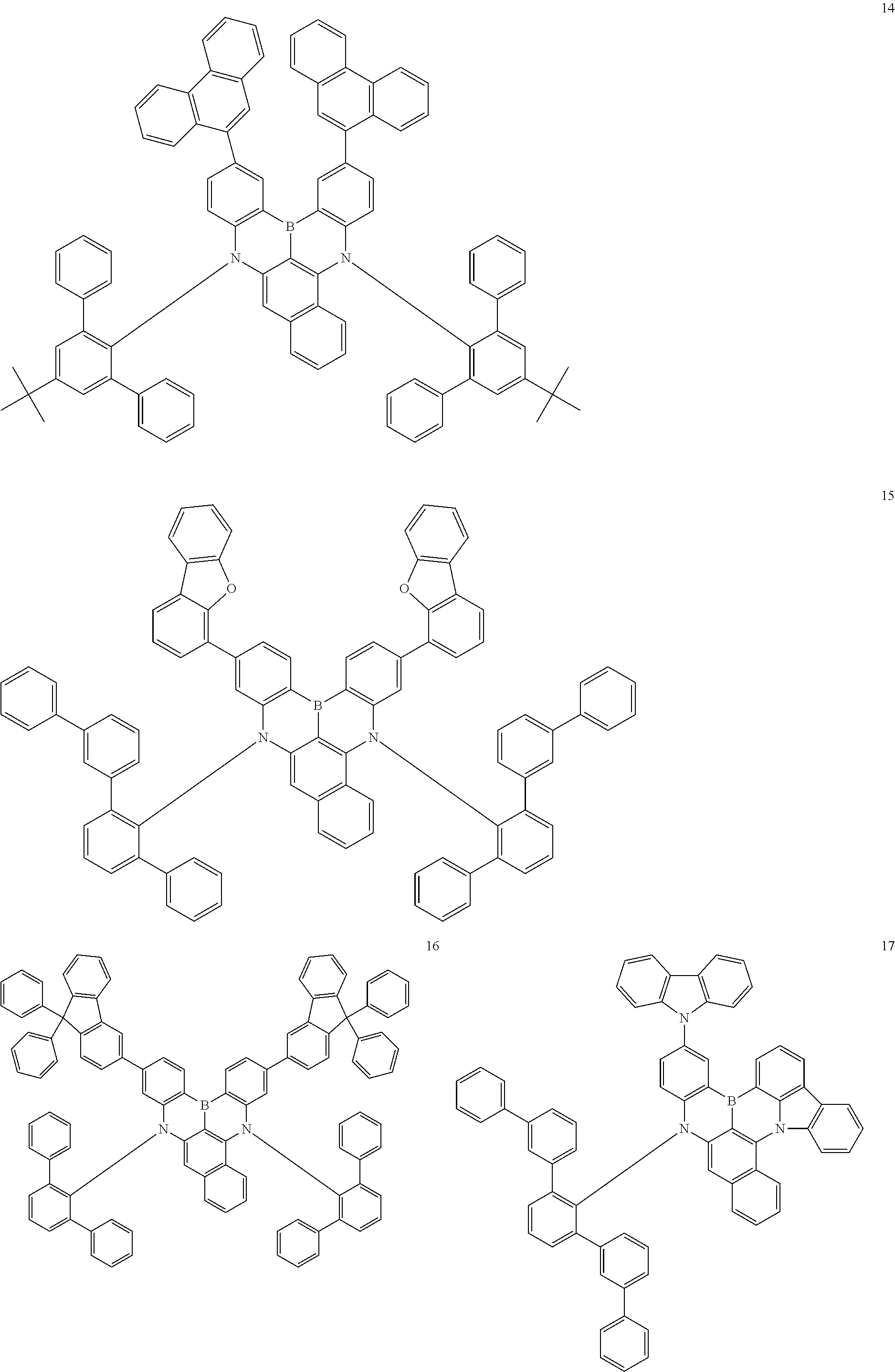 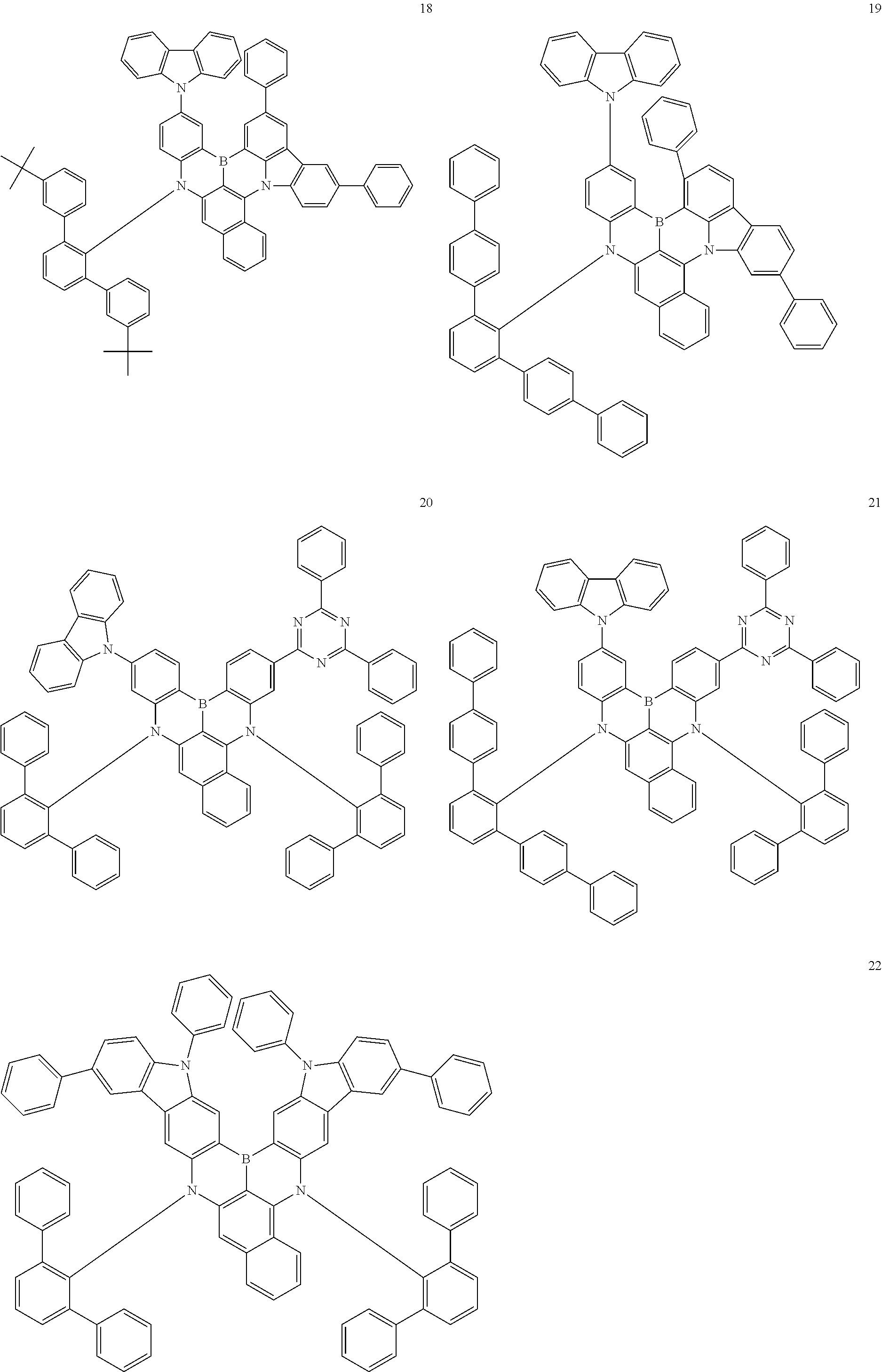 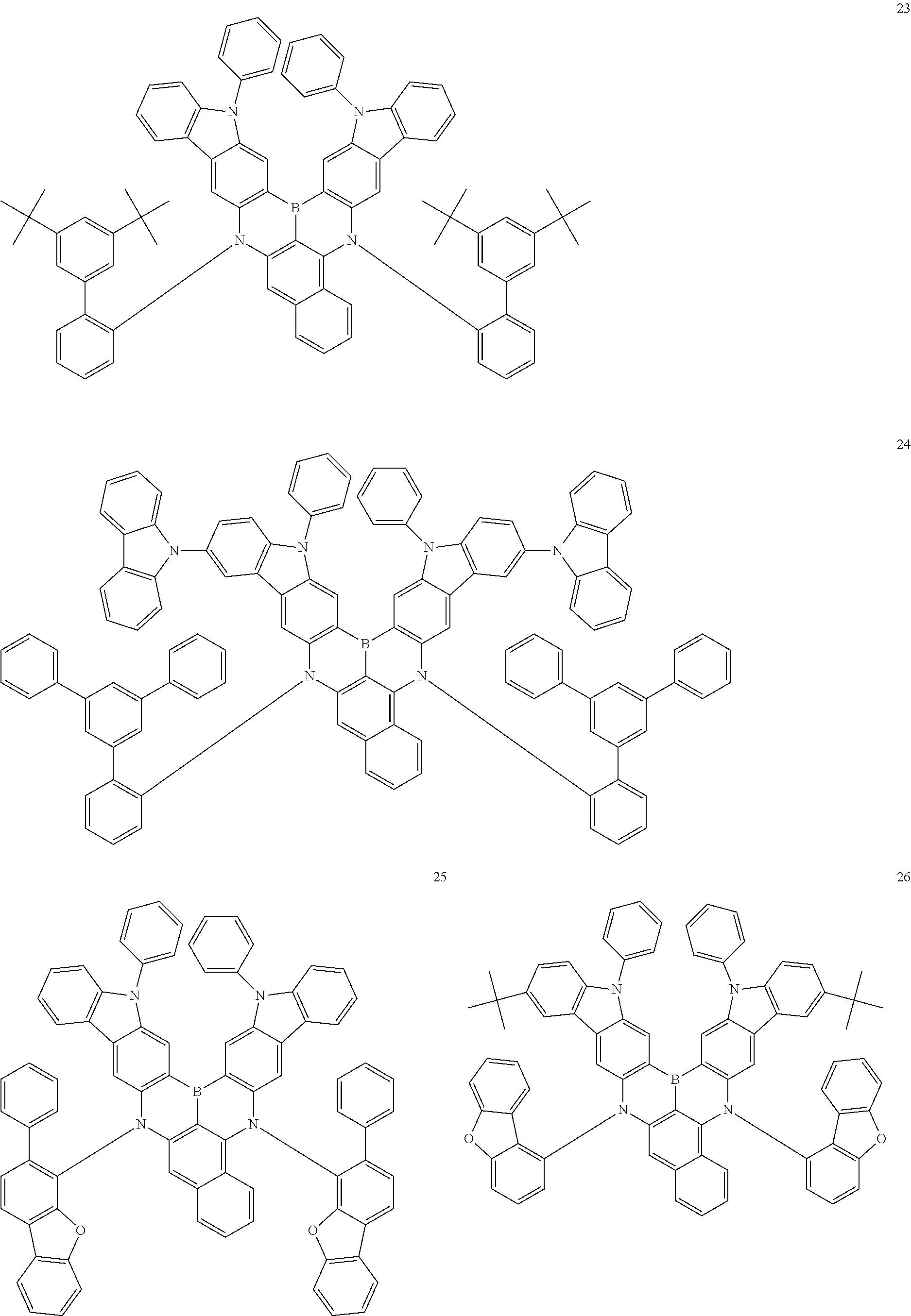 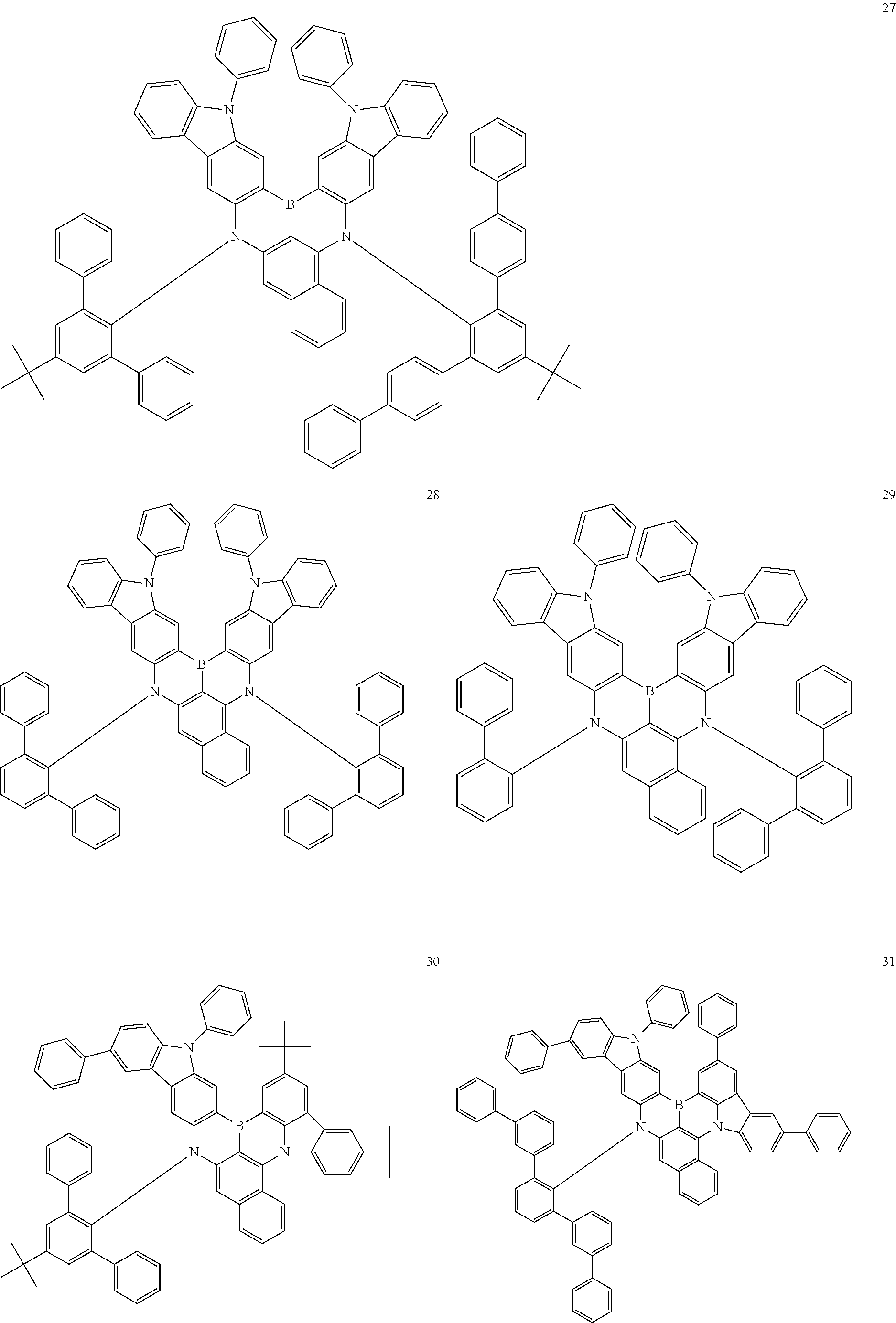 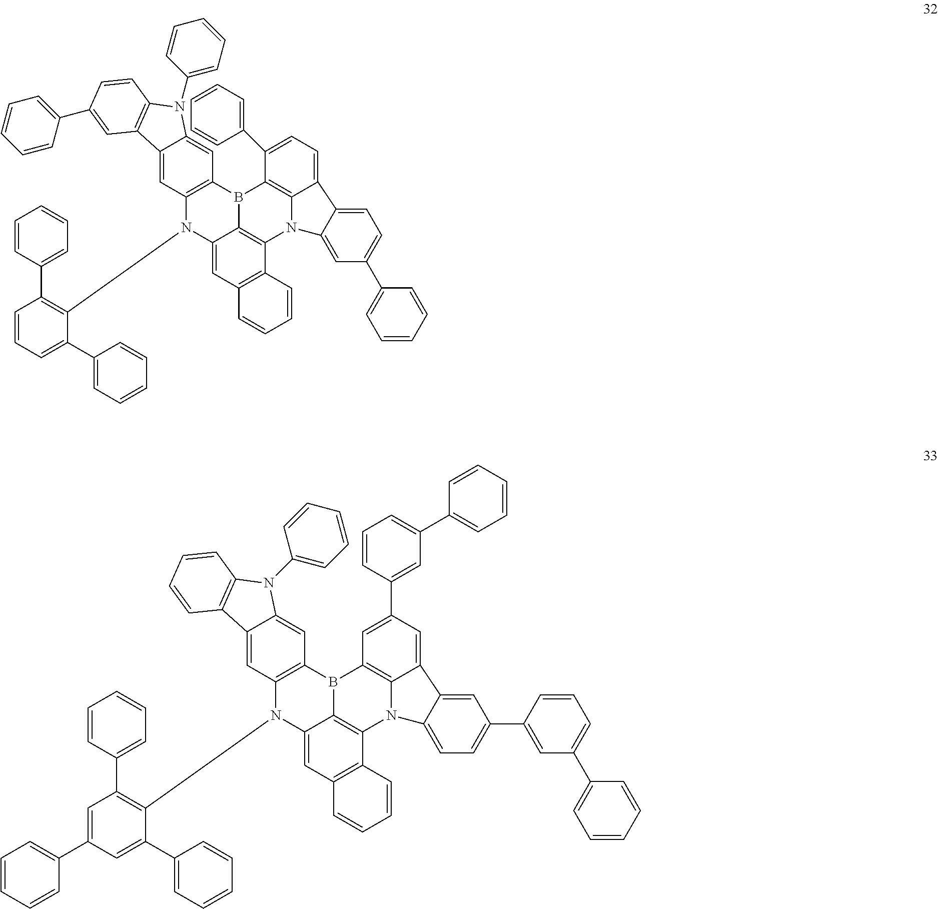 [SMILES: c1ccc(-c2ccc3c(c2)c2cc4c(cc2n3-c2ccccc2)B2c3c(cc5ccccc5c3-n3c5cc(-c6ccccc6)ccc5c5ccc(-c6ccccc6)c2c53)N4c2c(-c3ccccc3)cccc2-c2ccccc2)cc1 ; c1ccc(-c2cccc(-c3ccc4c(c3)c3cc(-c5cccc(-c6ccccc6)c5)cc5c3n4-c3c4c(cc6ccccc36)N(c3c(-c6ccccc6)cc(-c6ccccc6)cc3-c3ccccc3)c3cc6c7ccccc7n(-c7ccccc7)c6cc3B45)c2)cc1] 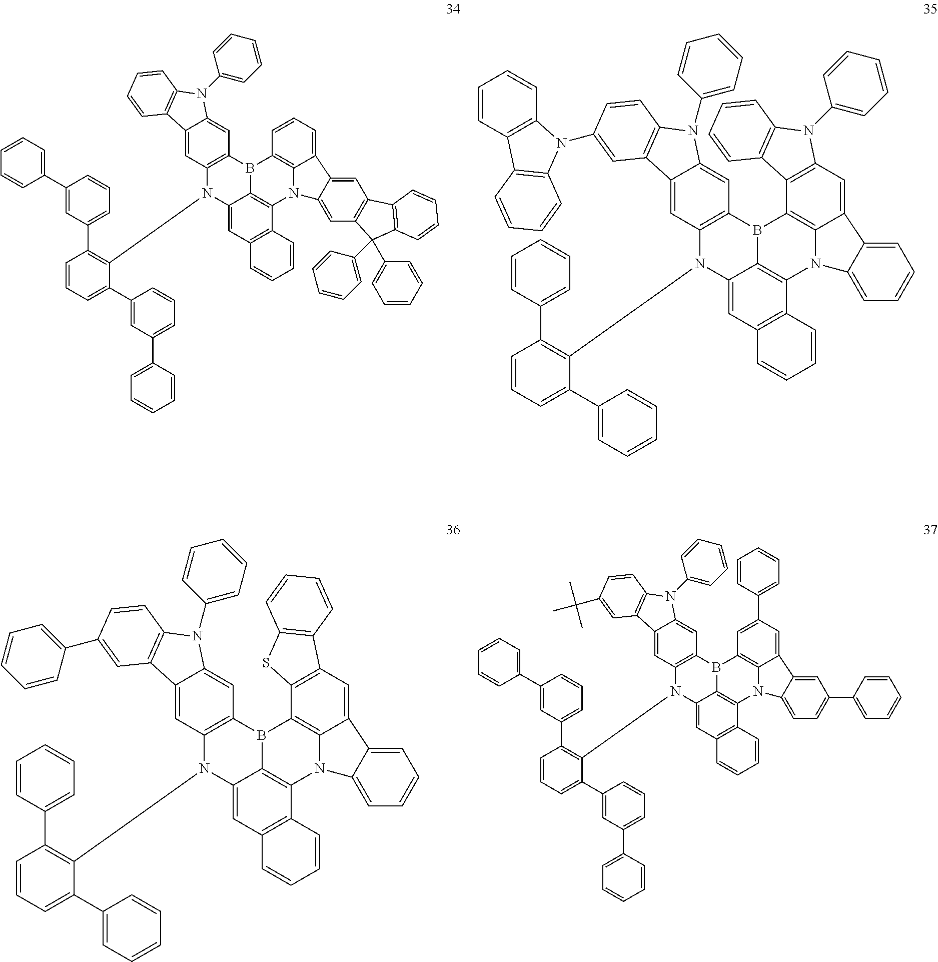 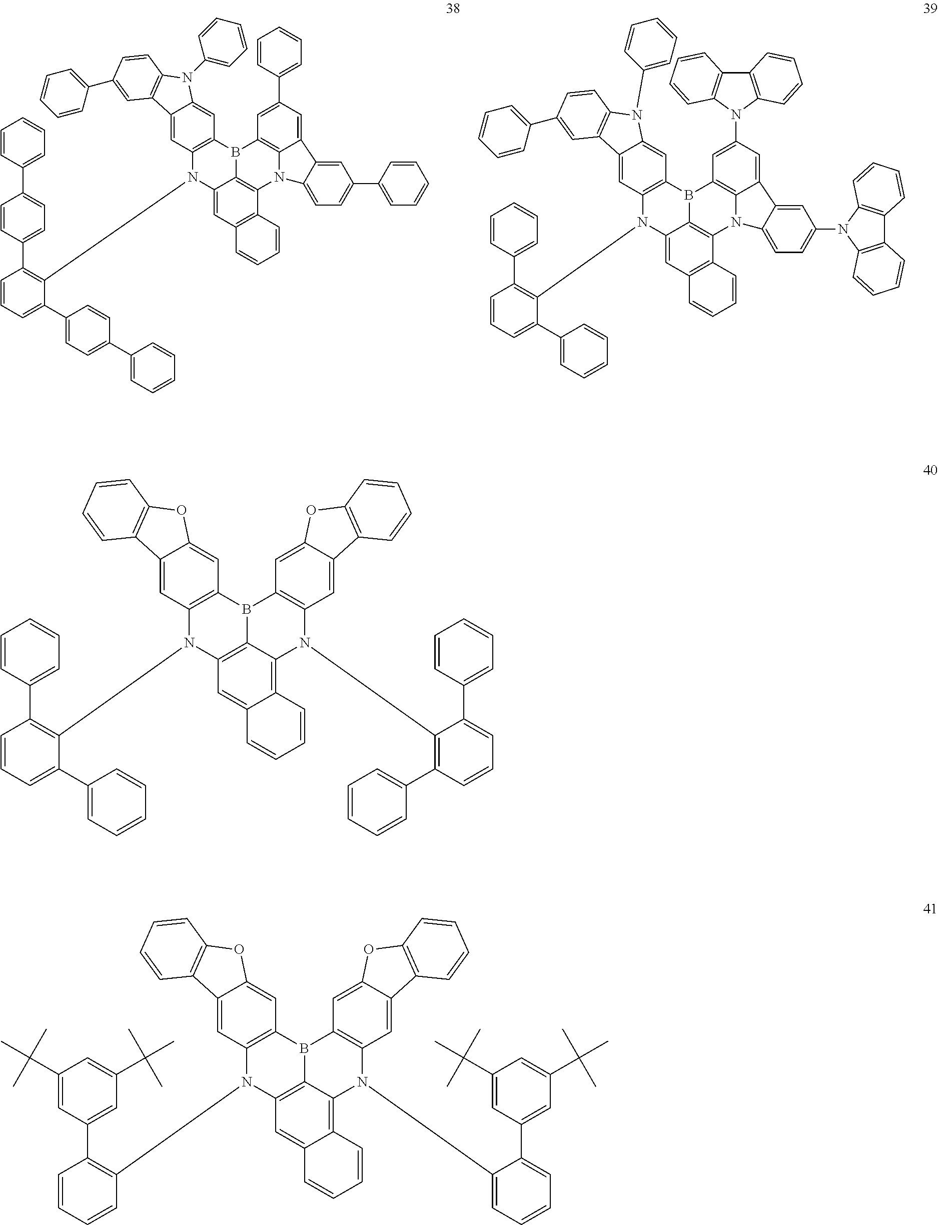 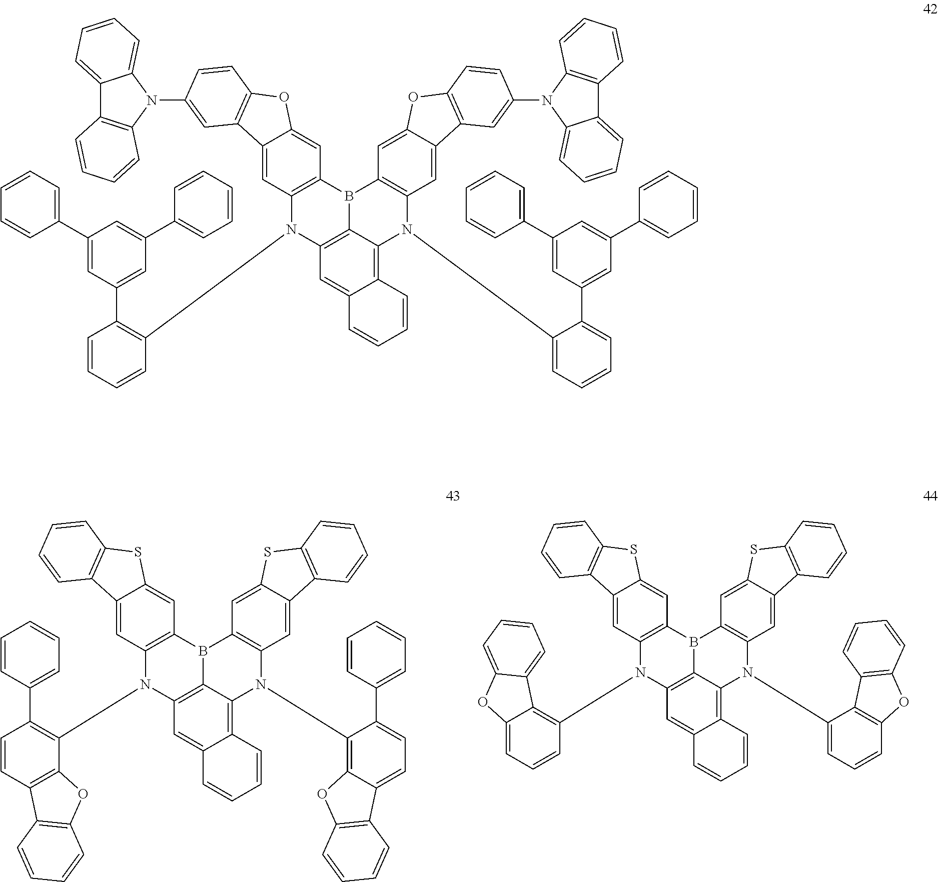 [SMILES: c1ccc(-c2cc(-c3ccccc3)cc(-c3ccccc3N3c4cc5c(cc4B4c6cc7oc8ccc(-n9c%10ccccc%10c%10ccccc%109)cc8c7cc6N(c6ccccc6-c6cc(-c7ccccc7)cc(-c7ccccc7)c6)c6c4c3cc3ccccc63)oc3ccc(-n4c6ccccc6c6ccccc64)cc35)c2)cc1 ; c1ccc(-c2ccc3c(oc4ccccc43)c2N2c3cc4c(cc3B3c5cc6sc7ccccc7c6cc5N(c5c(-c6ccccc6)ccc6c5oc5ccccc56)c5c3c2cc2ccccc52)sc2ccccc24)cc1 ; c1ccc2c3c4c(cc2c1)N(c1cccc2oc5ccccc5c12)c1cc2c(cc1B4c1cc4sc5ccccc5c4cc1N3c1cccc3oc4ccccc4c13)sc1ccccc12] 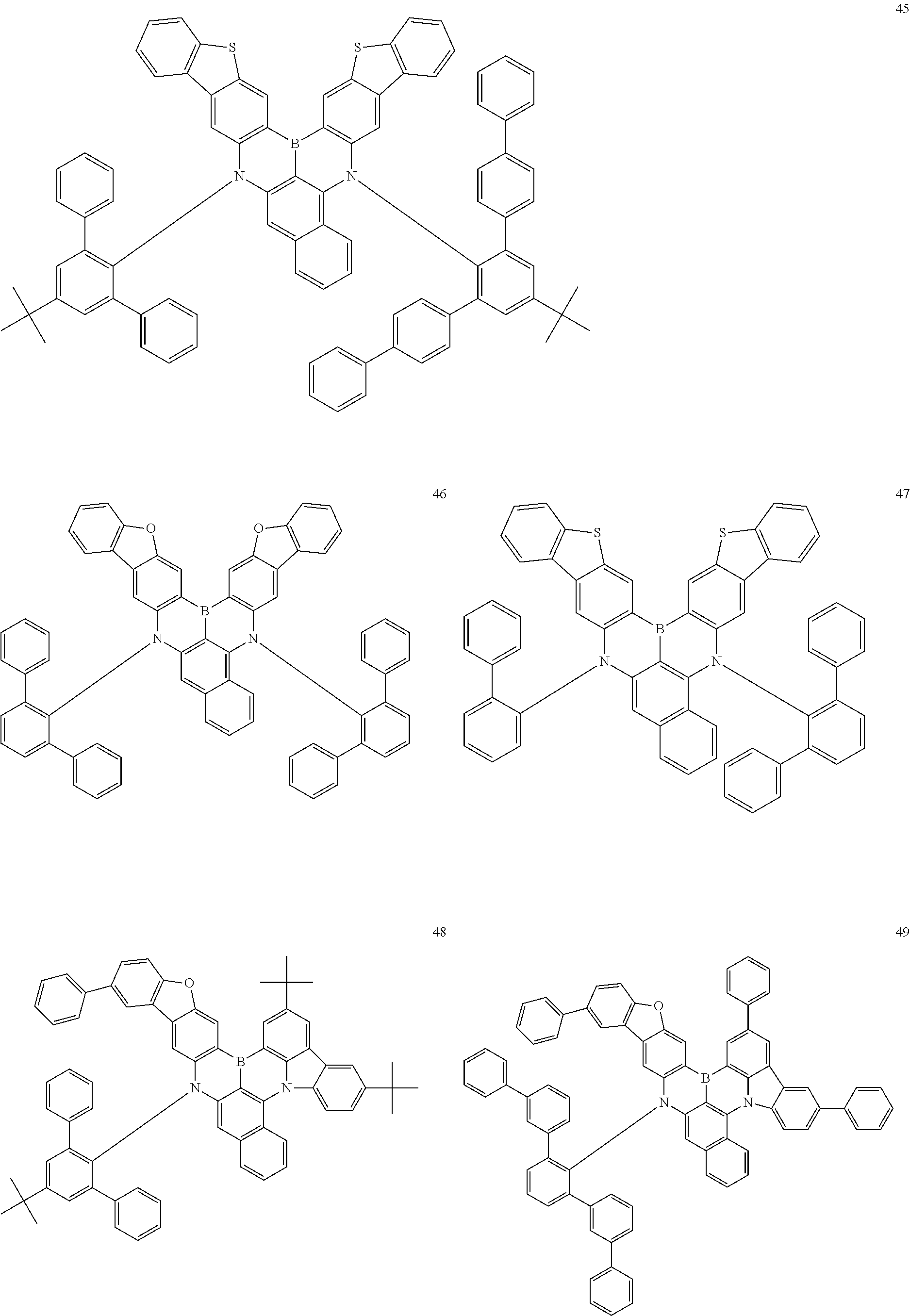 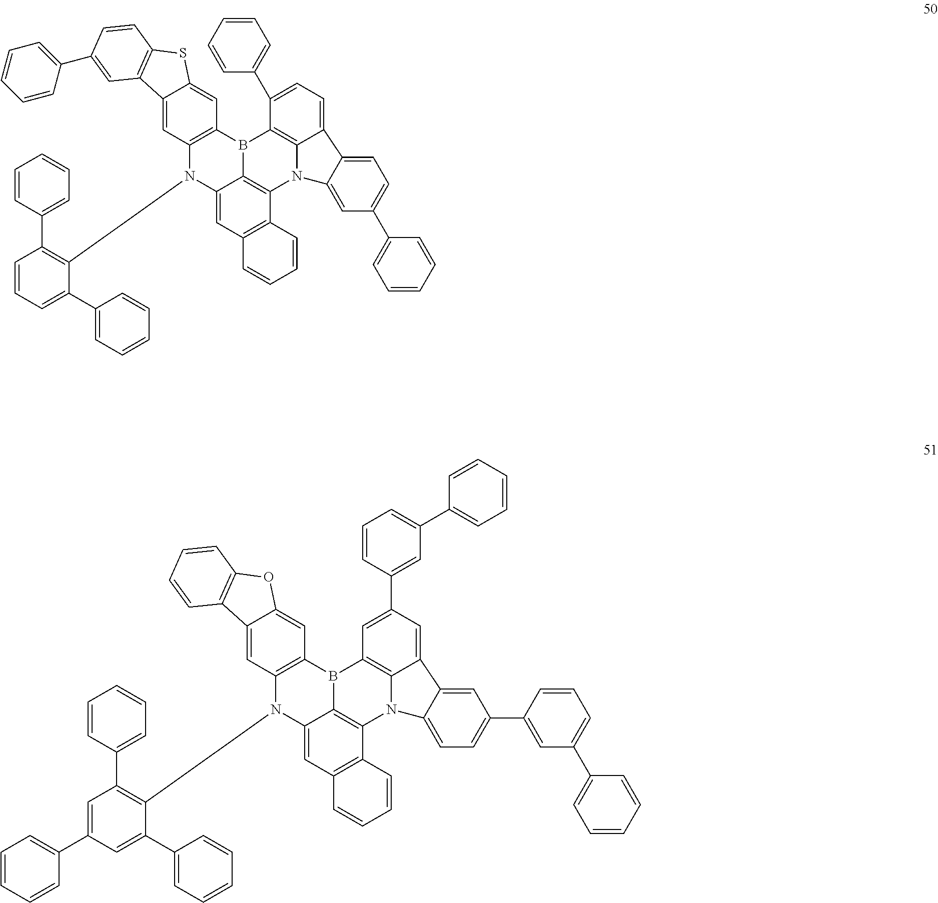 [SMILES: c1ccc(-c2ccc3sc4cc5c(cc4c3c2)N(c2c(-c3ccccc3)cccc2-c2ccccc2)c2cc3ccccc3c3c2B5c2c(-c4ccccc4)ccc4c5ccc(-c6ccccc6)cc5n-3c24)cc1 ; c1ccc(-c2cccc(-c3ccc4c(c3)c3cc(-c5cccc(-c6ccccc6)c5)cc5c3n4-c3c4c(cc6ccccc36)N(c3c(-c6ccccc6)cc(-c6ccccc6)cc3-c3ccccc3)c3cc6c(cc3B45)oc3ccccc36)c2)cc1] 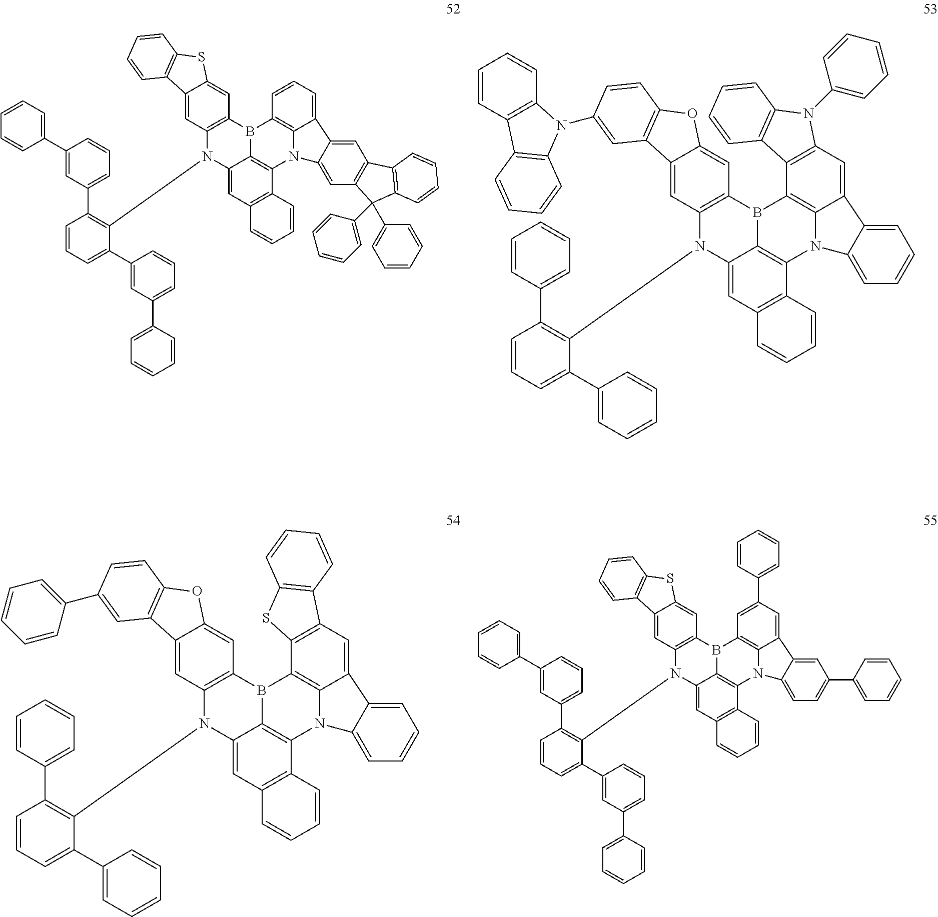 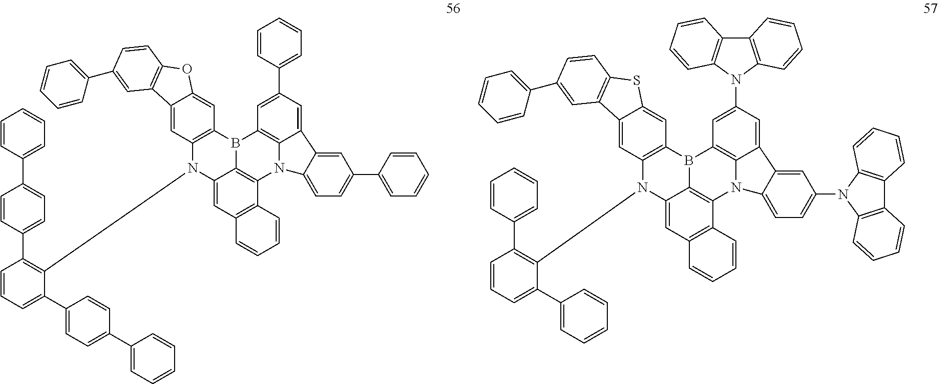 [SMILES: c1ccc(-c2ccc(-c3cccc(-c4ccc(-c5ccccc5)cc4)c3N3c4cc5c(cc4B4c6c3cc3ccccc3c6-n3c6ccc(-c7ccccc7)cc6c6cc(-c7ccccc7)cc4c63)oc3ccc(-c4ccccc4)cc35)cc2)cc1 ; c1ccc(-c2ccc3sc4cc5c(cc4c3c2)N(c2c(-c3ccccc3)cccc2-c2ccccc2)c2cc3ccccc3c3c2B5c2cc(-n4c5ccccc5c5ccccc54)cc4c5cc(-n6c7ccccc7c7ccccc76)ccc5n-3c24)cc1] 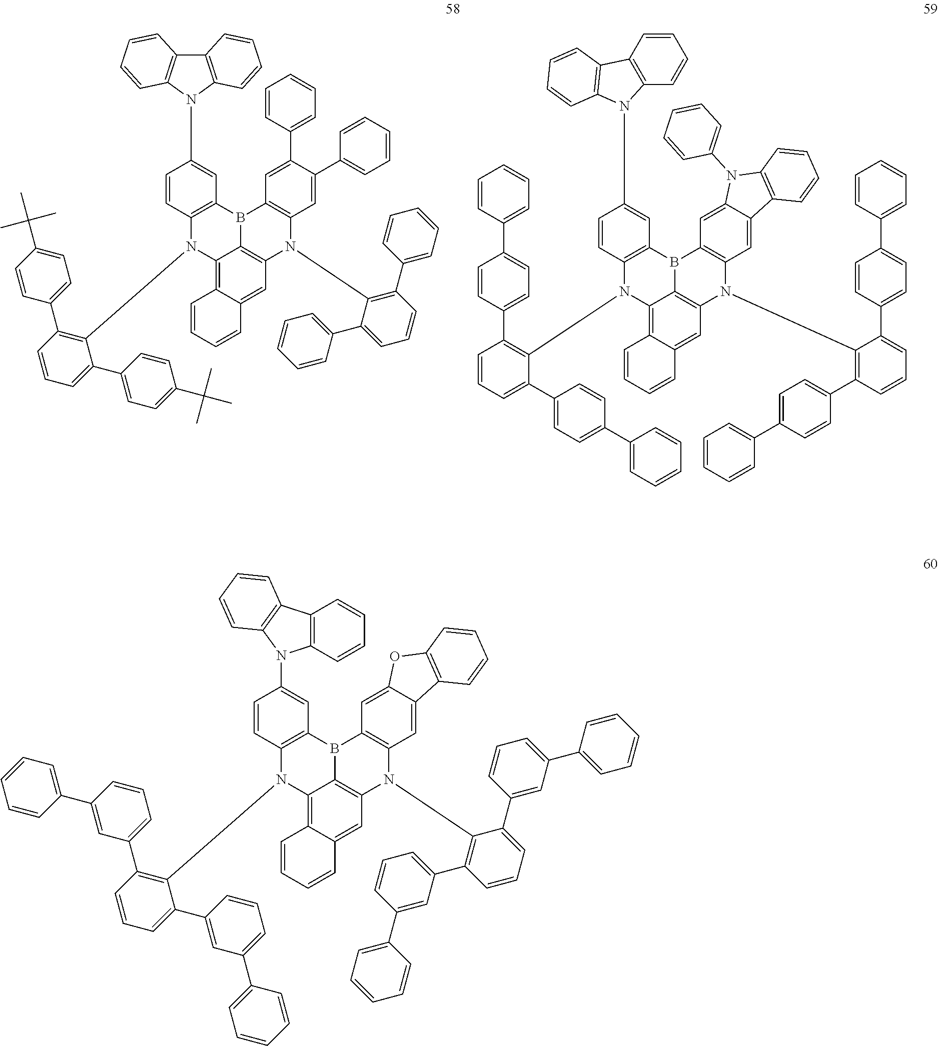 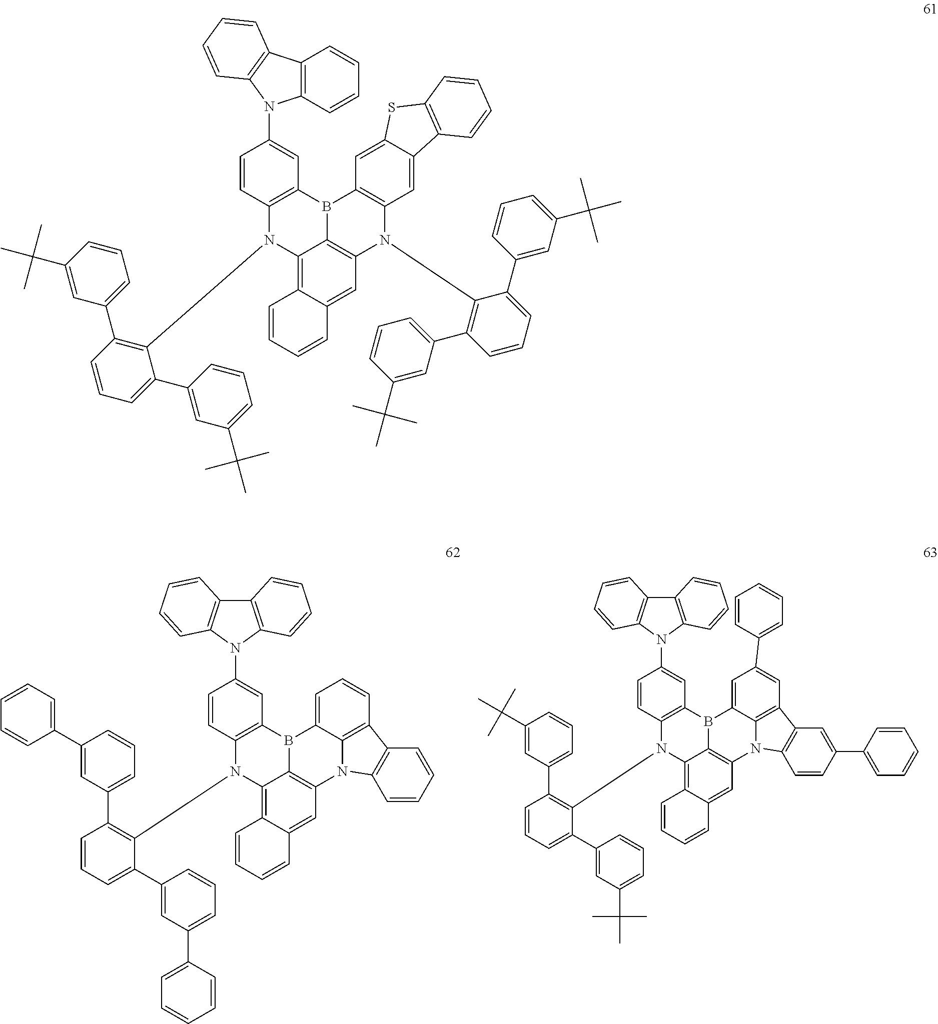 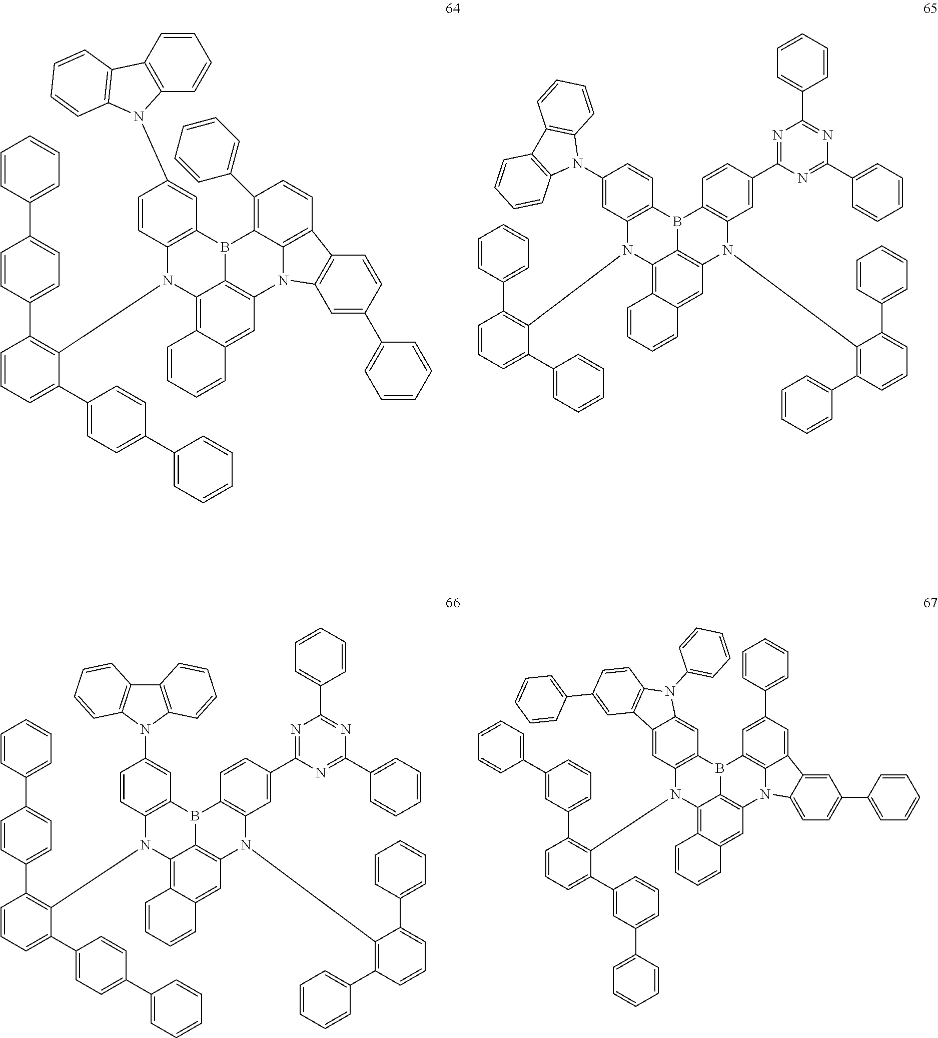 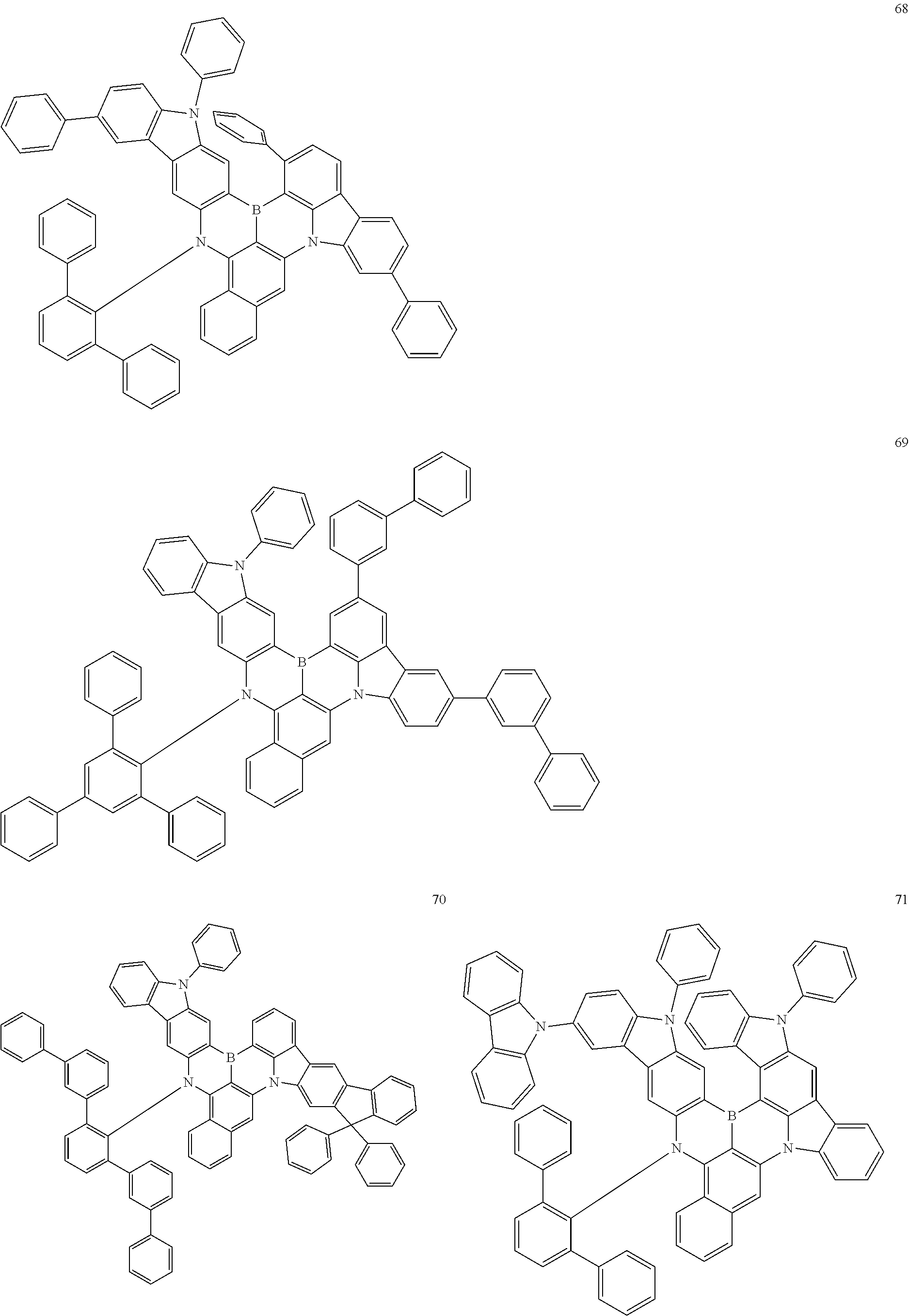 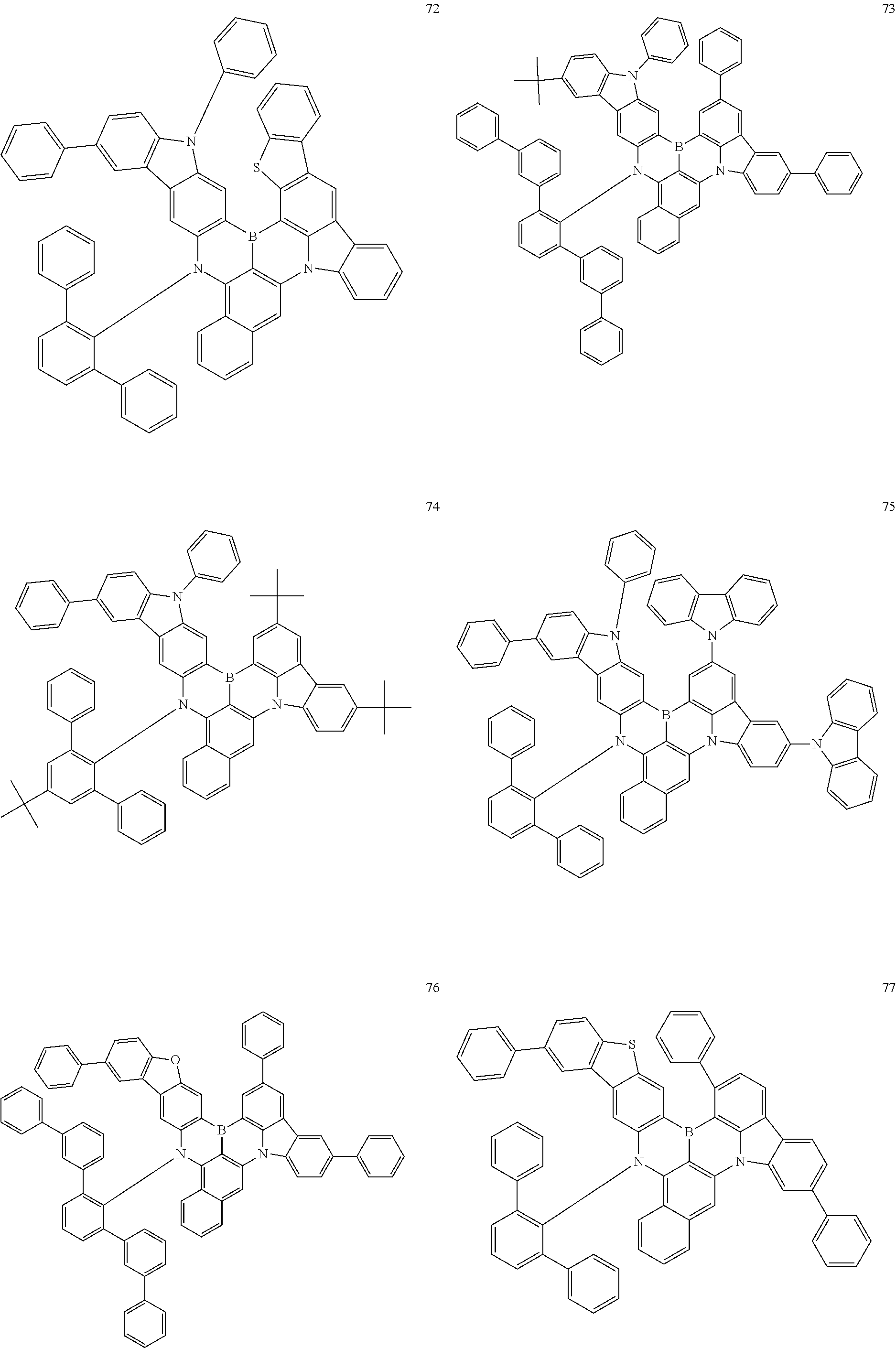 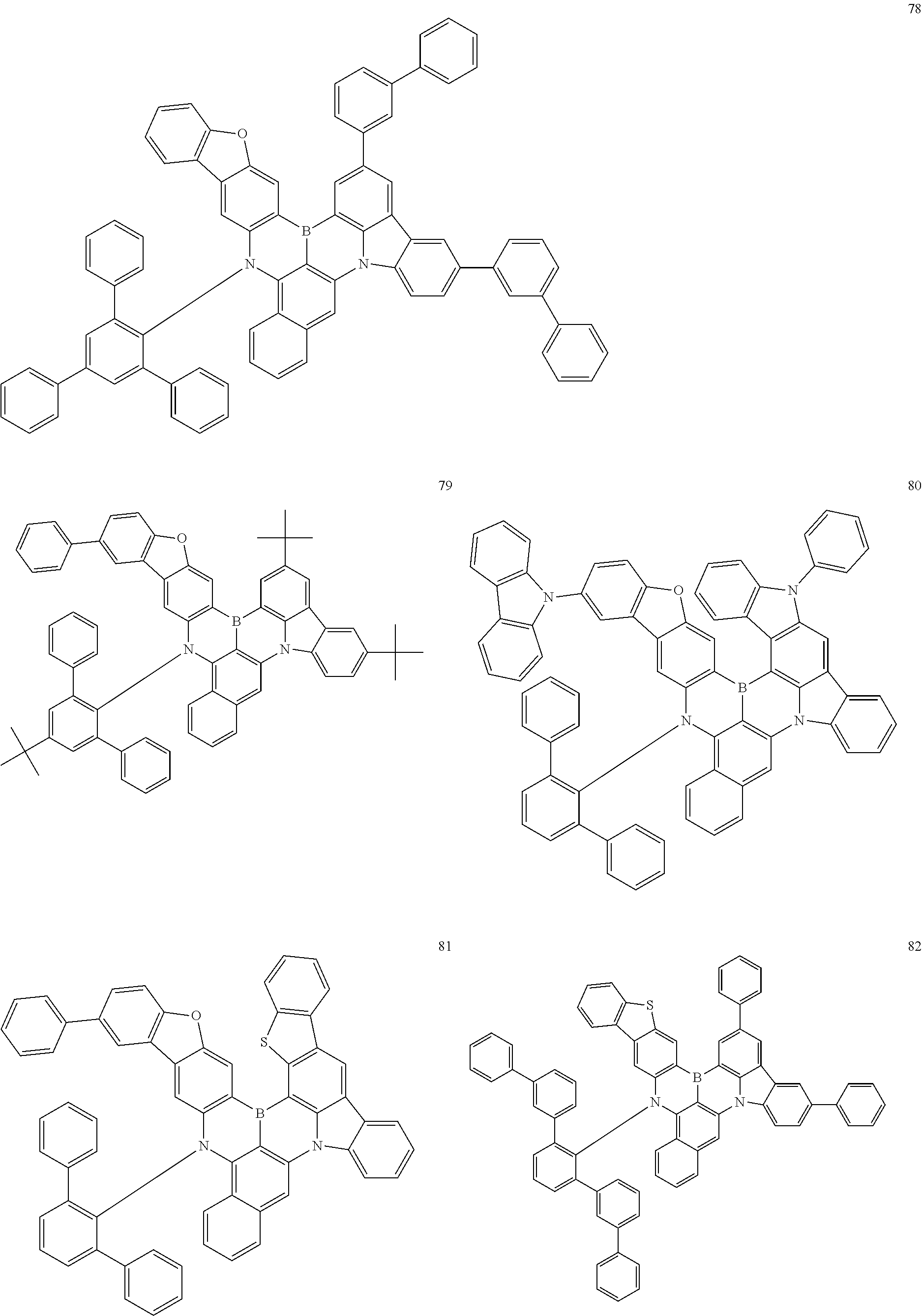 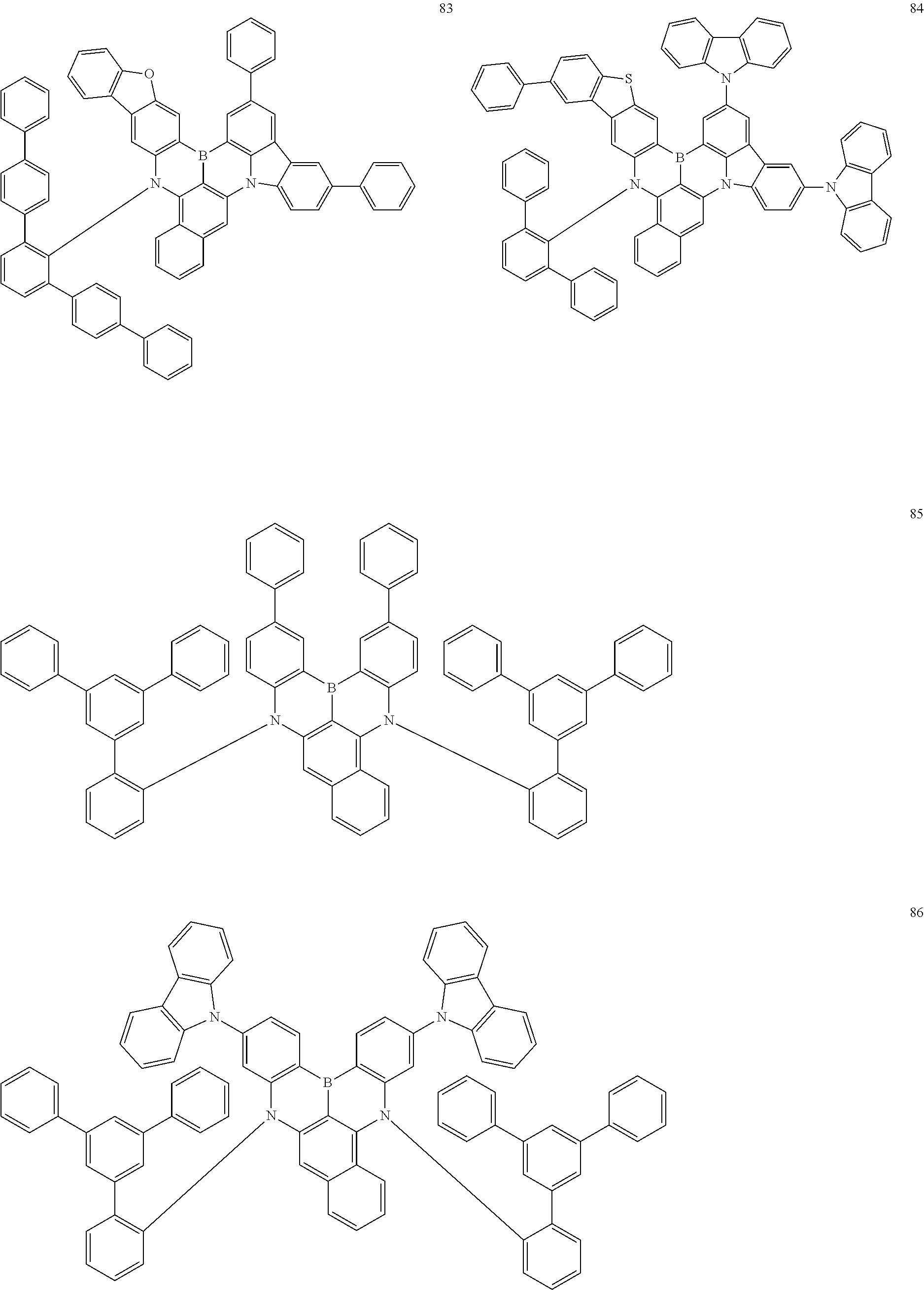 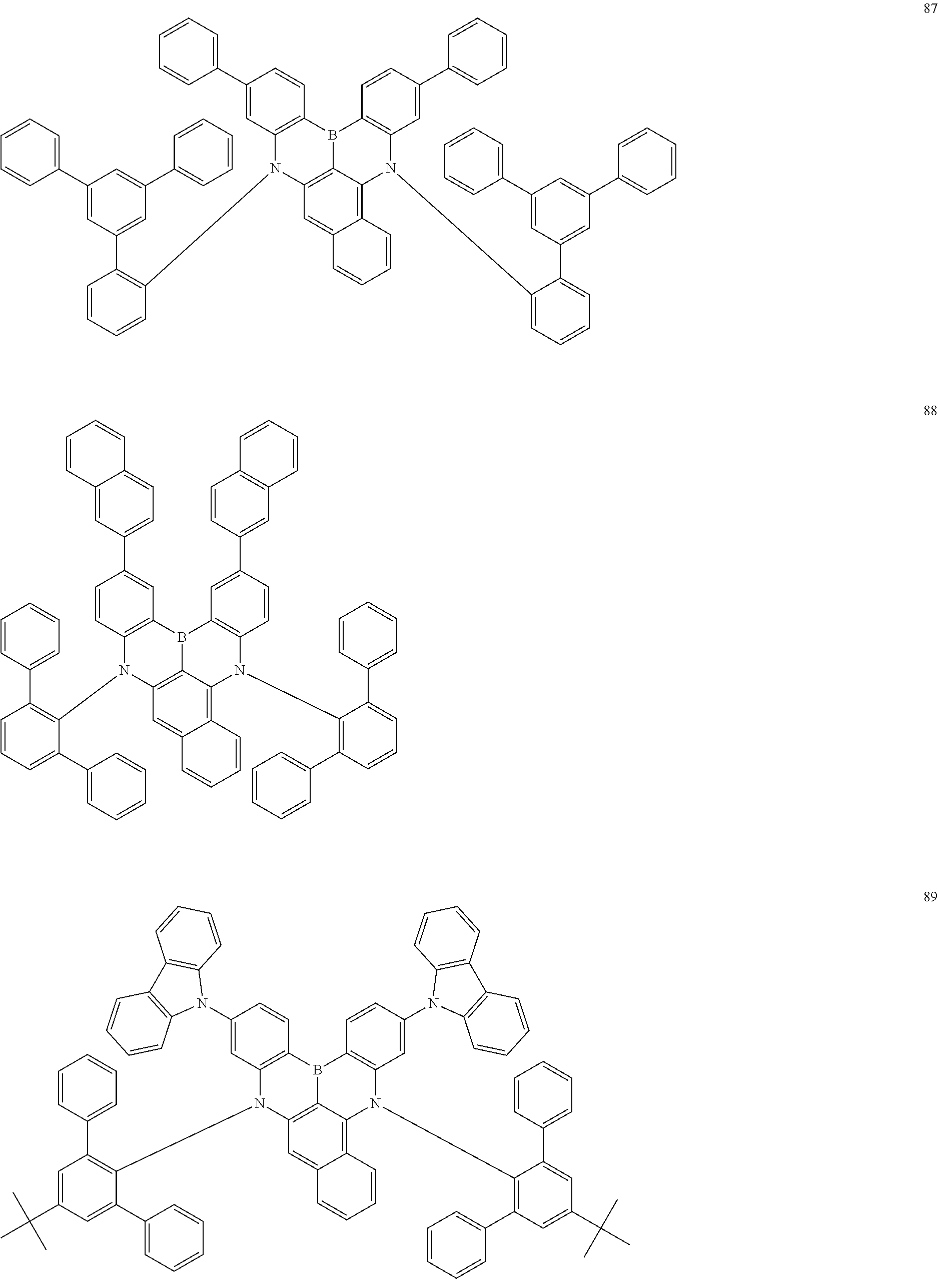 [SMILES: c1ccc(-c2cc(-c3ccccc3)cc(-c3ccccc3N3c4cc(-c5ccccc5)ccc4B4c5ccc(-c6ccccc6)cc5N(c5ccccc5-c5cc(-c6ccccc6)cc(-c6ccccc6)c5)c5c4c3cc3ccccc53)c2)cc1 ; c1ccc(-c2cccc(-c3ccccc3)c2N2c3ccc(-c4ccc5ccccc5c4)cc3B3c4cc(-c5ccc6ccccc6c5)ccc4N(c4c(-c5ccccc5)cccc4-c4ccccc4)c4c3c2cc2ccccc42)cc1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccccc4)c4c3c2cc2ccccc42)c(-c2ccccc2)c1] 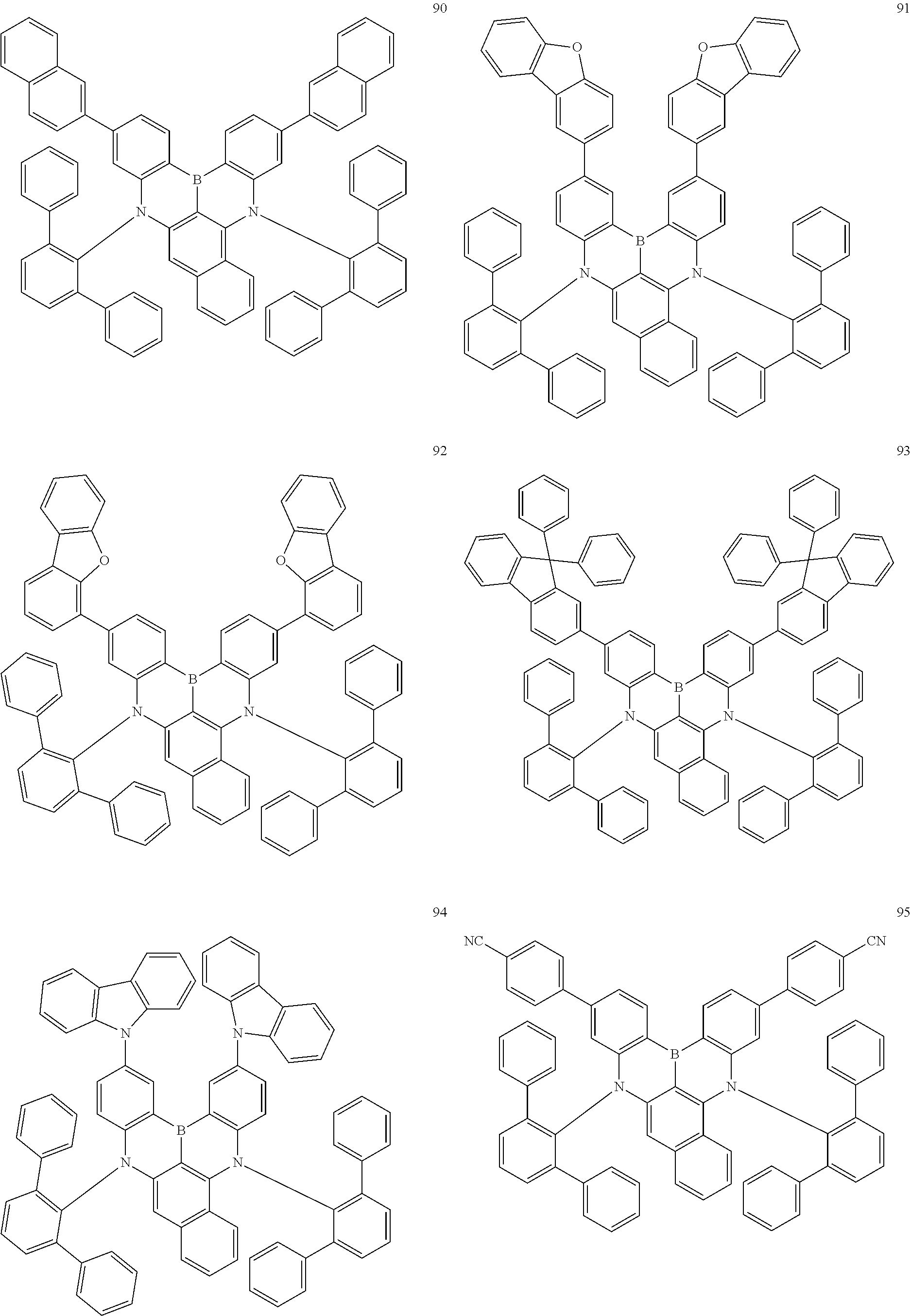 [chemical structure]
